(19) United States
(12) Patent Application Publication
(10) Pub. No.: US 2026/0068425 A1
(43) Pub. Date: Mar. 5, 2026

(54) LIGHT-EMITTING ELEMENT, FUSED POLYCYCLIC COMPOUND FOR LIGHT-EMITTING ELEMENT, AND DISPLAY DEVICE INCLUDING THE LIGHT-EMITTING ELEMENT

(71) Applicant: Samsung Display Co., Ltd., Yongin-si (KR)

(72) Inventors: MINJUNG JUNG, Yongin-si (KR); TAEIL KIM, Yongin-si (KR); JUNHA PARK, Yongin-si (KR); MinJae SUNG, Yongin-si (KR); MUN-KI SIM, Yongin-si (KR); Giwoong HAN, Yongin-si (KR); Seonhyoung HUR, Yongin-si (KR)

(73) Assignee: Samsung Display Co., Ltd., Yongin-si (KR)

(21) Appl. No.: 19/312,398

(22) Filed: Aug. 28, 2025

(30) Foreign Application Priority Data
Aug. 30, 2024 (KR) 10-2024-0118071

(51) Int. Cl. H10K 50/12; C09K 11/06; H10K 85/30; H10K 85/40; H10K 85/60; H10K 101/25

(52) U.S. Cl. CPC H10K 50/121; C09K 11/06; H10K 85/342; H10K 85/346; H10K 85/40; H10K 85/623; H10K 85/626; H10K 85/633; H10K 85/636; H10K 85/654; H10K 85/6572; H10K 85/6574; H10K 85/6576; H10K 85/658; H10K 2101/25

(57) ABSTRACT

Embodiments provide a light-emitting element that includes a fused polycyclic compound, an electronic device that includes the light-emitting element, and the fused polycyclic compound. The light-emitting element includes a first electrode, a second electrode disposed on the first electrode, and an emission layer disposed between the first electrode and the second electrode, wherein the emission layer includes the fused polycyclic compound. The fused polycyclic compound is represented by Formula 1, which is explained in the specification:

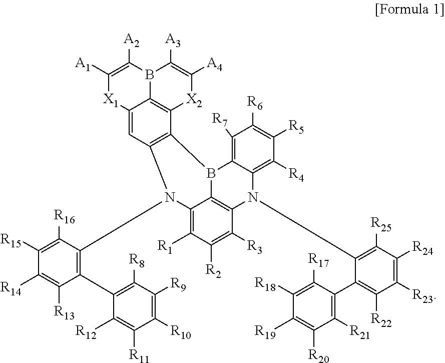

### CROSS-REFERENCE TO RELATED APPLICATION(S)

This application claims priority to and benefits of Korean Patent Application No. 10-2024-0118071 under 35 U.S.C. § 119, filed on Aug. 30, 2024, in the Korean Intellectual Property Office, the entire contents of which are incorporated herein by reference.

### BACKGROUND

### 1. Technical Field

The disclosure relates to a light-emitting element, a fused polycyclic compound used for the light-emitting element, and an electronic device including the light-emitting element.

### 2. Description of the Related Art

Ongoing development continues for organic electroluminescence display devices as image display devices. In contrast to liquid display devices, organic electroluminescence display devices are so-called self-emissive display devices in which holes and electrons respectively injected from a first electrode and a second electrode recombine in an emission layer, so that in the emission layer, an emission material that includes an organic compound emits light to achieve display.

In the application of an organic electroluminescence light-emitting element to display devices, there is a persistent demand for improvements in organic electroluminescence light-emitting elements having low driving voltage, high luminous efficiency, long lifespan, and the like. Thus, continuous development is required on materials for a light-emitting element that are capable of stably achieving such characteristics.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light-emitting element having improved emission efficiency and long lifespan.

The disclosure also provides a fused polycyclic compound for improving the emission efficiency and lifespan of the light-emitting element.

The disclosure also provides an electronic device having excellent display quality by including a light-emitting element that has improved emission efficiency and lifespan.

According to an embodiment, a light-emitting element may include a first electrode, a second electrode disposed on the first electrode, and an emission layer disposed between the first electrode and the second electrode, wherein the emission layer includes a first compound represented by Formula 1:

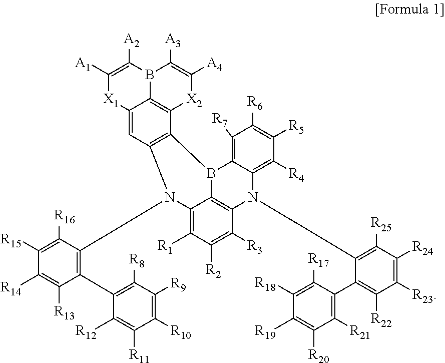

In Formula 1, X₁ and X₂ may each independently be O, S, Se, Te, N(R₂₆), or Si(R₂₇)(R₂₈). In Formula 1, R₁ to R₂₈ may each independently be a hydrogen atom, a deuterium atom, a halogen atom, a cyano group, a nitro group, a substituted or unsubstituted silyl group, a substituted or unsubstituted oxy group, a substituted or unsubstituted amine group, a substituted or unsubstituted alkyl group having 1 to 60 carbons, a substituted or unsubstituted cycloalkyl group having 3 to 60 ring-forming carbons, a substituted or unsubstituted alkenyl group having 2 to 60 carbons, a substituted or unsubstituted aryl group having 6 to 60 ring-forming carbons, or a substituted or unsubstituted heteroaryl group having 2 to 60 ring-forming carbons, or bonded to an adjacent group to form a ring; and at least one of R₁₆ and R₂₅ may each independently be a substituted or unsubstituted phenyl group. In Formula 1, at least one of a pair of A₁ and A₂ and a pair of A₃ and A₄ may each independently be bonded to a first substituent represented by Formula S-1; and the remainder of a pair of A₁ and A₂ and a pair of A₃ and A₄ that is not bonded to the first substituent represented by Formula S-1 may be bonded to a second substituent represented by Formula S-2:

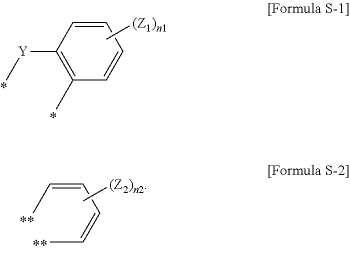

In Formula S-1, Y may be O, S, Se, Te, N(Rₛ₁), or Si(Rₛ₂)(Rₛ₃). In Formula S-1 and Formula S-2, Rₛ₁ to Rₛ₃, Z₁, and Z₂ may each independently be a hydrogen atom, a deuterium atom, a halogen atom, a cyano group, a nitro group, a substituted or unsubstituted silyl group, a substituted or unsubstituted oxy group, a substituted or unsubstituted amine group, a substituted or unsubstituted alkyl group having 1 to 60 carbons, a substituted or unsubstituted cycloalkyl group having 3 to 60 ring-forming carbons, a substituted or unsubstituted alkenyl group having 2 to 60 carbons, a substituted or unsubstituted aryl group having 6 to 60 ring-forming carbons, or a substituted or unsubstituted heteroaryl group having 2 to 60 ring-forming carbons, or bonded to an adjacent group to form a ring; n1 and n2 may each independently be an integer from 0 to 4; and *- and **- each represents a bond to the pair of A₁ and A₂ or the pair of A₃ and A₄ in Formula 1.

In an embodiment, the first compound may be represented by one of Formula 2 to Formula 4:

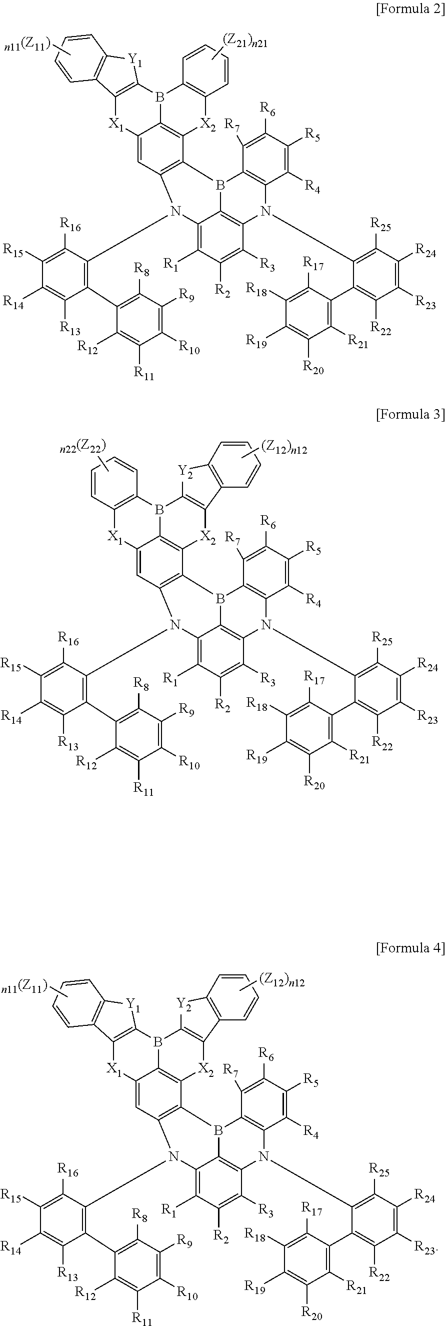

In Formula 2 to Formula 4, Y₁ and Y₂ may each independently be O, S, Se, Te, N(R_{y1}), or Si(R_{y2})(R_{y3}); Z₁₁, Z₁₂, Z₂₁, Z₂₂, R_{y1}, R_{y2}, and R_{y3} may each independently be a hydrogen atom, a deuterium atom, a halogen atom, a cyano group, a nitro group, a substituted or unsubstituted silyl group, a substituted or unsubstituted oxy group, a substituted or unsubstituted amine group, a substituted or unsubstituted alkyl group having 1 to 60 carbons, a substituted or unsubstituted cycloalkyl group having 3 to 60 ring-forming carbons, a substituted or unsubstituted alkenyl group having 2 to 60 carbons, a substituted or unsubstituted aryl group having 6 to 60 ring-forming carbons, or a substituted or unsubstituted heteroaryl group having 2 to 60 ring-forming carbons, or bonded to an adjacent group to form a ring; n11, n12, n21, and n22 may each independently be an integer from 0 to 4; and X₁, X₂, and R₁ to R₂₅ are the same as defined in Formula 1.

In an embodiment, the first compound represented by Formula 2 may be represented by one of Formula 2-1 to Formula 2-3:

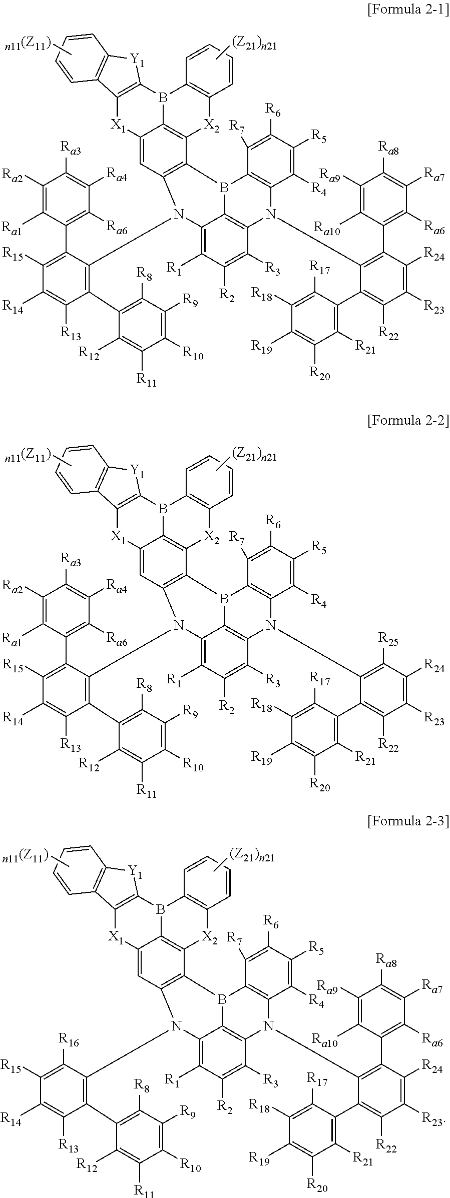

In Formula 2-1 to Formula 2-3, Rₐ₁ to Rₐ₁₀, R_{b1} to R_{b5}, and R_{b1} to R_{b5} may each independently be a hydrogen atom, a deuterium atom, a substituted or unsubstituted alkyl group having 1 to 30 carbons, or a substituted or unsubstituted aryl group having 6 to 30 ring-forming carbons; X₁, X₂, and R₁ to R₂₅ are the same as defined in Formula 1; and Y₁, Z₁₁, Z₂₁, n11, and n21 are the same as defined in Formula 2.

In an embodiment, the first compound represented by Formula 3 may be represented by one of Formula 3-1 to Formula 3-3:

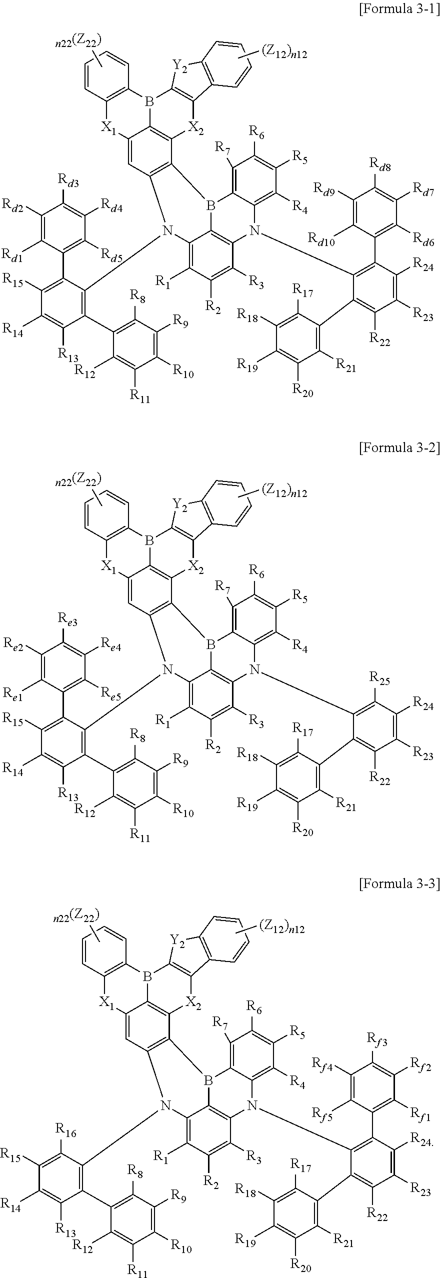

In Formula 3-1 to Formula 3-3, R_{d1} to R_{d10}, Rₑ₁ to Rₑ₅, and R_{f1} to R_{f5} may each independently be a hydrogen atom, a deuterium atom, a substituted or unsubstituted alkyl group having 1 to 30 carbons, or a substituted or unsubstituted aryl group having 6 to 30 ring-forming carbons; X₁, X₂, and R₁ to R₂₅ are the same as defined in Formula 1; and Y₂, Z₁₂, Z₂₂, n12, and n22 are the same as defined Formula 3.

In an embodiment, the first compound represented by Formula 4 may be represented by one of Formula 4-1 to Formula 4-3:

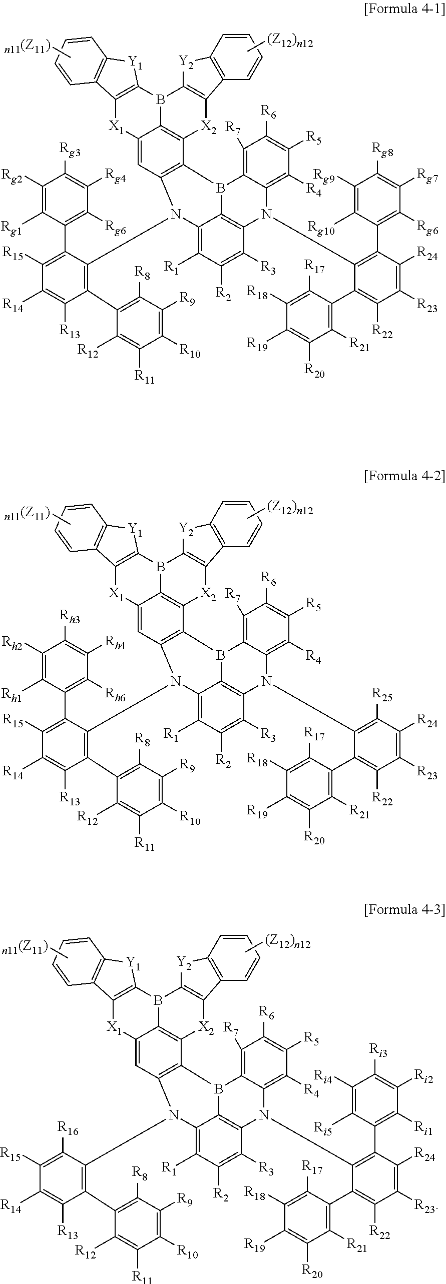

In Formula 4-1 to Formula 4-3, R_{g1} to R_{g10}, Rₕ₁ to Rₕ₁₅, and Rᵢ₁ to Rᵢ₅ may each independently be a hydrogen atom, a deuterium atom, a substituted or unsubstituted alkyl group having 1 to 30 carbons, or a substituted or unsubstituted aryl group having 6 to 30 ring-forming carbons; X₁, X₂, and R₁ to R₂₅ are the same as defined in Formula 1; and Y₁, Y₂, Z₁₁, Z₁₂, n11, and n12 are the same as defined in Formula 4.

In an embodiment, at least one of X₁ and X₂ may be O; and the remainder of X₁ and X₂ that is not O may be S, Se, Te, N(R₂₆), or Si(R₂₇)(R₂₈).

In an embodiment, R₄ to R₇ may each independently be a deuterium atom, a substituted or unsubstituted amine group, a substituted or unsubstituted t-butyl group, a substituted or unsubstituted phenyl group, or a substituted or unsubstituted carbazole group.

In an embodiment, Z₁ may be a hydrogen atom, a deuterium atom, a substituted or unsubstituted methyl group, a substituted or unsubstituted t-butyl group, a substituted or unsubstituted phenyl group, a substituted or unsubstituted carbazole group, or a substituted or unsubstituted diphenylamine group.

In an embodiment, Z₂ may be a hydrogen atom, a deuterium atom, a substituted or unsubstituted t-butyl group, a substituted or unsubstituted phenyl group, a substituted or unsubstituted carbazole group, a substituted or unsubstituted diphenylamine group, or a substituted or unsubstituted dibiphenylamine group.

In an embodiment, the first compound may include at least one deuterium atom as a substituent.

In an embodiment, the emission layer may further include at least one of a second compound represented by Formula HT-1, a third compound represented by Formula ET-1, and a fourth compound represented by Formula D-1, which are explained below.

In an embodiment, the emission layer may further include a compound represented by Formula E-1, which is explained below.

In an embodiment, the first compound may include at least one compound selected from Compound Group 1, which is explained below.

According to an embodiment, a fused polycyclic compound may be represented by Formula 1, which is explained herein.

In an embodiment, the fused polycyclic compound may be represented by one of Formula 2 to Formula 4, which are explained herein.

In an embodiment, the fused polycyclic compound may be represented by one of Formula 2-1 to Formula 2-3, which are explained herein.

In an embodiment, the fused polycyclic compound may be represented by one of Formula 3-1 to Formula 3-3, which are explained herein.

In an embodiment, the fused polycyclic compound may be represented by one of Formula 4-1 to Formula 4-3, which are explained herein.

In an embodiment, R₁₆ and R₂₅ may each independently be a substituted or unsubstituted phenyl group.

In an embodiment, the fused polycyclic compound may be selected from Compound Group 1, which is explained below.

According to an embodiment, an electronic device may include a display device, and the display device may include a circuit layer disposed on a base layer and a display element layer disposed on the circuit layer. The display element layer may include a light-emitting element; the light-emitting element may include a first electrode, a second electrode disposed on the first electrode, and an emission layer disposed between the first electrode and the second electrode; and the emission layer may include a fused polycyclic compound represented by Formula 1, which is explained herein.

In an embodiment, the electronic device may be a television, a monitor, a game console, a personal computer, a personal digital assistant, a laptop computer, a display device for vehicles, a mobile electronic device, or a camera.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a block diagram of an electronic device according to an embodiment;

FIG. 2 shows schematic diagrams of electronic devices according to embodiments;

FIG. 3 is a schematic plan view of a display device according to an embodiment;

FIG. 4 is a schematic cross-sectional view of a display device according to an embodiment, illustrating a portion taken along virtual line I-I′ in FIG. 3;

FIG. 5 is a schematic cross-sectional view of a light-emitting element according to an embodiment;

FIG. 6 is a schematic cross-sectional view of a light-emitting element according to an embodiment;

FIG. 7 is a schematic cross-sectional view of a light-emitting element according to an embodiment;

FIG. 8 is a schematic cross-sectional view of a light-emitting element according to an embodiment;

FIG. 9 is a schematic cross-sectional view of a display device according to an embodiment;

FIG. 10 is a schematic cross-sectional view of a display device according to an embodiment;

FIG. 11 is a schematic cross-sectional view of a display device according to an embodiment;

FIG. 12 is a schematic cross-sectional view of a display device according to an embodiment; and

FIG. 13 is a schematic diagram of an interior of a vehicle in which a display device according to an embodiment is disposed.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/of”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the term “bonded to an adjacent group to form a ring” may refer to a group that is bonded to an adjacent group to form a substituted or unsubstituted hydrocarbon ring or a substituted or unsubstituted heterocycle. A hydrocarbon ring may be aliphatic or aromatic. A heterocycle may be aliphatic or aromatic. A hydrocarbon ring and a heterocycle may each independently be monocyclic or polycyclic. A ring that is formed by adjacent groups being bonded to each other may itself be connected to another ring to form a spiro structure.

In the specification, the term “adjacent group” may be interpreted as a substituent that is substituted for an atom which is directly linked to an atom substituted with a corresponding substituent, as another substituent that is substituted for an atom which is substituted with a corresponding substituent, or as a substituent that is sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, and an iodine atom.

In the specification, an alkyl group may be linear or branched. The number of carbons in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, a cycloalkyl group may be a cyclic alkyl group. The number of carbons in a cycloalkyl group may be 3 to 60, 3 to 50, 3 to 30, 3 to 20, or 3 to 10. Examples of a cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but embodiments are not limited thereto.

In the specification, an alkenyl group may be a hydrocarbon group that includes at least one carbon-carbon double bond in the middle or at a terminus of an alkyl group having 2 or more carbon atoms. An alkenyl group may be linear or branched. The number of carbon atoms in an alkenyl group is not particularly limited, and may be 2 to 60, 2 to 30, 2 to 20, or 2 to 10. Examples of an alkenyl group may include a vinyl group, a 1-butenyl group, a 1-pentenyl group, a 1,3-butadienyl group, a styrenyl group, a styryl vinyl group, etc., but embodiments are not limited thereto.

In the specification, an alkynyl group may be a hydrocarbon group that includes at least one carbon-carbon triple bond in the middle or at a terminus of an alkyl group having 2 or more carbon atoms. An alkynyl group may be linear or branched. The number of carbon atoms in an alkynyl group is not particularly limited, and may be 2 to 60, 2 to 30, 2 to 20, or 2 to 10.

Examples of an alkynyl group may include an ethynyl group, a propynyl group, etc., but embodiments are not limited thereto.

In the specification, a hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the specification, an aryl group may be any functional group or substituent derived from an aromatic hydrocarbon ring. An aryl group may be monocyclic or polycyclic. The number of ring-forming carbon atoms in an aryl group may be 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorenyl group may be substituted, and two substituents may be bonded to each other to form a spiro structure. Examples of a substituted fluorenyl group may include the groups shown below. However, embodiments are not limited thereto.

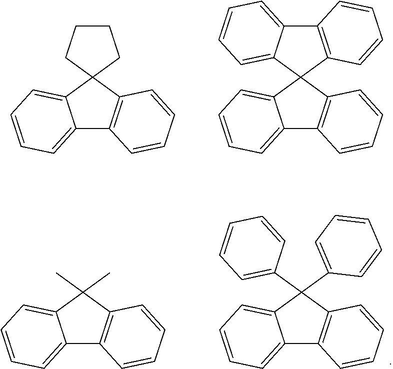

In the specification, a heterocyclic group may be any functional group or substituent derived from a ring that includes at least one of B, O, N, P, Si, S, Se, and Te as a heteroatom. A heterocyclic group may be aliphatic or aromatic. An aromatic heterocyclic group may be a heteroaryl group. An aliphatic heterocycle and an aromatic heterocycle may each independently be monocyclic or polycyclic.

If a heterocyclic group includes two or more heteroatoms, the two or more heteroatoms may be the same as or different from each other. The number of ring-forming carbon atoms in a heterocyclic group may be 2 to 30, 2 to 20, or 2 to 10.

Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of an aryl group may be applied to an arylene group, except that an arylene group is a divalent group. In the specification, the above description of a heteroaryl group may be applied to a heteroarylene group, except that a heteroarylene group is a divalent group.

In the specification, a silyl group may be an alkylsilyl group or an arylsilyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, the number of carbon atoms in a carbonyl group is not particularly limited, and may be 1 to 40, 1 to 30, or 1 to 20. For example, a carbonyl group may include one of the following structures, but embodiments are not limited thereto.

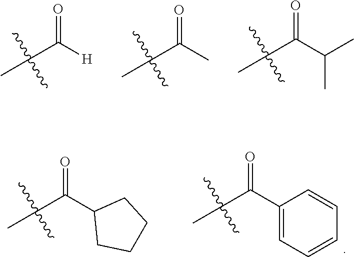

In the specification, the number of carbon atoms in a sulfinyl group or a sulfonyl group is not particularly limited, and may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkylthio group or an arylthio group. A thio group may be a sulfur atom that is bonded to an alkyl group or an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments are not limited thereto.

In the specification, an oxy group may be an oxygen atom that is bonded to an alkyl group or an aryl group as defined above. An oxy group may be an alkoxy group or an aryl oxy group. An alkoxy group may be linear, branched, or cyclic. The number of carbon atoms in an alkoxy group is not particularly limited, and may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a boron group may be a boron atom that is bonded to an alkyl group or an aryl group as defined above. A boron group may be an alkyl boron group or an aryl boron group. Examples of a boron group may include a dimethylboron group, a trimethylboron group, a t-butyldimethylboron group, a diphenylboron group, a phenylboron group, etc., but embodiments are not limited thereto.

In the specification, the number of carbon atoms in an amine group is not particularly limited, and may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, etc., but embodiments are not limited thereto.

In the specification, an alkyl group within an alkylthio group, an alkylsulfoxy group, an alkylaryl group, an alkylamino group, an alkyl boron group, an alkyl silyl group, or an alkyl amine group may be the same as an example of an alkyl group as described above.

In the specification, an aryl group within an aryloxy group, an arylthio group, an arylsulfoxy group, an arylamino group, an arylboron group, an arylsilyl group, or an arylamine group may be the same as an example of an aryl group as described above.

In the specification, a direct linkage may be a single bond.

In the specification, the symbols

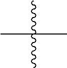

and -* each represent a bond to a neighboring atom in a corresponding formula or moiety.

Hereinafter, embodiments will be described with reference to the accompanying drawings.

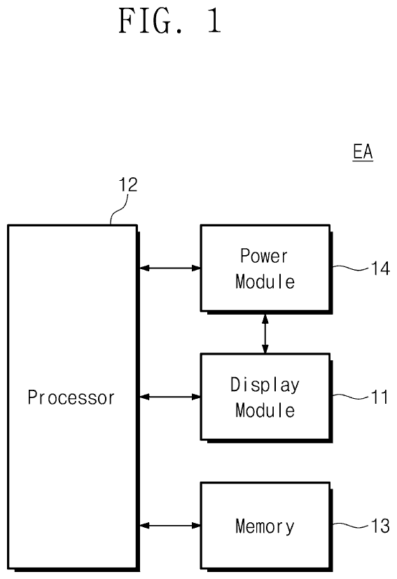

FIG. 1 is a block diagram of an electronic device according to an embodiment. Referring to FIG. 1, an electronic device EA according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and information for the operation of the processor 12 or the display module 11. When the processor 12 executes an application stored in the memory 13, an image data signal and/or an input control signal may be transmitted to the display module 11, and the display module 11 may process the provided signal and output image information through a display screen.

The power module 14 may include a power supply module such as a power adapter or a battery device, and a power conversion module which converts power supplied by the power supply module to generate power required for an operation of the electronic device EA.

At least one module of the electronic device EA described above may be included in the display device according to an embodiment as described herein. In embodiments, some individual components that are functionally included in a module may be included in the display device, and other components may be provided separately from the display device. For example, the display device may include the display module 11, and the processor 12, the memory 13, and the power module 14 may be provided within the electronic device EA, apart from the display device.

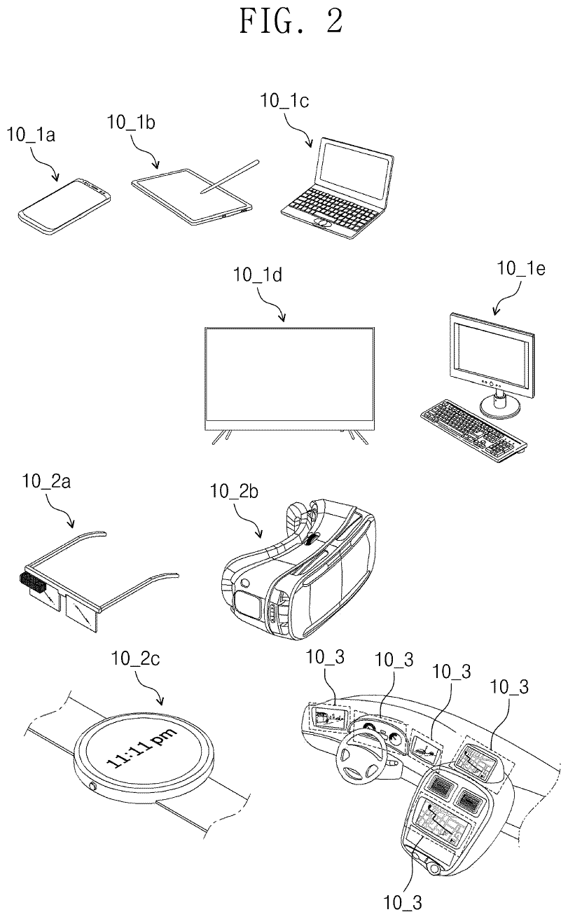

FIG. 2 shows schematic diagrams of electronic devices according to various embodiments.

Referring to FIG. 2, examples of electronic devices that include a display device according to an embodiment may include electronic devices for displaying images, such as a smartphone 10_1a, a tablet computer 10_1b, a laptop computer 10_1c, a television 10_1d, and a desktop monitor 10_1e. Further examples of electronic devices that include a display device according to an embodiment may include wearable electronic devices that include a display module such as smart glasses 10_2a, a head mounted display 10_2b, and a smart watch 10_2c, as well as vehicle electronic devices 10_3 that include display modules such as a vehicle instrument panel, a center fascia, a center information display (CID) disposed on a dashboard, and a mirror display.

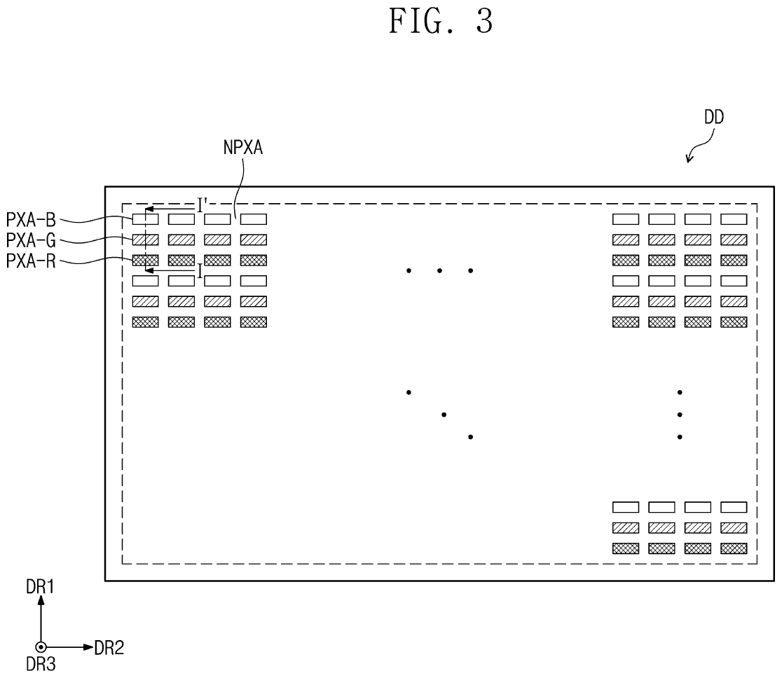

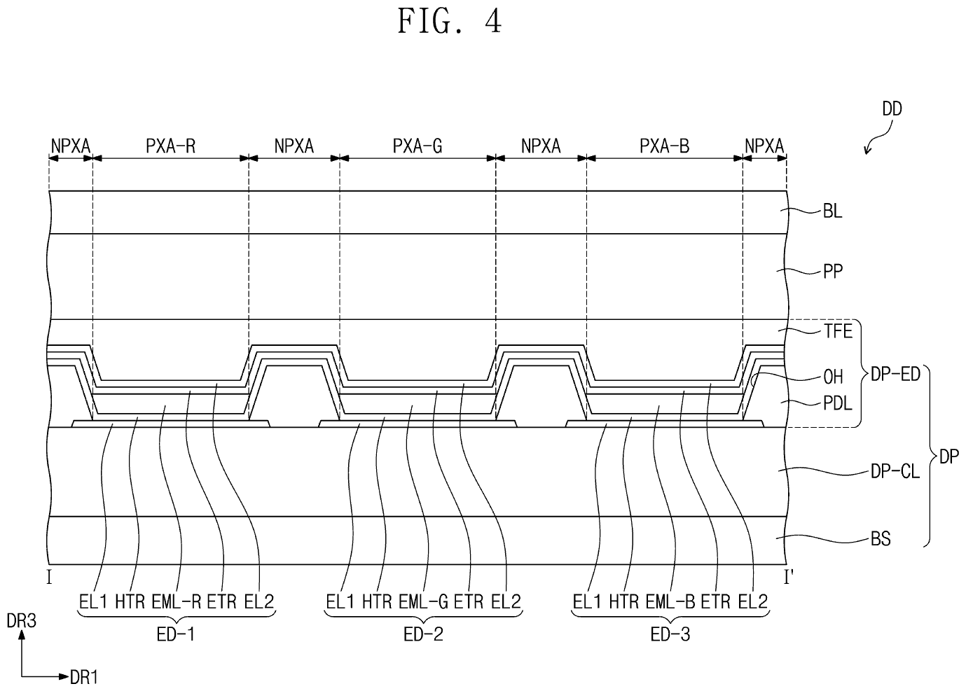

FIG. 3 is a schematic plan view of a display device DD according to an embodiment. FIG. 4 is a schematic cross-sectional view of the display device DD. FIG. 4 is a schematic cross-sectional view of a portion taken along virtual line I-I′ in FIG. 3. The display device DD according to an embodiment may be included in the electronic device EA as described above. The display device DD may be a part that provides an image in the electronic device EA.

The display device DD may include a display panel DP and an optical layer PP disposed on the display panel DP. The display panel DP includes light-emitting elements ED-1, ED-2, and ED-3. The display device DD may include multiples of each of the light-emitting elements ED-1, ED-2, and ED-3. The optical layer PP may be disposed on the display panel DP to control light that is reflected at the display panel DP from an external light. The optical layer PP may include, for example, a polarization layer or a color filter layer. Although not shown in the drawings, in an embodiment, the optical layer PP may be omitted from the display device DD.

A base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display device DD according to an embodiment may further include a filling layer (not shown). The filling layer (not shown) may be disposed between a display element layer DP-ED and the base substrate BL. The filling layer (not shown) may be an organic material layer. The filling layer (not shown) may include at least one of an acrylic-based resin, a silicone-based resin, and an epoxy-based resin.

The display panel DP may include a base layer BS, a circuit layer DP-CL provided on the base layer BS, and the display element layer DP-ED. The display element layer DP-ED may include a pixel defining film PDL, light-emitting elements ED-1, ED-2, and ED-3 disposed between portions of the pixel defining film PDL, and an encapsulation layer TFE disposed on the light-emitting elements ED-1, ED-2, and ED-3.

The base layer BS may provide a base surface on which the display element layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light-emitting elements ED-1, ED-2, and ED-3 of the display element layer DP-ED.

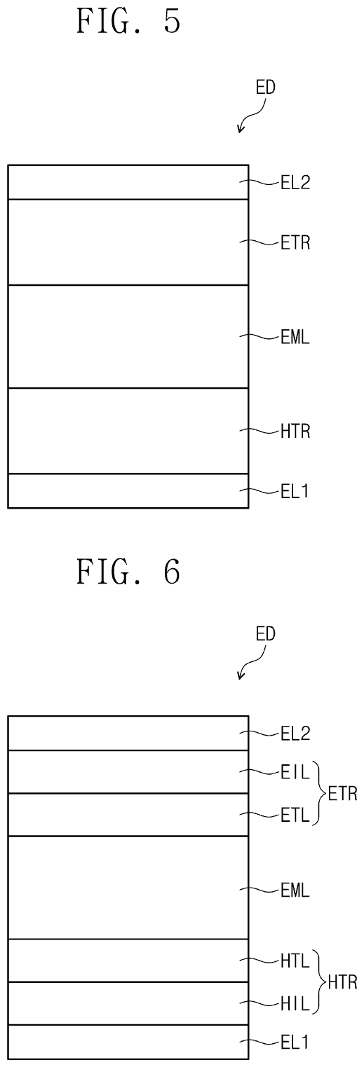

The light-emitting elements ED-1, ED-2, and ED-3 may each have a structure of a light-emitting element ED according to any one of FIGS. 5 to 8, which will be described later. The light-emitting elements ED-1, ED-2, and ED-3 may each include a first electrode EL1, a hole transport region HTR, emission layers EML-R, EML-G, and EML-B, an electron transport region ETR, and a second electrode EL2.

FIG. 4 illustrates an embodiment in which the emission layers EML-R, EML-G, and EML-B of the light-emitting elements ED-1, ED-2, and ED-3 are disposed in openings OH defined in the pixel defining film PDL, and the hole transport region HTR, the electron transport region ETR, and the second electrode EL2 are each provided as a common layer for the light-emitting elements ED-1, ED-2, and ED-3. However, embodiments are not limited thereto. Although not shown in FIG. 4, in an embodiment, the hole transport region HTR and the electron transport region ETR may each be provided by being patterned in the openings OH defined in the pixel defining film PDL. For example, in an embodiment, the hole transport region HTR, the emission layers EML-R, EML-G, and EML-B, and the electron transport region ETR of the light-emitting elements ED-1, ED-2, and ED-3 may be provided by being patterned through an inkjet printing method.

The encapsulation layer TFE may cover the light-emitting elements ED-1, ED-2, and ED-3. The encapsulation layer TFE may seal the display device layer DP-ED. The encapsulation layer TFE may be a thin film encapsulation layer. The encapsulation layer TFE may be formed of a single layer or of multiple layers. The encapsulation layer TFE may include at least one insulation layer. The encapsulation layer TFE according to an embodiment may include at least one inorganic film (hereinafter, an encapsulation-inorganic film). The encapsulation layer TFE according to an embodiment may include at least one organic film (hereinafter, an encapsulation-organic film) and at least one encapsulation-inorganic film.

The encapsulation-inorganic film protects the display element layer DP-ED from moisture and/or oxygen, and the encapsulation-organic film protects the display element layer DP-ED from foreign substances such as dust particles. The encapsulation-inorganic film may include silicon nitride, silicon oxynitride, silicon oxide, titanium oxide, aluminum oxide, or the like, but embodiments are not limited thereto. The encapsulation-organic film may include an acrylic-based compound, an epoxy-based compound, or the like. The encapsulation-organic film may include a photopolymerizable organic material, but embodiments are not limited thereto.

The encapsulation layer TFE may be disposed on the second electrode EL2 and may be disposed to fill the openings OH.

Referring to FIGS. 3 and 4, the display device DD may include non-light emitting regions NPXA and light emitting regions PXA-R, PXA-G, and PXA-B. The light emitting regions PXA-R, PXA-G, and PXA-B may each be a region that emits light respectively generated by the light-emitting elements ED-1, ED-2, and ED-3. The light emitting regions PXA-R, PXA-G, and PXA-B may be spaced apart from each other in a plan view.

The light emitting regions PXA-R, PXA-G, and PXA-B may be regions that are separated from each other by the pixel defining film PDL. The non-light emitting regions NPXA may be regions between the adjacent light emitting regions PXA-R, PXA-G, and PXA-B, and which may correspond to the pixel defining film PDL. In an embodiment, the light emitting regions PXA-R, PXA-G, and PXA-B may each correspond to a pixel. The pixel defining film PDL may separate the light-emitting elements ED-1, ED-2, and ED-3. The emission layers EML-R, EML-G, and EML-B of the light-emitting elements ED-1, ED-2, and ED-3 may be disposed in openings OH defined in the pixel defining film PDL and separated from each other.

The light emitting regions PXA-R, PXA-G, and PXA-B may be arranged into groups according to the color of light generated from the light-emitting elements ED-1, ED-2, and ED-3. In the display device DD shown in FIGS. 3 and 4, three light emitting regions PXA-R, PXA-G, and PXA-B, which respectively emit red light, green light, and blue light, are illustrated as an example. For example, the display device DD may include a red light emitting region PXA-R, a green light emitting region PXA-G, and a blue light emitting region PXA-B, which are distinct from each other.

In the display device DD according to an embodiment, the light-emitting elements ED-1, ED-2, and ED-3 may emit light having wavelengths that are different from each other. For example, in an embodiment, the display device DD may include a first light-emitting element ED-1 that emits red light, a second light-emitting element ED-2 that emits green light, and a third light-emitting element ED-3 that emits blue light. For example, the red light emitting region PXA-R, the green light emitting region PXA-G, and the blue light emitting region PXA-B of the display device DD may respectively correspond to the first light-emitting element ED-1, the second light-emitting element ED-2, and the third light-emitting element ED-3.

However, embodiments are not limited thereto, and the first to third light-emitting elements ED-1, ED-2, and ED-3 may emit light in a same wavelength range, or at least one light-emitting element may emit light in a wavelength range that is different from the remainder. For example, the first to third light-emitting elements ED-1, ED-2, and ED-3 may each emit blue light.

The light emitting regions PXA-R, PXA-G, and PXA-B in the display device DD according to an embodiment may be arranged in a stripe configuration. Referring to FIG. 3, the red light emitting regions PXA-R, the green light emitting regions PXA-G, and the blue light emitting regions PXA-B may be respectively arranged along a second directional axis DR2. In another embodiment, the red light emitting region PXA-R, the green light emitting region PXA-G, and the blue light emitting region PXA-B may be arranged in this repeating order along a first directional axis DR1.

FIGS. 3 and 4 illustrate that the light emitting regions PXA-R, PXA-G, and PXA-B all have a similar area, but embodiments are not limited thereto. In an embodiment, the light emitting regions PXA-R, PXA-G, and PXA-B may be different in size and/or shape from each other, according to a wavelength range of emitted light. The areas of the light emitting regions PXA-R, PXA-G, and PXA-B may be areas in a plan view that are defined by the first directional axis DR1 and the second directional axis DR2. A third directional axis DR3 may be perpendicular to a plane defined by the first directional axis DR1 and the second directional axis DR2.

An arrangement of the light emitting regions PXA-R, PXA-G, and PXA-B is not limited to the configuration illustrated in FIG. 3, and the order in which the red light emitting region PXA-R, the green light emitting region PXA-G, and the blue light emitting region PXA-B are arranged may be provided in various combinations, according to the display quality characteristics that are required for the display device DD. For example, the light emitting regions PXA-R, PXA-G, and PXA-B may be arranged in a pentile configuration (such as PenTile®) or in a diamond configuration (such as Diamond Pixel®).

The areas of the light emitting regions PXA-R, PXA-G, and PXA-B may be different in size from each other. For example, in an embodiment, an area of a green light emitting region PXA-G may be smaller than an area of a blue light emitting region PXA-B, but embodiments are not limited thereto.

Hereinafter, FIG. 5 to FIG. 8 are each a schematic cross-sectional view of a light-emitting element ED according to an embodiment. The light-emitting element ED according to an embodiment may include a first electrode EL1, a second electrode EL2 facing the first electrode EL1, and at least one functional layer disposed between the first electrode EL1 and the second electrode EL2. The light-emitting element ED according to an embodiment may include a fused polycyclic compound according to an embodiment, which will be described below, in the at least one functional layer.

The light-emitting element ED may include, as the at least one functional layer, a hole transport region HTR, an emission layer EML, an electron transport region ETR, and the like, which may be stacked in that order. For example, as shown in FIG. 5, the light-emitting element ED according to an embodiment may include a first electrode EL1, a hole transport region HTR, an emission layer EML, an electron transport region ETR, and a second electrode EL2, which are stacked in that order.

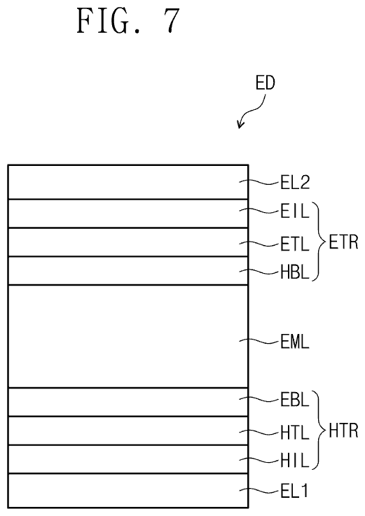

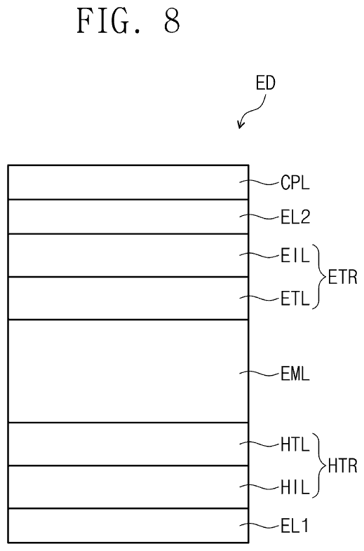

In comparison to FIG. 5, FIG. 6 is a schematic cross-sectional view of a light-emitting element ED, in which a hole transport region HTR includes a hole injection layer HIL and a hole transport layer HTL, and an electron transport region ETR includes an electron injection layer EIL and an electron transport layer ETL. In comparison to FIG. 5, FIG. 7 is a schematic cross-sectional view of a light-emitting element ED, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison to FIG. 6, FIG. 8 is a schematic cross-sectional view of a light-emitting element ED, in which a capping layer CPL is disposed on a second electrode EL2.

The light-emitting element ED according to an embodiment may include, in the at least one functional layer, a fused polycyclic compound according to an embodiment, which will be described below. In the light-emitting element ED according to an embodiment, at least one of a hole transport region HTR, an emission layer EML, and an electron transport region ETR may include the fused polycyclic compound according to an embodiment. For example, in the light-emitting element ED, the emission layer EML may include the fused polycyclic compound according to an embodiment.

The first electrode EL1 has conductivity. The first electrode EL1 may include a metal material, a metal alloy, or a conductive compound. The first electrode EL1 may be an anode or a cathode. However, embodiments are not limited thereto. In an embodiment, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, and a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In another embodiment, the first electrode EL1 may have a multilayered structure that includes a reflective film or a transflective film formed of the above-described materials, and a transparent conductive film formed of ITO, IZO, ZnO, ITZO, etc. For example, the first electrode EL1 may have a three-layered structure of ITO/Ag/ITO, but embodiments are not limited thereto. In an embodiment, the first electrode EL1 may include the above-described metal materials, combinations of at least two of the above-described metal materials, oxides of the above-described metal materials, or the like. A thickness of the first electrode EL1 may be in a range of about 700 Å to about 10,000 Å. For example, the thickness of the first electrode EL1 may be in a range of about 1,000 Å to about 3,000 Å.

The hole transport region HTR may be provided on the first electrode EL1. The hole transport region HTR may include at least one of a hole injection layer HIL, a hole transport layer HTL, a buffer layer (not shown), an emission-auxiliary layer (not shown), and an electron blocking layer EBL. A thickness of the hole transport region HTR may be, for example, in a range of about 50 Å to about 15,000 Å.

The hole transport region HTR may have a structure consisting of a layer consisting of a single material, a structure consisting of a layer including different materials, or a structure including multiple layers including different materials.

For example, the hole transport region HTR may have a single-layered structure of a hole injection layer HIL or a hole transport layer HTL, or the hole transport region HTR may have a single-layered structure formed of a hole injection material and a hole transport material. In embodiments, the hole transport region HTR may have a hole injection layer HIL/hole transport layer HTL structure, a hole injection layer HIL/hole transport layer HTL/buffer layer (not shown) structure, a hole injection layer HIL/buffer layer (not shown) structure, a hole transport layer HTL/buffer layer (not shown) structure, or a hole injection layer HIL/hole transport layer HTL/electron blocking layer EBL structure, in which the layers of each structure may be stacked in its respective stated order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In light-emitting element ED according to an embodiment, the hole transport region HTR may include a compound represented by Formula H-1:

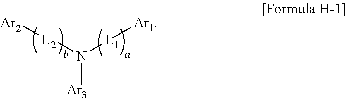

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, a and b may each independently be an integer from 0 to 10. When a or b is 2 or greater, multiple L₁ or multiple L₂ may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In Formula H-1, Ar₃ may be a substituted or unsubstituted aryl group having 6 to 30 ring-forming carbon atoms or a substituted or unsubstituted heteroaryl group having 2 to 30 ring-forming carbon atoms.

In an embodiment, the compound represented by Formula H-1 may be a monoamine compound. In another embodiment, the compound represented by Formula H-1 may be a diamine compound in which at least one of Ar₁ to Ar₃ includes an amine group as a substituent. In an embodiment, the compound represented by Formula H-1 may be a carbazole-based compound in which at least one of Ar₁ and Ar₂ includes a substituted or unsubstituted carbazole group, or may be a fluorene-based compound in which at least one of Ar₁ and Ar₂ includes a substituted or unsubstituted fluorene group.

The compound represented by Formula H-1 may be any compound selected from Compound Group H. However, the compounds listed in Compound Group H are only examples, and a compound represented by Formula H-1 is not limited to Compound Group H:

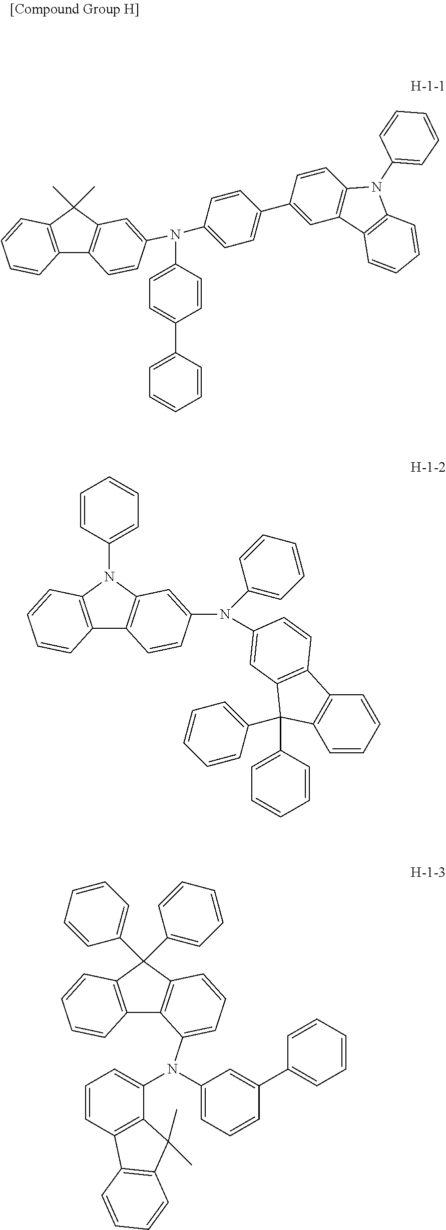 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

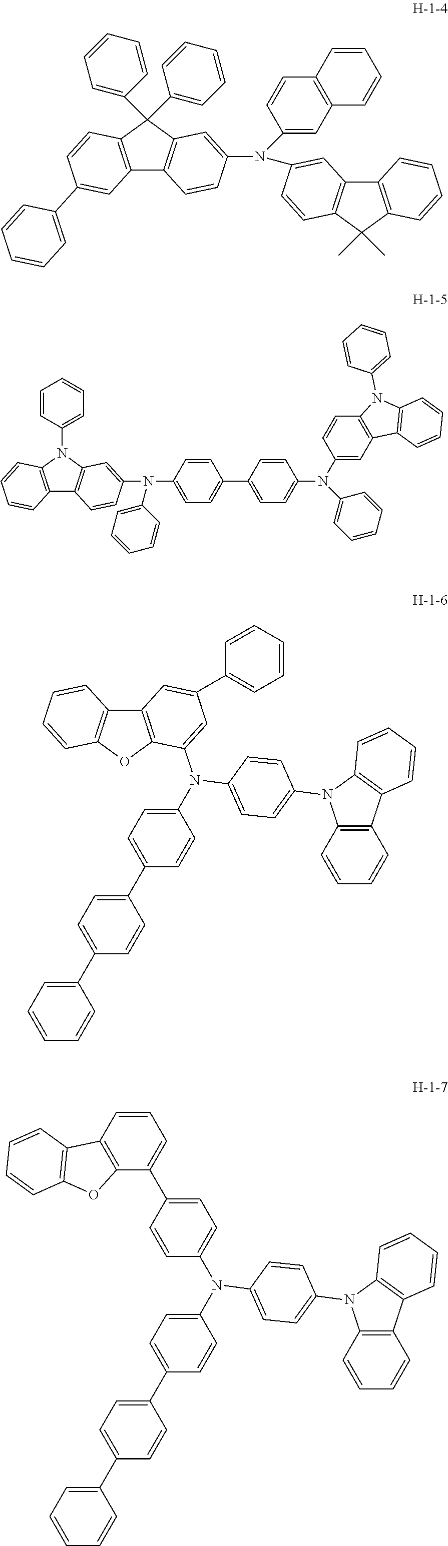 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

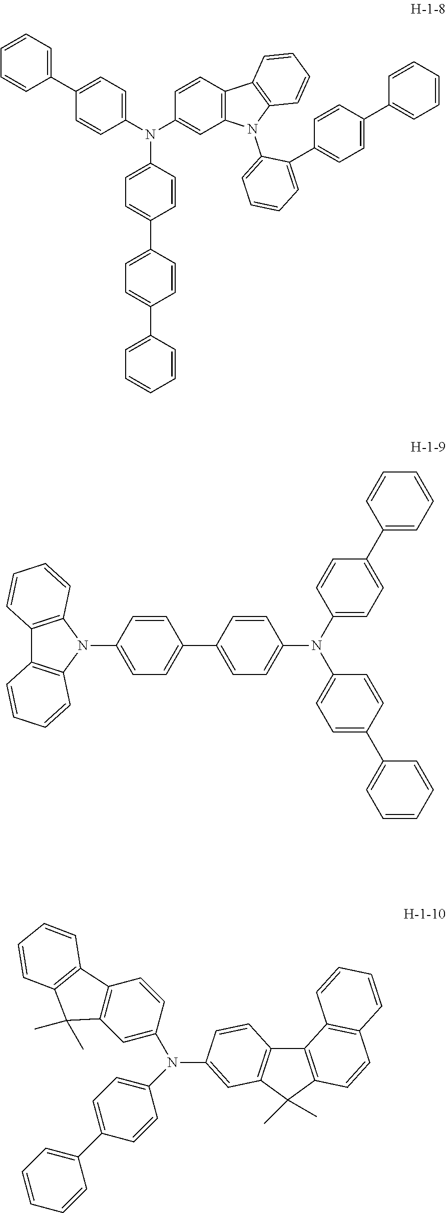 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

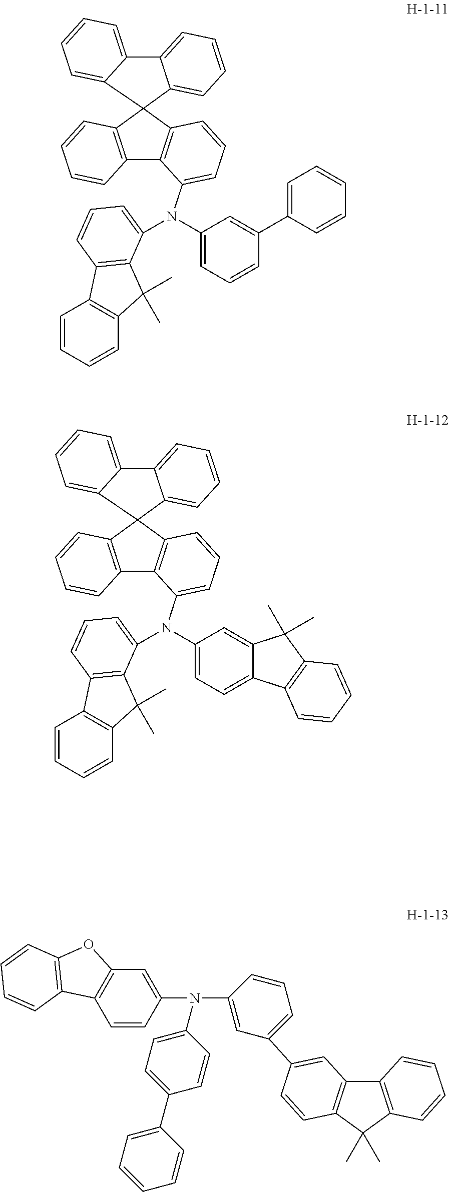 [SMILES: CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

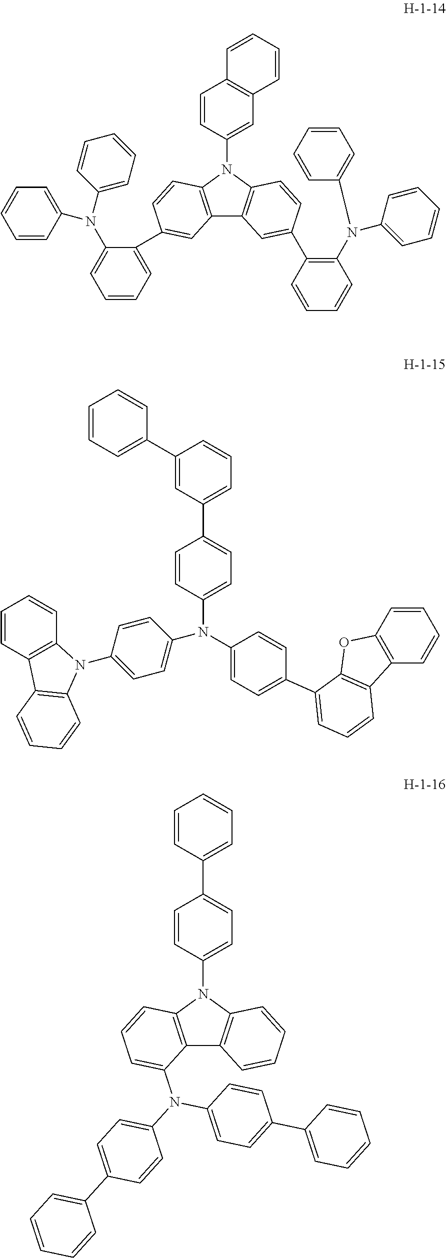 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

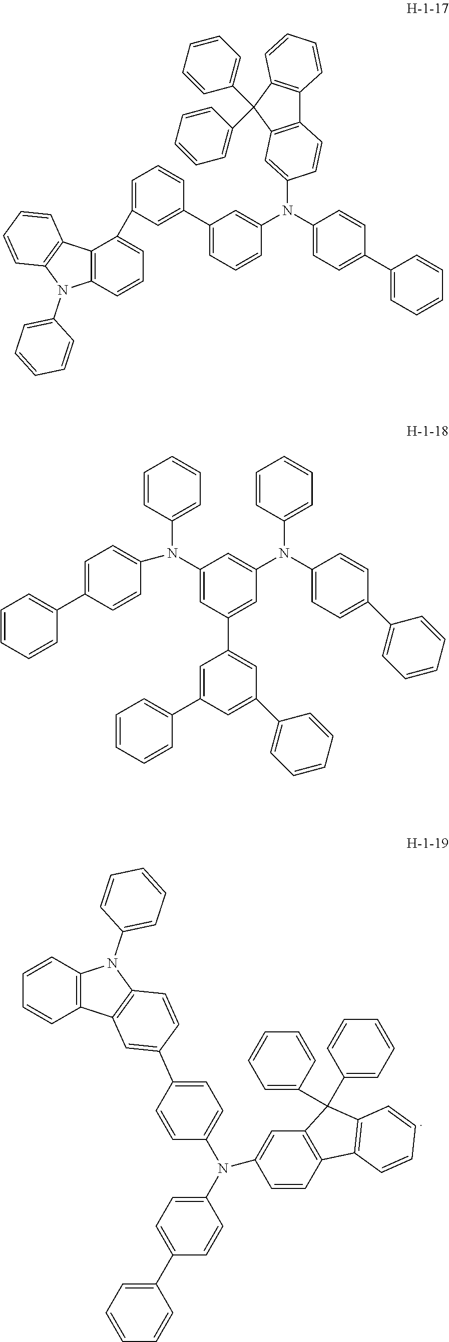 [SMILES: c1ccc(-c2ccc(N(c3cccc(-c4cccc(-c5cccc6c5c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine, N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium[tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), etc.

In an embodiment, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, and an electron blocking layer EBL.

A thickness of the hole transport region HTR may be in a range of about 100 Å to about 10,000 Å. For example, the thickness of the hole transport region HTR may be in a range of about 100 Å to about 5,000 Å. When the hole transport region HTR includes a hole injection layer HIL, the hole injection layer HIL may have a thickness in a range of about 30 Å to about 1,000 Å. When the hole transport region HTR includes a hole transport layer HTL, the hole transport layer HTL may have a thickness in a range of about 30 Å to about 1,000 Å. When the hole transport region HTR includes an electron blocking layer EBL, the electron blocking layer EBL may have a thickness in a range of about 10 Å to about 1,000 Å. If the thicknesses of the hole transport region HTR, the hole injection layer HIL, the hole transport layer HTL, and the electron blocking layer EBL satisfy the above-described ranges, satisfactory hole transport properties may be achieved without a substantial increase in driving voltage.

The hole transport region HTR may further include a charge generating material to increase conductivity, in addition to the above-described materials. The charge generating material may be dispersed uniformly or non-uniformly in the hole transport region HTR. The charge generating material may be, for example, a p-dopant. The p-dopant may include at least one of a metal halide, a quinone derivative, a metal oxide, and a cyano group-containing compound, but embodiments are not limited thereto. For example, the p-dopant may include a metal halide such as CuI or RbI, a quinone derivative such as tetracyanoquinodimethane (TCNQ) or 2,3,5,6-tetrafluoro-7,7,8,8-tetracyanoquinodimethane (F4-TCNQ), a metal oxide such as tungsten oxide or molybdenum oxide, a cyano group-containing compound such as dipyrazino[2,3-f: 2′,3′-h]quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the hole transport region HTR may further include at least one of a buffer layer (not shown) and an electron blocking layer EBL, in addition to a hole injection layer HIL and a hole transport layer HTL. The buffer layer (not shown) may compensate for a resonance distance according to a wavelength of light emitted from the emission layer EML and may thus increase light emission efficiency. A material that may be included in the hole transport region HTR may be used as a material in the buffer layer (not shown). The electron blocking layer EBL may prevent the injection of electrons from an electron transport region ETR to the hole transport region HTR.

The emission layer EML may be provided on the hole transport region HTR. The emission layer EML may have a thickness in a range of about 100 Å to about 1,000 Å. For example, the emission layer EML may have a thickness in a range of about 100 Å to about 300 Å. The emission layer EML may have a structure consisting of a layer consisting of a single material, a structure consisting of a layer including different materials, or a structure including multiple layers including different materials.

The light-emitting element ED according to an embodiment may include a fused polycyclic compound represented by Formula 1 in at least one functional layer disposed between a first electrode EL1 and a second electrode EL2. The at least one functional layer may include a hole transport region HTR, an emission layer EML and an electron transport region ETR. For example, the light-emitting element ED may include a fused polycyclic compound according to an embodiment in the emission layer EML. In an embodiment, the emission layer EML may include the fused polycyclic compound according to an embodiment as a dopant. The fused polycyclic compound according to an embodiment may be a dopant material in the emission layer EML. In the specification, the fused polycyclic compound according to an embodiment may be referred to as a first compound.

The fused polycyclic compound according to an embodiment includes a fused ring core that includes two boron atoms, in which properties of multiple resonance (MR) and charge transfer (CT) are exhibited. The fused polycyclic compound according to an embodiment may include a core (hereinafter, MR core) that includes two nitrogen atoms and a boron atom as ring-forming atoms and exhibits multiple resonance properties and a core (hereinafter CT core) that includes two heteroatoms and a boron atom as ring-forming atoms and exhibits charge transfer properties. In the fused polycyclic compound according to an embodiment, the MR core and the CT core may be fused by sharing a benzene ring.

In the fused polycyclic compound according to an embodiment, a substituent that includes a five-membered ring is fused on the CT core, which may enhance electron withdrawing properties. Therefore, characteristics of improved reverse intersystem crossing (RISC) rates may be exhibited. In the fused polycyclic compound according to an embodiment, since the substituent including a five-membered ring is fused on the CT core, rigidity may be improved and vibrational energy may be adjusted in a region with a high energy level, and thus characteristics of a narrow full width at half maximum of an emission spectrum may be achieved. Therefore, color purity may be improved. In the fused polycyclic compound according to an embodiment, a terphenyl group may be linked to at least one of the two nitrogen atoms in the MR core, and thus the fused polycyclic compound may include a moiety that surrounds and protects the MR core. In the fused polycyclic compound according to an embodiment, a p-orbital of the boron atom in the MR core is protected to thereby inhibit Dexter energy transfer and the like, so that material stability may increase.

The fused polycyclic compound according to an embodiment may include a MR core where five rings are fused with a first boron atom and first and second nitrogen atoms, and may include a CT core where three or more rings are fused around a second boron atom, a first heteroatom, and a second heteroatom, in which the CT core shares a benzene ring with the MR core. In the fused polycyclic compound according to an embodiment, one or two first substituents may be fused on the CT core.

The fused polycyclic compound according to an embodiment may be represented by Formula 1:

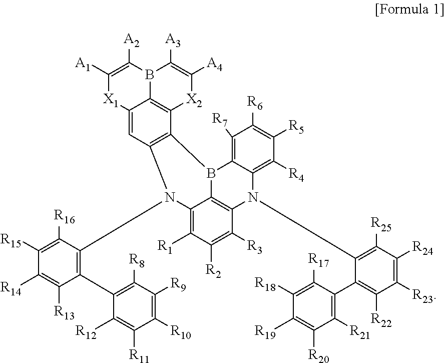

In Formula 1, X₁ and X₂ may each independently be O, S, Se, Te, N(R₂₆), or Si(R₂₇)(R₂₈). X₁ may correspond to the first heteroatom, and X₂ may correspond to the second heteroatom, each included in the CT core. In an embodiment, in Formula 1, X₁ and X₂ may be the same as or different from each other. In an embodiment, at least one of X₁ and X₂ may be O, and the remainder of X₁ and X₂ that is not O may be S, Se, Te, N(R₂₆), or Si(R₂₇)(R₂₈), but embodiments are not limited thereto. As another example, X₁ and X₂ may each be S.

In an embodiment, X₁ may be O, S, Se, Te, N(R₂₆), or Si(R₂₇)(R₂₈); and X₂ may be O. For example, X₁ may be N(R₂₆), and X₂ may be O. In another embodiment, X₁ and X₂ may each be O.

In Formula 1, R₁ to R₂₈ may each independently be a hydrogen atom, a deuterium atom, a halogen atom, a cyano group, a nitro group, a substituted or unsubstituted silyl group, a substituted or unsubstituted oxy group, a substituted or unsubstituted amine group, a substituted or unsubstituted alkyl group having 1 to 60 carbons, a substituted or unsubstituted cycloalkyl group having 3 to 60 ring-forming carbons, a substituted or unsubstituted alkenyl group having 2 to 60 carbons, a substituted or unsubstituted aryl group having 6 to 60 ring-forming carbons, or a substituted or unsubstituted heteroaryl group having 2 to 60 ring-forming carbons, or bonded to an adjacent group to form a ring. For example, R₁ to R₂₈ may each independently be a hydrogen atom, a deuterium atom, a cyano group, a substituted or unsubstituted diphenylamine group, a substituted or unsubstituted dibiphenylamine group,

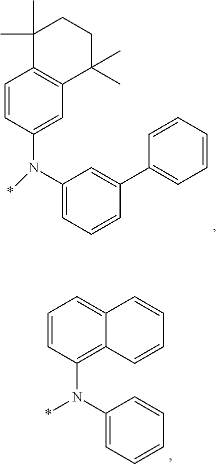 [SMILES: *N(c1cccc(-c2ccccc2)c1)c1ccc2c(c1)C(C)(C)CCC2(C)C ; *N(c1ccccc1)c1cccc2ccccc12]

a substituted or unsubstituted methyl group, a substituted or unsubstituted i-propyl group, a substituted or unsubstituted t-butyl group, a substituted or unsubstituted n-butyl group, a substituted or unsubstituted cyclohexyl group, a substituted or unsubstituted adamantyl group, a substituted or unsubstituted phenyl group, a substituted or unsubstituted biphenyl group, a substituted or unsubstituted terphenyl group, a substituted or unsubstituted naphthyl group, a substituted or unsubstituted phenanthryl group, a substituted or unsubstituted pyrenyl group, a substituted or unsubstituted anthracenyl group, a substituted or unsubstituted carbazole group, a substituted or unsubstituted dibenzofuran group, a substituted or unsubstituted pyridine group, a substituted or unsubstituted pyrimidine group, or a substituted or unsubstituted triazine group, but embodiments are not limited thereto. For example, R₁ to R₂₈ may be bonded to an adjacent group to form a hydrocarbon ring or a heterocycle.

In an embodiment, in Formula 1, R₄ to R₇ may each be substituted. In an embodiment, R₄ to R₇ may each independently be a deuterium atom, a substituted or unsubstituted amine group, a substituted or unsubstituted t-butyl group, a substituted or unsubstituted phenyl group, or a substituted or unsubstituted carbazole group, but embodiments are not limited thereto.

In Formula 1, at least one of R₁₆ and R₂₅ may each independently be a substituted or unsubstituted phenyl group. For example, in an embodiment, R₁₆ and R₂₅ may each independently be a substituted or unsubstituted phenyl group, or one of R₁₆ and R₂₅ may be a substituted or unsubstituted phenyl group. In the fused polycyclic compound, at least one of R₁₆ and R₂₅ is each independently a substituted or unsubstituted phenyl group, so that in the MR core, the first boron atom may be protected.

In Formula 1, at least one of a pair of A₁ and A₂ and a pair of A₃ and A₄ may each independently be bonded to a first substituent represented by Formula S-1; and the remainder of a pair of A₁ and A₂ and a pair of A₃ and A₄ that is not bonded to the first substituent represented by Formula S-1 may be bonded to a second substituent represented by Formula S-2. For example, in Formula 1, the first substituent represented by Formula S-1 may be connected to A₁ and A₂, and the second substituent represented by Formula S-2 may be connected to A₃ and A₄. As another example, in Formula 1, the second substituent represented by Formula S-2 may be connected to A₁ and A₂, and the first substituent represented by Formula S-1 may be connected to A₃ and A₄. As yet another example, in Formula 1, a first substituent represented by Formula S-1 may be connected to each of the pair of A₁ and A₂ and the pair of A₃ and A₄. In Formula 1, if a first substituent represented by Formula S-1 is connected to each of the pair of A₁ and A₂ and the pair of A₃ and A₄, each first substituent may be the same as or different from each other. The first substituent connected to Formula 1 may correspond to a substituent that includes the five-membered ring described above.

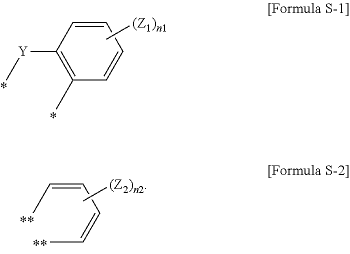

In Formula S-1, Y may be O, S, Se, Te, N(Rₛ₁), or Si(Rₛ₂)(Rₛ₃). When the pair of A₁ and A₂ and the pair of A₃ and A₄ are each bonded to a first substituent represented by S-1, each Y may be the same as or different from each other.

In Formula S-1 and Formula S-2, Rₛ₁ to Rₛ₃, Z₁, and Z₂ may each independently be a hydrogen atom, a deuterium atom, a halogen atom, a cyano group, a nitro group, a substituted or unsubstituted silyl group, a substituted or unsubstituted oxy group, a substituted or unsubstituted amine group, a substituted or unsubstituted alkyl group having 1 to 60 carbons, a substituted or unsubstituted cycloalkyl group having 3 to 60 ring-forming carbons, a substituted or unsubstituted alkenyl group having 2 to 60 carbons, a substituted or unsubstituted aryl group having 6 to 60 ring-forming carbons, or a substituted or unsubstituted heteroaryl group having 2 to 60 ring-forming carbons, or bonded to an adjacent group to form a ring. For example, Rₛ₁ to Rₛ₃, Z₁, and Z₂ may each independently be a hydrogen atom, a deuterium atom, a substituted or unsubstituted methyl group, a substituted or unsubstituted t-butyl group, a substituted or unsubstituted phenyl group, a substituted or unsubstituted diphenylamine group, a substituted or unsubstituted dibiphenylamine group, or a substituted or unsubstituted carbazole group. For example, if n1 is 2 or greater, multiple Z₁ may be bonded to each other to form a hydrocarbon ring or a heterocycle. For example, if n2 is 2 or greater, multiple Z₂ may be bonded to each other to form a hydrocarbon ring. However, embodiments are not limited thereto, and Rₛ₁, Rₛ₂, Rₛ₃, and/or Z₁ may also be bonded to each other to form a ring.

In Formula S-1 and Formula S-2, n1 and n2 may each independently be an integer from 0 to 4. If n1 and n2 are each 0, the fused polycyclic compound may not be substituted with of Z₁ and Z₂, respectively. A case where n1 and n2 are each 4 and four Z₁ and four Z₂ are all hydrogen atoms may be the same as a case where n1 and n2 are each 0. If n1 and n2 are each 2 or greater, multiple Z₁ and multiple Z₂ may all be the same, or at least one thereof may be different from the remainder.

In Formula S-1 and Formula S-2, *- and **- each represents a bond to the pair of A₁ and A₂ or the pair of A₃ and A₄ in Formula 1.

In the fused polycyclic compound according to an embodiment, one or two first substituents are connected to the CT core, and a terphenyl group is connected to at least one of the first and second nitrogen atoms of the MR core, and thus improvements in high efficiency and long lifespan of the light-emitting element ED may be achieved.

In the fused polycyclic compound according to an embodiment, an energy gap between a lowest triplet energy level and a lowest singlet energy level may be equal to or less than about 0.2 eV, thereby improving reverse intersystem crossing (RISC) rates, which rapidly converts a triplet exciton to a singlet exciton. Therefore, efficiency and lifespan of the light-emitting element ED may be improved. In the fused polycyclic compound according to an embodiment, since a delayed fluorescence speed (tau) is fast due to the inclusion of the first substituent in the CT core, a decrease in lifespan of the light-emitting element ED is small, thereby imparting properties of a long lifespan in the light-emitting element ED.

In the fused polycyclic compound according to an embodiment, a trigonal planar structure of a boron atom may be effectively maintained by inducing a steric hindrance effect via one or two substituted or unsubstituted terphenyl groups, which are connected to the MR core. The boron atom has electron-deficiency properties due to an unoccupied p-orbital, and thus may form a bond with another nucleophile to change into a tetrahedral structure, which may cause deterioration of the element. In the fused polycyclic compound according to an embodiment, since the substituted or unsubstituted terphenyl group is connected to the MR core, the unoccupied p-orbital of the boron atom may be effectively protected. Therefore, deterioration due to structural transformation may be prevented.

In an embodiment, the fused polycyclic compound represented by Formula 1 may be represented by one of Formula 2 to Formula 4. Formula 2 to Formula 4 each represent an embodiment that includes at least one first substituent. In Formula 2 to Formula 4, Z₁₁ and Z₁₂ may each correspond to Z₁ in the first substituent represented by Formula S-1, and n11 and n12 may each correspond to n1 in the first substituent represented by Formula S-1. In Formula 2 to Formula 4, Y₁ and Y₂ may each correspond to Y in the first substituent represented by Formula S-1. In Formula 2 and Formula 3, Z₂₁ and Z₂₂ may each correspond to Z₂ in the second substituent represented by Formula S-2, and n21 and n22 may each correspond to n2 in the second substituent represented by Formula S-2.

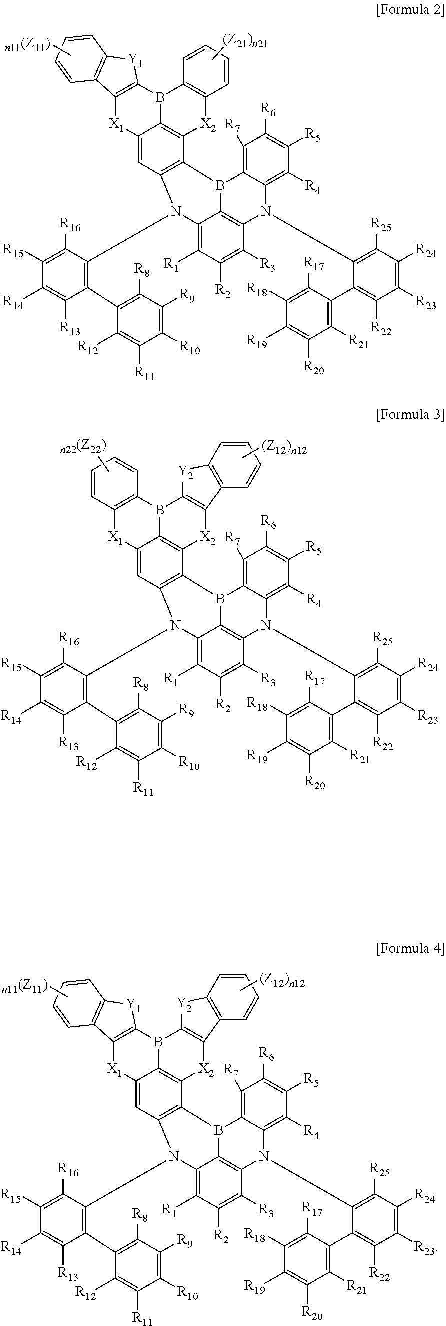

In Formula 2 to Formula 4, Y₁ and Y₂ may each independently be O, S, Se, Te, N(R_{y1}), or Si(R_{y2})(R_{y3}). Y₁ and Y₂ may be the same as or different from each other.

In Formula 2 to Formula 4, Z₁₁, Z₁₂, Z₂₁, Z₂₂, R_{y1}, R_{y2}, and R_{y3} may each independently be a hydrogen atom, a deuterium atom, a halogen atom, a cyano group, a nitro group, a substituted or unsubstituted silyl group, a substituted or unsubstituted oxy group, a substituted or unsubstituted amine group, a substituted or unsubstituted alkyl group having 1 to 60 carbons, a substituted or unsubstituted cycloalkyl group having 3 to 60 ring-forming carbons, a substituted or unsubstituted alkenyl group having 2 to 60 carbons, a substituted or unsubstituted aryl group having 6 to 60 ring-forming carbons, or a substituted or unsubstituted heteroaryl group having 2 to 60 ring-forming carbons, or bonded to an adjacent group to form a ring. For example, Z₁₁, Z₁₂, Z₂₁, Z₂₂, R_{y1}, R_{y2}, and R_{y3} may each independently be a hydrogen atom, a deuterium atom, a substituted or unsubstituted methyl group, a substituted or unsubstituted t-butyl group, a substituted or unsubstituted phenyl group, a substituted or unsubstituted diphenylamine group, a substituted or unsubstituted dibiphenylamine group, or a substituted or unsubstituted carbazole group. For example, if n11 is 2 or greater, multiple Z₁ may be bonded to each other to form a hydrocarbon ring or a heterocycle. For example, if n12 is 2 or greater, multiple Z₁₂ may be bonded to each other to form a hydrocarbon ring or a heterocycle. For example, if n21 and n22 are each 2 or greater, multiple Z₂₁ may be bonded to each other to form a hydrocarbon ring, and multiple Z₂₂ may be bonded to each other to form a hydrocarbon ring. However, embodiments are not limited thereto, and R_{y1}, R_{y2}, and/or R_{y3} may also be bonded to Z₁₁ or Z₁₂ to form a ring.

In Formula 2 to Formula 4, n11, n12, n21, and n22 may each independently be an integer from 0 to 4. If n11, n12, n21, and n22 are each 0, the fused polycyclic compound may not be substituted with Z₁₁, Z₁₂, Z₂₁, and Z₂₂, respectively. A case where n11, n12, n21, and n22 are each 4 and four of each of Z₁, Z₁₂, Z₂₁, and Z₂₂ are all hydrogen atoms may be the same as a case where n11, n12, n21, and n22 are each 0. If n11, n12, n21, and n22 are each 2 or greater, multiples of each of Z₁₁, Z₁₂, Z₂₁, and Z₂₂ may all be the same, or at least one thereof may be different from the remainder.

In Formula 2 to Formula 4, X₁, X₂, and R₁ to R₂₅ are the same as defined in Formula 1.

In an embodiment, the fused polycyclic compound represented by Formula 2 may be represented by one of Formula 2-1 to Formula 2-3:

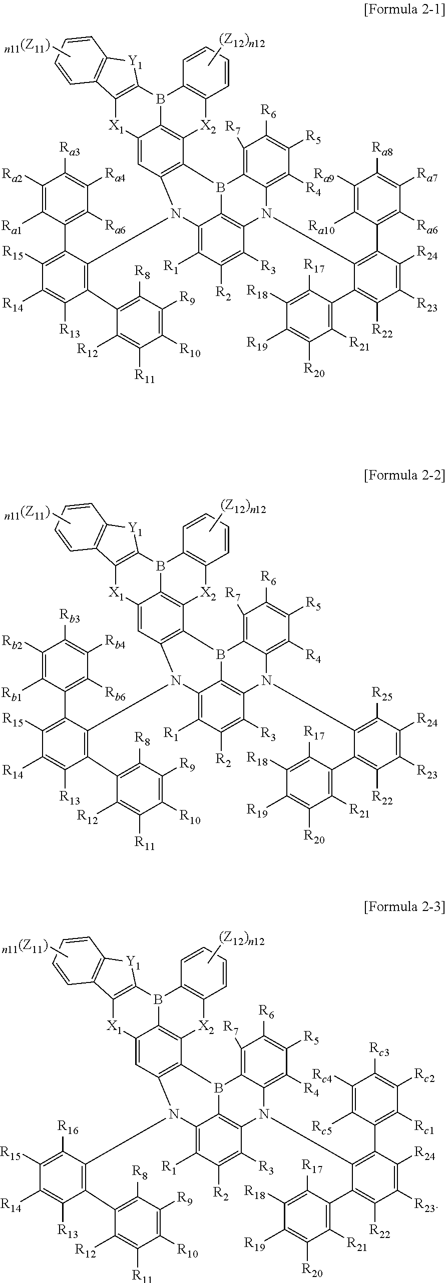

In Formula 2-1 to Formula 2-3, Rₐ₁ to Rₐ₁₀, R_{b1} to R_{b5}, and R_{b1} to R_{b5} may each independently be a hydrogen atom, a deuterium atom, a substituted or unsubstituted alkyl group having 1 to 30 carbons, or a substituted or unsubstituted aryl group having 6 to 30 ring-forming carbons. For example, Rₐ₁ to Rₐ₁₀, R_{b1} to R_{b5}, and R_{c1} to R_{c5} may each independently be a hydrogen atom or a deuterium atom.

In Formula 2-1 to Formula 2-3, X₁, X₂, and R₁ to R₂₅ are the same as defined in Formula 1; and Y₁, Z₁₁, Z₂₁, n11, and n21 are the same as defined in Formula 2.

In an embodiment, the fused polycyclic compound represented by Formula 3 may be represented by one of Formula 3-1 to Formula 3-3:

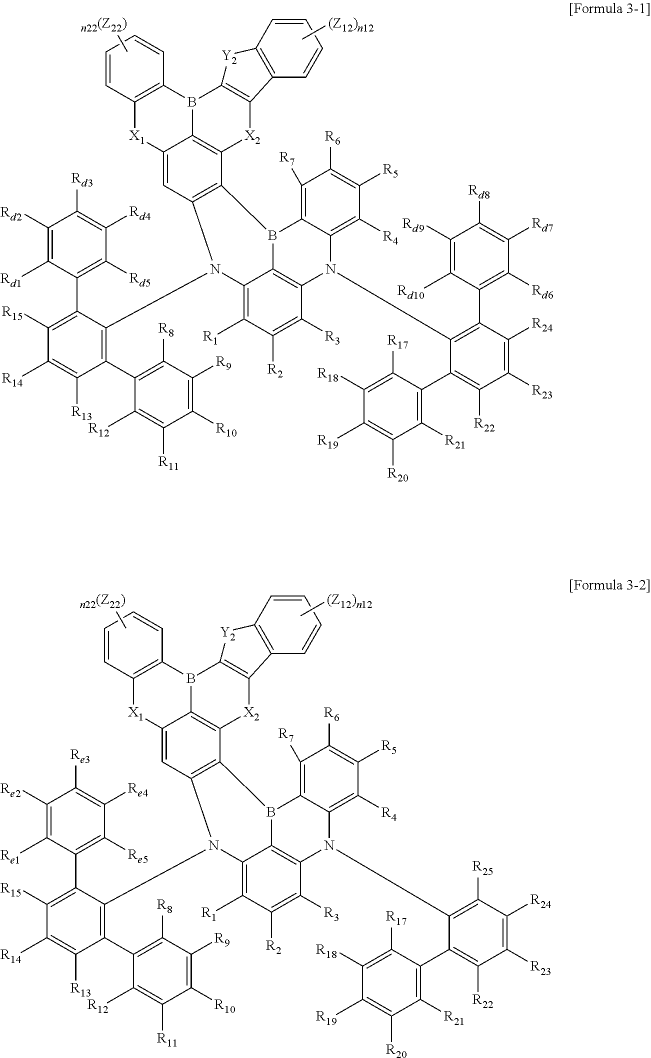

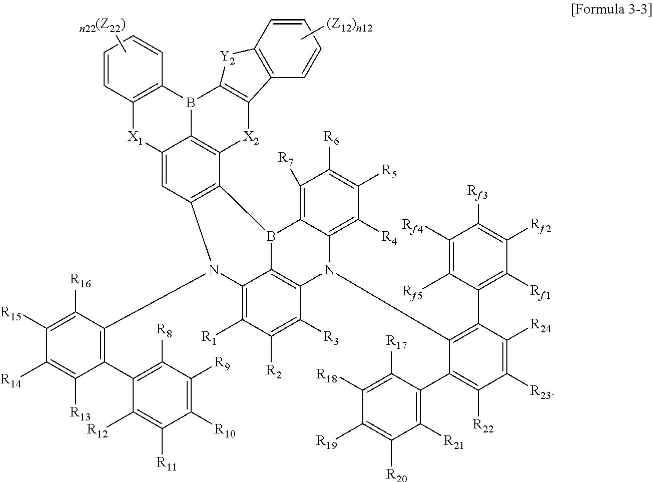

In Formula 3-1 to Formula 3-3, R_{d1} to R_{d10}, R_{b1} to R_{b5}, and R_{f1} to R_{f5} may each independently be a hydrogen atom, a deuterium atom, a substituted or unsubstituted alkyl group having 1 to 30 carbons, or a substituted or unsubstituted aryl group having 6 to 30 ring-forming carbons. For example, R_{d1} to R_{d10}, R_{b1} to R_{b5}, and Rfl to R_{f5} may each independently be a hydrogen atom or a deuterium atom.

In Formula 3-1 to Formula 3-3, X₁, X₂, and R₁ to R₂₅ are the same as defined in Formula 1; and Y₂, Z₁₂, Z₂₂, n12, and n22 are the same as defined in Formula 3.

In an embodiment, the fused polycyclic compound represented by Formula 4 may be represented by one of Formula 4-1 to Formula 4-3:

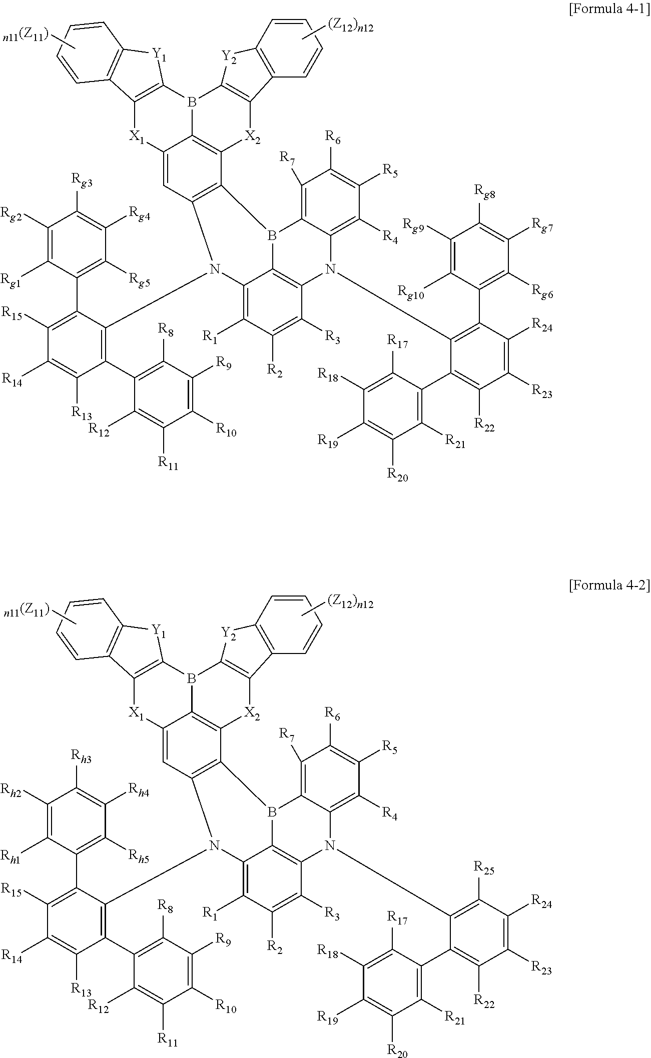

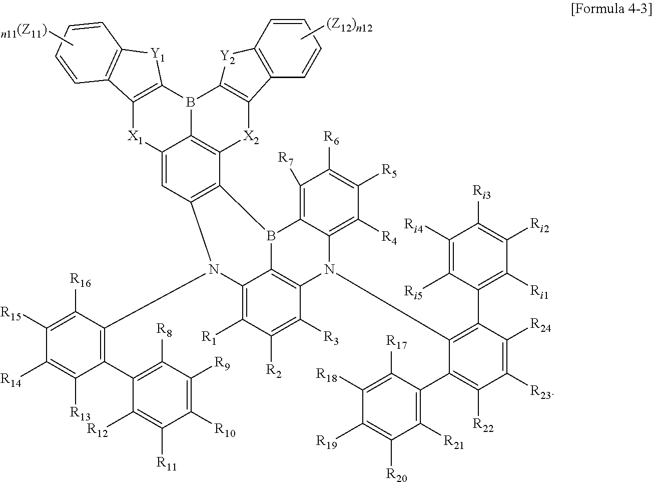

In Formula 4-1 to Formula 4-3, R_{g1} to R_{g10}, Rₕ₁ to Rₕ₅, and Rᵢ₁ to Rᵢ₅ may each independently be a hydrogen atom, a deuterium atom, a substituted or unsubstituted alkyl group having 1 to 30 carbons, or a substituted or unsubstituted aryl group having 6 to 30 ring-forming carbons. For example, R_{g1} to R_{g10}, Rₕ₁ to Rₕ₅, and Rᵢ₁ to Rᵢ₅ may each independently be a hydrogen atom a deuterium atom.

In Formula 4-1 to Formula 4-3, X₁, X₂, and R₁ to R₂₅ are the same as defined in Formula 1; and Y₁, Y₂, Z₁₁, Z₁₂, n11, and n12 are the same as defined in Formula 4.

In an embodiment, the fused polycyclic compound may include at least one deuterium atom as a substituent. For example, the fused polycyclic compound according to an embodiment may have a structure in which at least one hydrogen atom is substituted with a deuterium atom.

In an embodiment, the fused polycyclic compound represented by Formula 1 may be any compound selected from Compound Group 1. In an embodiment, in the light-emitting element ED, at least one functional layer may include at least one compound selected from Compound Group 1. In an embodiment, in the light-emitting element ED, the first compound may include at least one compound selected from Compound Group 1:

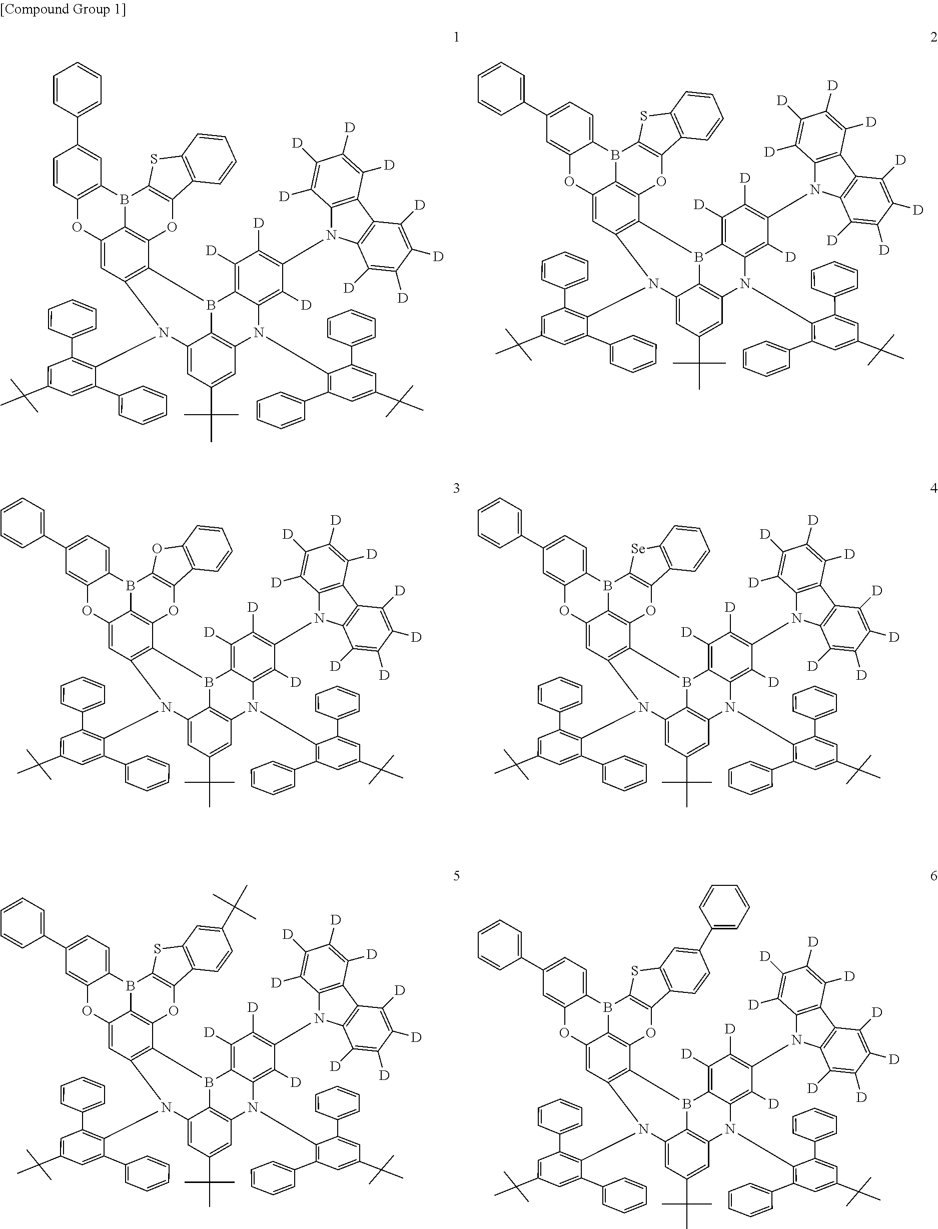

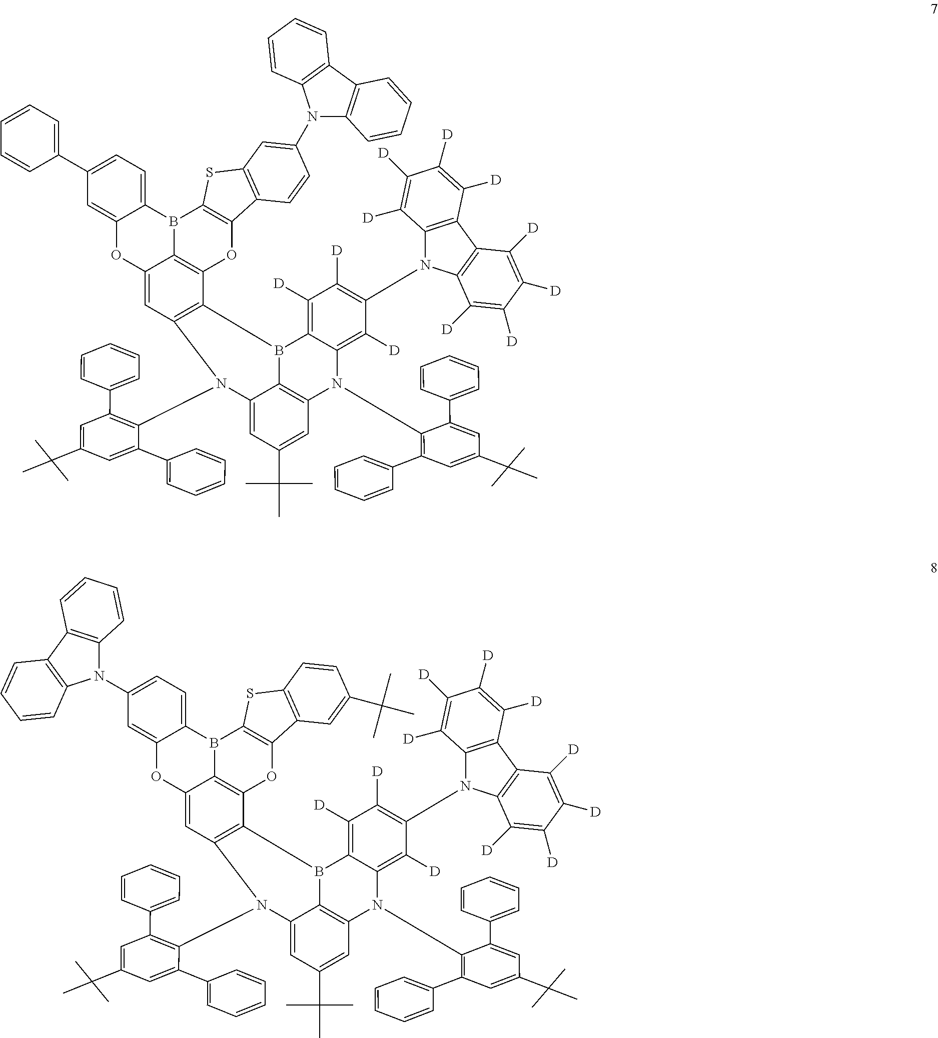

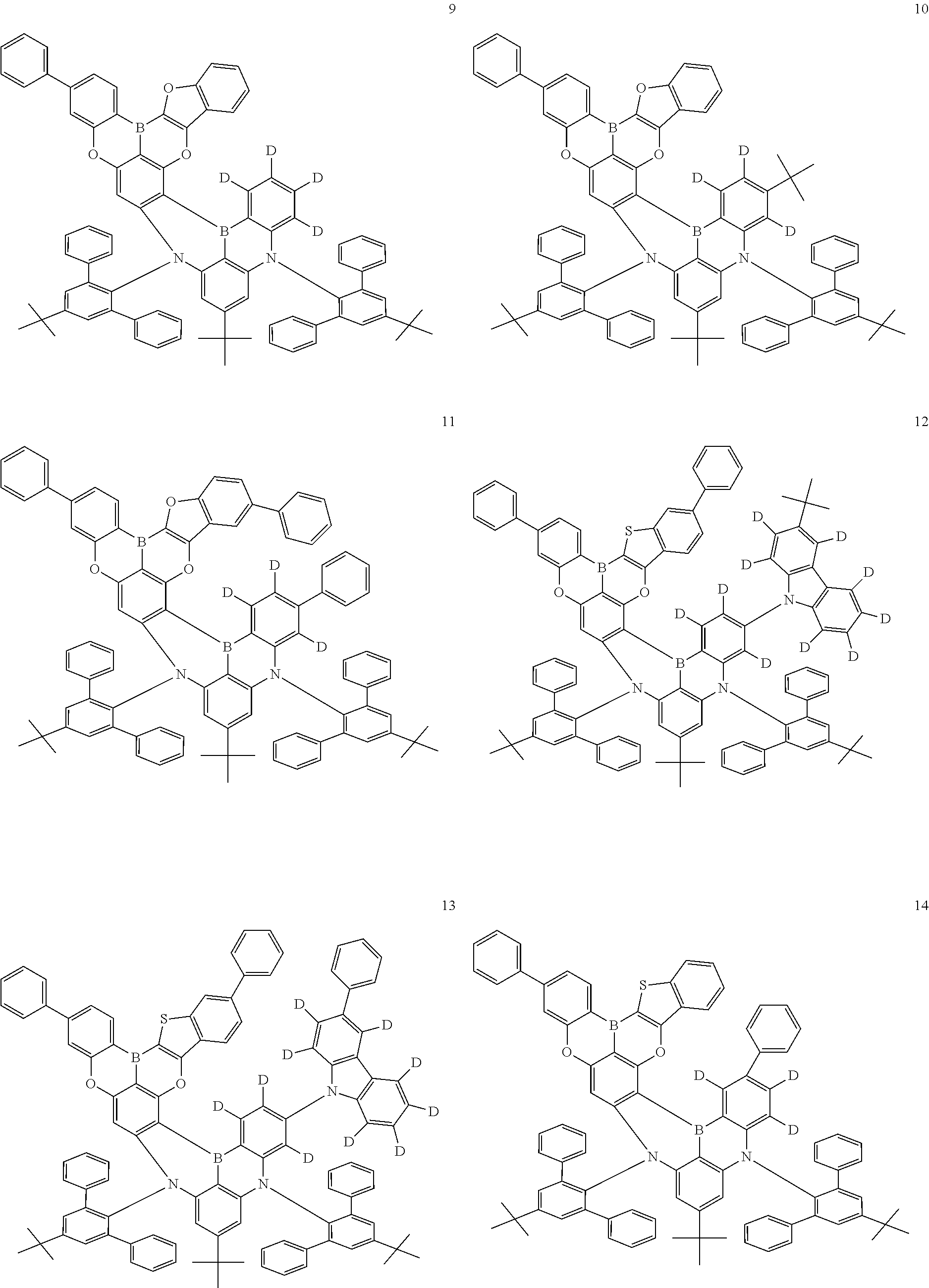

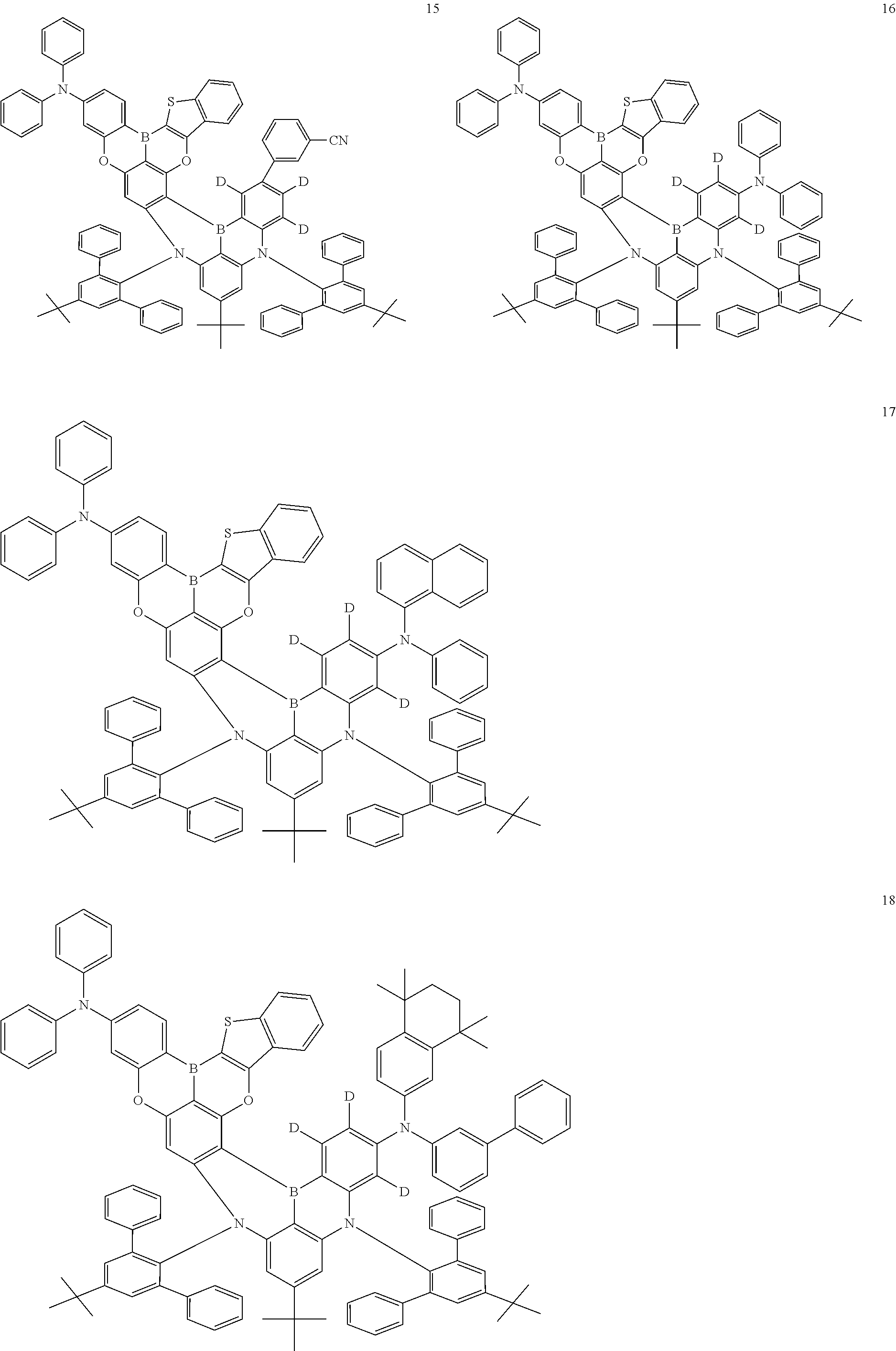

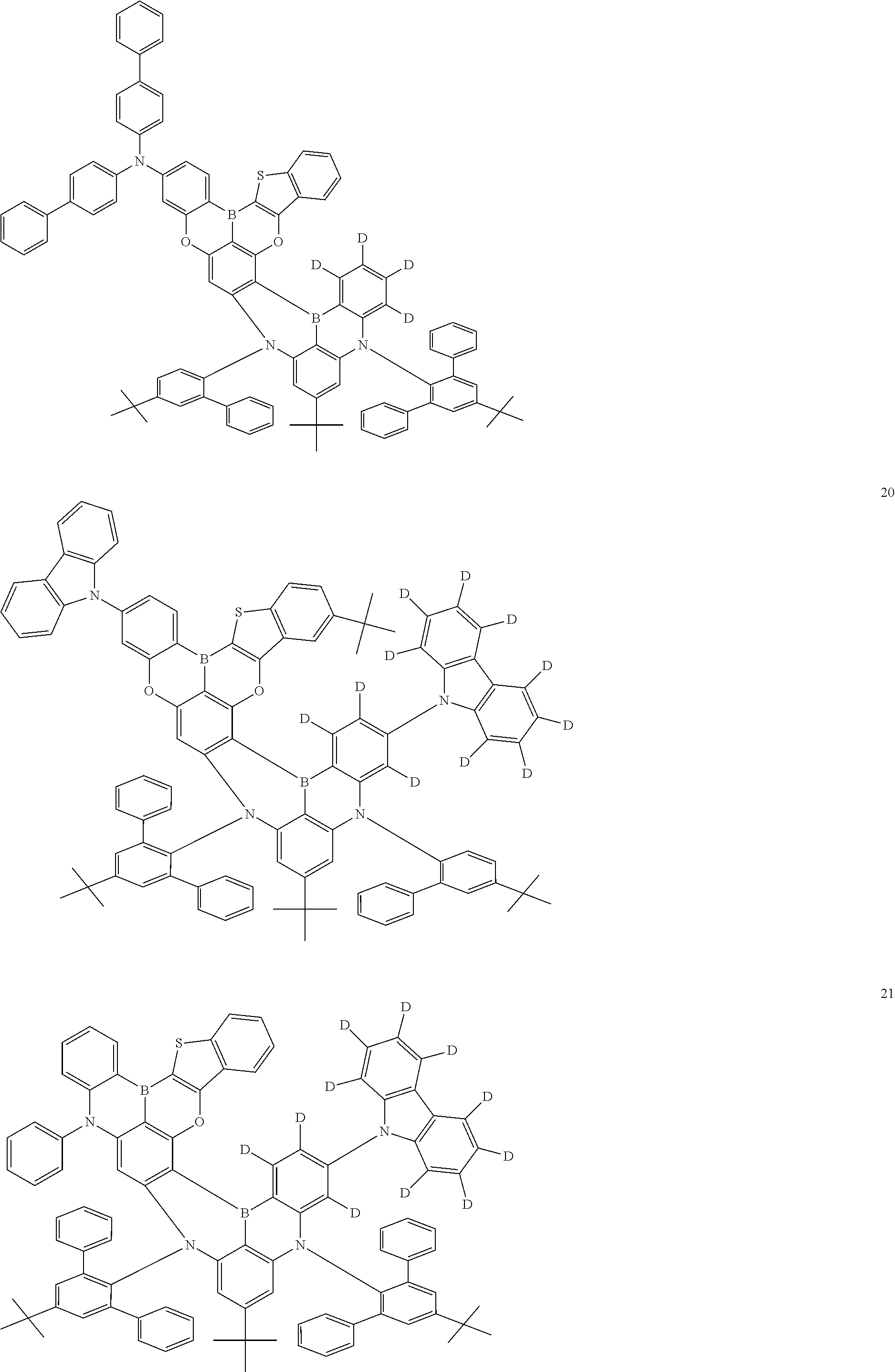

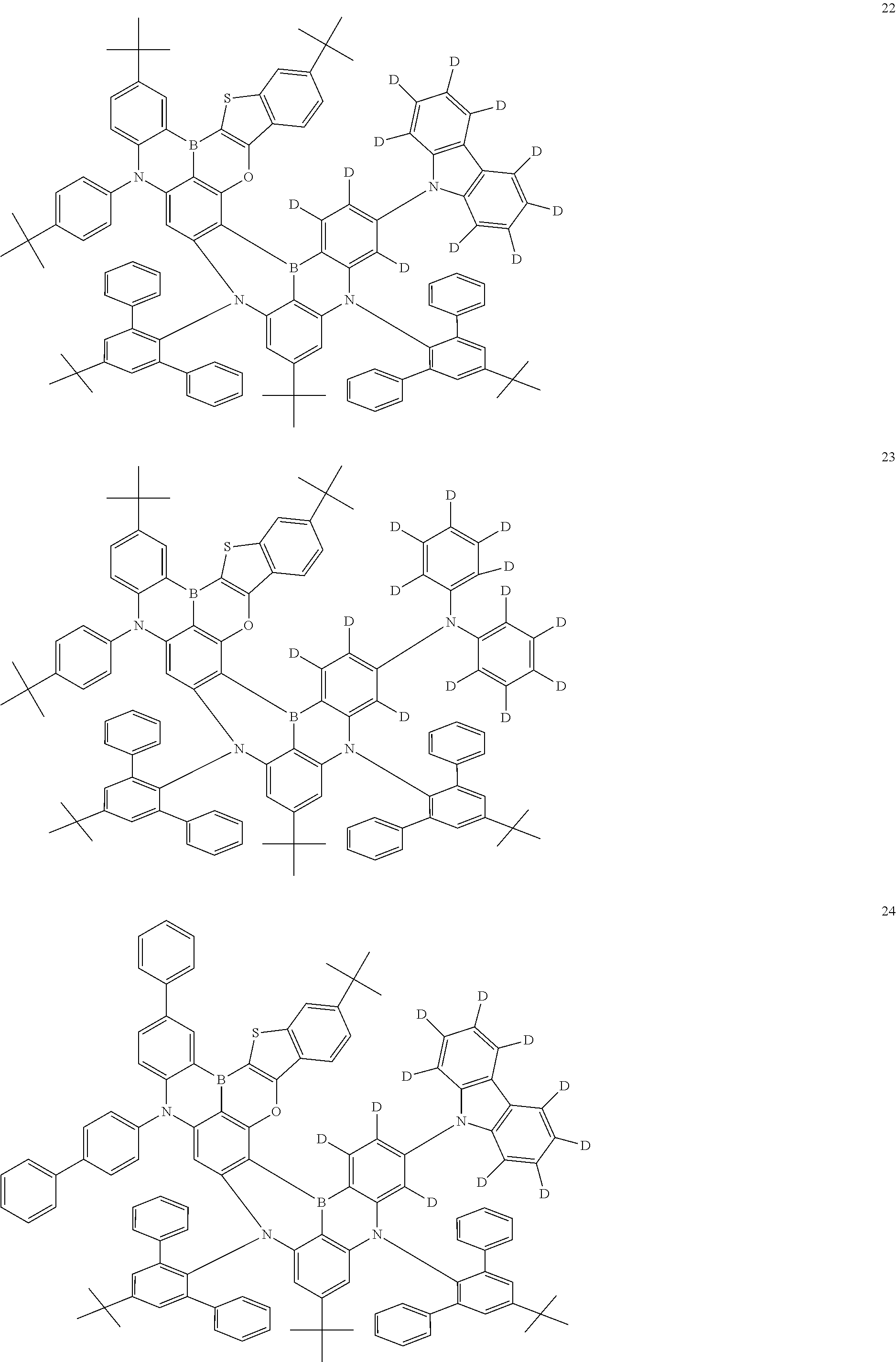

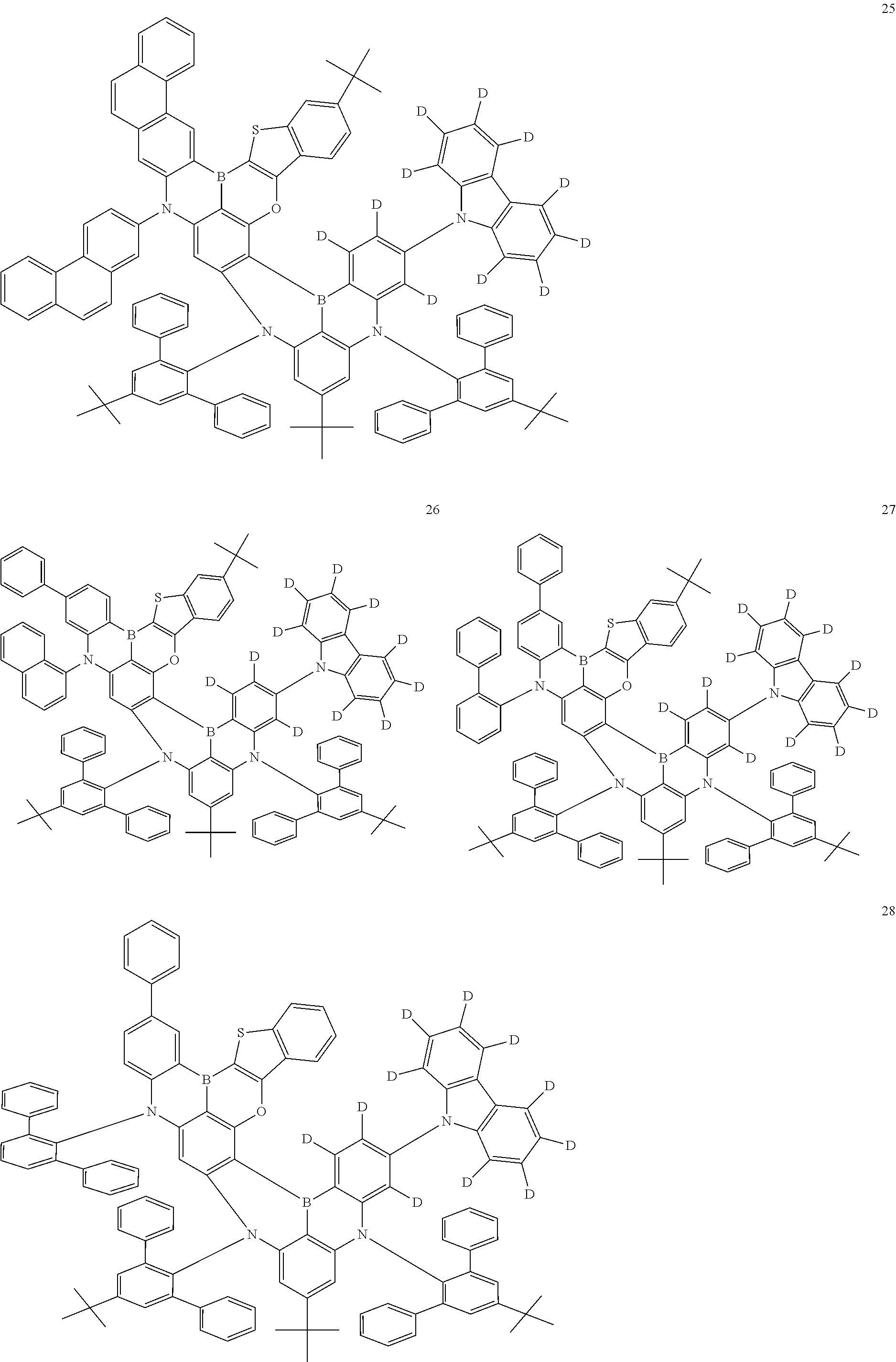

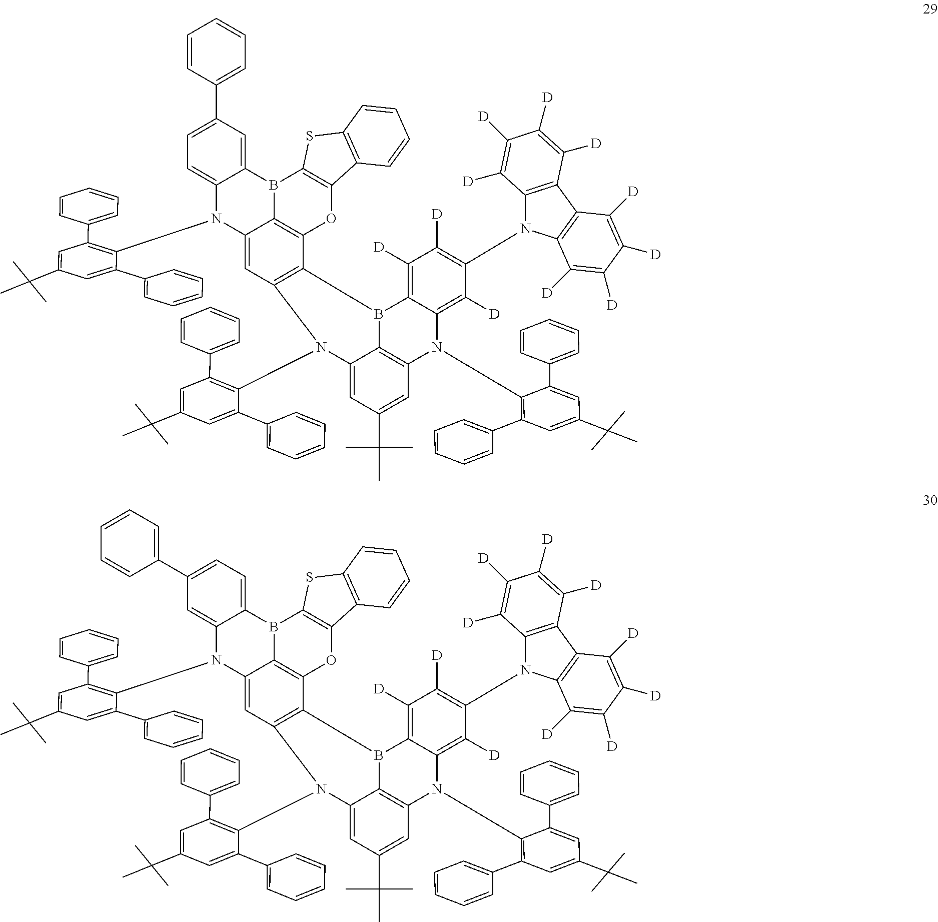

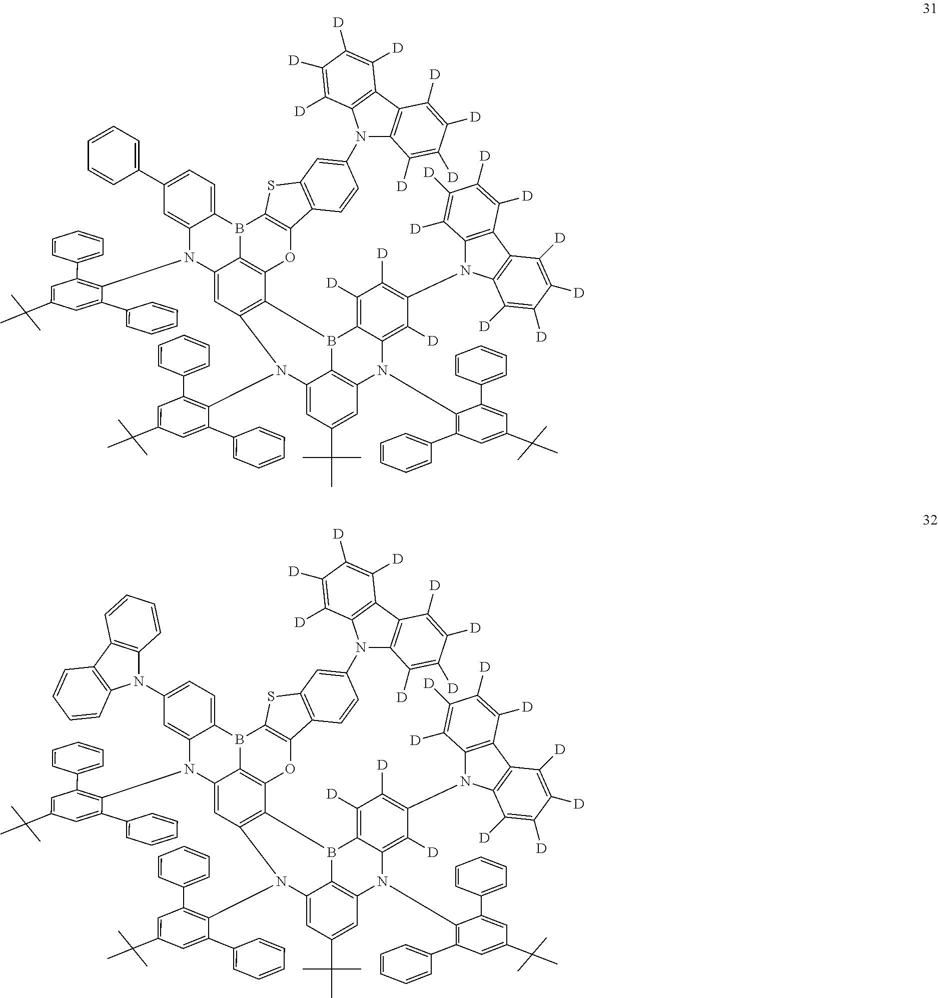

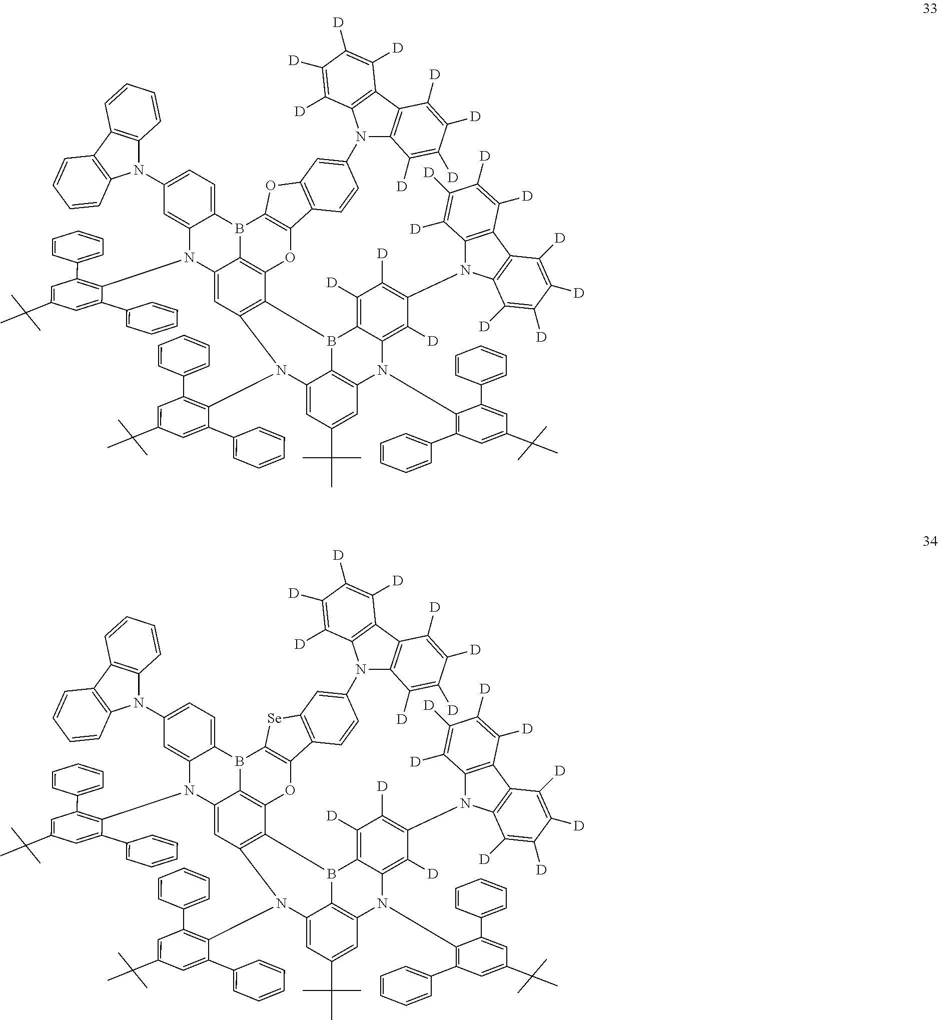

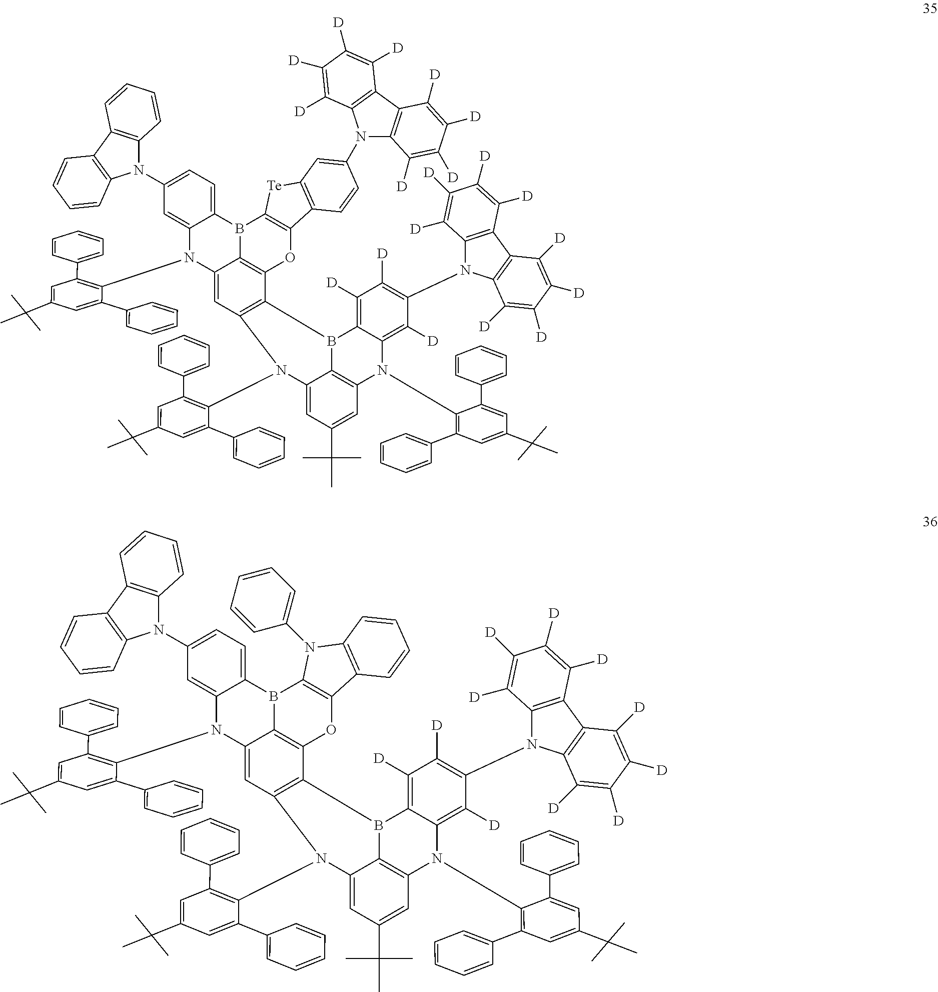

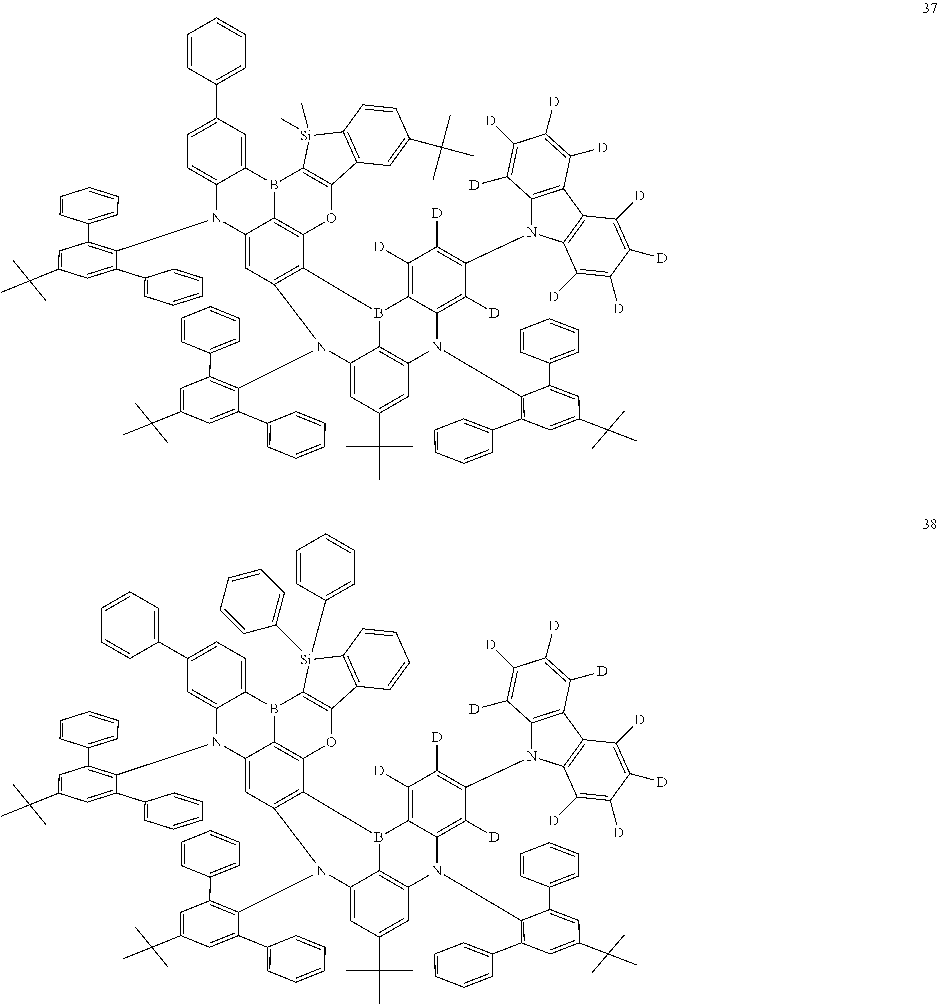

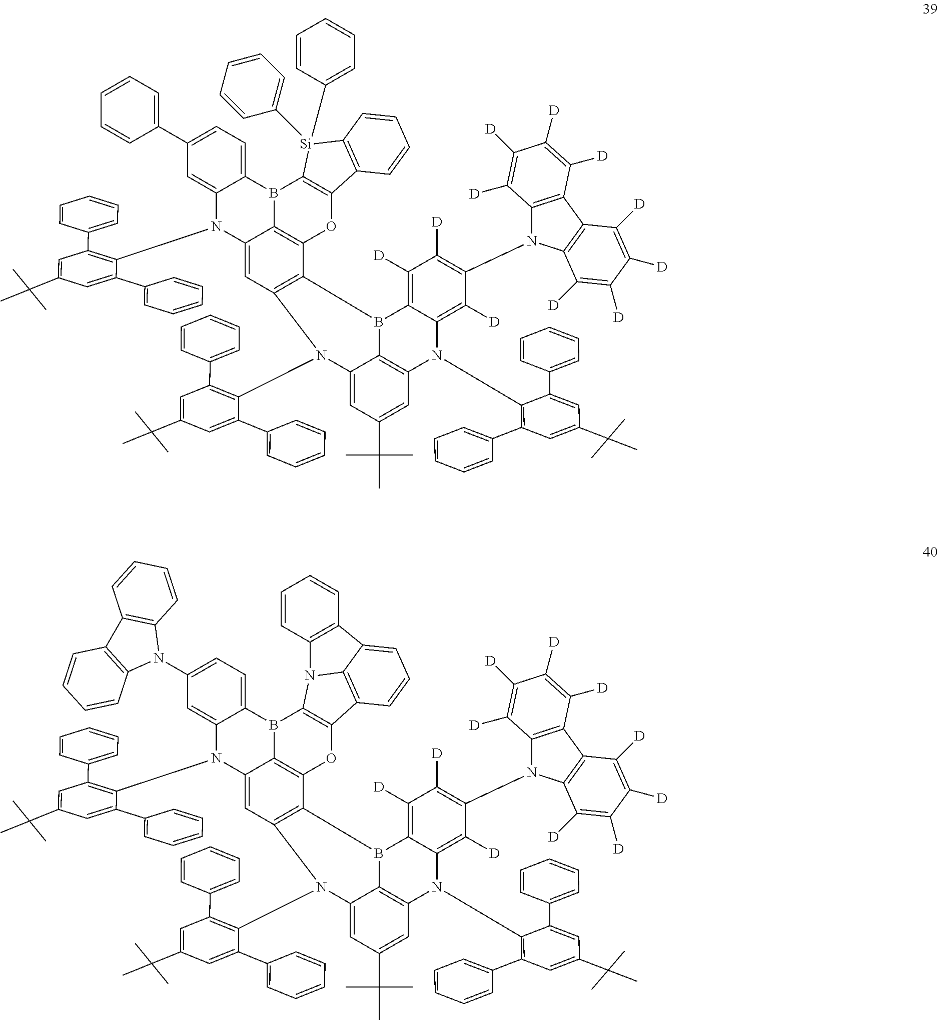

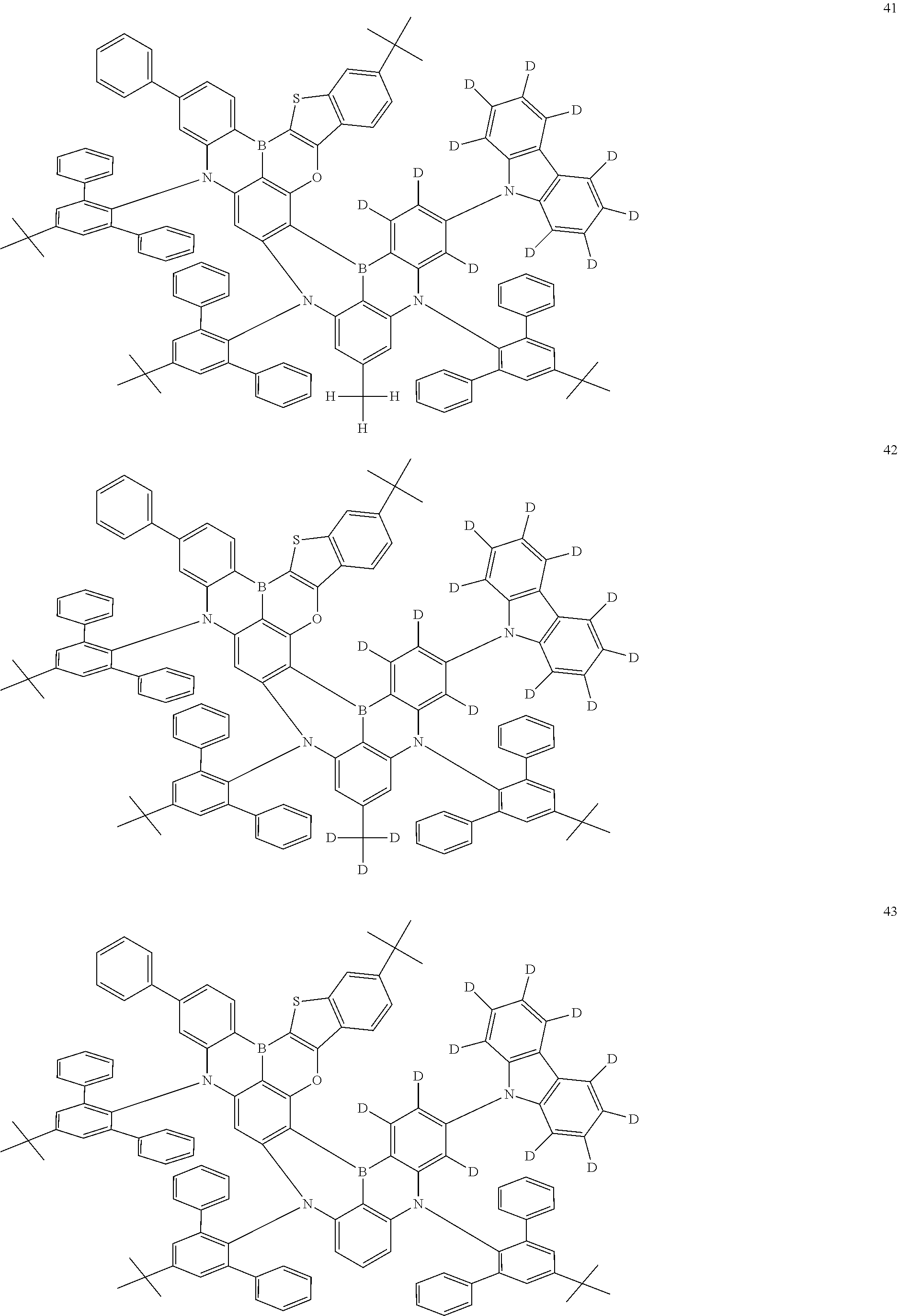

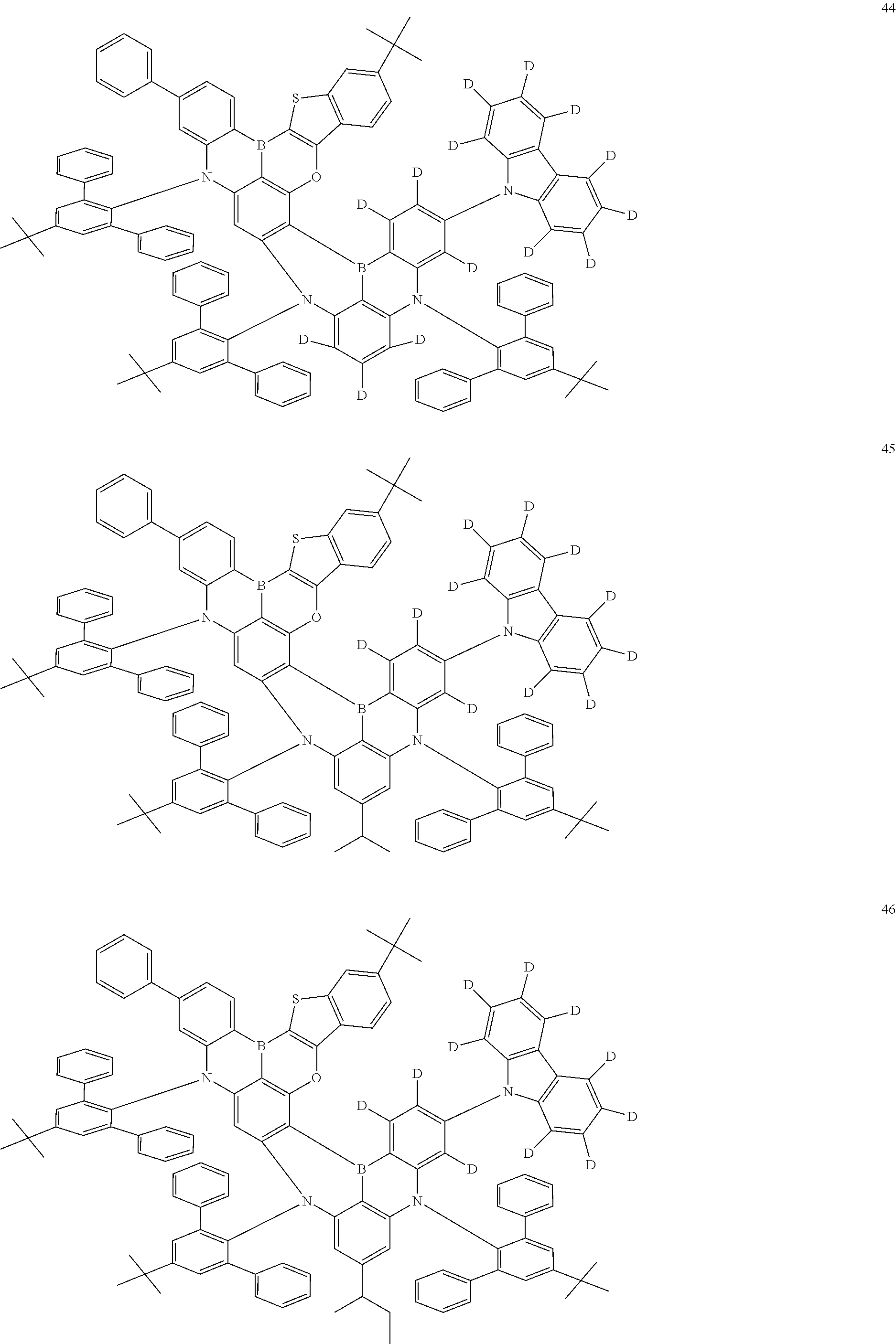

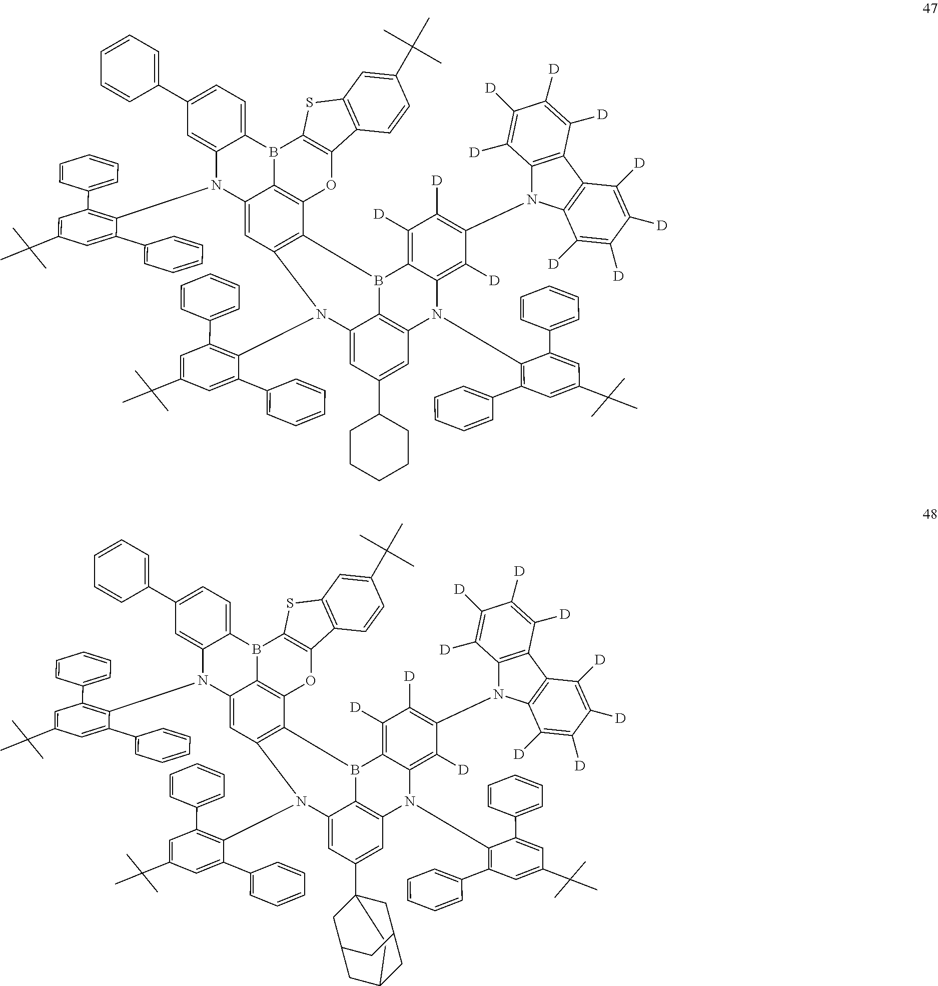

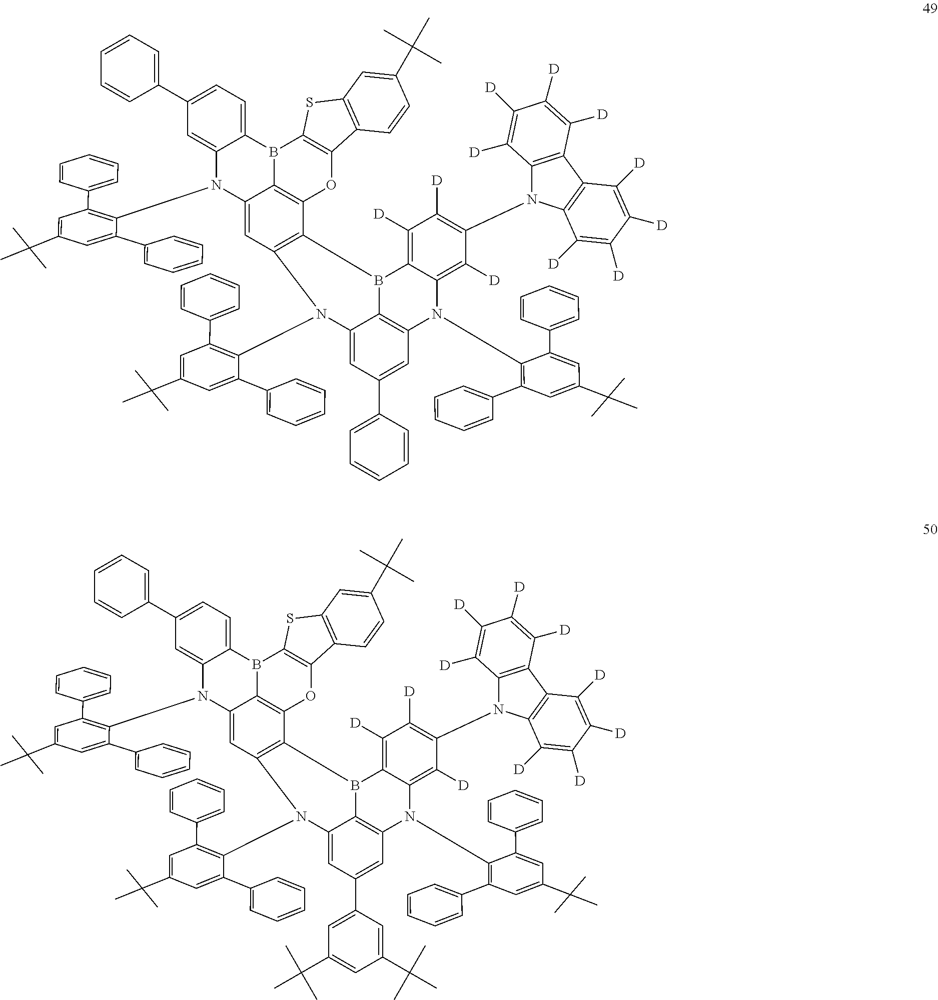

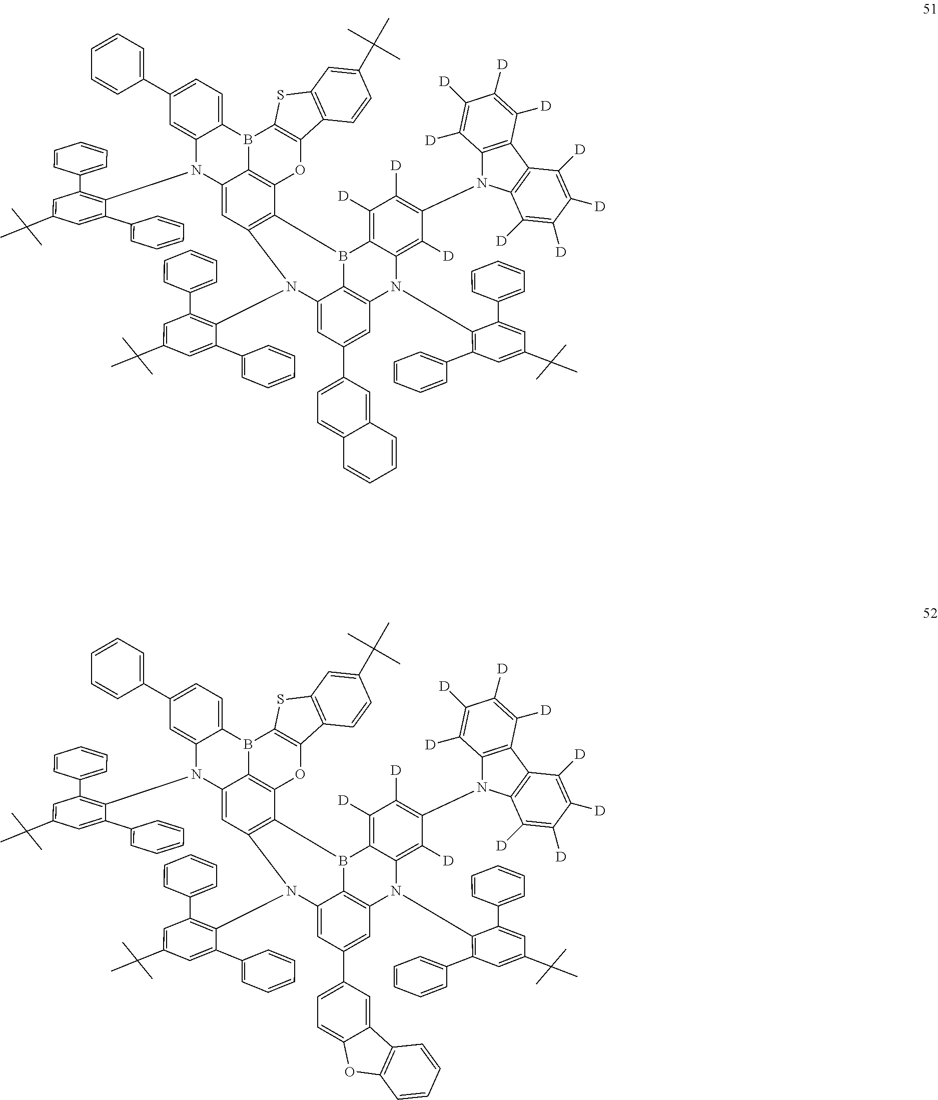

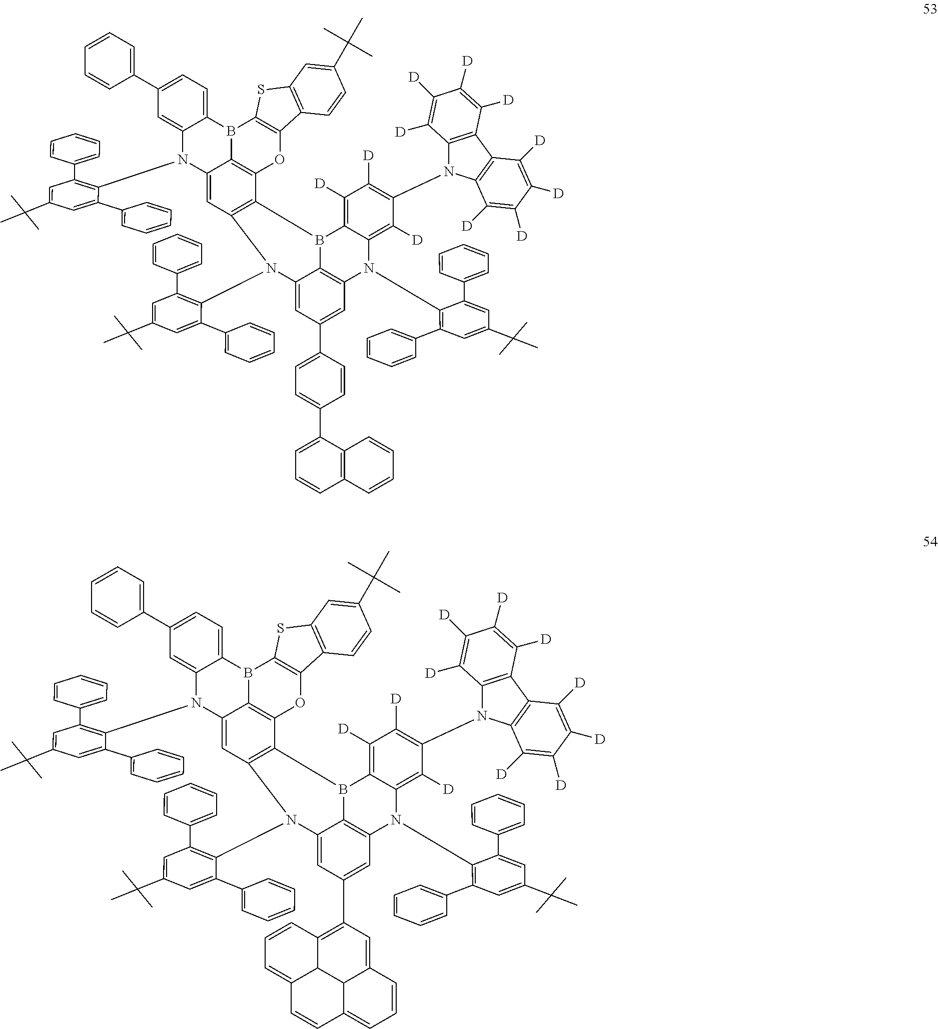

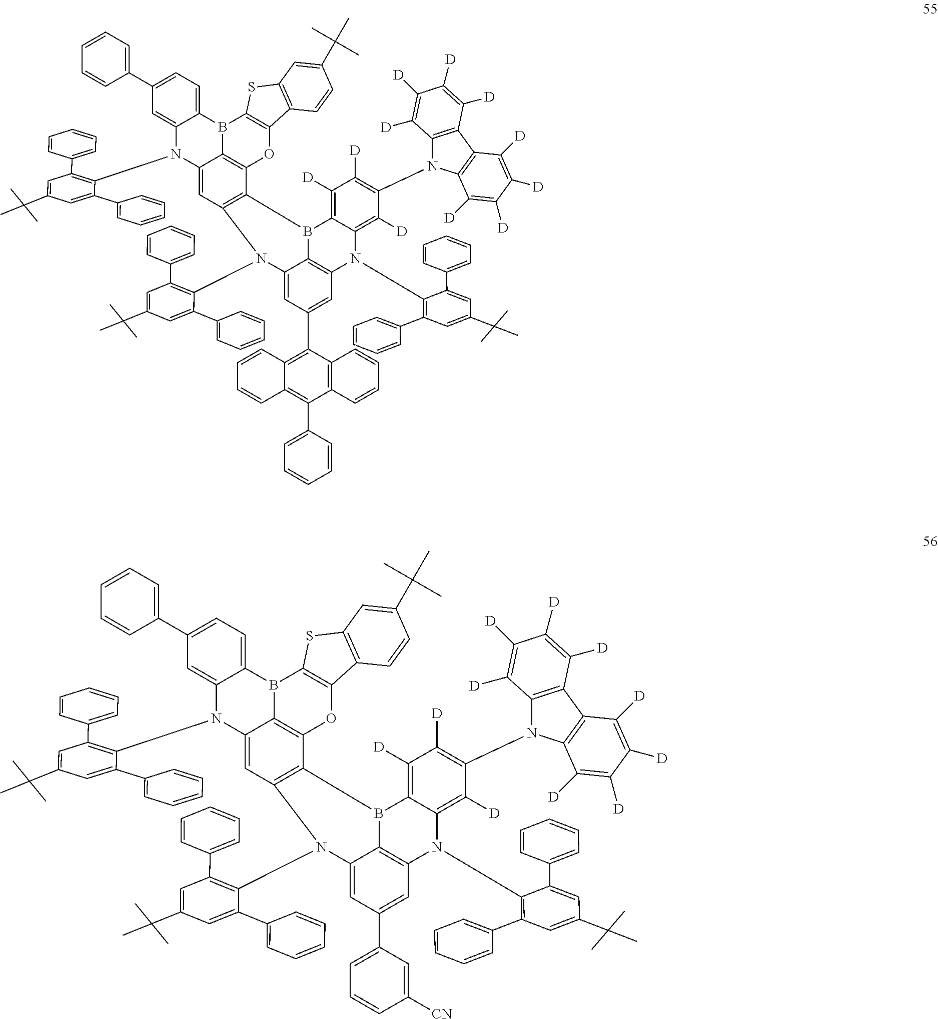

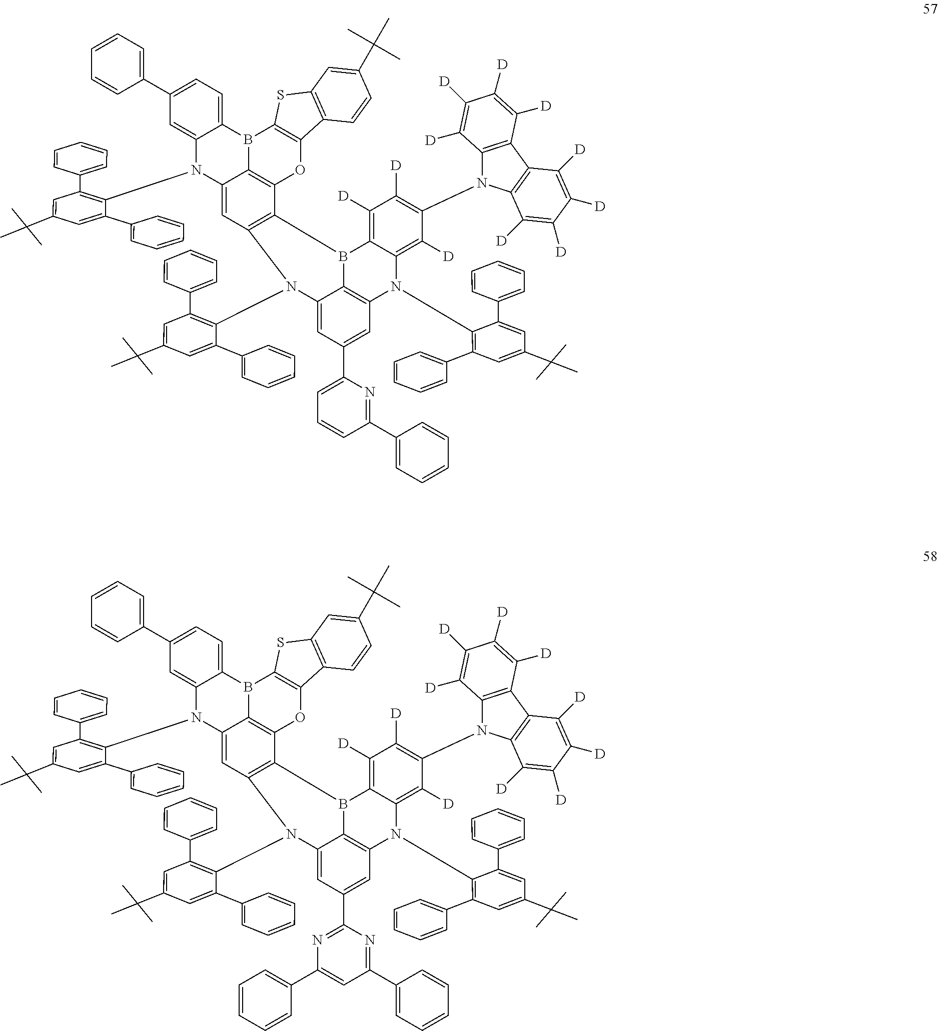

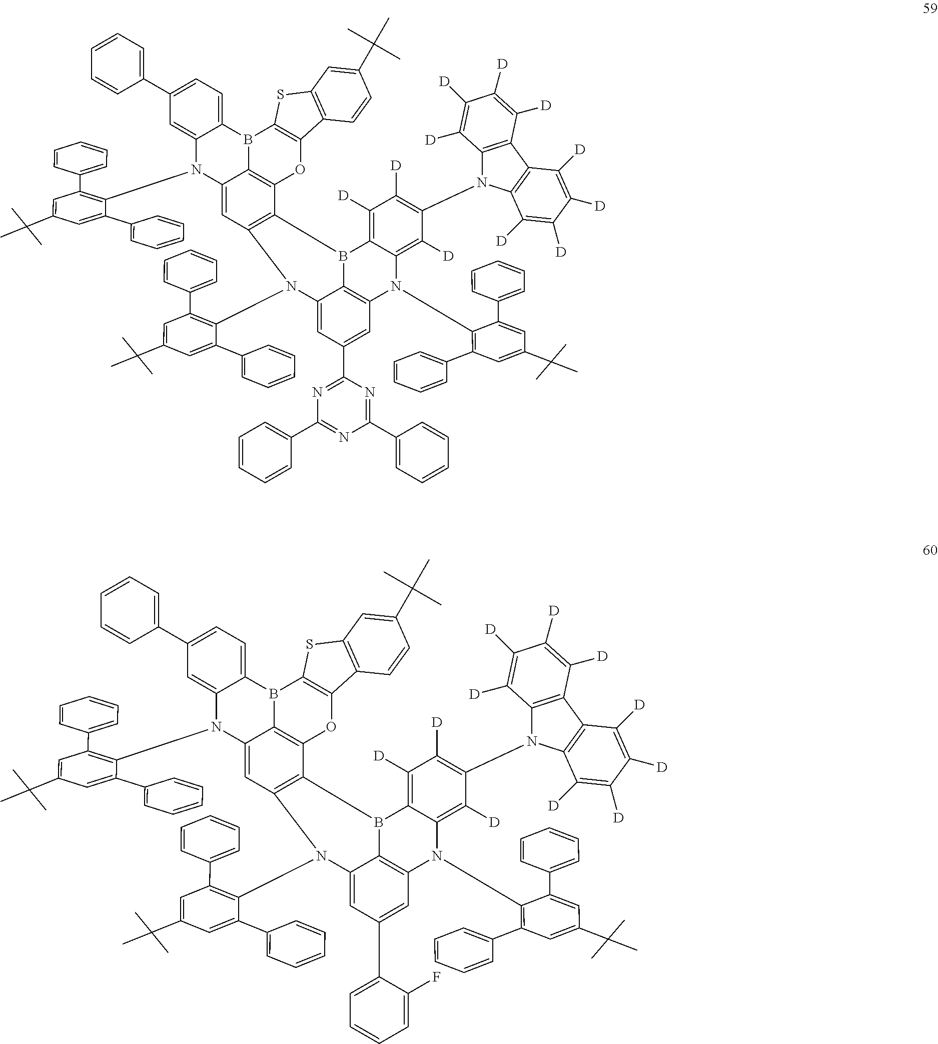

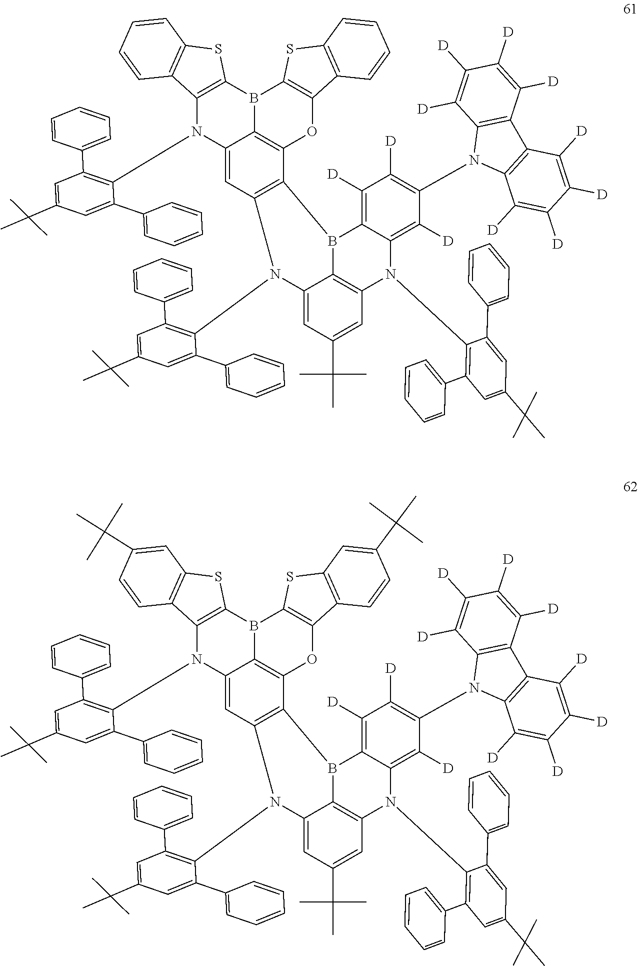

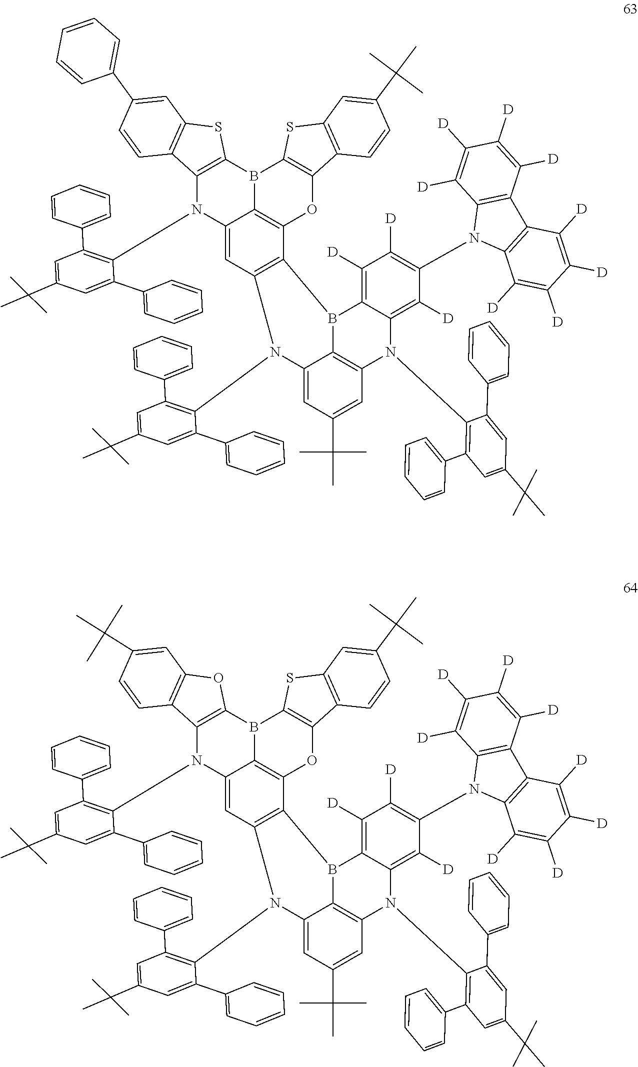

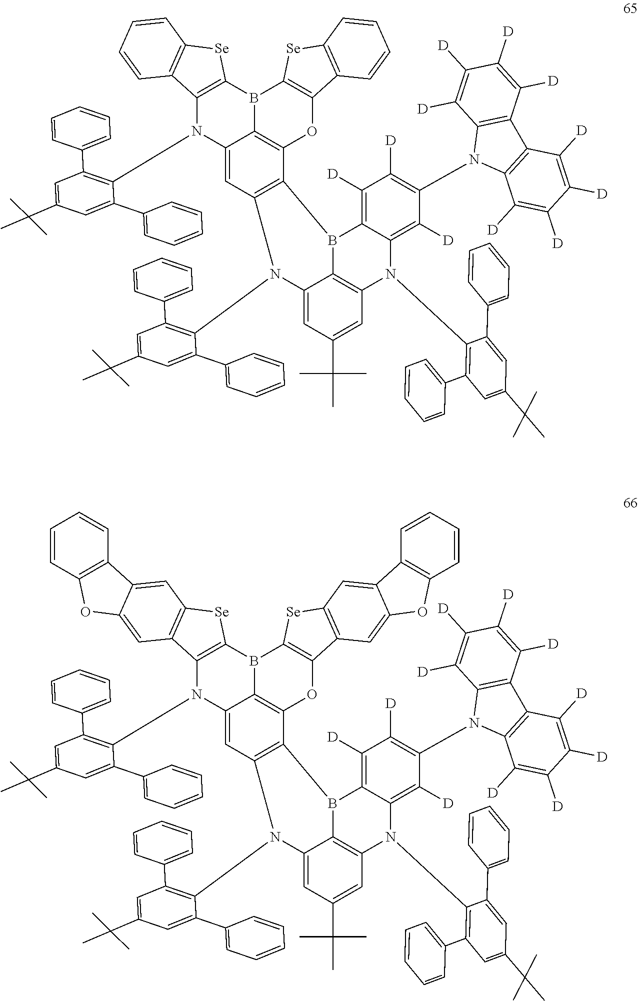

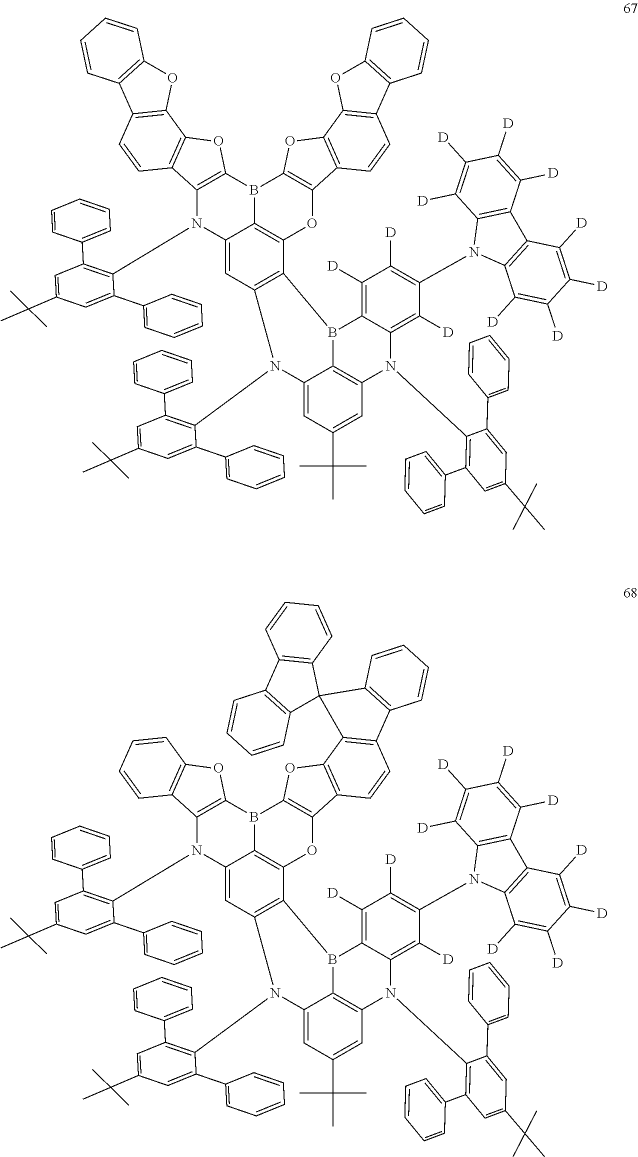

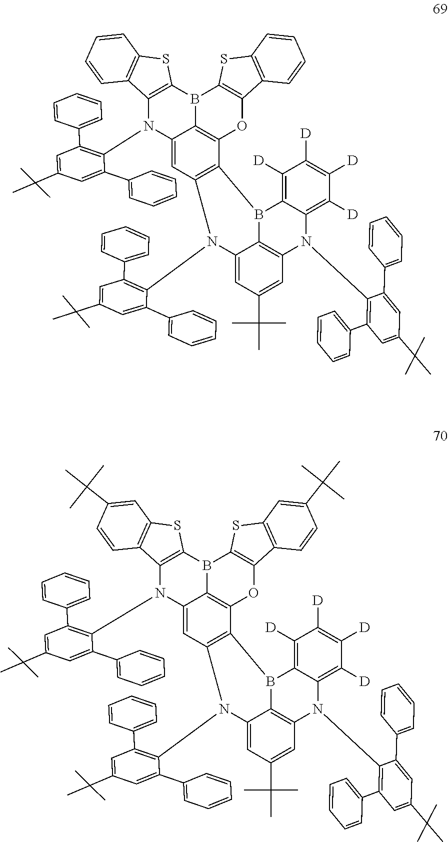

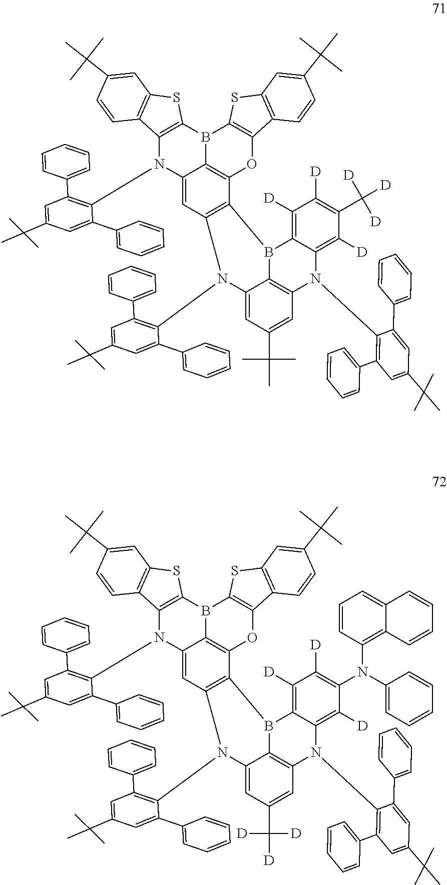

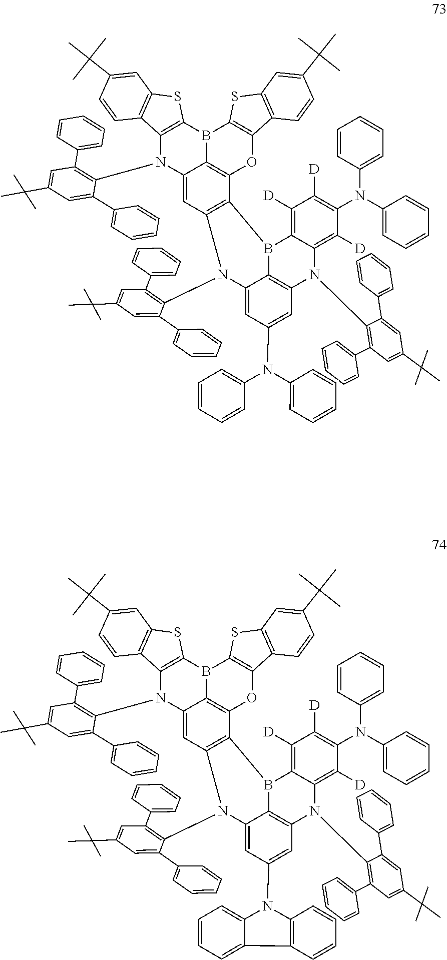

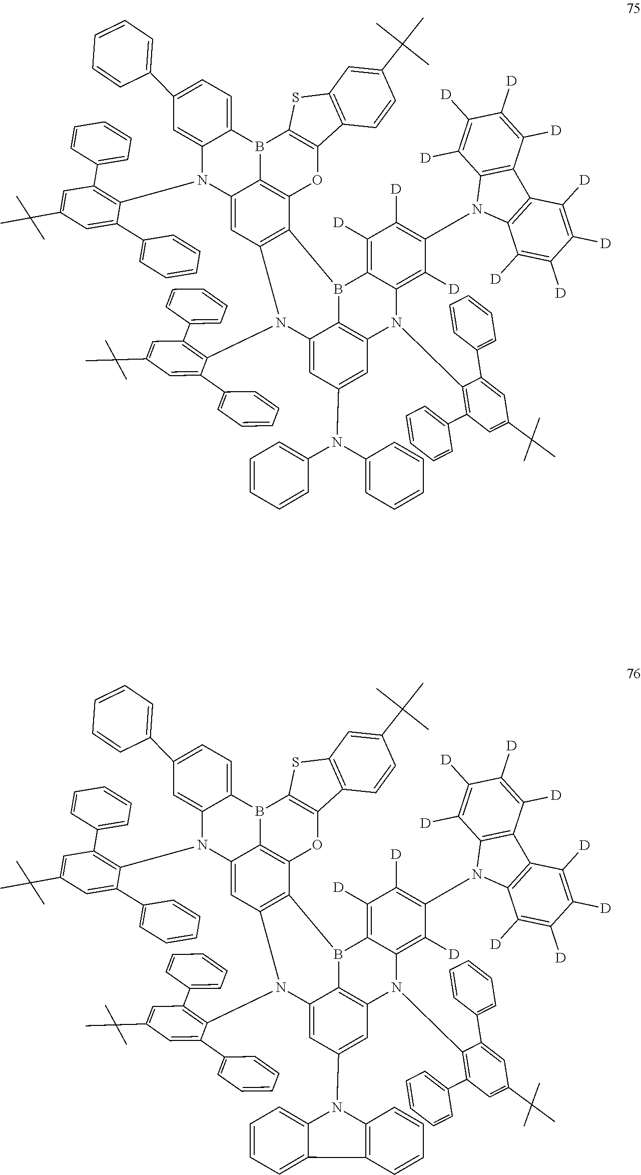

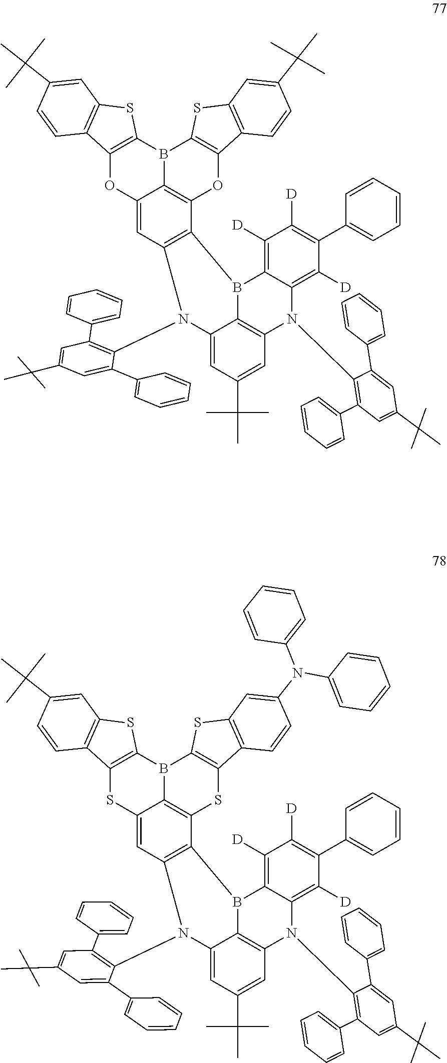

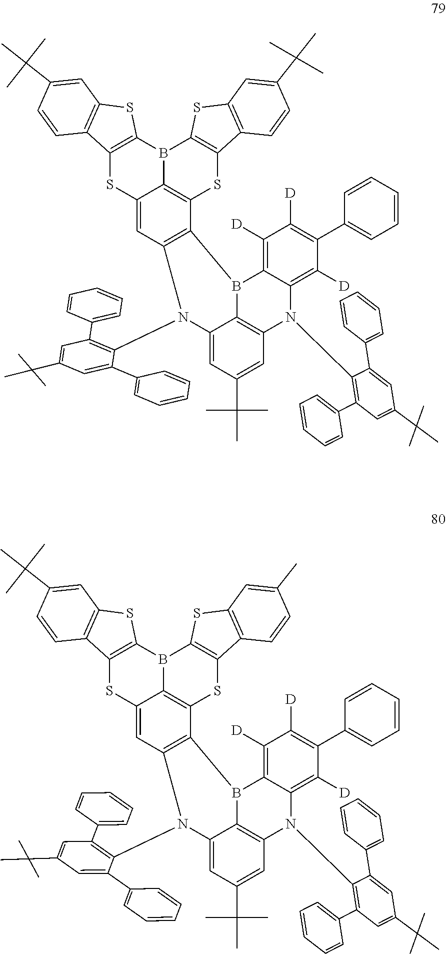

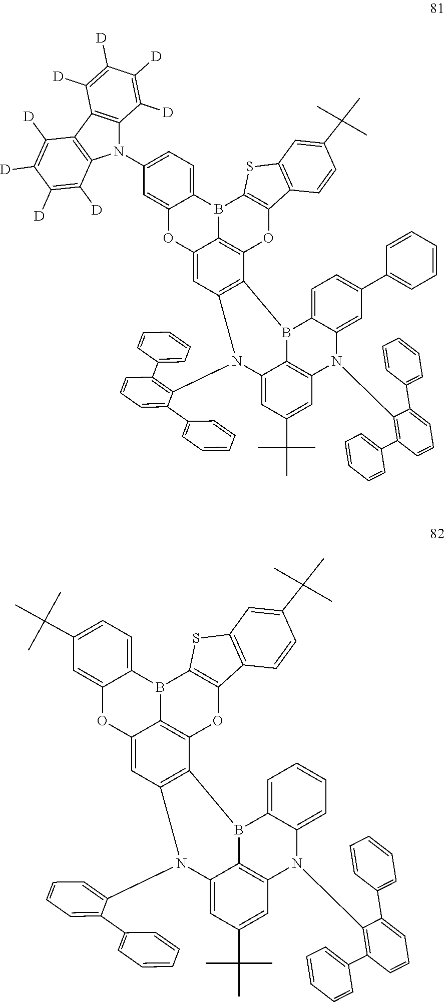 [SMILES: [2H]c1c([2H])c([2H])c2c(c1[2H])c1c([2H])c([2H])c([2H])c([2H])c1n2-c1ccc2c(c1)Oc1cc3c(c4c1B2c1sc2cc(C(C)(C)C)ccc2c1O4)B1c2ccc(-c4ccccc4)cc2N(c2c(-c4ccccc4)cccc2-c2ccccc2)c2cc(C(C)(C)C)cc(c21)N3c1c(-c2ccccc2)cccc1-c1ccccc1 ; CC(C)(C)c1ccc2c(c1)Oc1cc3c(c4c1B2c1sc2cc(C(C)(C)C)ccc2c1O4)B1c2ccccc2N(c2c(-c4ccccc4)cccc2-c2ccccc2)c2cc(C(C)(C)C)cc(c21)N3c1ccccc1-c1ccccc1]

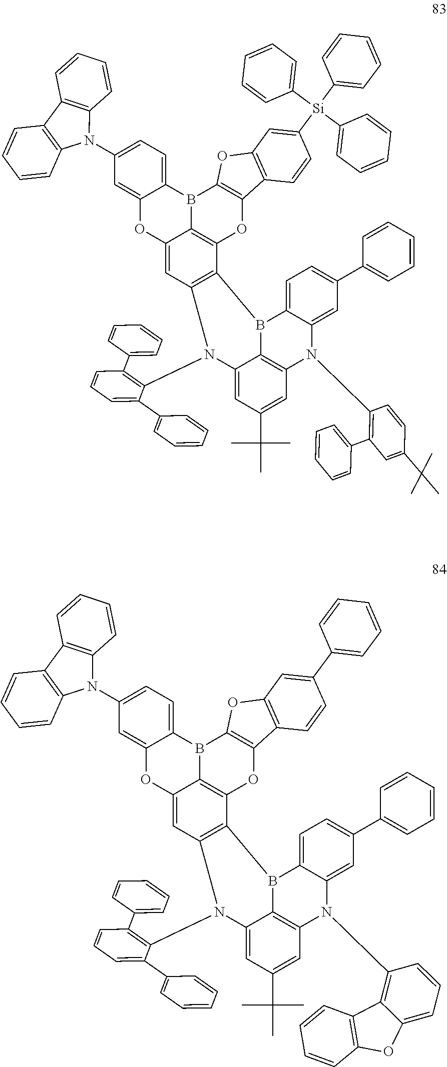 [SMILES: CC(C)(C)c1ccc(N2c3cc(-c4ccccc4)ccc3B3c4c2cc(C(C)(C)C)cc4N(c2c(-c4ccccc4)cccc2-c2ccccc2)c2cc4c5c(c23)Oc2c(oc3cc([Si](c6ccccc6)(c6ccccc6)c6ccccc6)ccc23)B5c2ccc(-n3c5ccccc5c5ccccc53)cc2O4)c(-c2ccccc2)c1 ; CC(C)(C)c1cc2c3c(c1)N(c1cccc4oc5ccccc5c14)c1cc(-c4ccccc4)ccc1B3c1c(cc3c4c1Oc1c(oc5cc(-c6ccccc6)ccc15)B4c1ccc(-n4c5ccccc5c5ccccc54)cc1O3)N2c1c(-c2ccccc2)cccc1-c1ccccc1]

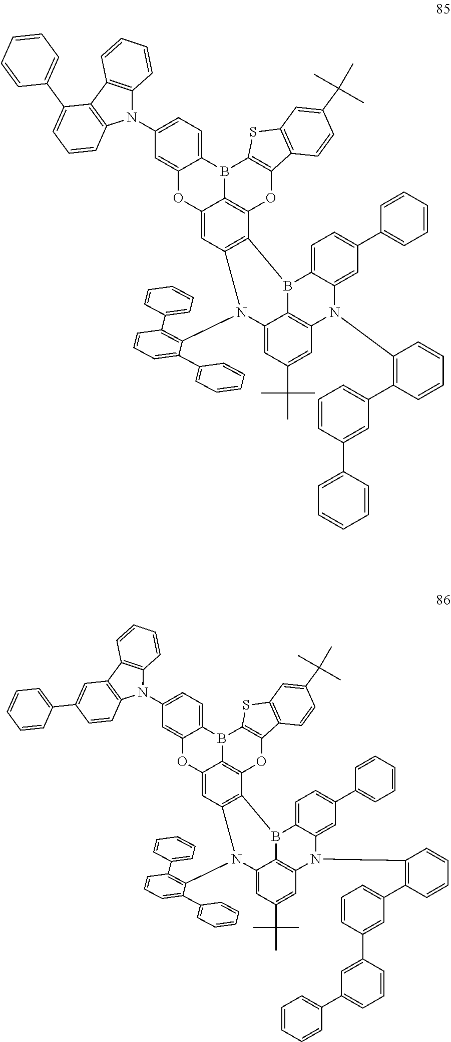 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1ccccc1-c1cccc(-c2ccccc2)c1)Oc1c(sc2cc(C(C)(C)C)ccc12)B5c1ccc(-n2c3ccccc3c3c(-c5ccccc5)cccc32)cc1O4 ; CC(C)(C)c1cc2c3c(c1)N(c1c(-c4ccccc4)cccc1-c1ccccc1)c1cc4c5c(c1B3c1ccc(-c3ccccc3)cc1N2c1ccccc1-c1cccc(-c2cccc(-c3ccccc3)c2)c1)Oc1c(sc2cc(C(C)(C)C)ccc12)B5c1ccc(-n2c3ccccc3c3cc(-c5ccccc5)ccc32)cc1O4]

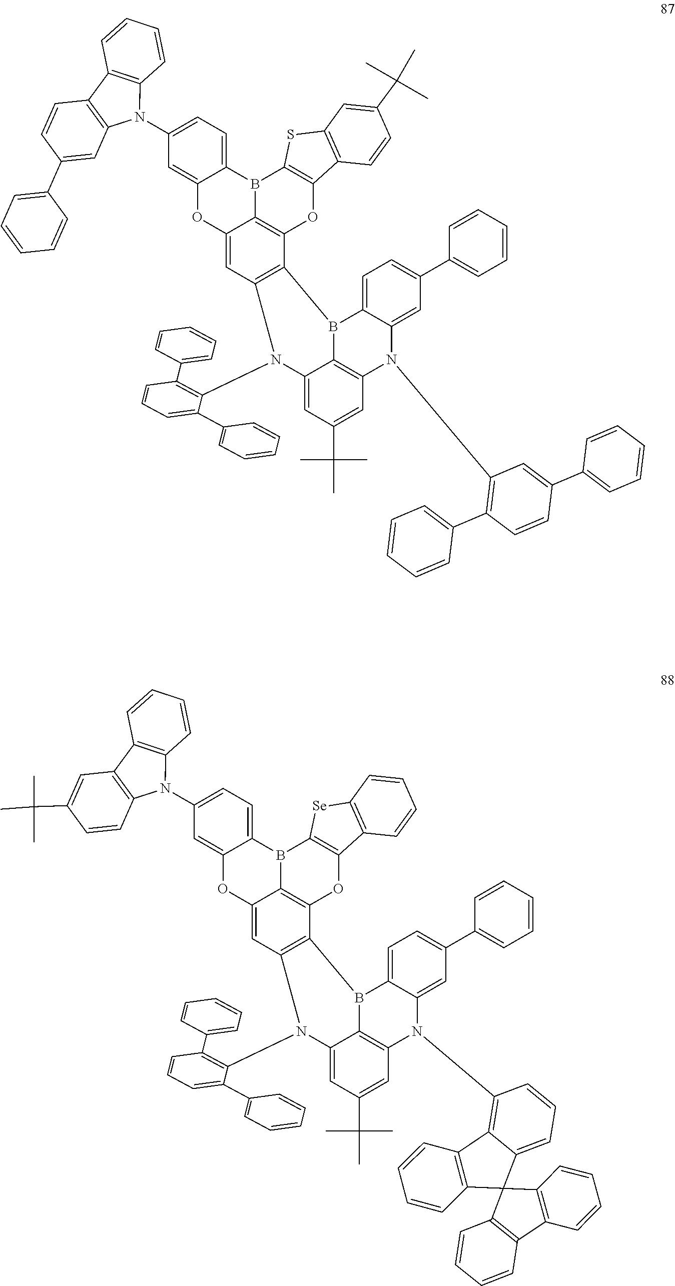 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1cc(-c2ccccc2)ccc1-c1ccccc1)Oc1c(sc2cc(C(C)(C)C)ccc12)B5c1ccc(-n2c3ccccc3c3ccc(-c5ccccc5)cc32)cc1O4 ; CC(C)(C)c1cc2c3c(c1)N(c1c(-c4ccccc4)cccc1-c1ccccc1)c1cc4c5c(c1B3c1ccc(-c3ccccc3)cc1N2c1cccc2c1-c1ccccc1C21c2ccccc2-c2ccccc21)Oc1c([se]c2ccccc12)B5c1ccc(-n2c3ccccc3c3cc(C(C)(C)C)ccc32)cc1O4]

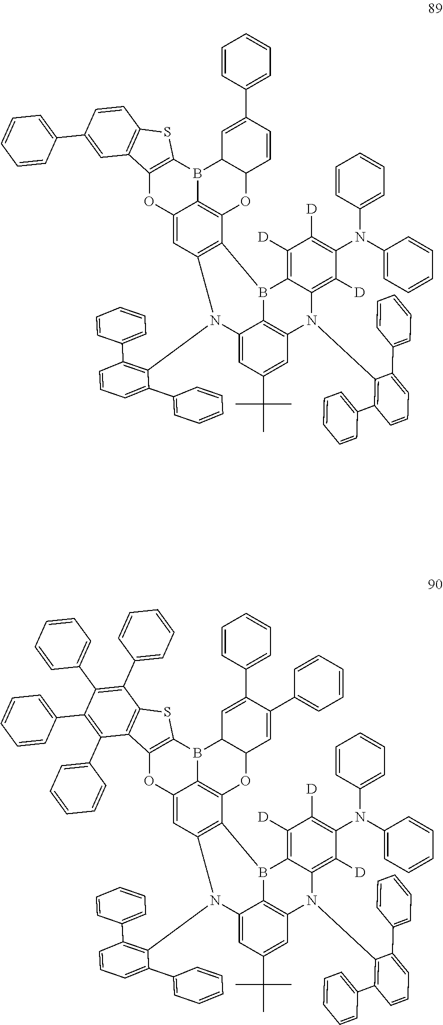 [SMILES: [2H]c1c([2H])c(N(c2ccccc2)c2ccccc2)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)OC1C=CC(c2ccccc2)=CC1B4c1sc2ccc(-c4ccccc4)cc2c1O3 ; [2H]c1c([2H])c(N(c2ccccc2)c2ccccc2)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)OC1C=C(c2ccccc2)C(c2ccccc2)=CC1B4c1sc2c(-c4ccccc4)c(-c4ccccc4)c(-c4ccccc4)c(-c4ccccc4)c2c1O3]

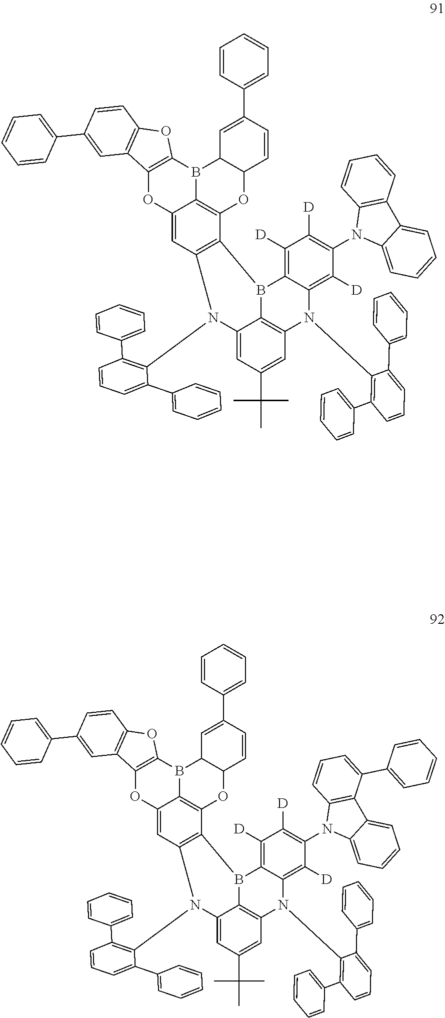 [SMILES: [2H]c1c([2H])c(-n2c3ccccc3c3ccccc32)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)OC1C=CC(c2ccccc2)=CC1B4c1oc2ccc(-c4ccccc4)cc2c1O3 ; [2H]c1c([2H])c(-n2c3ccccc3c3c(-c4ccccc4)cccc32)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)OC1C=CC(c2ccccc2)=CC1B4c1oc2ccc(-c4ccccc4)cc2c1O3]

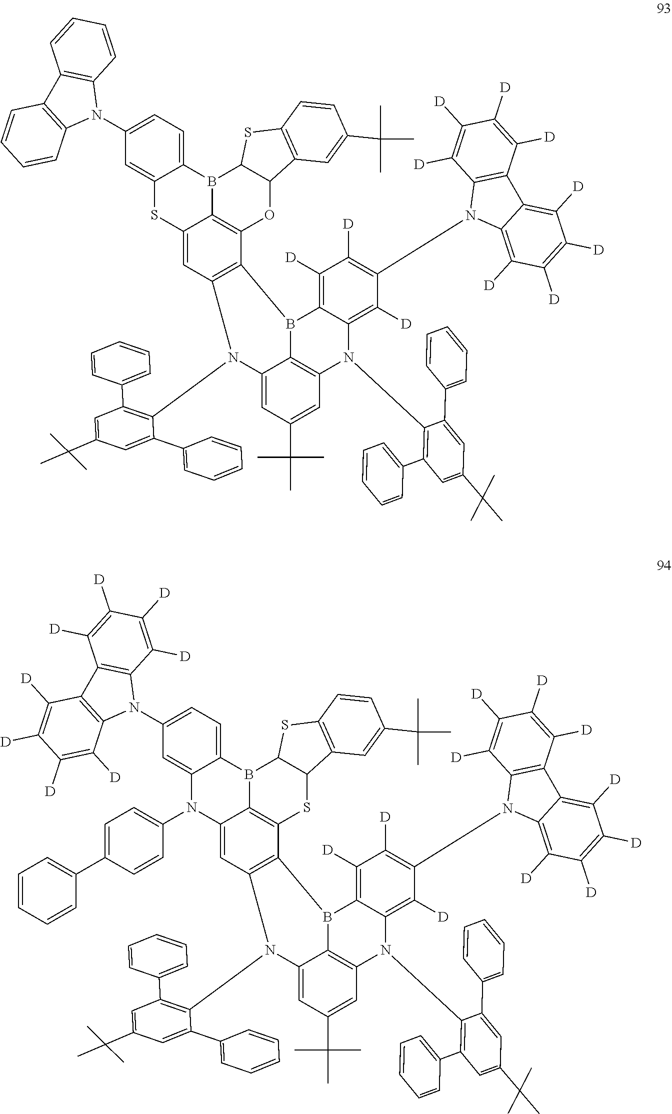

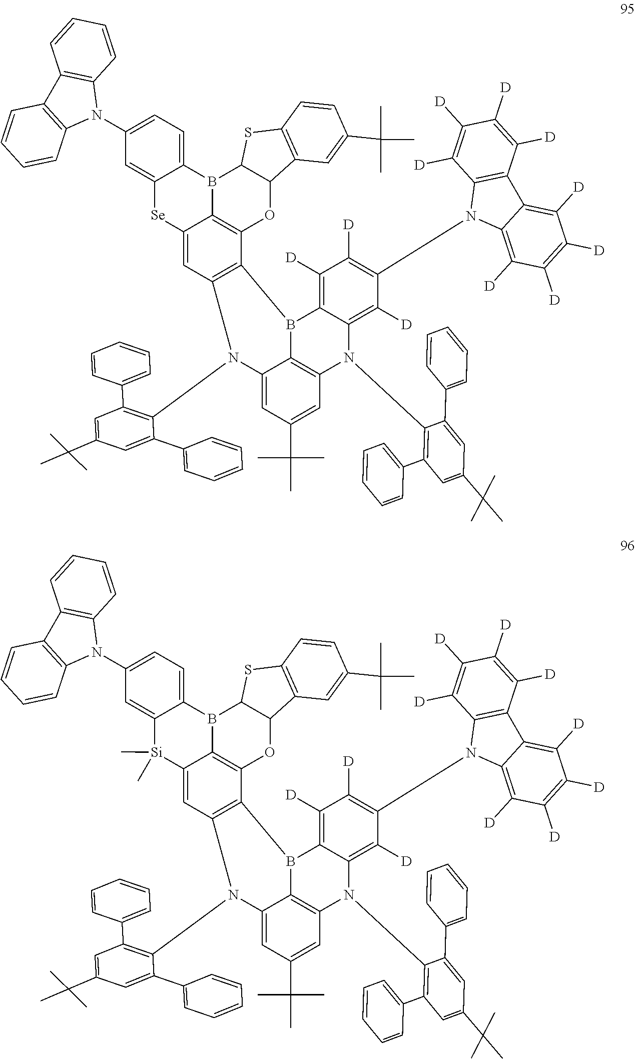

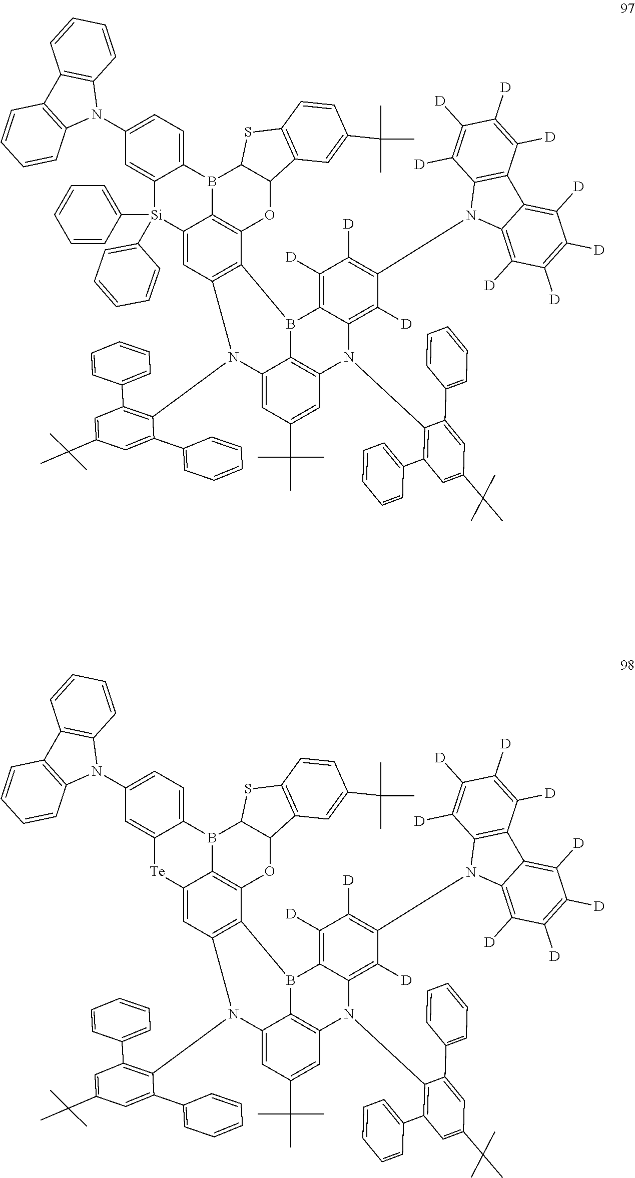

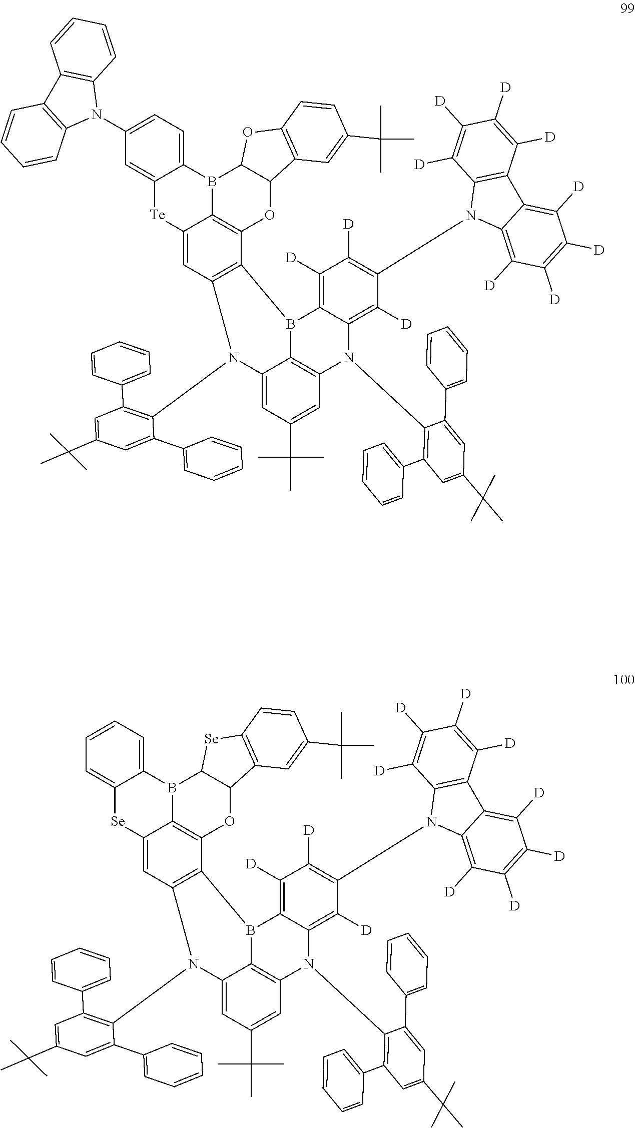

In Compound Group 1, D represents a deuterium atom.

In an embodiment, the fused polycyclic compound may have a full width at half maximum (FWHM) of an emission spectrum in a range of about 20 nm to about 40 nm. For example, the fused polycyclic compound may have an FWHM of an emission spectrum in a range of about 20 nm to about 30 nm. Since the emission spectrum of the fused polycyclic compound represented by Formula 1 has an FWHM in the range described above, excellent color purity may be exhibited when the fused polycyclic compound is applied as a dopant material.

In an embodiment, the fused polycyclic compound may be a thermally activated delayed fluorescence emission material. In an embodiment, the fused polycyclic compound may be a thermally activated delayed fluorescent dopant which has gap (ΔE_{ST}) between a lowest triplet excited energy level (T1 level) and a lowest singlet excited energy level (S1 level) equal to or less than about 0.2 eV.

In an embodiment, the fused polycyclic compound may include a first substituent and a second substituent. By adjusting a quantity, a bonding position, and the like of each of the first substituent and the second substituent, the singlet energy level and the triplet energy level of the fused polycyclic compound may be adjusted accordingly. Therefore, the fused polycyclic compound according to an embodiment may exhibit improved properties of thermally activated delayed fluorescence. However, embodiments are not limited thereto. The fused polycyclic compound represented by Formula 1 may be applied to both a phosphorescent element and a fluorescent element. For example, when a carbazole derivative substituent is included in at least one of the MR core and the CT core, the fused polycyclic compound may exhibit suitable properties as a thermally activated delayed fluorescent (TADF) material. In an embodiment, in the fused polycyclic compound, when an arylamine derivative substituent (e.g., a diphenylamine derivative) is included in at least one of the MR core and the CT core, the fused polycyclic compound may exhibit suitable properties as a fluorescent material. However, embodiments are not limited thereto.

In an embodiment, the fused polycyclic compound may be an emission material having a peak emission wavelength in a range of about 430 nm to about 490 nm. For example, the fused polycyclic compound according to an embodiment may be a blue thermally activated delayed fluorescent (TADF) dopant. However, embodiments are not limited thereto, and the fused polycyclic compound according to an embodiment may be used as a phosphorescent dopant material or a fluorescent dopant material. If the fused polycyclic compound is used as an emission material, it may be used as a dopant material that emits light in various wavelength regions, such as a red light emitting dopant or a green light emitting dopant.

In the light-emitting element ED according to an embodiment, the emission layer EML may emit delayed fluorescence. For example, the emission layer EML may emit thermally activated delayed fluorescence (TADF). However, embodiments are not limited thereto, and the emission layer EML may emit phosphorescence or fluorescence.

In an embodiment, the emission layer EML of the light-emitting element ED may emit blue light. For example, in an embodiment, the emission layer EML of the light-emitting element ED may emit blue light in a wavelength equal to or less than about 490 nm. However, embodiments are not limited thereto, and the emission layer EML may also emit green light or red light.

In an embodiment, the emission layer EML may include the fused polycyclic compound. The emission layer EML may include the fused polycyclic compound as a dopant material. The fused polycyclic compound may be a thermally activated delayed fluorescence emission material. For example, the fused polycyclic compound according to an embodiment may be used as a thermally activated delayed fluorescence dopant. In an embodiment, in the light-emitting element ED according, the emission layer EML may include at least one compound selected from Compound Group 1 described above as a thermally activated delayed fluorescent dopant. However, a use of the fused polycyclic compound according to an embodiment is not limited thereto.

In an embodiment, the emission layer EML may include multiple compounds. The emission layer EML according to an embodiment may contain a fused polycyclic compound represented by Formula 1 as a first compound, and may further include at least one of a second compound represented by Formula HT-1, a third compound represented by Formula ET-1, and a fourth compound represented by Formula D-1.

In an embodiment, the emission layer EML may include the first compound represented by Formula 1, and may further include at least one of a second compound represented by Formula HT-1 and a third compound represented by Formula ET-1.

In an embodiment, the emission layer EML may further include a second compound represented by Formula HT-1. In an embodiment, the second compound may be used as a hole transport host material in the emission layer EML.

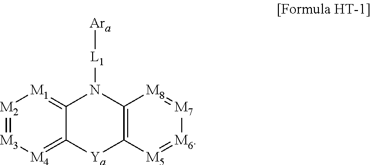

In Formula HT-1, M₁ to M₈ may each independently be N or C(R₅₁). For example, M₁ to M₈ may each independently be C(R₅₁). As another example, one of M₁ to M₈ may be N, and the remainder of M₁ to M₈ may each independently be C(R₅₁).

In Formula HT-1, L₁ may be a direct linkage, a substituted or unsubstituted arylene group having 6 to 30 ring-forming carbons, or a substituted or unsubstituted heteroarylene group having 2 to 30 ring-forming carbons. For example, L₁ may be a direct linkage, a substituted or unsubstituted phenylene group, a substituted or unsubstituted divalent biphenyl group, a substituted or unsubstituted divalent carbazole group, etc., but embodiments are not limited thereto.

In Formula HT-1, Yₐ may be a direct linkage, C(R₅₂)(R₅₃), or Si(R₅₄)(R₅₅). For example, the two benzene rings that are linked to the nitrogen atom in Formula HT-1 may be linked to each other via a direct linkage,

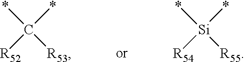

In Formula HT-1, when Yₐ is a direct linkage, the second compound represented by Formula HT-1 may include a carbazole moiety.

In Formula HT-1, Arₐ may be a substituted or unsubstituted aryl group having 6 to 30 ring-forming carbons or a substituted or unsubstituted heteroaryl group having 2 to 30 ring-forming carbons. For example, Arₐ may be a substituted or unsubstituted carbazole group, a substituted or unsubstituted dibenzofuran group, a substituted or unsubstituted dibenzothiophene group, a substituted or unsubstituted biphenyl group, etc., but embodiments are not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbons, a substituted or unsubstituted alkenyl group having 2 to 20 carbons, a substituted or unsubstituted aryl group having 6 to 60 ring-forming carbons, or a substituted or unsubstituted heteroaryl group having 2 to 60 ring-forming carbons, or bonded to an adjacent group to form a ring. For example, R₅₁ to R₅₅ may each independently be a hydrogen atom or a deuterium atom. As another example, R₅₁ to R₅₅ may each independently be an unsubstituted methyl group or an unsubstituted phenyl group.

In an embodiment, the second compound represented by Formula HT-1 may be selected from Compound Group 2. In an embodiment, in the light-emitting element ED, the second compound may include at least one compound selected from Compound Group 2:

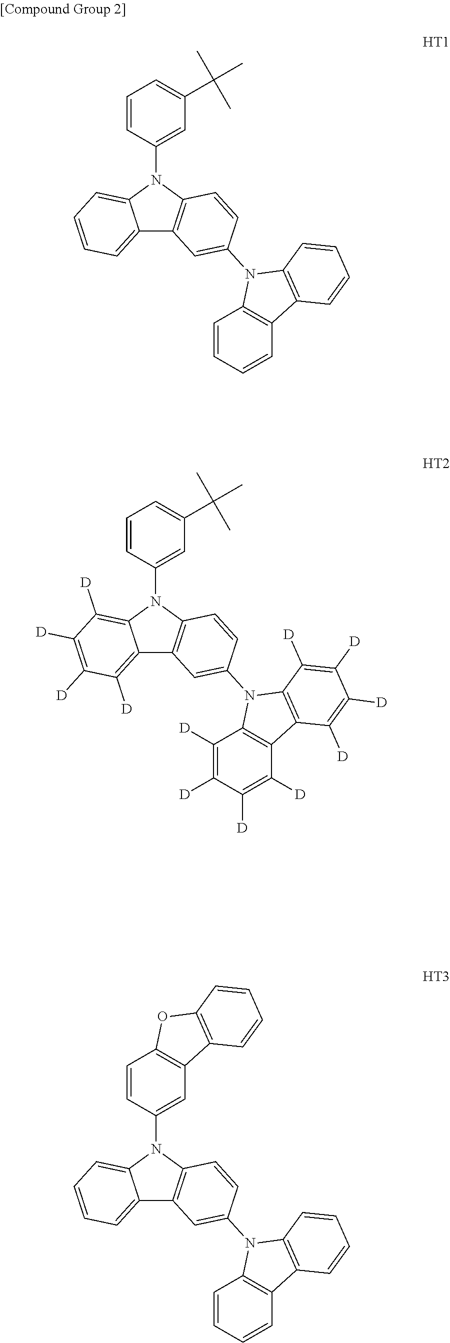 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

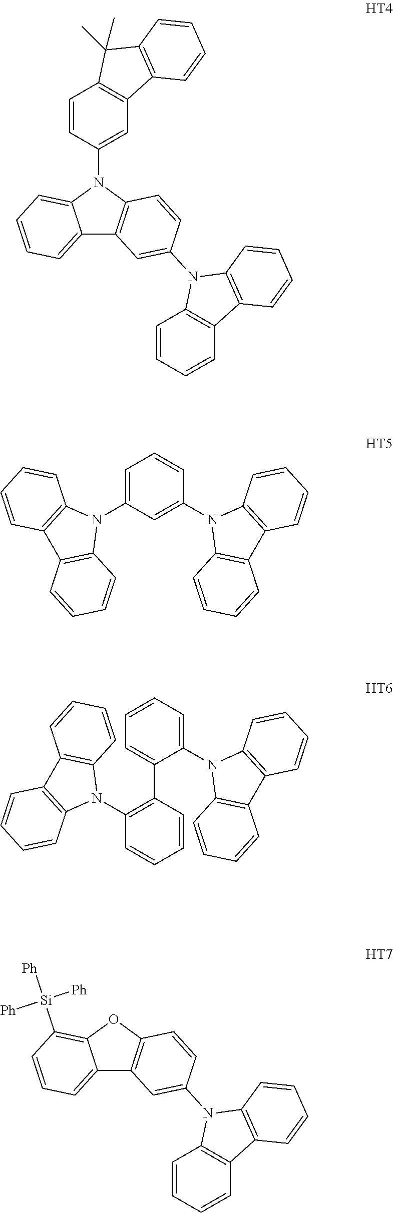 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

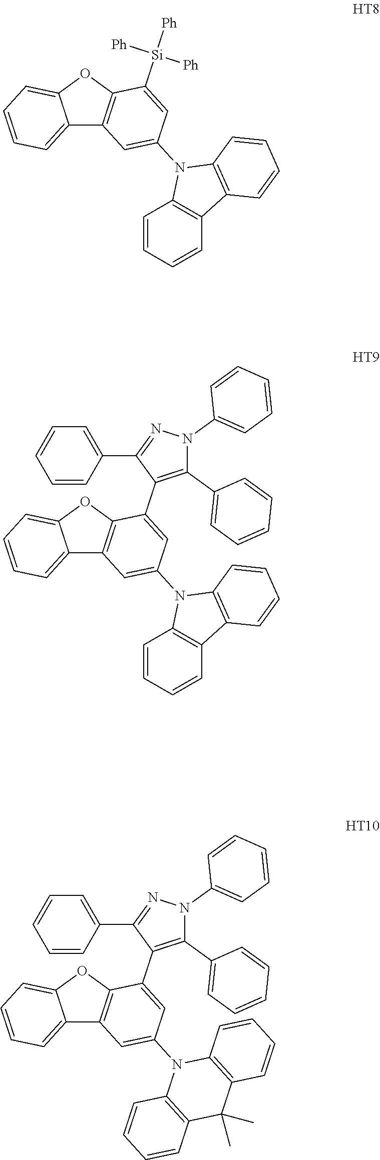 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21]

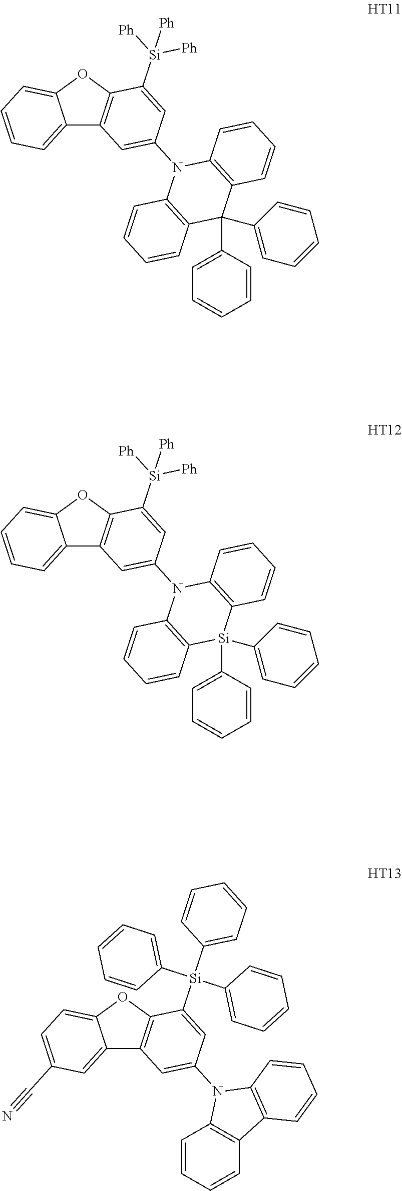 [SMILES: c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1]

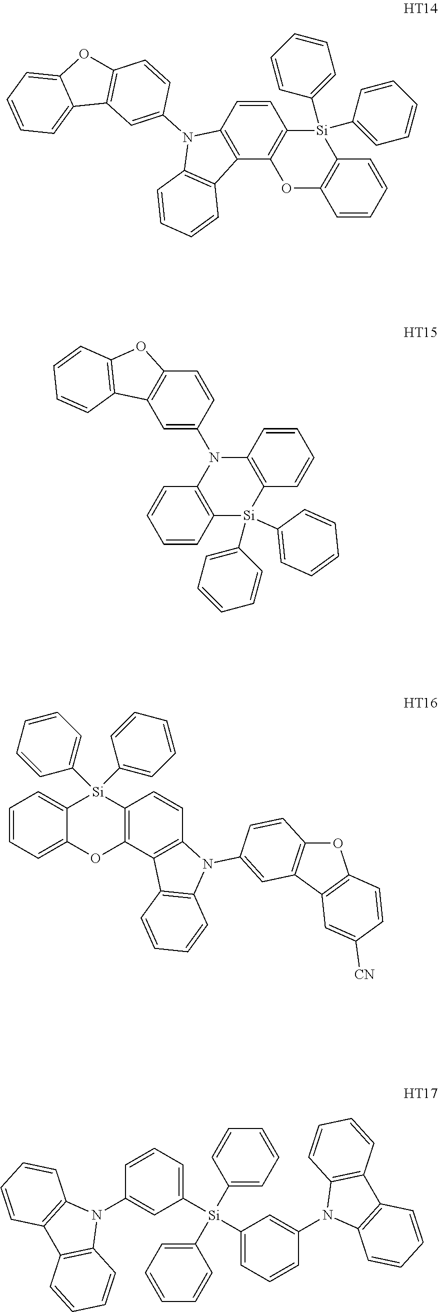 [SMILES: c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1]

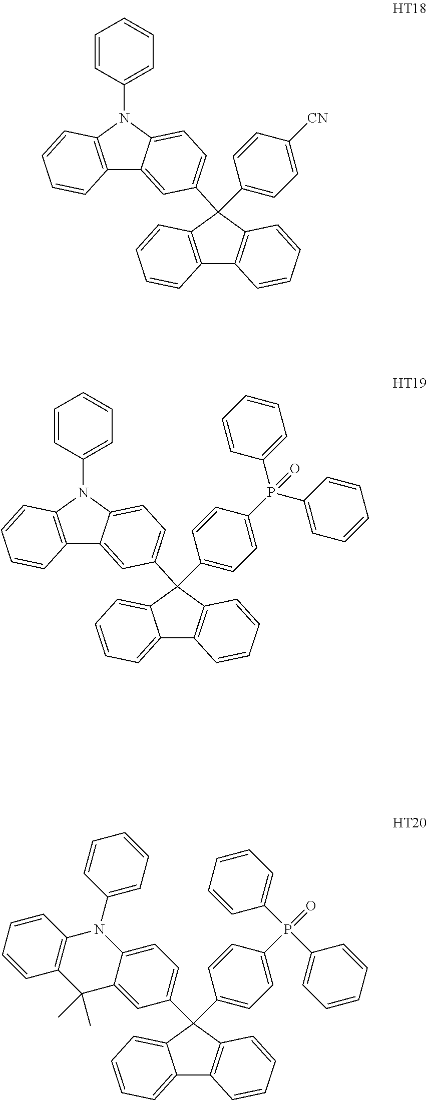 [SMILES: N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21]

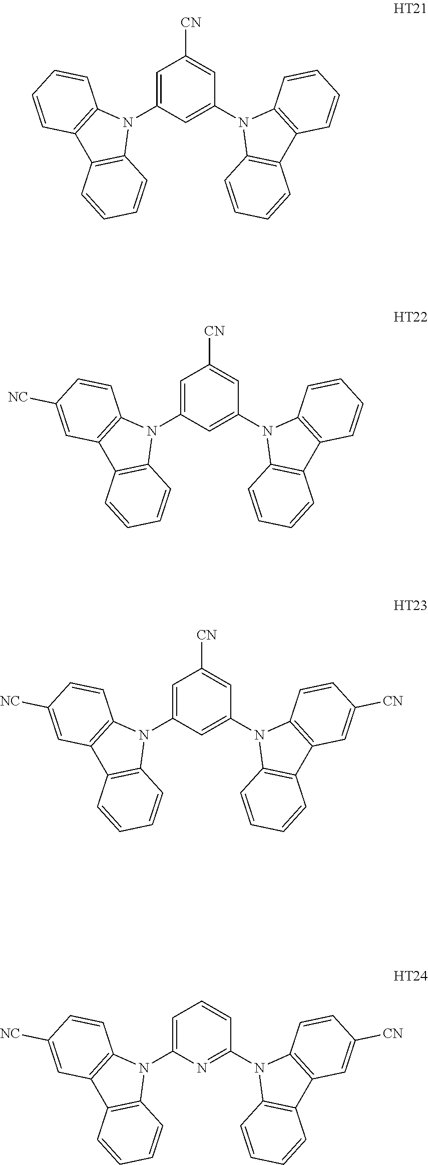 [SMILES: N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1]

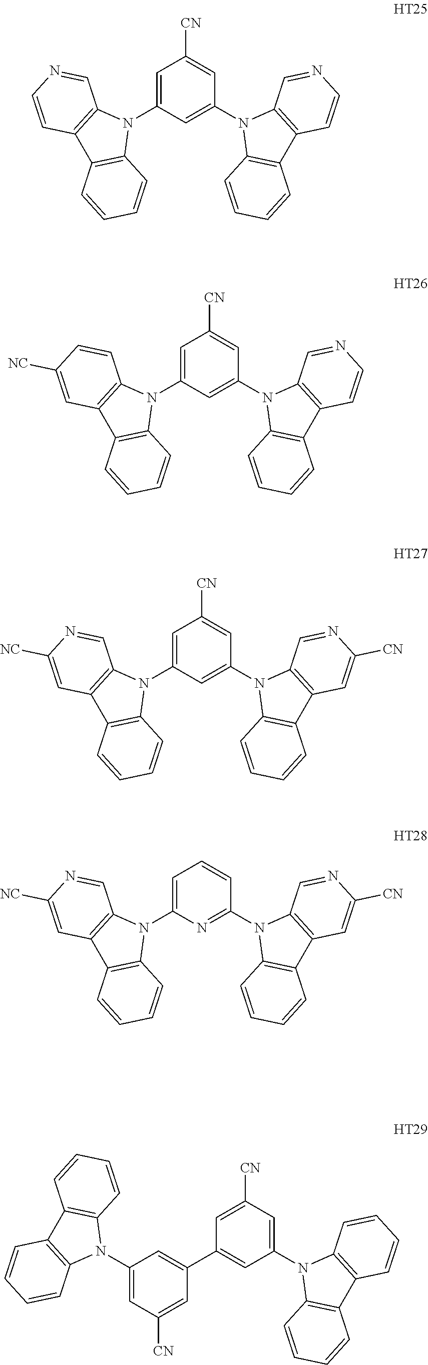 [SMILES: N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1]

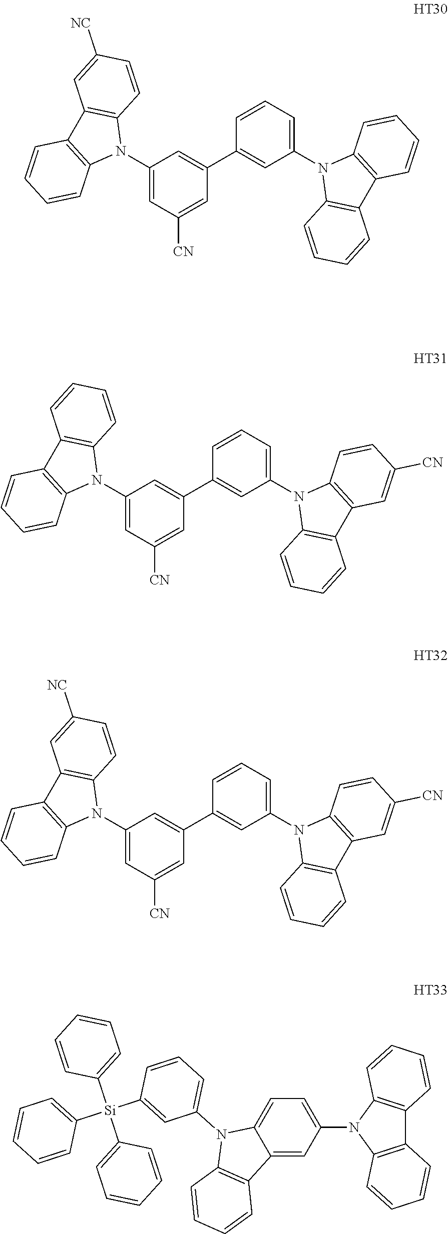 [SMILES: N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1]

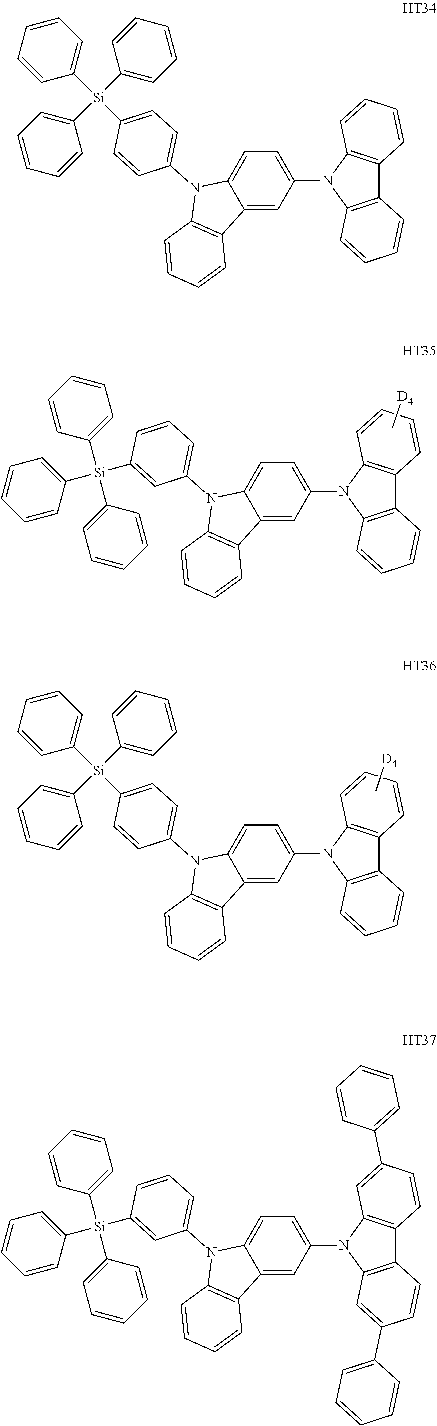

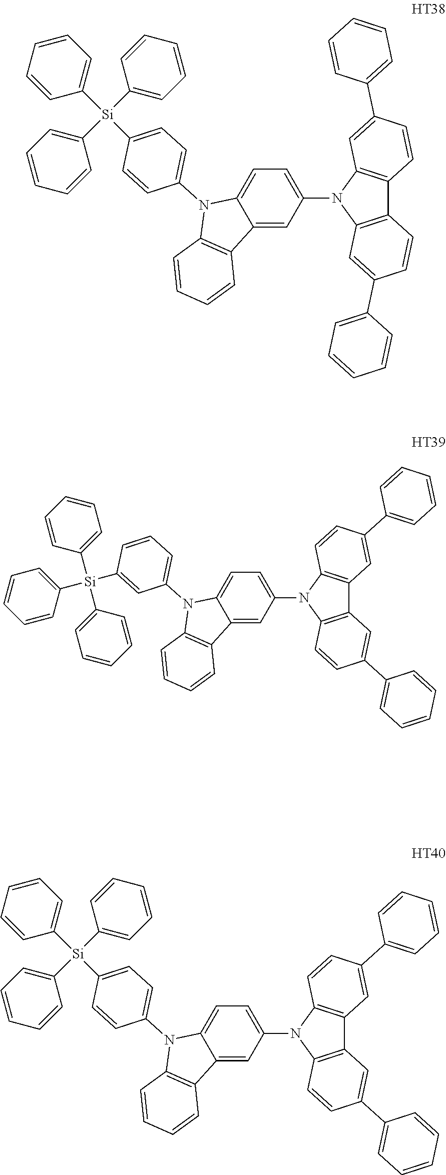 [SMILES: c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1]

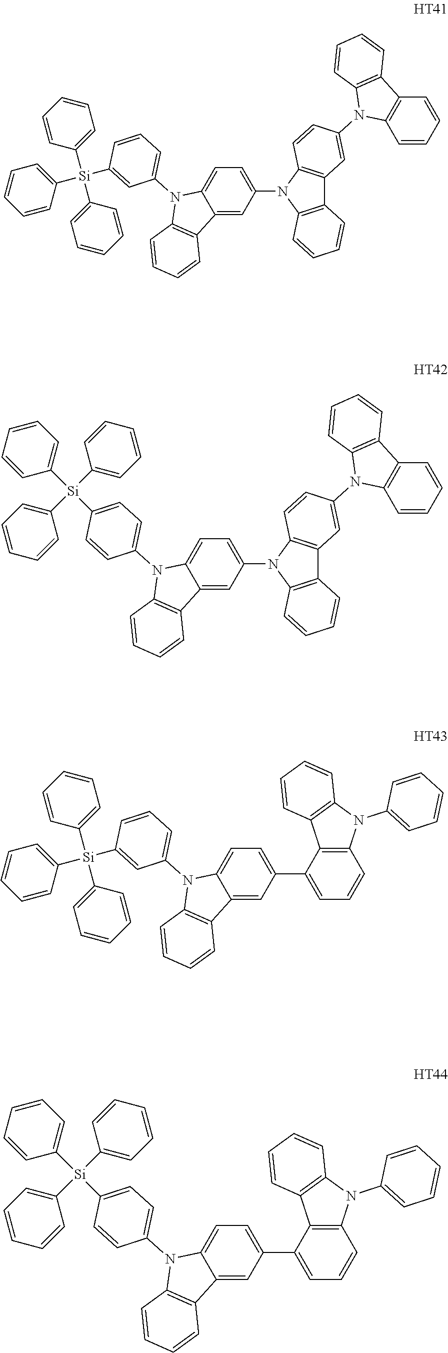 [SMILES: c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1 ; c1ccc(-n2c3ccccc3c3c(-c4ccc5c(c4)c4ccccc4n5-c4cccc([Si](c5ccccc5)(c5ccccc5)c5ccccc5)c4)cccc32)cc1 ; c1ccc(-n2c3ccccc3c3c(-c4ccc5c(c4)c4ccccc4n5-c4ccc([Si](c5ccccc5)(c5ccccc5)c5ccccc5)cc4)cccc32)cc1]

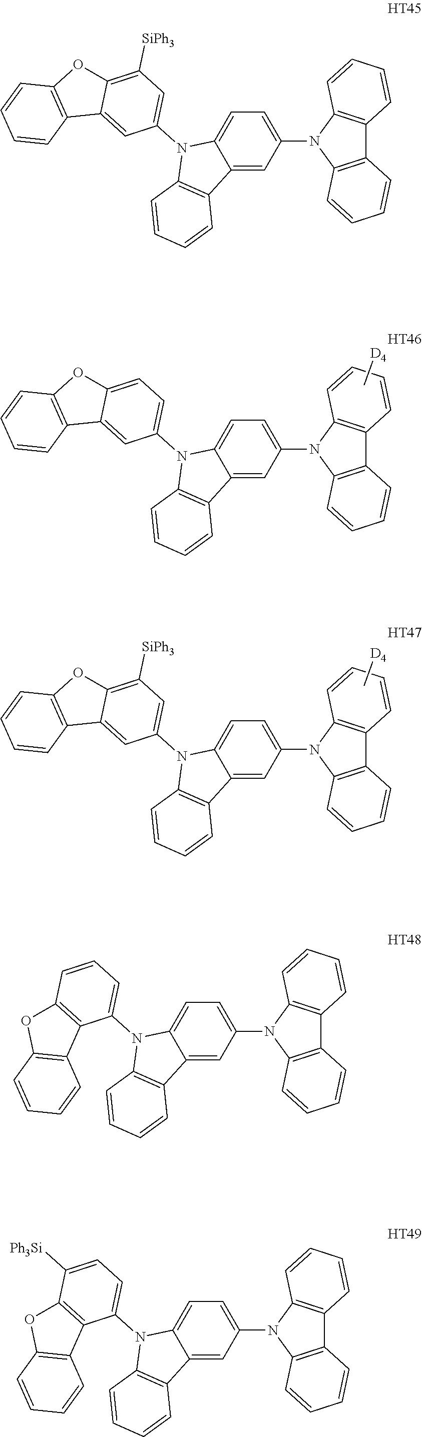

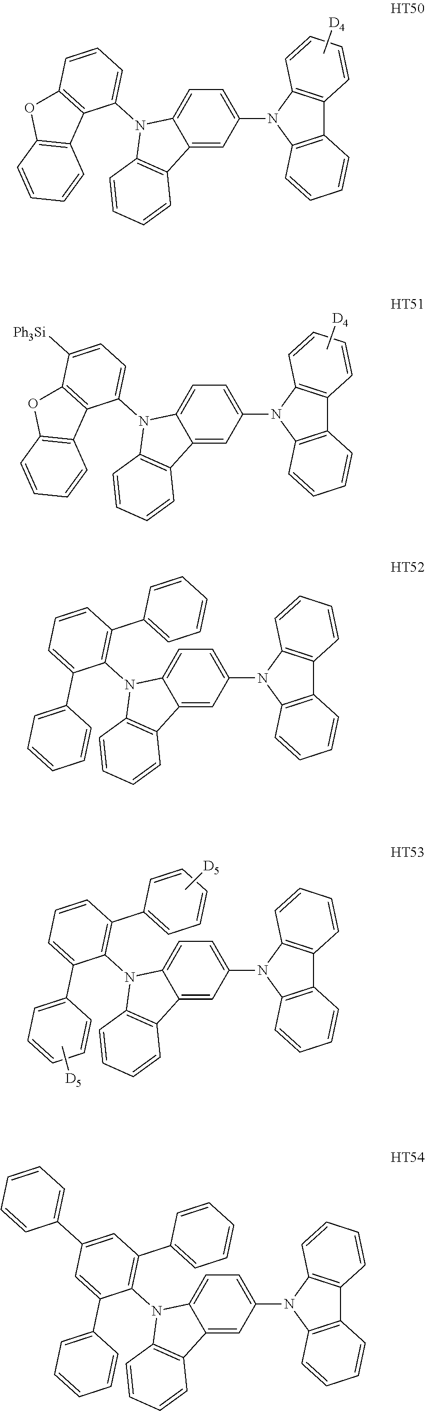

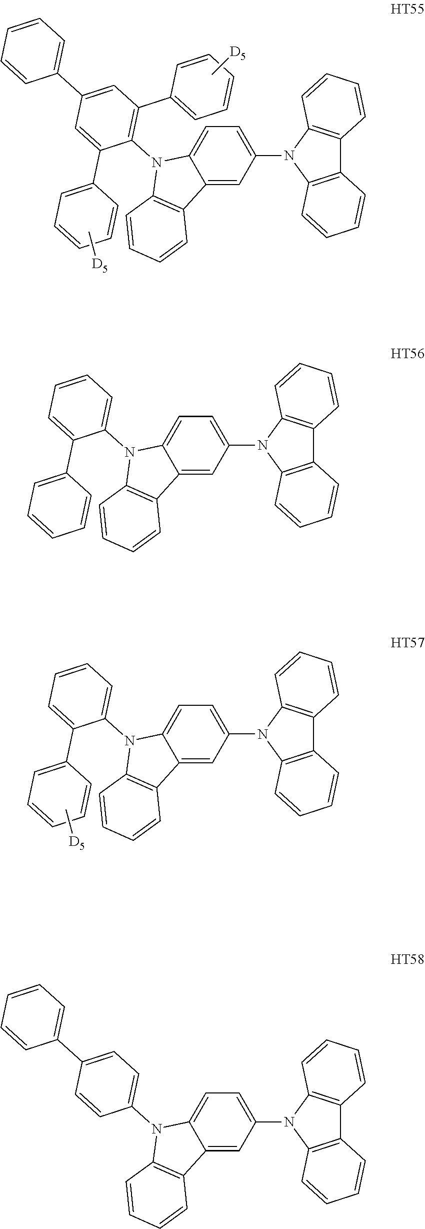

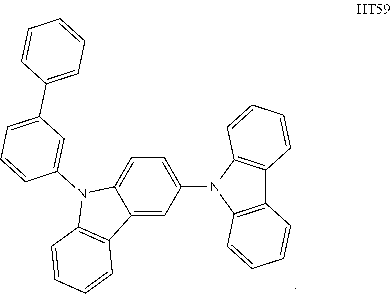 [SMILES: c1ccc(-c2cccc(-n3c4ccccc4c4cc(-n5c6ccccc6c6ccccc65)ccc43)c2)cc1]

In Compound Group 2, D represents a deuterium atom, and Ph represents a substituted or unsubstituted phenyl group. For example, in Compound Group 2, Ph may represent an unsubstituted phenyl group.

In an embodiment, the emission layer EML may further include a third compound represented by Formula ET-1. In an embodiment, the third compound may be used as an electron transport host material in the emission layer EML.

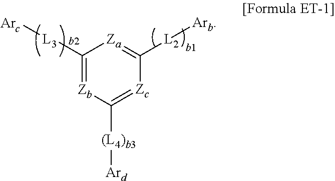

In Formula ET-1, at least one of Zₐ to Z_{c} may be N, and the remainder of Zₐ to Z_{c} may each independently be C(R₅₆). For example, one of Zₐ to Z_{c} may be N, and the remainder of Zₐ to Z_{c} may each independently be C(R₅₆). Thus, the third compound represented by Formula ET-1 may include a pyridine moiety. As another example, two of Zₐ to Z_{c} may each be N, and the remainder of Zₐ to Z_{c} may be C(R₅₆). Thus, the third compound represented by Formula ET-1 may include a pyrimidine moiety. As yet another example, Zₐ to Z_{c} may each be N. Thus, the third compound represented by Formula ET-1 may include a triazine moiety.

In Formula ET-1, R₅₆ may be a hydrogen atom, a deuterium atom, a substituted or unsubstituted alkyl group having 1 to 20 carbons, a substituted or unsubstituted aryl group having 6 to 60 ring-forming carbons, or a substituted or unsubstituted heteroaryl group having 2 to 60 ring-forming carbons.

In Formula ET-1, b1 to b3 may each independently be an integer from 0 to 10.

In Formula ET-1, Arb to Ard may each independently be a hydrogen atom, a deuterium atom, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons. For example, Arb to Ard may each independently be a substituted or unsubstituted phenyl group or a substituted or unsubstituted carbazole group.

In Formula ET-1, L₂ to L₄ may each independently be a direct linkage, a substituted or unsubstituted arylene group having 6 to 30 ring-forming carbons, or a substituted or unsubstituted heteroarylene group having 2 to 30 ring-forming carbons. When b1 to b3 are each 2 or greater, multiples of each of L₂ to L₄ may each independently be a substituted or unsubstituted arylene group having 6 to 30 ring-forming carbons or a substituted or unsubstituted heteroarylene group having 2 to 30 ring-forming carbons.

In an embodiment, the third compound represented by Formula ET-1 may be selected from Compound Group 3. In an embodiment, in the light-emitting element ED, the third compound may include at least one compound selected from Compound Group 3:

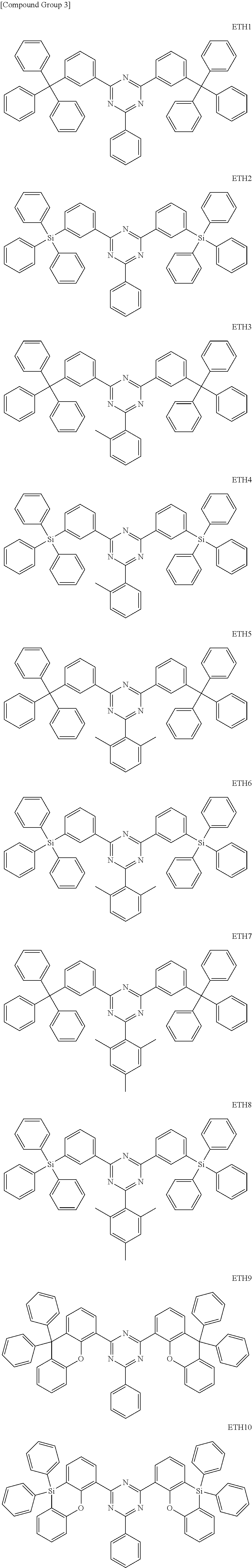

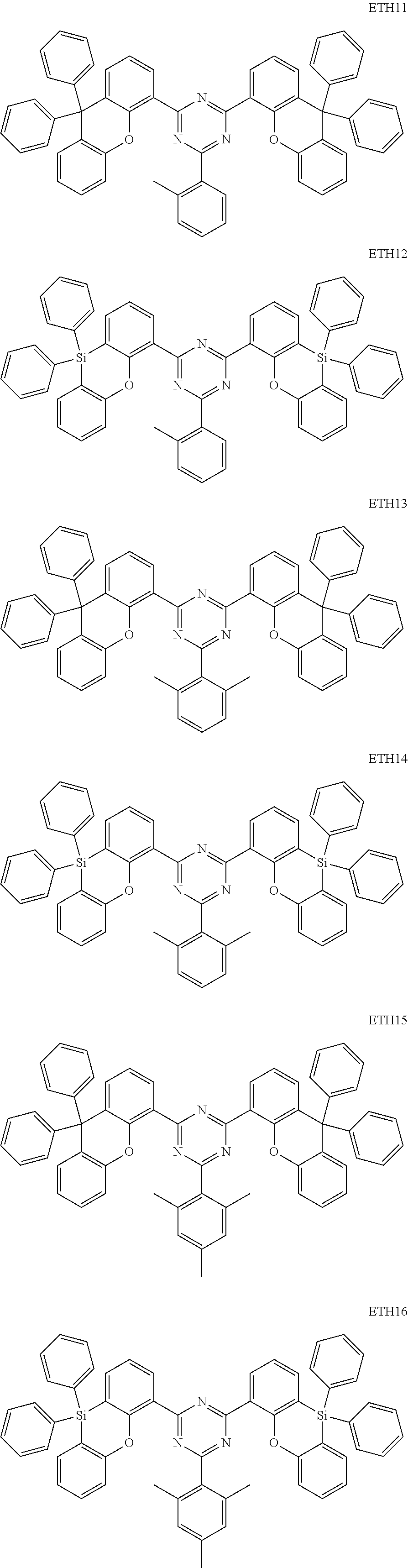

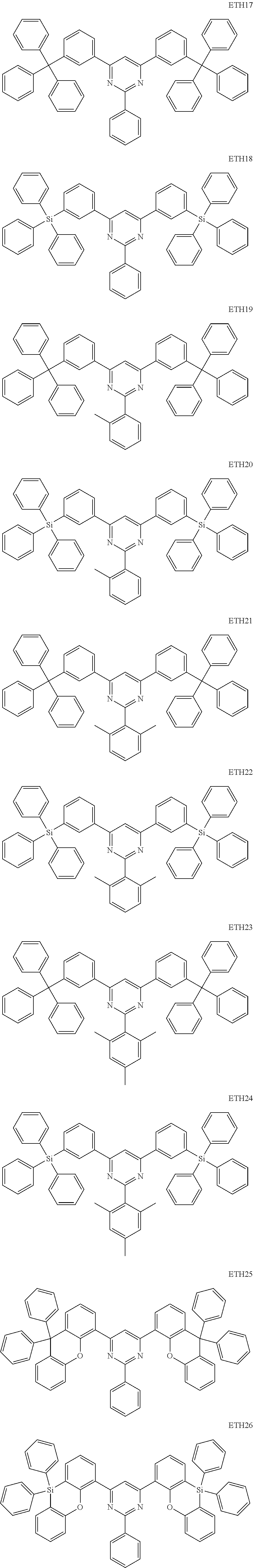

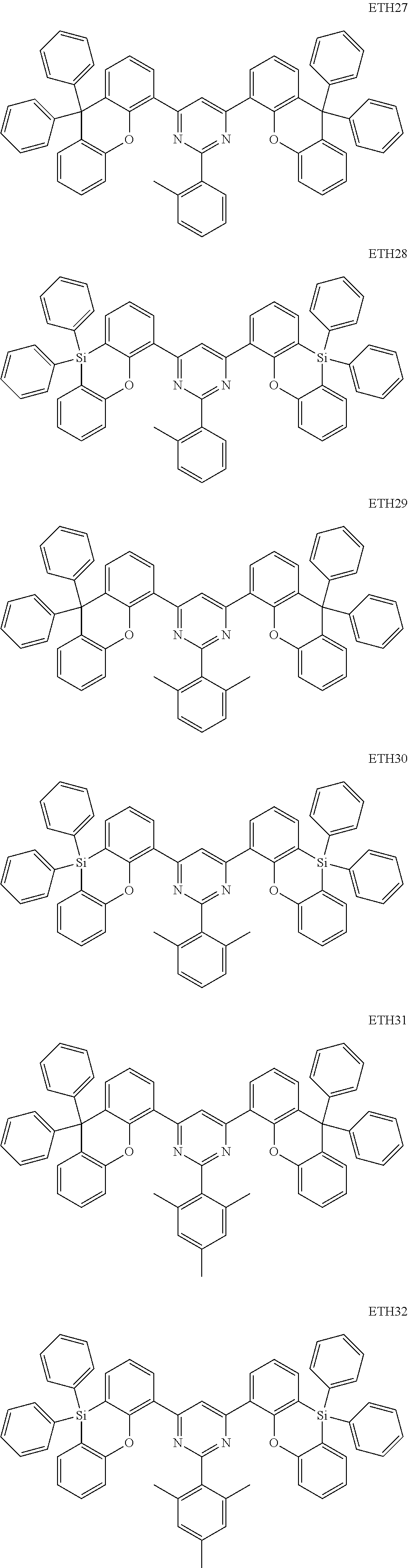

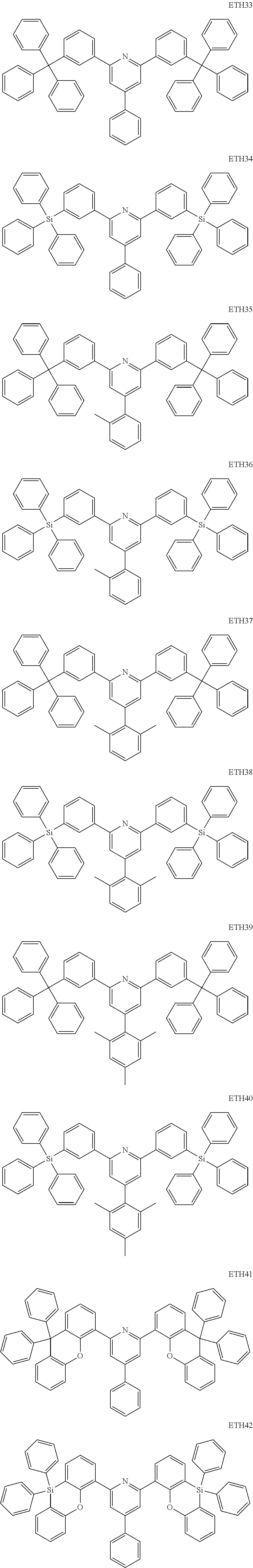

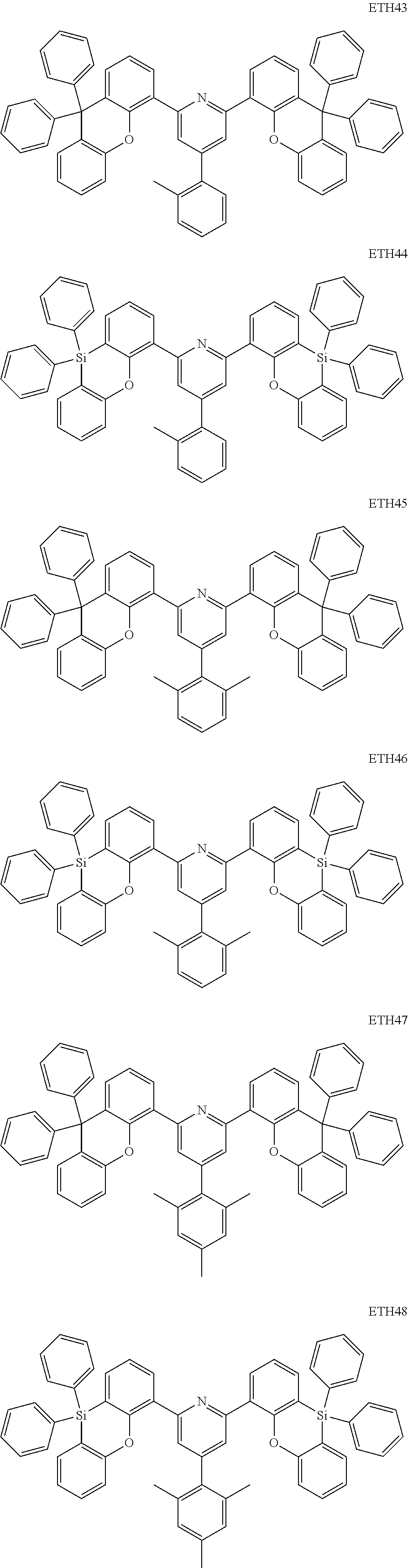

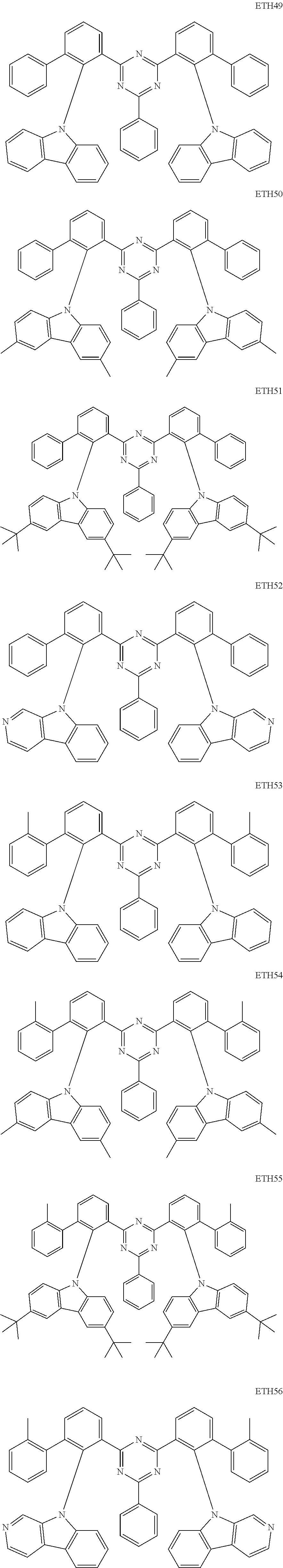

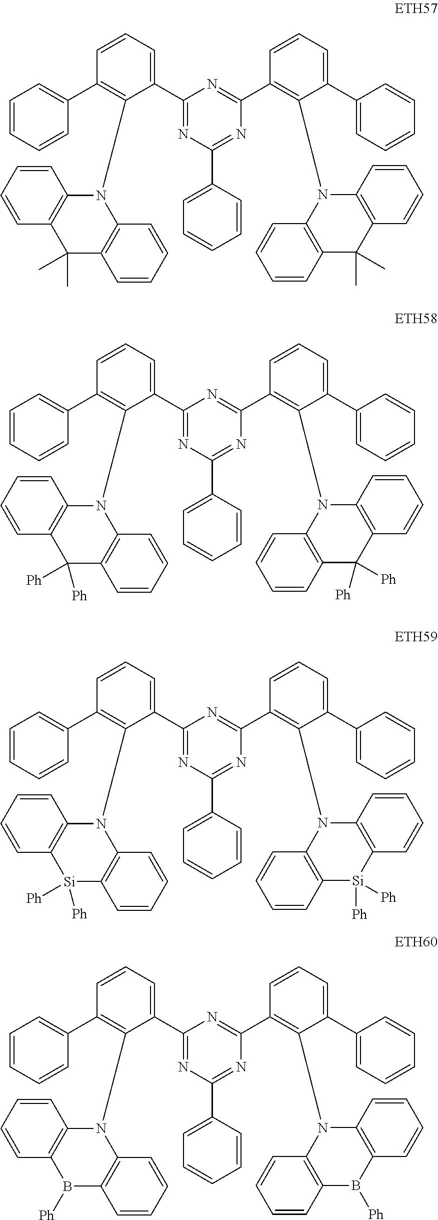

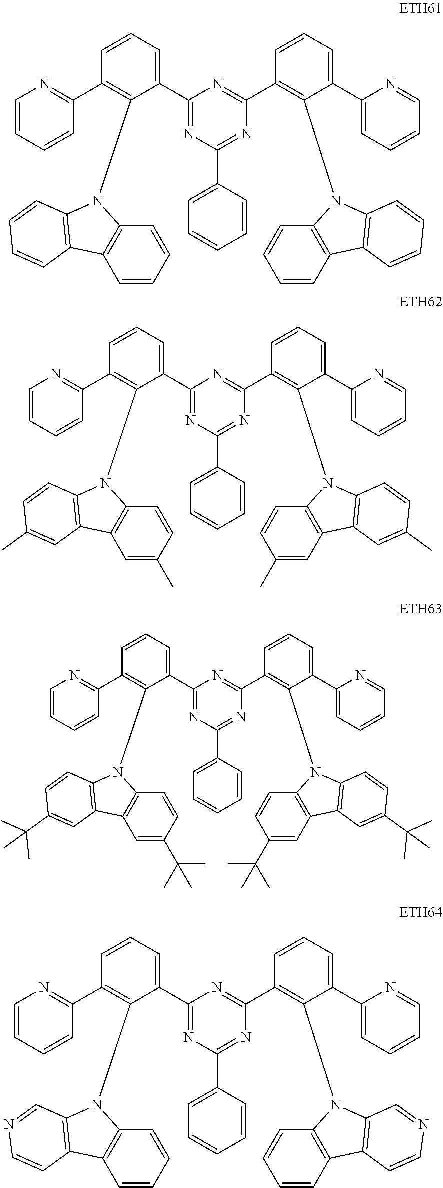

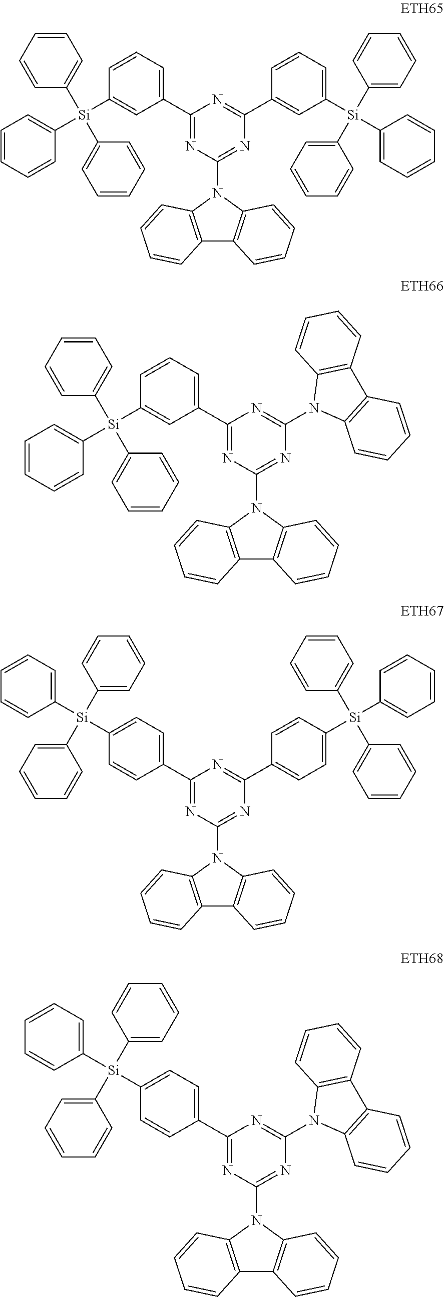 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

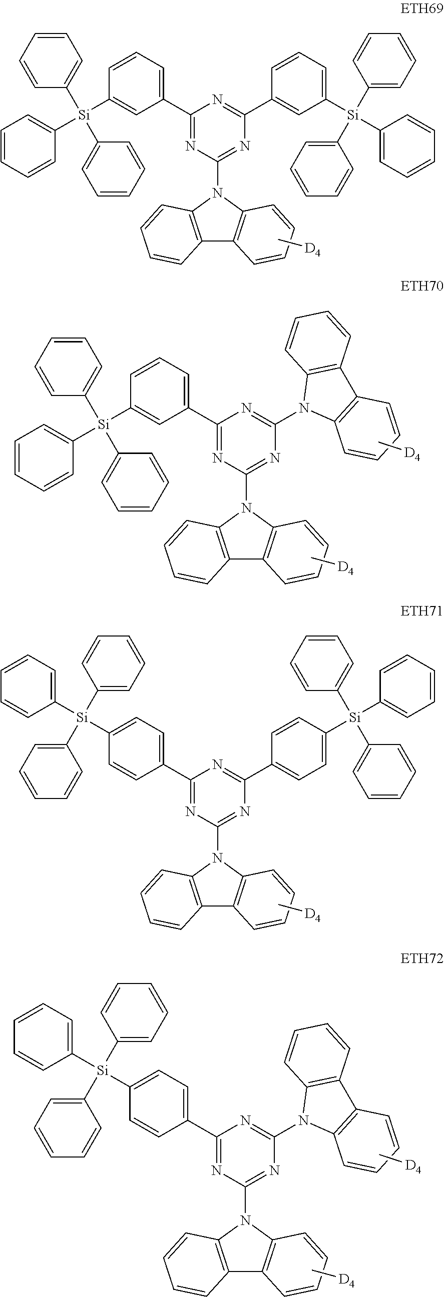

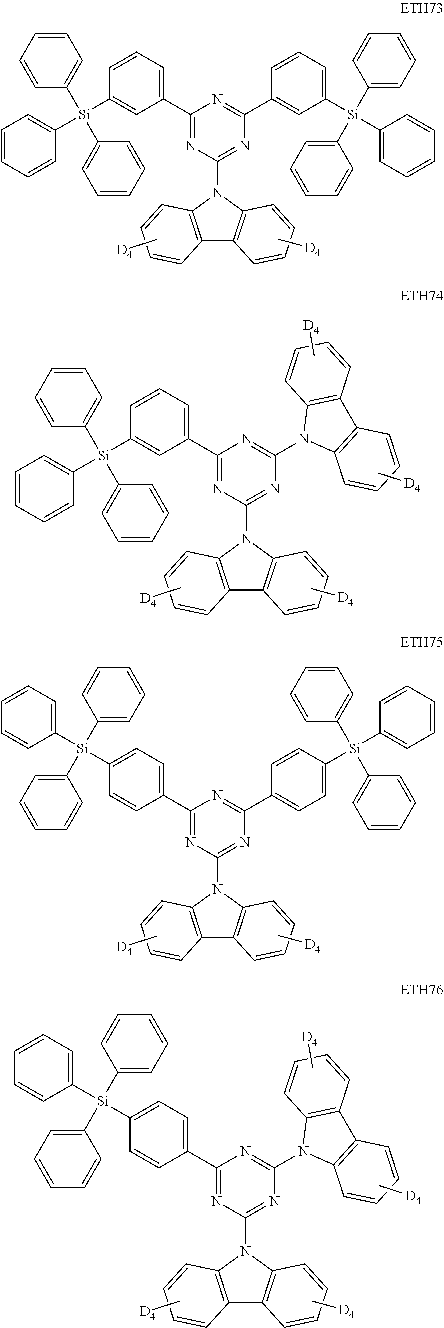

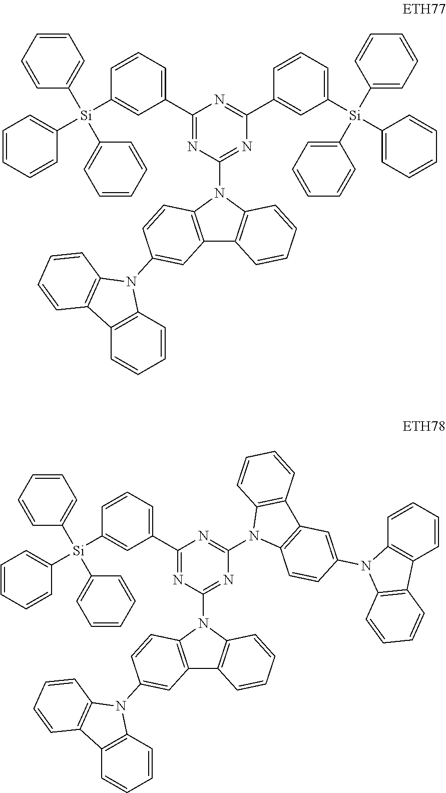 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1]

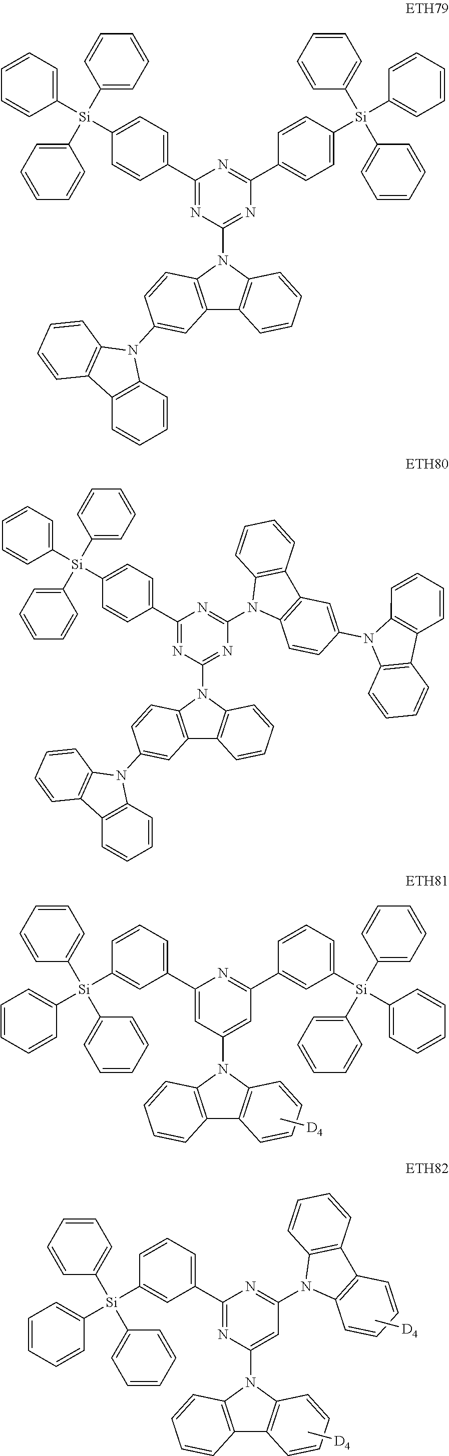

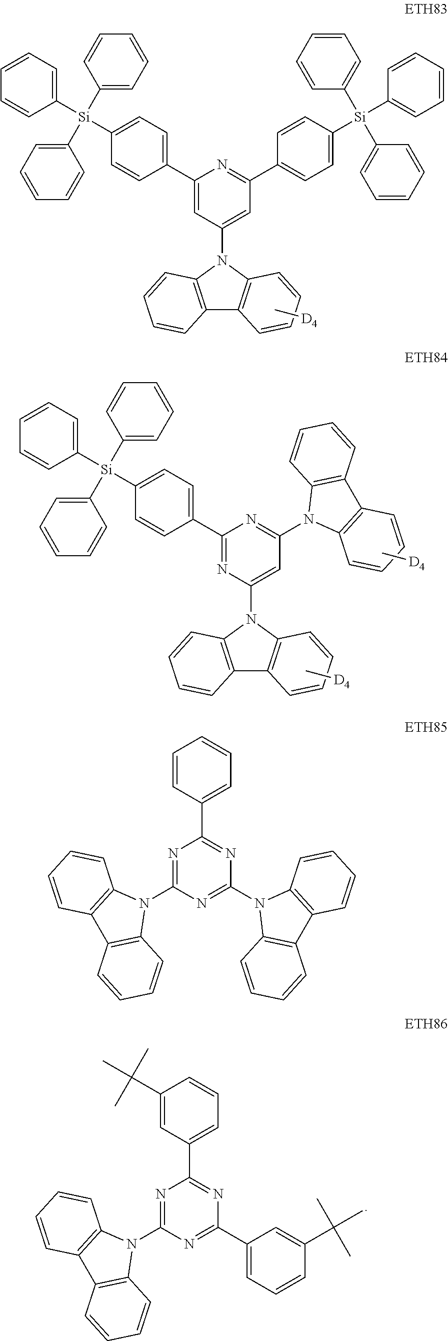

In Compound Group 3, D represents a deuterium atom, and Ph represents an unsubstituted phenyl group.

In an embodiment, the emission layer EML may include the second compound and the third compound, and the second compound and the third compound may form an exciplex. In the emission layer EML, an exciplex may be formed by a hole transport host and an electron transport host. A triplet energy level of the exciplex formed by a hole transport host and an electron transport host may correspond to a difference between a lowest unoccupied molecular orbital (LUMO) energy level of the electron transport host and a highest occupied molecular orbital (HOMO) energy level of the hole transport host.

For example, an absolute value of a triplet energy level (T1) of the exciplex formed by the hole transport host and the electron transport host may be in a range of about 2.4 eV to about 3.0 eV. The triplet energy level of the exciplex may be a value that is less than an energy gap of each host material. The exciplex may have a triplet energy level equal to or less than about 3.0 eV, which is an energy gap between the hole transport host and the electron transport host.

In an embodiment, the emission layer EML may further include a fourth compound, in addition to the first compound, the second compound, and the third compound as described above. The fourth compound may be used as a phosphorescent sensitizer in the emission layer EML. Energy may be transferred from the fourth compound to the first compound, thereby implementing light emission.

In an embodiment, the emission layer EML may further include, as a fourth compound, an organometallic complex that includes platinum (Pt) as a central metal atom and ligands linked to the central metal atom. In an embodiment, the emission layer EML may include a fourth compound represented by Formula D-1:

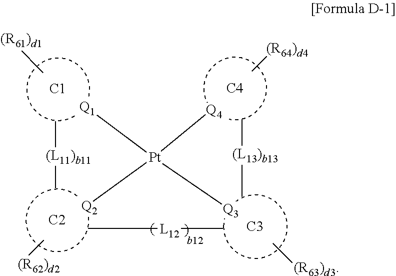

In Formula D-1, Q₁ to Q₄ may each independently be C or N.

In Formula D-1, C1 to C4 may each independently be a substituted or unsubstituted hydrocarbon ring having 5 to 30 ring-forming carbons or a substituted or unsubstituted heterocycle having 2 to 30 ring-forming carbons.

In Formula D-1, L₁₁ to L₁₃ may each independently be a direct linkage,

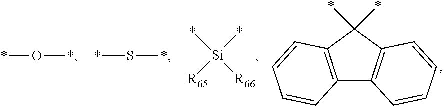

a substituted or unsubstituted alkylene group having 1 to 20 carbons, a substituted or unsubstituted arylene group having 6 to 30 ring-forming carbons, or a substituted or unsubstituted heteroarylene group having 2 to 30 ring-forming carbons. In L₁₁ to L₁₃, -* represents a bond to one of C1 to C4.

In Formula D-1, b11 to b13 may each independently be 0 or 1. If b11 is 0, C1 and C2 may not be directly linked to each other. If b12 is 0, C2 and C3 may not be directly linked to each other. If b13 is 0, C3 and C4 may not be directly linked to each other.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbons, a substituted or unsubstituted alkenyl group having 2 to 20 carbons, a substituted or unsubstituted aryl group having 6 to 60 ring-forming carbons, or a substituted or unsubstituted heteroaryl group having 2 to 60 ring-forming carbons, or bonded to an adjacent group to form a ring. For example, R₆₁ to R₆₆ may each independently be a substituted or unsubstituted methyl group or a substituted or unsubstituted t-butyl group.

In Formula D-1, d1 to d4 may each independently be an integer from 0 to 4. In Formula D-1, if d1 to d4 are each 0, the fourth compound may not be substituted with R₆₁ to R₆₄, respectively. A case where d1 to d4 are each 4 and four of each of R₆₁ to R₆₄ are all hydrogen atoms may be the same as a case where d1 to d4 are each 0. When d1 to d4 are each 2 or more, multiples of each of R₆₁ to R₆₄ may all be the same, or at least one thereof may be different from the remainder.

In an embodiment, in Formula D-1, C1 to C4 may each independently be a substituted or unsubstituted hydrocarbon ring or a substituted or unsubstituted heterocycle that is represented by one of Formula C-1 to Formula C-4:

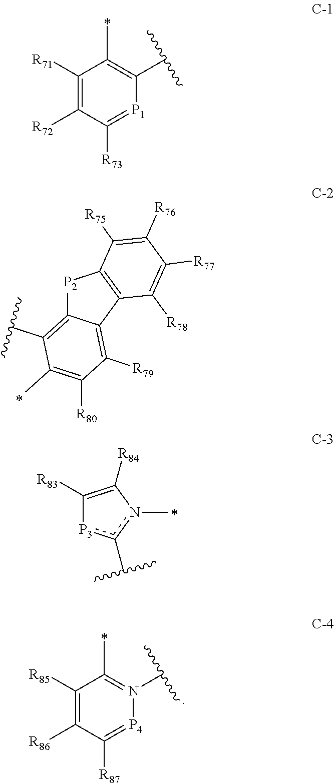

In Formula C-1 to Formula C-4, P₁ may be C—* or C(R₇₄), P₂ may be N—* or N(Rₛ₁), P₃ may be N—* or N(Rₛ₂), and P₄ may be C—* or C(R₈₈). In Formula C—1 to Formula C—4, R₇₁ to R₈₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

In Formula C—1 to Formula C—4,

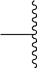

represents a bond to Pt, which is a central metal atom, and -* represents a bond to a neighboring cyclic group (C1 to C4) or to a linking moiety (L₁₁ to L₁₃).

In an embodiment, the emission layer EML may include the first compound represented by Formula 1, and at least one of the second compound, the third compound, and the fourth compound. In an embodiment, the emission layer EML may include the first compound, the second compound, and the third compound. In the emission layer EML, the second compound and the third compound may form an exciplex, and energy may be transferred from the exciplex to the first compound, thereby implementing light emission.

In another embodiment, the emission layer EML may include the first compound, the second compound, the third compound, and the fourth compound. In the emission layer EML, the second compound and the third compound may form an exciplex, and energy may be transferred from the exciplex to the fourth compound and to the first compound, thereby implementing light emission. In an embodiment, the fourth compound may be a sensitizer. In the light-emitting element ED, the fourth compound included in the emission layer EML may serve as a sensitizer that transfers energy from a host (for example, an exciplex host) to the first compound, which is a light emitting dopant. For example, the fourth compound, which serves as an auxiliary dopant, may accelerate energy transfer to the first compound, which is a light emitting dopant, thereby increasing an emission ratio of the first compound. Therefore, luminous efficiency of the emission layer EML may improve. When energy transfer to the first compound increases, excitons formed in the emission layer EML may not accumulate and may emit light rapidly, so that deterioration of the device may be reduced. Therefore, the service life of the light-emitting element ED according to an embodiment may increase.

The light-emitting element ED may include the first compound, the second compound, the third compound, and the fourth compound, and the emission layer EML may include a combination of two host materials and two dopant materials. In the light-emitting element ED, the emission layer EML may include the second compound and the third compound, which are two different hosts, the first compound that emits delayed fluorescence, and the fourth compound that includes an organometallic complex, so that the light-emitting element ED may exhibit excellent luminous efficiency characteristics.

In an embodiment, the fourth compound represented by Formula D-1 may be selected from Compound Group 4. In an embodiment, in the light-emitting element ED, the fourth compound may include at least one compound selected from Compound Group 4:

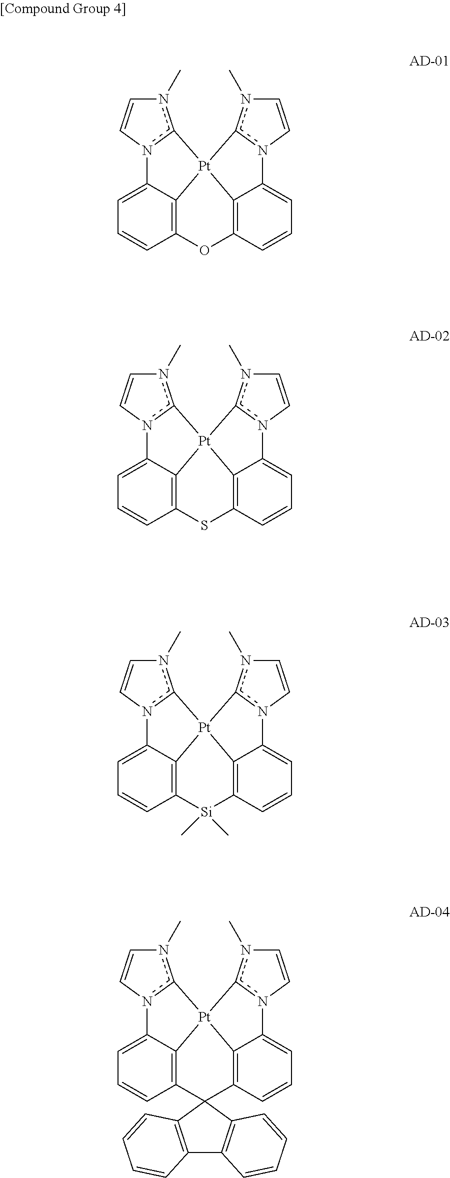

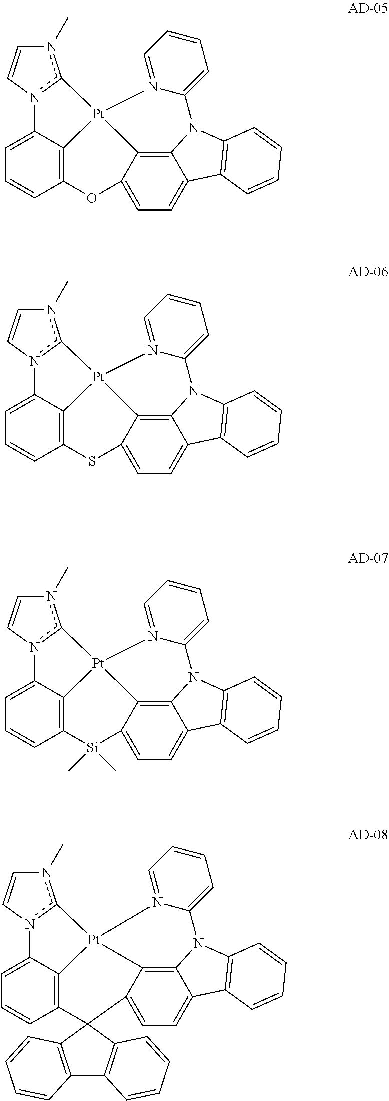

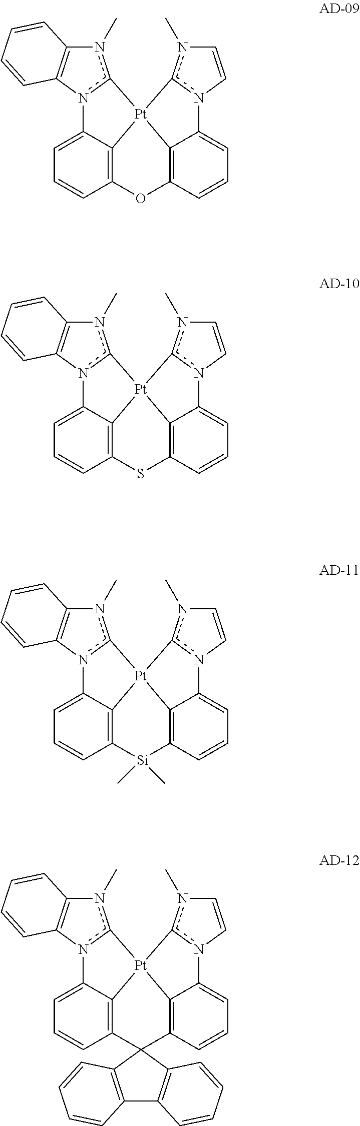

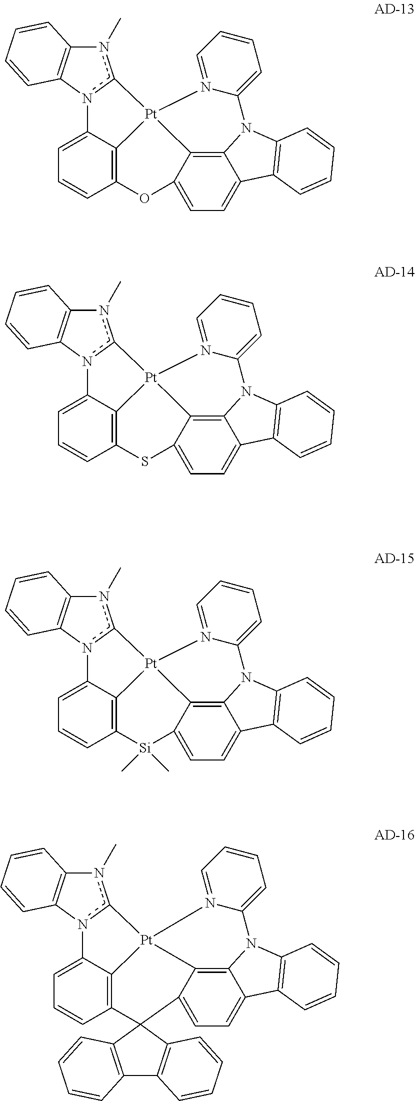

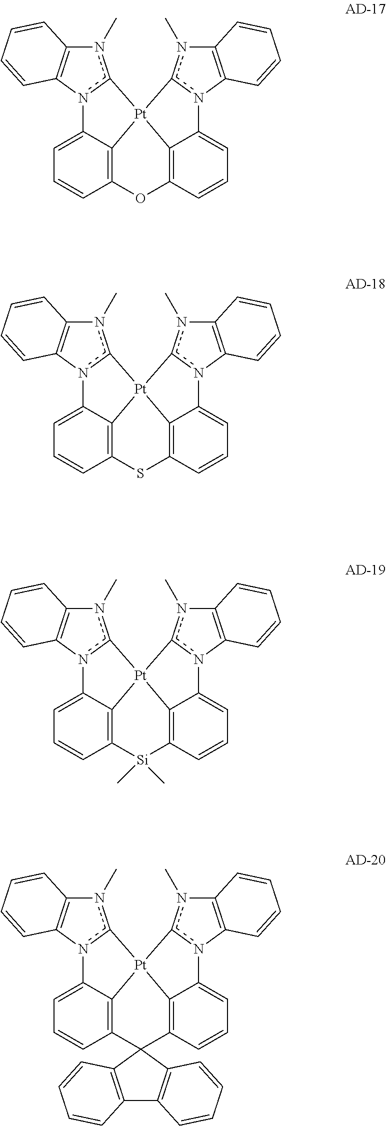

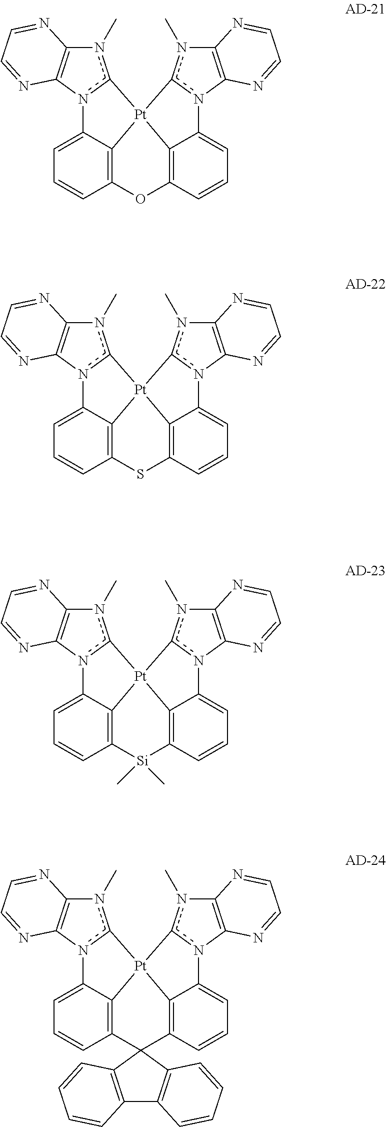

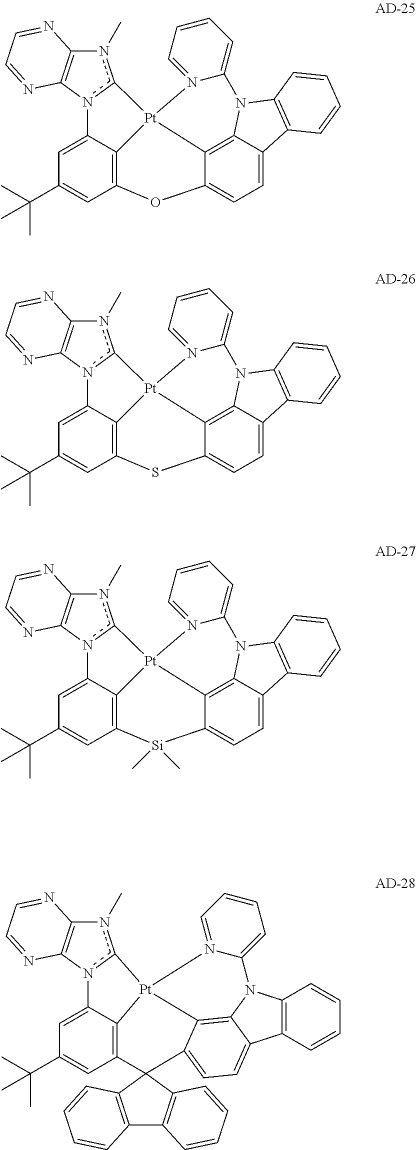

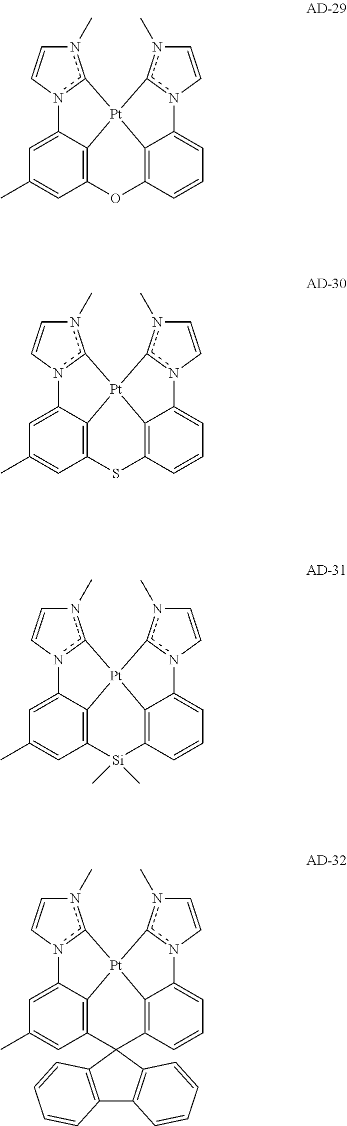

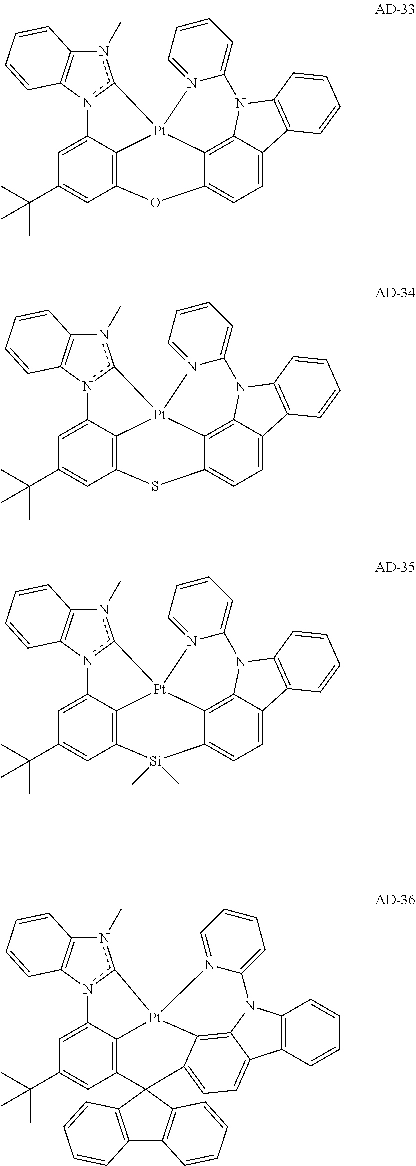

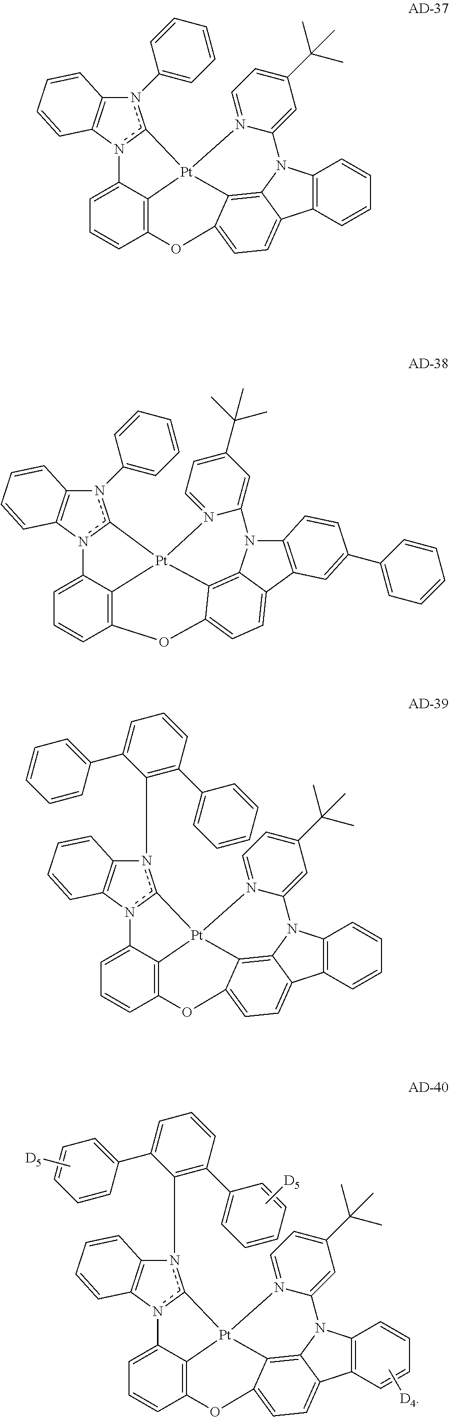

In Compound Group 4, D represents a deuterium atom.

In an embodiment, the light-emitting element ED may include multiple emission layers. The emission layers may be provided as a stack, so that the light-emitting element ED may emit white light. The light-emitting element ED including multiple emission layers may have a tandem structure. If the light-emitting element ED includes multiple emission layers, at least one emission layer EML may each independently include the first compound represented by Formula 1. If the light-emitting element ED includes multiple emission layers, at least one emission layer EML may include the first compound, the second compound, the third compound, and the fourth compound, as described previously.

When the emission layer EML includes the first compound, the second compound, and the third compound, an amount of the first compound may be in a range of about 0.1 wt % to about 5 wt %, with respect to a total weight of the first compound, the second compound, and the third compound. However, embodiments are not limited thereto. When an amount of the first compound satisfies the range described above, energy transfer from the second compound and the third compound to the first compound may increase, so that luminous efficiency and device service life may increase.

In the emission layer EML, a combined amount of the second compound and the third compound may be the remainder of the total weight of the first compound, the second compound, the third compound, and the fourth compound, excluding the amount of the first compound and the fourth compound. For example, a combined amount of the second compound and the third compound in the emission layer EML may be in a range of about 65 wt % to about 95 wt %, with respect to a total weight of the first compound, the second compound, and the third compound.

Within the combined amount of the second compound and the third compound, a weight ratio of the second compound to the third compound may be in a range of about 3:7 to about 7:3.

When the amounts of the second compound and the third compound satisfy the above-described ranges and ratios, charge balance characteristics of the emission layer EML may improve, and luminous efficiency and device service life may increase. When the amounts of the second compound and the third compound deviate from the above-described ranges and ratios, charge balance in the emission layer EML may not be achieved, so that luminous efficiency may be reduced and the element may readily deteriorate.

When the emission layer EML includes the fourth compound, an amount of the fourth compound may be in a range of about 4 wt % to about 30 wt %, with respect to a total weight of the first compound, the second compound, the third compound, and the fourth compound. However, embodiments are not limited thereto. When an amount of the fourth compound satisfies the above-described range, energy transfer from a host (for example, an exciplex host) to the first compound, which is a light emitting dopant, may increase, so that an emission ratio may improve, and thus luminous efficiency of the emission layer EML may be improved. When the amounts of the first compound, the second compound, the third compound, and the fourth compound included in the emission layer EML satisfy the above-described ranges and ratios, excellent luminous efficiency and long service life may be achieved.

In the light-emitting element ED, the emission layer EML may include an anthracene derivative, a pyrene derivative, a fluoranthene derivative, a chrysene derivative, a dihydrobenzanthracene derivative, or a triphenylene derivative. For example, the emission layer EML may include an anthracene derivative or a pyrene derivative.

In the light-emitting element ED according to embodiments as shown in FIGS. 5 to 8, the emission layer EML may further include a host and a dopant of the related art, in addition to the host and dopant as described above. In an embodiment, the emission layer EML may include a compound represented by Formula E-1. The compound represented by Formula E-1 may be used as a fluorescent host material. In an embodiment, the emission layer EML may include the fused polycyclic compound according to an embodiment as a dopant material and a compound represented by Formula E-1 as a host material:

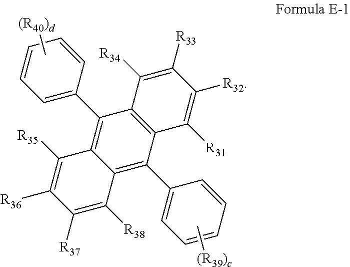

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbons, a substituted or unsubstituted alkenyl group having 2 to 10 carbons, a substituted or unsubstituted aryl group having 6 to 30 ring-forming carbons, or a substituted or unsubstituted heteroaryl group having 2 to 30 ring-forming carbons, or bonded to an adjacent group to form a ring. For example, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

In an embodiment, the compound represented by Formula E-1 may be any compound selected from Compound E1 to Compound E21:

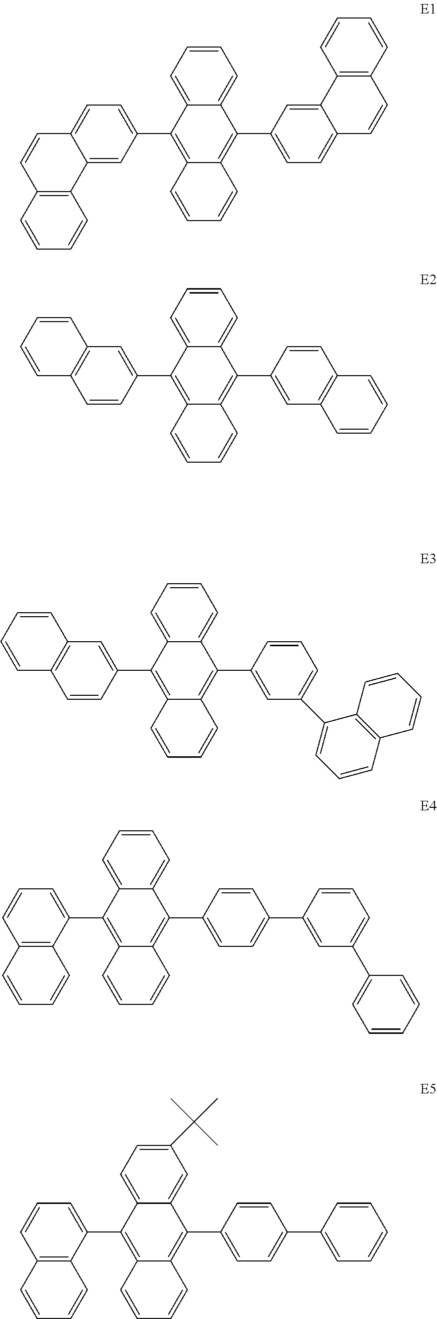

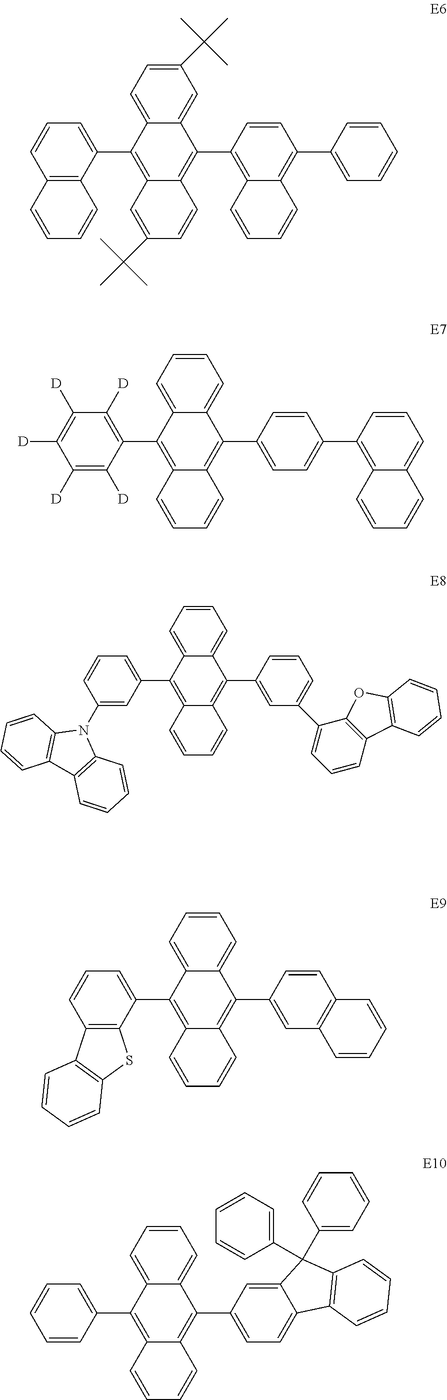

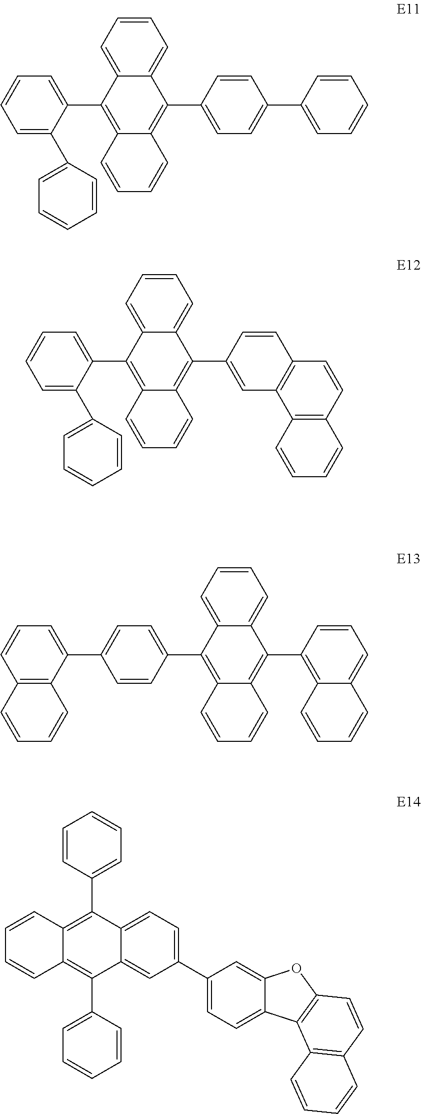

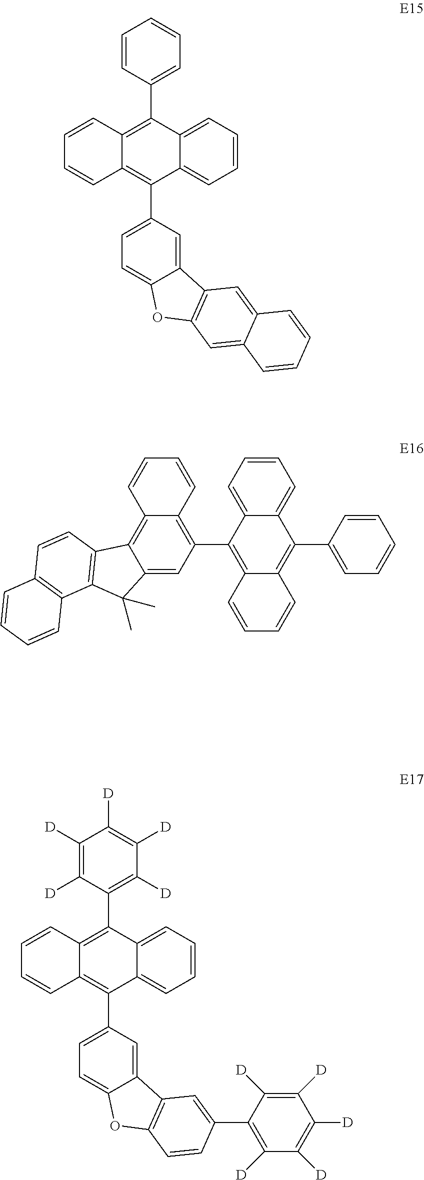

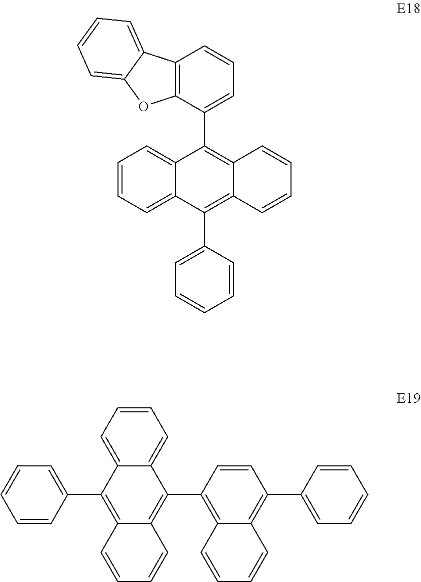

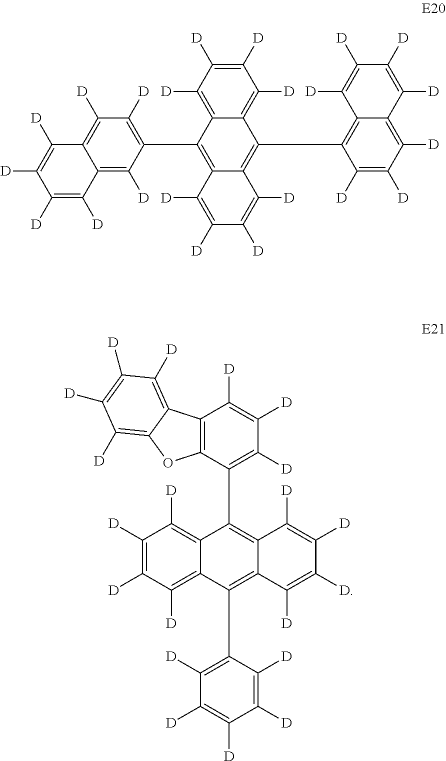

In an embodiment, the emission layer EML may include a compound represented by Formula E-2a or Formula E-2b. The compound represented by Formula E-2a or Formula E-2b may be used as a host material for a phosphorescent light emitting element.

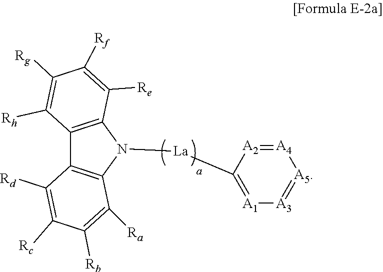

In Formula E-2a, a may be an integer from 0 to 10; and La may be a direct linkage, a substituted or unsubstituted arylene group having 6 to 30 ring-forming carbon atoms, or a substituted or unsubstituted heteroarylene group having 2 to 30 ring-forming carbon atoms. When a is 2 or greater, multiple Lₐ may each independently be a substituted or unsubstituted arylene group having 6 to 30 ring-forming carbon atoms or a substituted or unsubstituted heteroarylene group having 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. For example, Rₐ to Rᵢ may be bonded to an adjacent group to form a hydrocarbon ring or a heterocycle containing N, O, S, etc., as a ring-forming atom.

In Formula E-2a, two or three of A₁ to A₅ may each be N, and the remainder of A₁ to A₅ may each independently be C(Rᵢ).

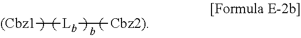

In Formula E-2b, Cbz1 and Cbz2 may each independently be an unsubstituted carbazole group or a carbazole group substituted with an aryl group having 6 to 30 ring-forming carbon atoms. In Formula E-2b, Le may be a direct linkage, a substituted or unsubstituted arylene group having 6 to 30 ring-forming carbon atoms, or a substituted or unsubstituted heteroarylene group having 2 to 30 ring-forming carbon atoms. In Formula E-2b, b may be an integer from 0 to 10. When b is 2 or more, multiple Le may each independently be a substituted or unsubstituted arylene group having 6 to 30 ring-forming carbon atoms or a substituted or unsubstituted heteroarylene group having 2 to 30 ring-forming carbon atoms.

In an embodiment, the compound represented by Formula E-2a or Formula E-2b may be any compound selected from Compound Group E-2. However, the compounds listed in Compound Group E-2 are only examples, and the compound represented by Formula E-2a or Formula E-2b is not limited to Compound Group E-2:

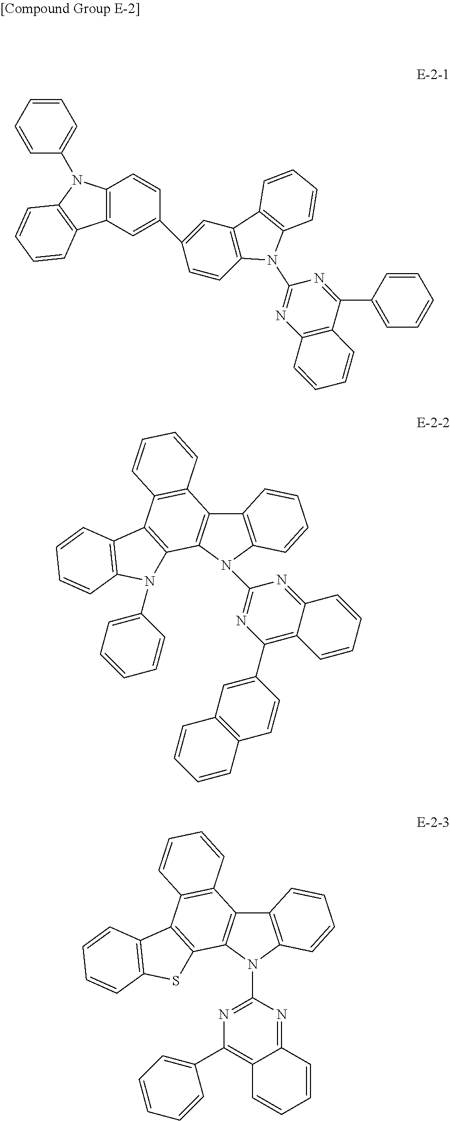 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

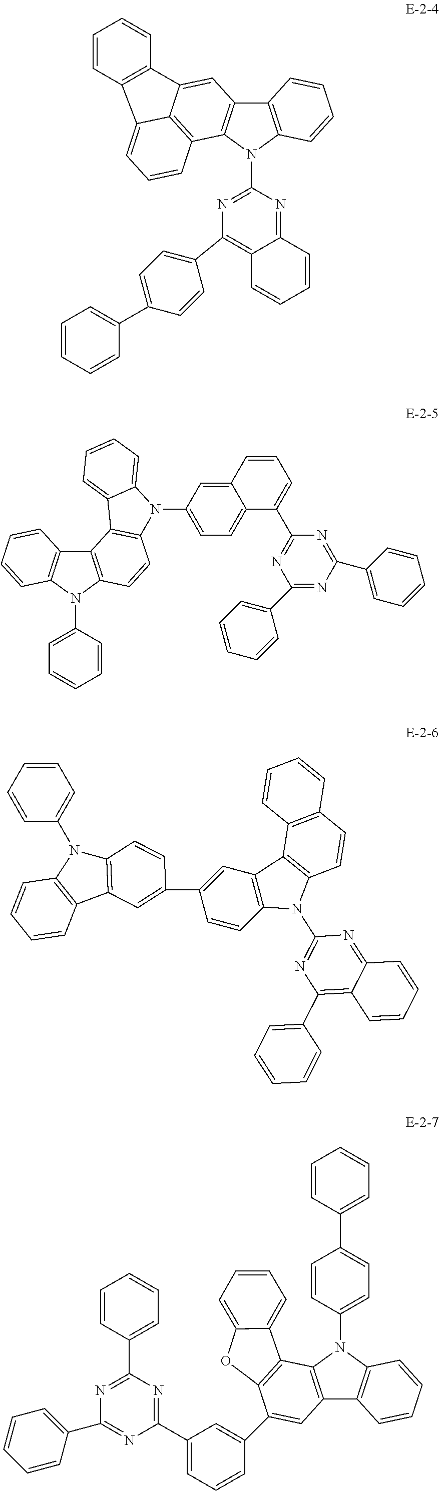 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1]

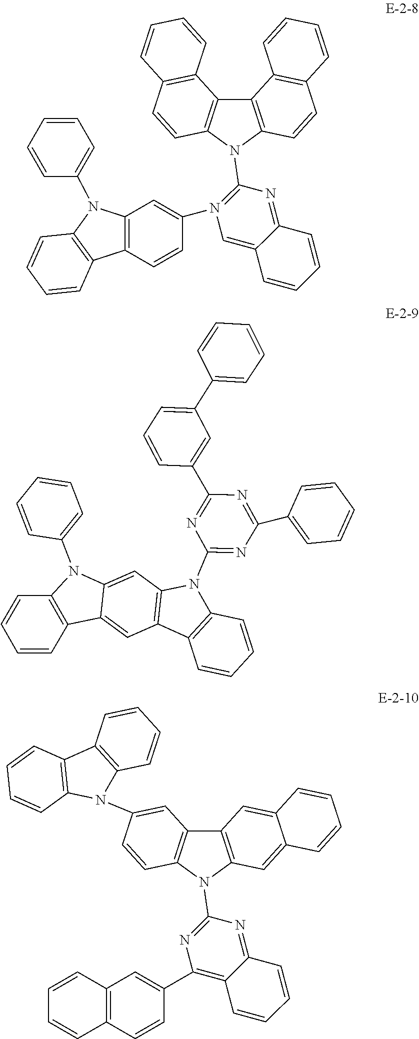

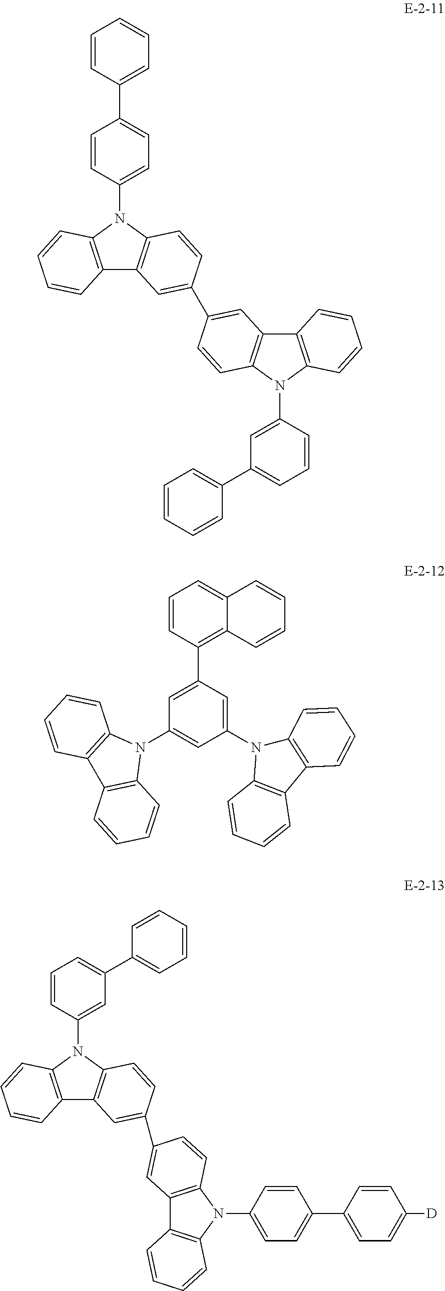

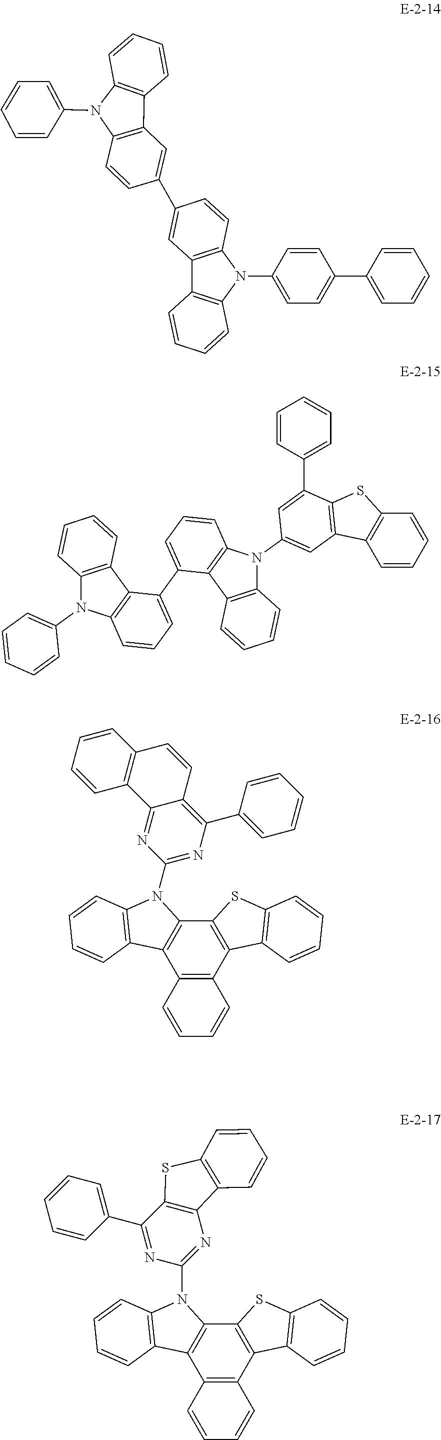 [SMILES: c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1 ; c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1]

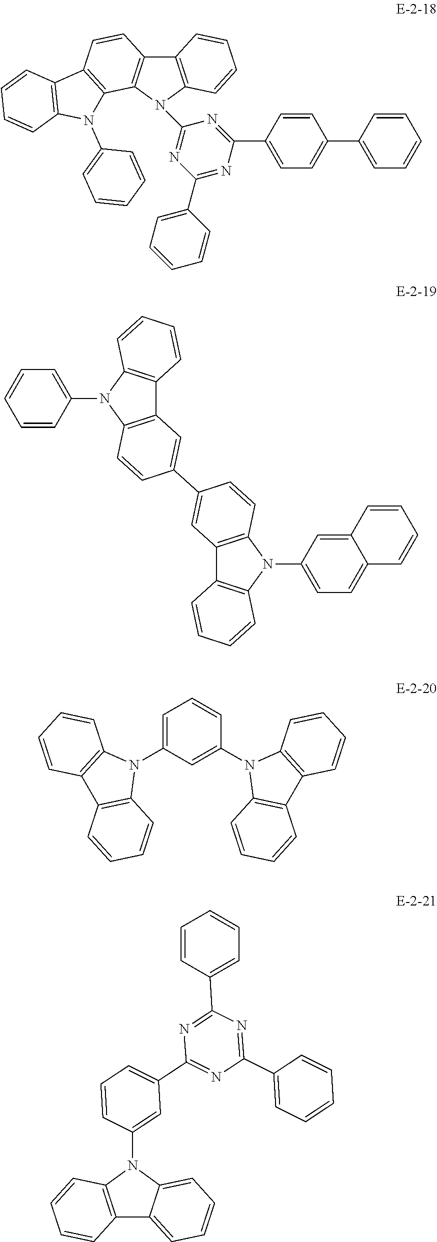 [SMILES: c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1]

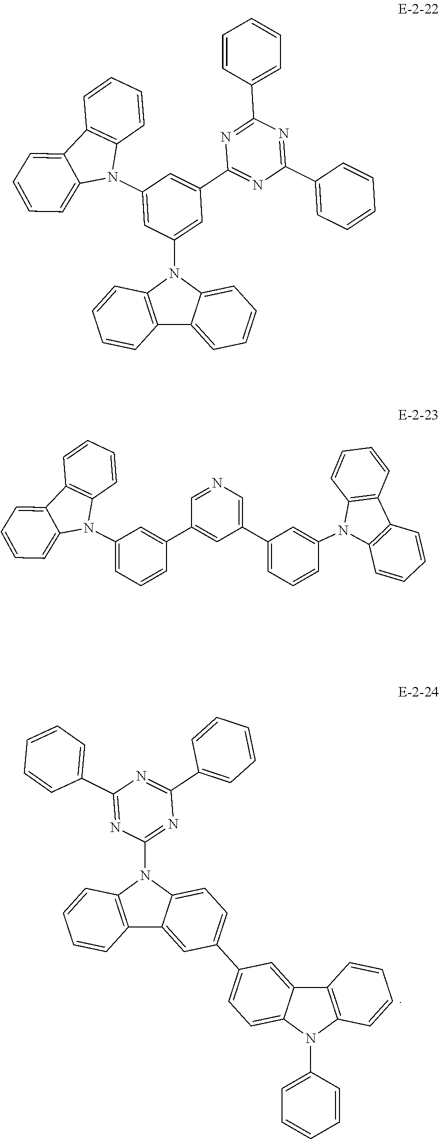 [SMILES: c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

In embodiments, the emission layer EML may further include a material of the related art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), and 1,3,5-tris(1-phenyl-1H-benzo[d]imidazole-2-yl)benzene (TPBi). However, embodiments are not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), etc. may be used as a host material.

In an embodiment, the emission layer EML may include a compound represented by Formula M-a. The compound represented by Formula M-a may be used as a phosphorescent dopant material.

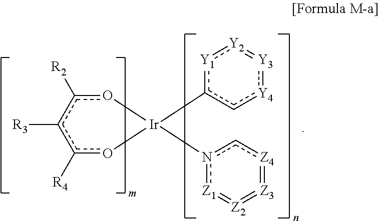

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. In Formula M-a, m may be 0 or 1, and n may be 2 or 3. In Formula M-a, when m is 0, n may be 3, and when m is 1, n may be 2.

In an embodiment, the compound represented by Formula M-a may be any compound selected from Compound M-a1 to Compound M-a25. However, Compounds M-a1 to M-a25 are only examples, and the compound represented by Formula M-a is not limited to Compounds M-a1 to M-a25:

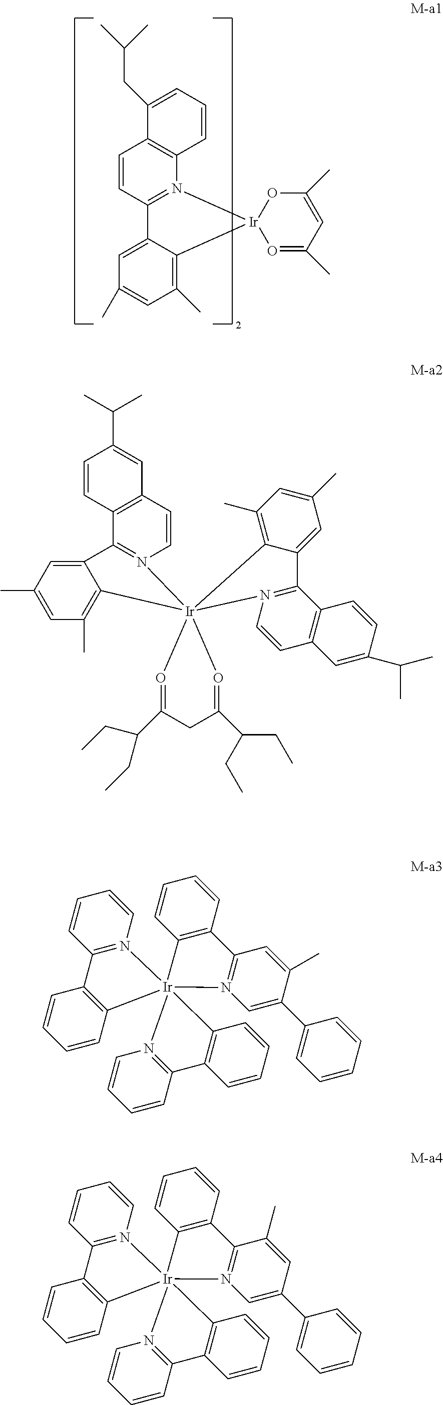

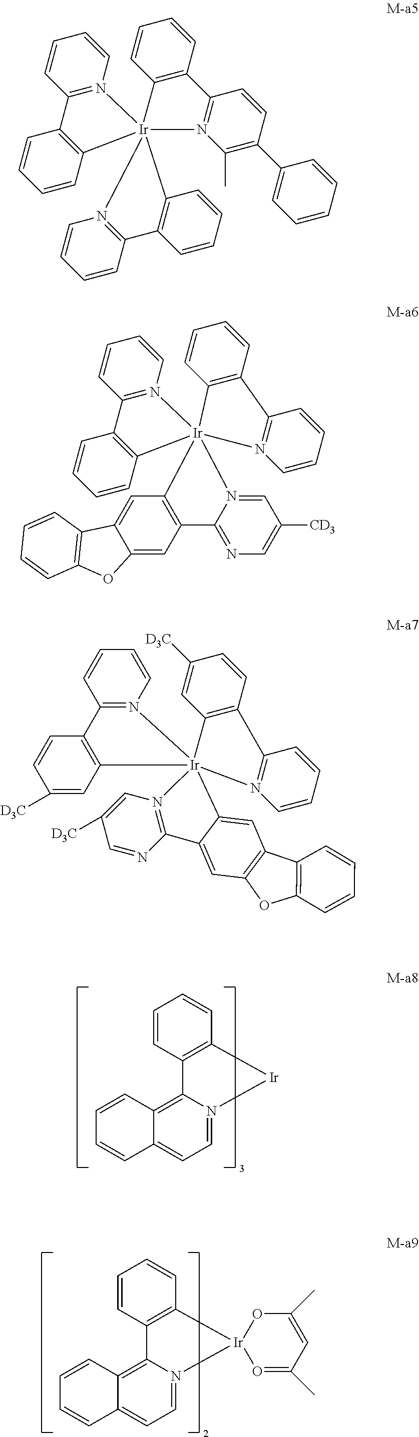

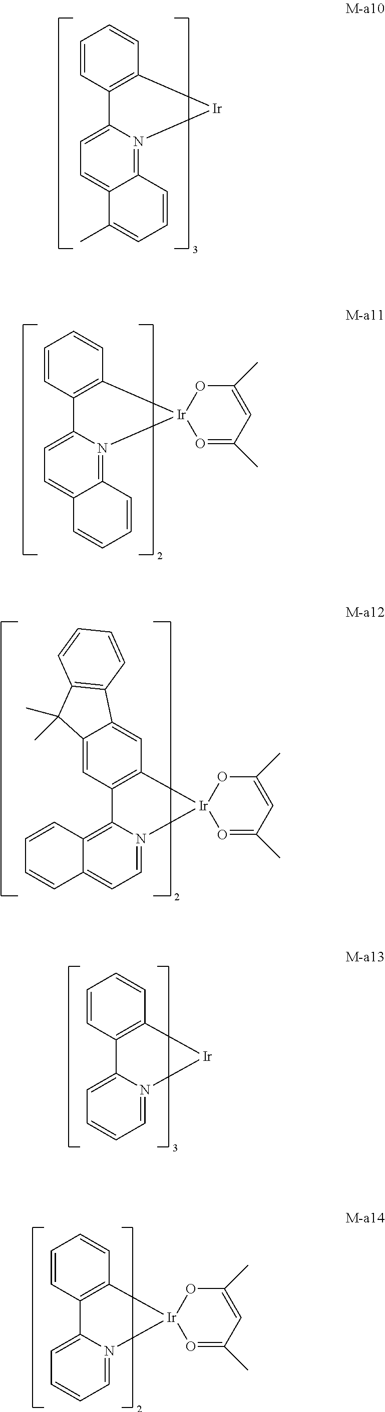

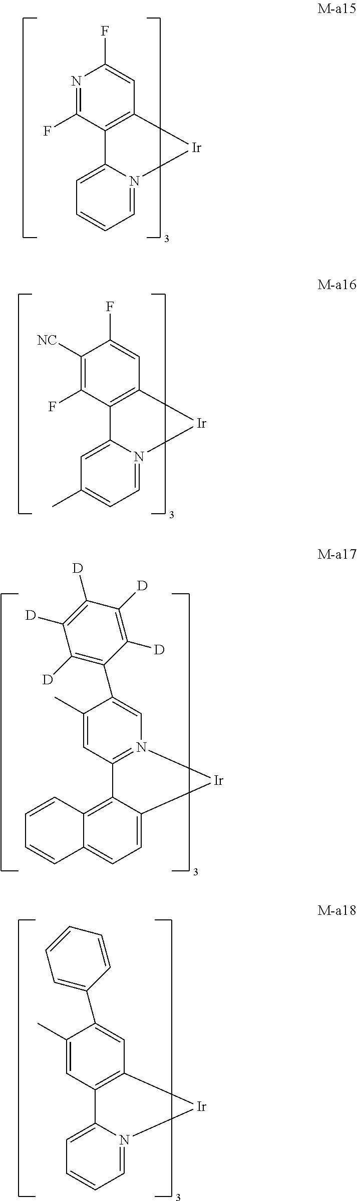

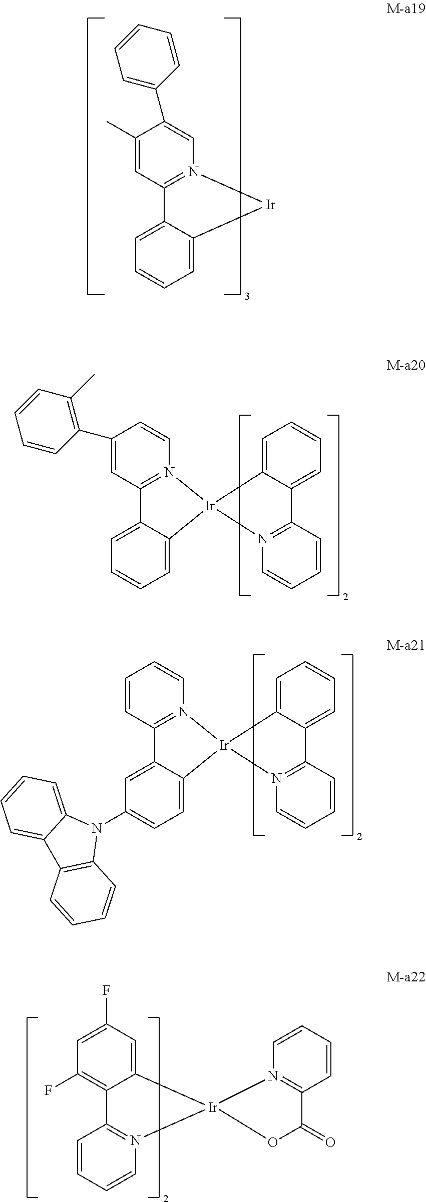

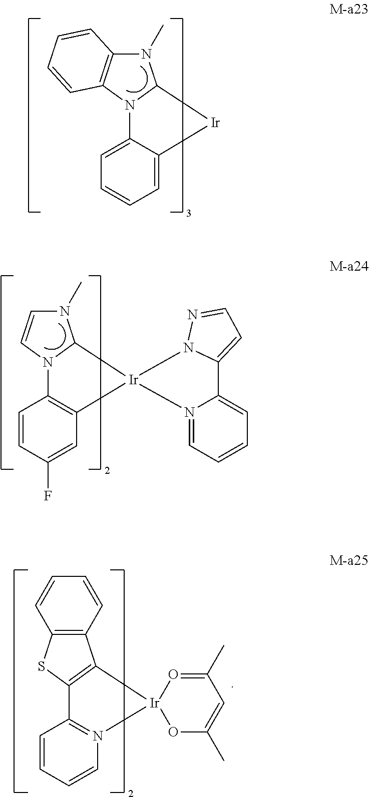

In an embodiment, the emission layer EML may include a compound represented by one of Formula F-a to Formula F-c. The compound represented by one of Formula F-a to Formula F-c may be used as a fluorescence dopant material.

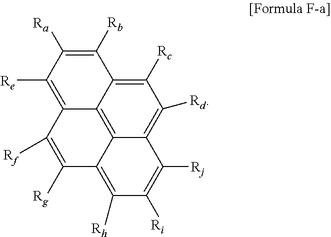

In Formula F-a, two of Rₐ to Rⱼ may each independently be substituted with a group represented by *—NAr₁Ar₂. The remainder of Rₐ to Rⱼ that are not substituted with the group represented by *—NAr₁Ar₂ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In the group represented by *—NAr₁Ar₂, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ and Ar₂ may each independently be a heteroaryl group containing O or S as a ring-forming atom.

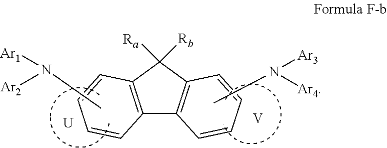

In Formula F-b, Rₐ and Rb may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula F-b, Ar₁ to Ar₄ may each independently be a substituted or unsubstituted aryl group having 6 to 30 ring-forming carbon atoms or a substituted or unsubstituted heteroaryl group having 2 to 30 ring-forming carbon atoms. For example, at least one of Ar1 to Ar4 may each independently be a heteroaryl group containing O or S as a ring-forming atom.

In Formula F-b, U and V may each independently be a substituted or unsubstituted hydrocarbon ring having 5 to 30 ring-forming carbon atoms or a substituted or unsubstituted heterocycle having 2 to 30 ring-forming carbon atoms.

In Formula F-b, the number of rings represented by U and V may each independently be 0 or 1. When the number of U or V is 1, a fused ring may be present at a portion respectively indicated by U or V, and when the number of U or V is 0, a fused ring may not be present at the portion respectively indicated by U or V. When the number of U is 0 and the number of V is 1, or when the number of U is 1 and the number of V is 0, a fused ring having the fluorene core of Formula F-b may be a cyclic compound having four rings. When the number of U and V is each 0, a fused ring having the fluorene core of Formula F-b may be a cyclic compound having three rings. When the number of U and V is each 1, a fused ring having the fluorene core of Formula F-b may be a cyclic compound having five rings.

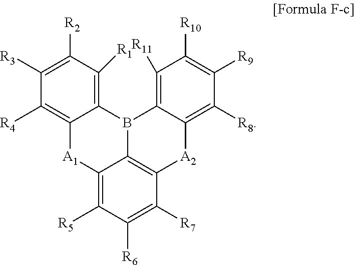

In Formula F-c, A₁ and A₂ may each independently be O, S, Se, or N(Rₘ); and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

In Formula F-c, A₁ and A₂ may each independently be bonded to a substituent of an adjacent ring to form a fused ring. For example, when A₁ and A₂ are each independently N(Rₘ), A₁ may be bonded to R₄ or R₅ to form a ring, and/or A₂ may be bonded to R₇ or R₈ to form a ring.

In an embodiment, the emission layer EML may further include, as a dopant material of the related art, a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi)), perylene or a derivative thereof (e.g., 2,5,8,11-tetra-t-butylperylene (TBP)), pyrene or a derivative thereof (e.g., 1,1-dipyrene, 1,4-dipyrenylbenzene, 1,4-bis(N,N-diphenylamino)pyrene), etc.

The emission layer EML may further include a phosphorescence dopant material of the related art. For example, a metal complex that includes iridium (Ir), platinum (Pt), osmium (Os), gold (Au), titanium (Ti), zirconium (Zr), hafnium (Hf), europium (Eu), terbium (Tb), or thulium (Tm) may be used as a phosphorescent dopant. For example, iridium(III) bis(4,6-difluorophenylpyridinato-N,C2) (FIrpic), bis(2,4-difluorophenylpyridinato)-tetrakis(1-pyrazolyl)borate iridium(III) (Fir6), or platinum octaethyl porphyrin (PtOEP) may be used as a phosphorescent dopant. However, embodiments are not limited thereto.

In embodiments, the emission layer EML may include a quantum dot. In the specification, a quantum dot may be a crystal of a semiconductor compound. A quantum dot may emit light of various emission wavelengths, depending on a size of the crystal. A quantum dot may also emit light of various emission wavelengths by adjusting an elemental ratio within a quantum dot compound.

A quantum dot may have a diameter, for example, in a range of about 1 nm to about 10 nm.

The quantum dot may be synthesized by a wet chemical process, a metal organic chemical vapor deposition process, a molecular beam epitaxy process, or similar processes.

The wet chemical process is a method of growing a crystal of quantum dot particles in which an organic solvent and a precursor material are mixed together. While the crystal grows, the organic solvent may naturally serve as a dispersant that is coordinated onto a surface of a quantum dot crystal, and may control the growth of the crystal. Therefore, the wet chemical process may control the growth of a quantum dot through low-cost process that may be more readily performed than vapor deposition such as metal organic chemical vapor deposition (MOCVD), and molecular beam epitaxy (MBE).

The quantum dot may include a Group II-VI compound, a Group III-VI compound, a Group 1-III-VI compound, a Group III-V compound, a Group III-II-V compound, a Group IV-VI compound, a Group IV element, a Group IV compound, or a combination thereof.

Examples of a Group II-VI compound may include: a binary compound such as CdSe, CdTe, CdS, ZnS, ZnSe, ZnTe, ZnO, HgS, HgSe, HgTe, MgSe, MgS, and a mixture thereof; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; a quaternary compound such as CdZnSeS, CdZnSeTe, CdZnSTe, CdHgSeS, CdHgSeTe, CdHgSTe, HgZnSeS, HgZnSeTe, HgZnSTe, and a mixture thereof; and any combination thereof.

Examples of a Group III-VI compound may include: a binary compound such as In₂S₃ and In₂Se₃; a ternary compound such as InGaS₃ and InGaSe₃; and any combination thereof.

Examples of a Group 1-III-VI compound may include: a ternary compound such as AgInS, AgInS₂, CuInS, CuInS₂, AgGaS₂, CuGaS₂, CuGaO₂, AgGaO₂, AgAlO₂, and a mixture thereof; a quaternary compound such as AgInGaS, AgInGaS₂, AgInGaSe, AgInGaSe₂, CuInGaS, and CuInGaS₂; and any combination thereof.

Examples of a Group III-V compound may include: a binary compound such as GaN, GaP, GaAs, GaSb, AlN, AlP, AlAs, AlSb, InN, InP, InAs, InSb, and a mixture thereof; a ternary compound such as GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof; and any combination thereof. In an embodiment, a Group III-V compound may further include a Group II metal. Examples of a Group III-II-V compound may include InZnP, etc.

Examples of a Group IV-VI compound may include: a binary compound such as SnS, SnSe, SnTe, PbS, PbSe, PbTe, and a mixture thereof; a ternary compound such as SnSeS, SnSeTe, SnSTe, PbSeS, PbSeTe, PbSTe, SnPbS, SnPbSe, SnPbTe, and a mixture thereof; a quaternary compound such as SnPbSSe, SnPbSeTe, SnPbSTe, and a mixture thereof; and any combination thereof. Examples of a Group IV element may include Si, Ge, and a mixture thereof. Examples of a Group IV compound may include a binary compound such as SiC, SiGe, and a mixture thereof.

Each element included in a compound, such as a binary compound, a ternary compound, or a quaternary compound, may be present in a particle at a uniform concentration distribution or at a non-uniform concentration distribution. For example, a formula may indicate the elements that are included in a compound, but an elemental ratio within the compound may vary. For example, AgInGaS₂ may indicate AgInxGaixS₂ (wherein x is a real number between 0 to 1).

In embodiments, a quantum dot may have a single structure, in which the concentration of each element included in the quantum dot is uniform, or a quantum dot may have a core-shell structure in which a quantum dot surrounds another quantum dot. For example, a material included in the core may be different from a material included in the shell.

The shell of a quantum dot may serve as a protection layer that prevents chemical deformation of the core to maintain semiconductor properties, and/or may serve as a charging layer that imparts electrophoretic properties to the quantum dot. The shell may be a single layer or multiple layers. An interface between the core and the shell may have a concentration gradient in which the concentration of an element that is present in the shell decreases towards the core.

In embodiments, a quantum dot may have the above-described core/shell structure that includes a core containing nanocrystals and a shell surrounding the core. Examples of a shell of a quantum dot may include a metal oxide, a non-metal oxide, a semiconductor compound, and a combination thereof.

Examples of a metal oxide or a non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO; or a ternary compound such as MgAl₂O₄, CoFe₂O₄, NiFe₂O₄, and CoMn₂O₄, but embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

A quantum dot may have a full width at half maximum (FWHM) of an emission wavelength spectrum equal to or less than about 45 nm. For example, the quantum dot may have an FWHM of an emission wavelength spectrum equal to or less than about 40 nm. For example, the quantum dot may have an FWHM of an emission wavelength spectrum equal to or less than about 30 nm. Color purity or color reproducibility may be improved in any of the above ranges. Light emitted through a quantum dot may be emitted in all directions, so that a wide viewing angle may be improved.

The form of a quantum dot is not particularly limited, and may be any form used in the related art. For example, a quantum dot may have a spherical shape, a pyramidal shape, a multi-arm shape, or a cubic shape, or a quantum dot may be in the form of nanoparticles, nanotubes, nanowires, nanofibers, nanoplate particles, etc.

As a size of a quantum dot is adjusted or an elemental ratio within a quantum dot compound is adjusted, an energy band gap may be changed accordingly, so that light in various wavelength ranges may be obtained from a quantum dot emission layer. Therefore, when a quantum dot is adjusted as described above (such as by using different sizes of quantum dots or different elemental ratios within a quantum dot compound), a light-emitting element that emits light in various wavelengths may be implemented. For example, a size of a quantum dot or an elemental ratio within a quantum dot compound may be adjusted to emit red light, green light, and/or blue light. In an embodiment, quantum dots may be configured to emit white light by combining various colors of light.

In the light-emitting element ED according to embodiments as shown in each of FIGS. 5 to 8, the electron transport region ETR may be provided on the emission layer EML. The electron transport region ETR may include at least one of a hole blocking layer HBL, an electron transport layer ETL, and an electron injection layer EIL, but embodiments are not limited thereto.

The electron transport region ETR may have a structure consisting of a layer consisting of a single material, a structure consisting of a layer including different materials, or a structure including multiple layers including different materials.

For example, the electron transport region ETR may have a single-layered structure of an electron injection layer EIL or an electron transport layer ETL, or the electron transport region ETR may have a single-layered structure formed of an electron injection material and an electron transport material. In embodiments, the electron transport region ETR may have an electron transport layer ETL/electron injection layer EIL structure, or a hole blocking layer HBL/electron transport layer ETL/electron injection layer EIL structure, in which the layers of each structure may be stacked in its respective stated order from the emission layer EML, but embodiments are not limited thereto. The electron transport region ETR may have a thickness, for example, in a range of about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light-emitting element ED according to an embodiment, the electron transport region ETR may include a compound represented by Formula ET-2:

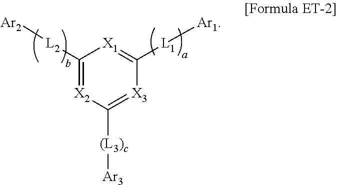

In Formula ET-2, at least one of X₁ to X₃ may each be N, and the remainder of X₁ to X₃ may each independently be C(Ra). In Formula ET-2, Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula ET-2, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer from 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When a to c are each 2 or more, multiples of each of L₁ to L₃ may each independently be a substituted or unsubstituted arylene group having 6 to 30 ring-forming carbon atoms or a substituted or unsubstituted heteroarylene group having 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(biphenyl-4-yl)-5-(4-tert-butylphenyl)-4-phenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), or a mixture thereof.

In an embodiment, the electron transport region ETR may include at least one of Compound ET1 to Compound ET36:

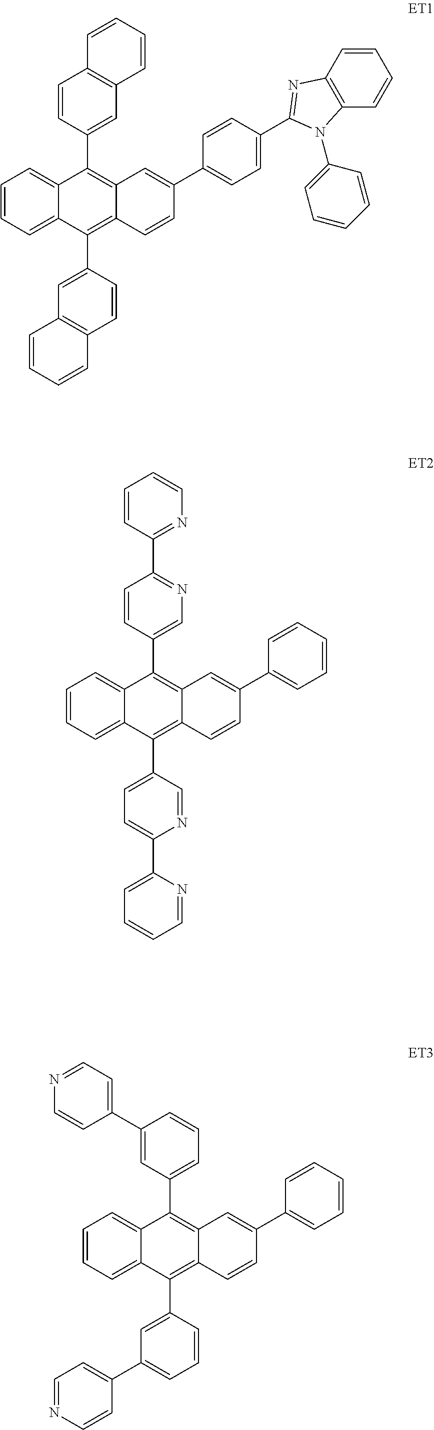 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

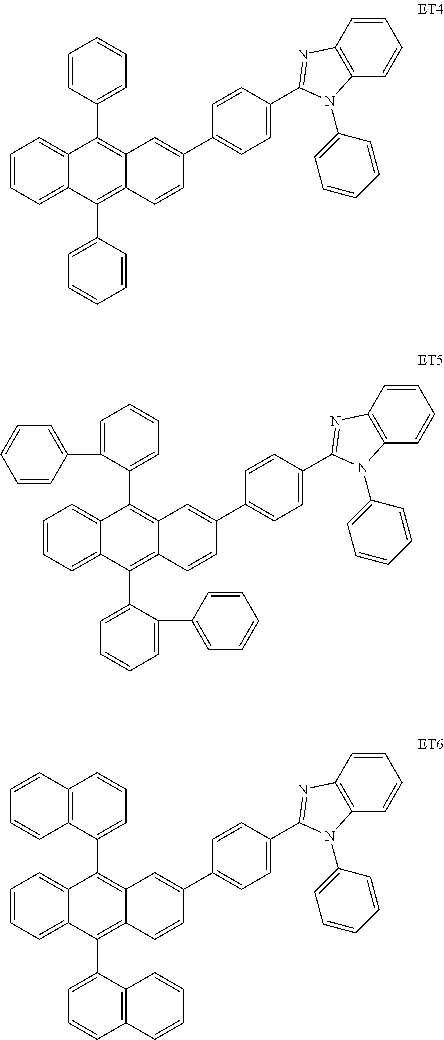 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

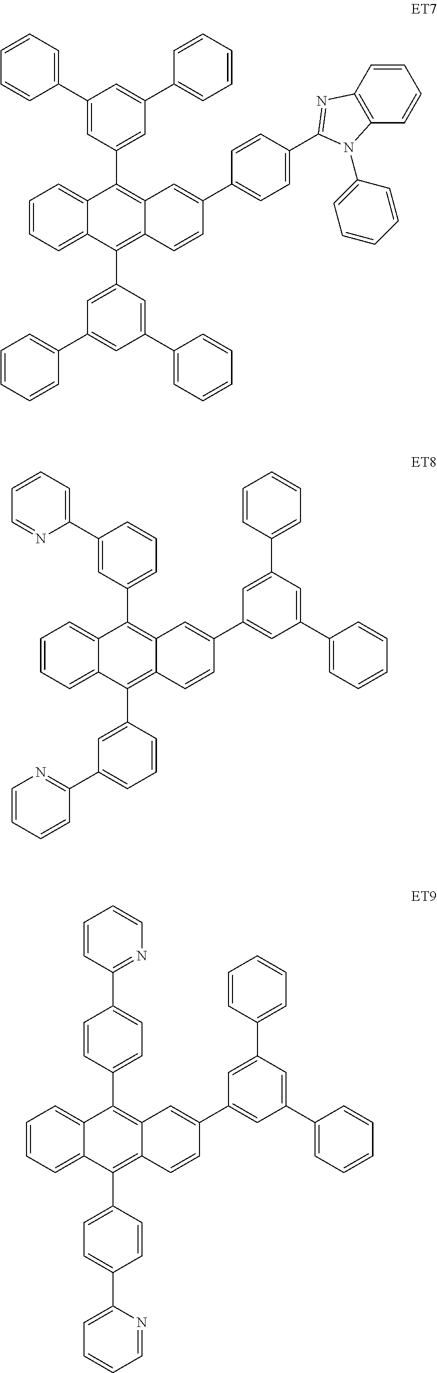 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

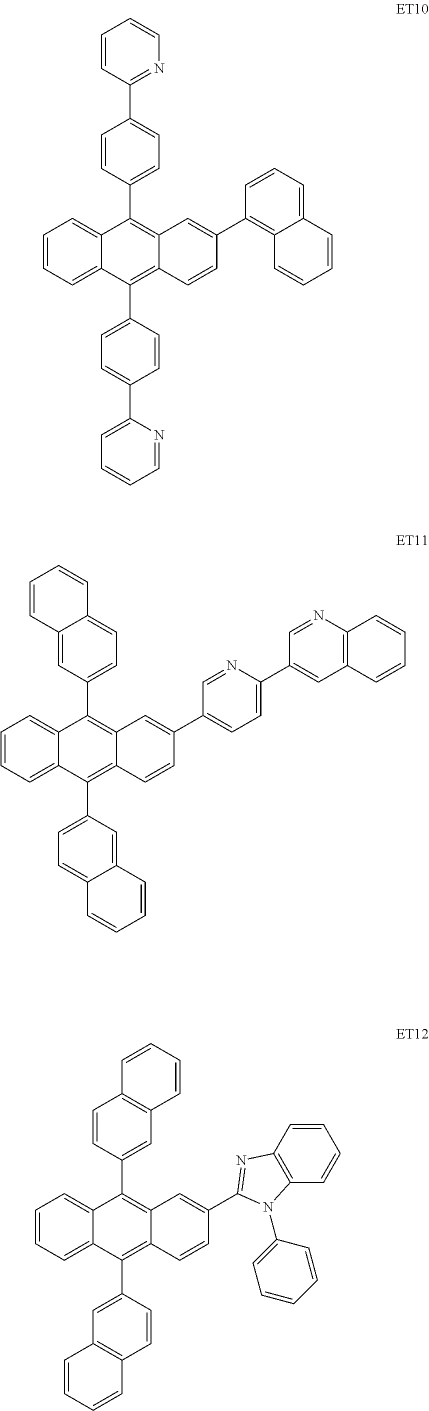 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

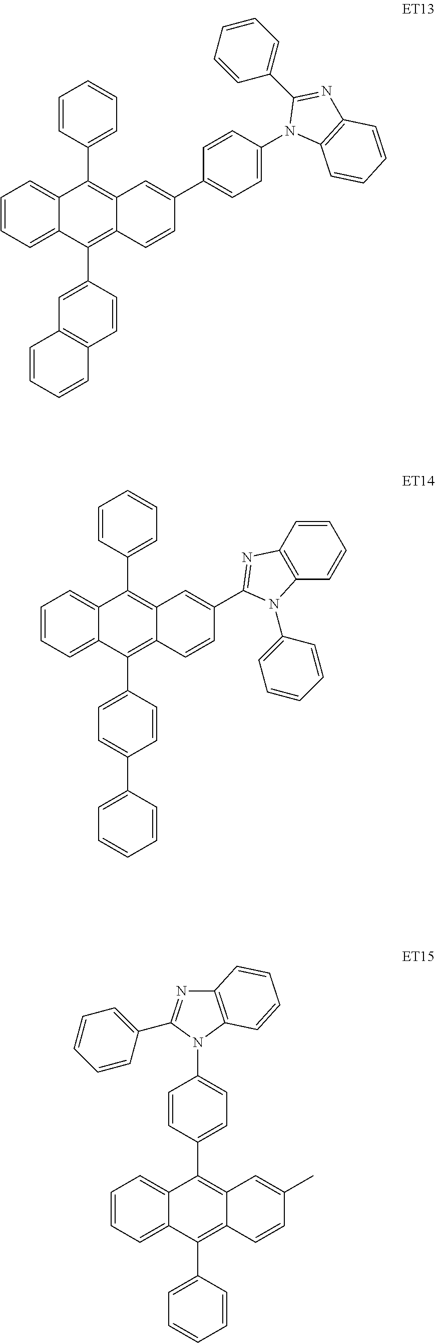 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

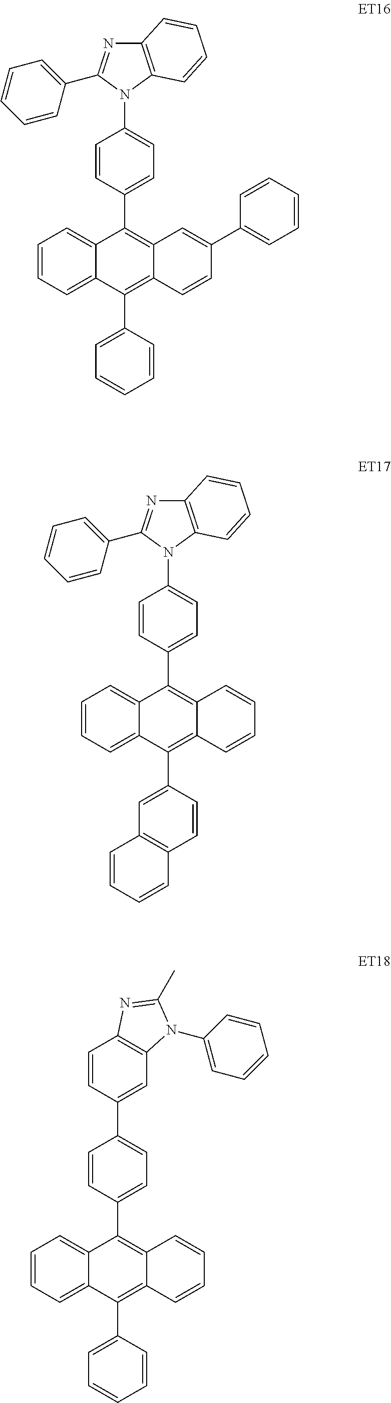 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

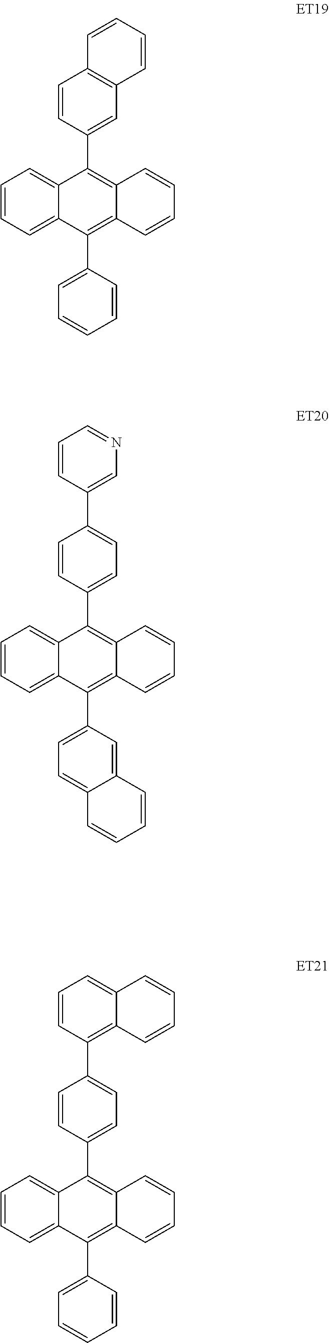

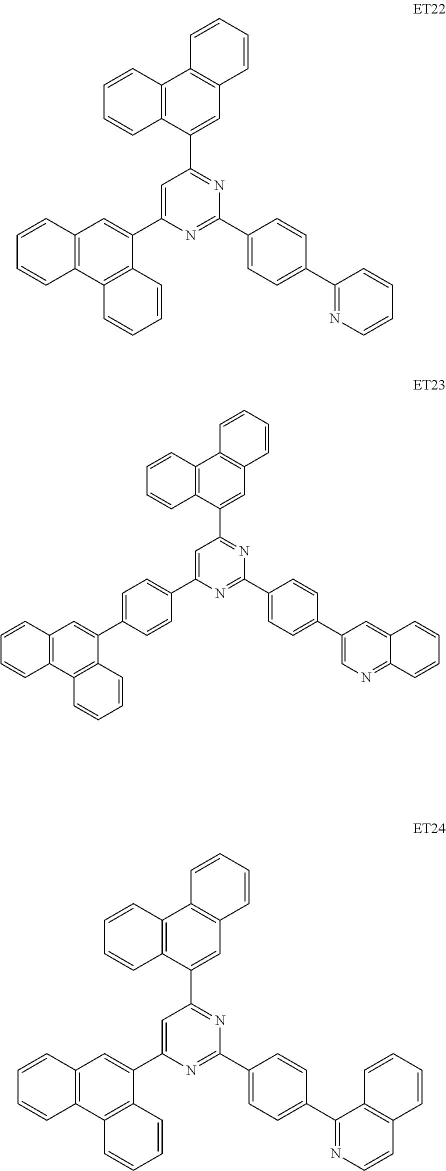 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

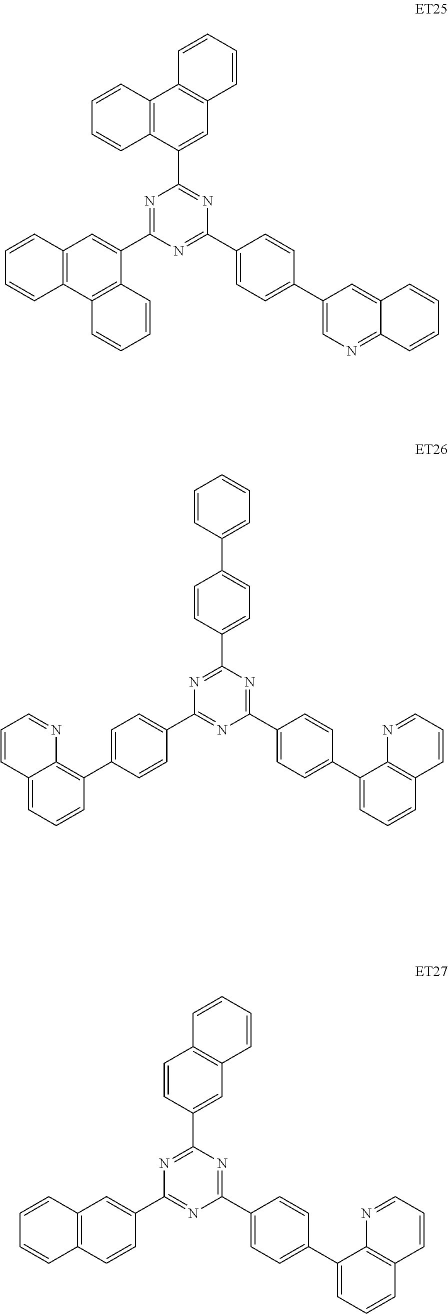 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

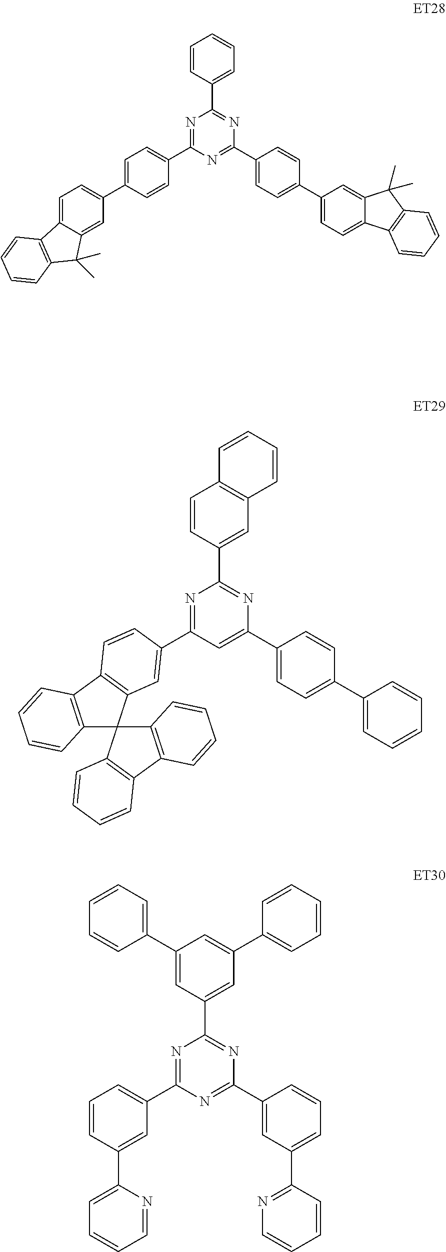 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

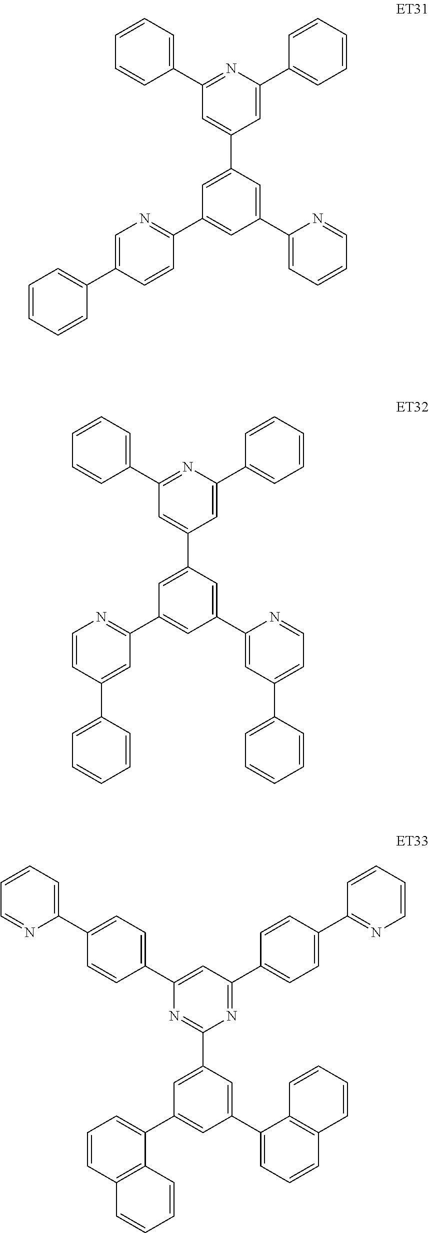 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

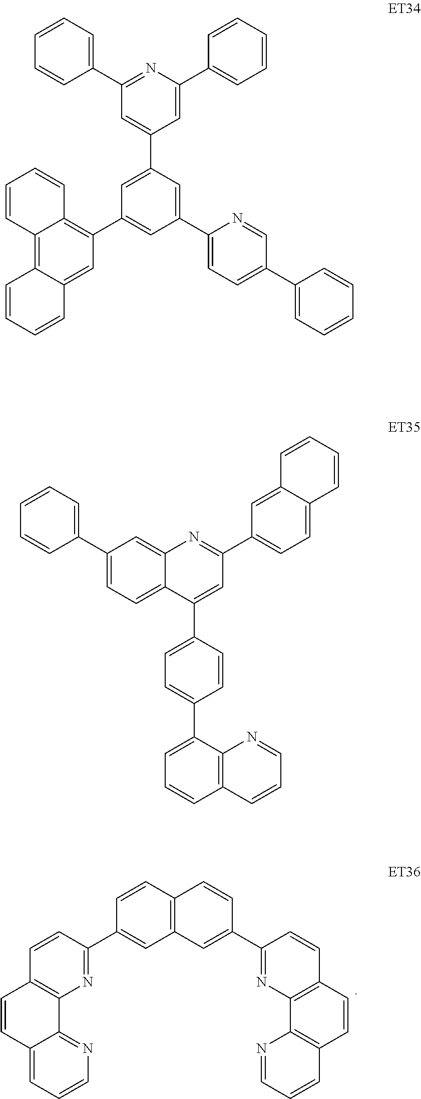 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In an embodiment, the electron transport region ETR may include: a metal halide such as LiF, NaCl, CsF, RbCl, RbI, CuI, and KI; a lanthanide metal such as Yb; or a co-deposited material of a metal halide and a lanthanide metal. For example, the electron transport region ETR may include KI:Yb, RbJ:Yb, LiF:Yb, etc., as a co-deposited material. The electron transport region ETR may include a metal oxide such as Li₂O or BaO, or 8-hydroxyl-lithium quinolate (Liq), etc., but embodiments are not limited thereto. In another embodiment, the electron transport region ETR may include a mixture material of an electron transport material and an insulating organometallic salt. The organometallic salt may be a material having an energy band gap equal to or greater than about 4 eV. For example, the organometallic salt may include a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), and 4,7-diphenyl-1,10-phenanthroline (Bphen), in addition to the above-described materials, but embodiments are not limited thereto.

The electron transport region ETR may include the above-described compounds of the electron transport region in at least one of an electron injection layer EIL, an electron transport layer ETL, and a hole blocking layer HBL.

When the electron transport region ETR includes an electron transport layer ETL, the electron transport layer ETL may have a thickness in a range of about 100 Å to about 1,000 Å. For example, the electron transport layer ETL may have a thickness in a range of about 150 Å to about 500 Å. If the thickness of the electron transport layer ETL satisfies any of the aforementioned ranges, satisfactory electron transport characteristics may be obtained without a substantial increase in driving voltage. When the electron transport region ETR includes an electron injection layer EIL, the electron injection layer EIL may have a thickness in a range of about 1 Å to about 100 Å. For example, the electron injection layer EIL may have a thickness in a range of about 3 Å to about 90 Å. If the thickness of the electron injection layer EIL satisfies any of the above-described ranges, satisfactory electron injection characteristics may be obtained without a substantial increase in driving voltage.

The second electrode EL2 may be provided on the electron transport region ETR. The second electrode EL2 may be a common electrode. The second electrode EL2 may be a cathode or an anode, but embodiments are not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is a transmissive electrode, the second electrode EL2 may include a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, or MgYb). In an embodiment, the second electrode EL2 may have a multilayered structure that includes a reflective film or a transflective film formed of the above-described materials, and a transparent conductive film formed of ITO, IZO, ZnO, ITZO, etc. For example, the second electrode EL2 may include the above-described metal materials, combinations of at least two of the above-described metal materials, oxides of the above-described metal materials, or the like.

Although not shown in the drawings, in an embodiment, the second electrode EL2 may be electrically connected to an auxiliary electrode. If the second electrode EL2 is electrically connected to an auxiliary electrode, resistance of the second electrode EL2 may decrease.

In an embodiment, the light-emitting element ED may further include a capping layer CPL disposed on the second electrode EL2. The capping layer CPL may have a multilayered structure or a single-layered structure.

In an embodiment, the capping layer CPL may be an organic layer or an inorganic layer. For example, when the capping layer CPL includes an inorganic material, the inorganic material may include an alkaline metal compound (e.g., LiF), an alkaline earth metal compound (e.g., MgF₂), SiON, SiNₓ, SiO_{y}, etc.

For example, when the capping layer CPL includes an organic material, the organic material may include a-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), etc., or may include an epoxy resin, or an acrylate such as methacrylate. However, embodiments are not limited thereto. In an embodiment, the capping layer CPL may include at least one of Compounds P1 to P5:

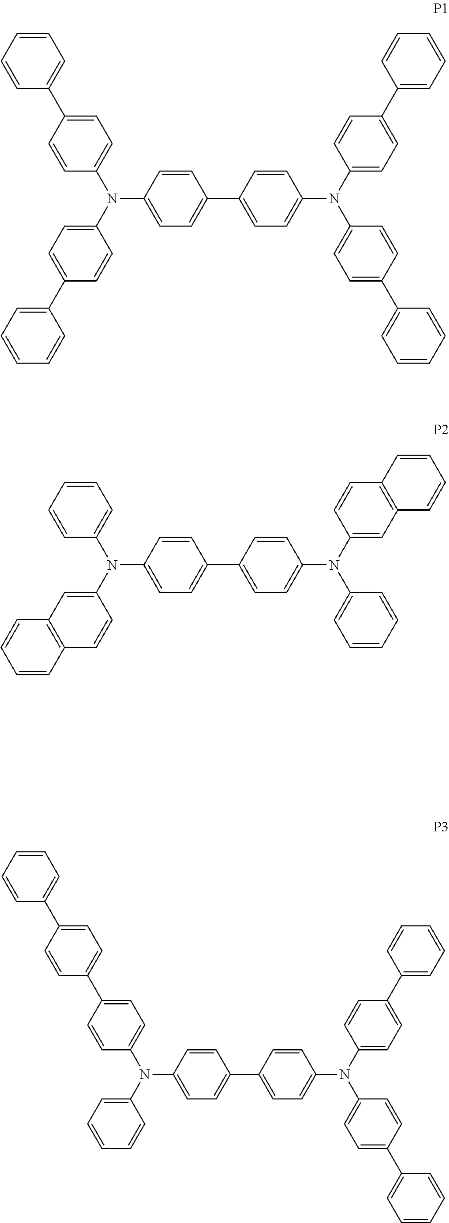 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

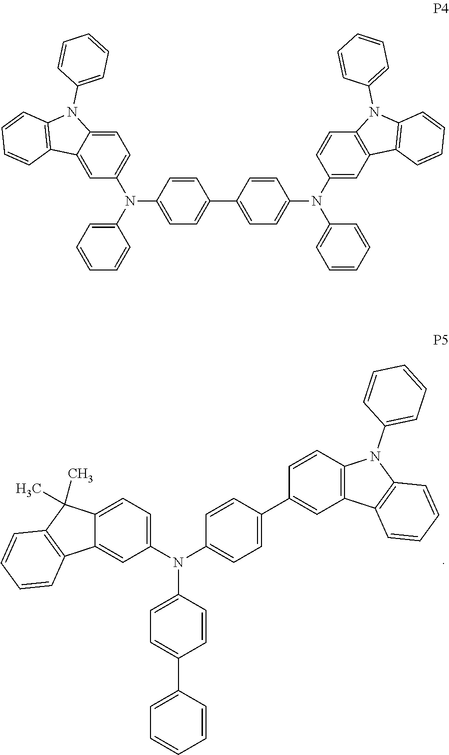 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be equal to or greater than about 1.6 or more. For example, the refractive index of the capping layer CPL may be equal to or greater than about 1.6, with respect to light in a wavelength range of about 550 nm to about 660 nm.

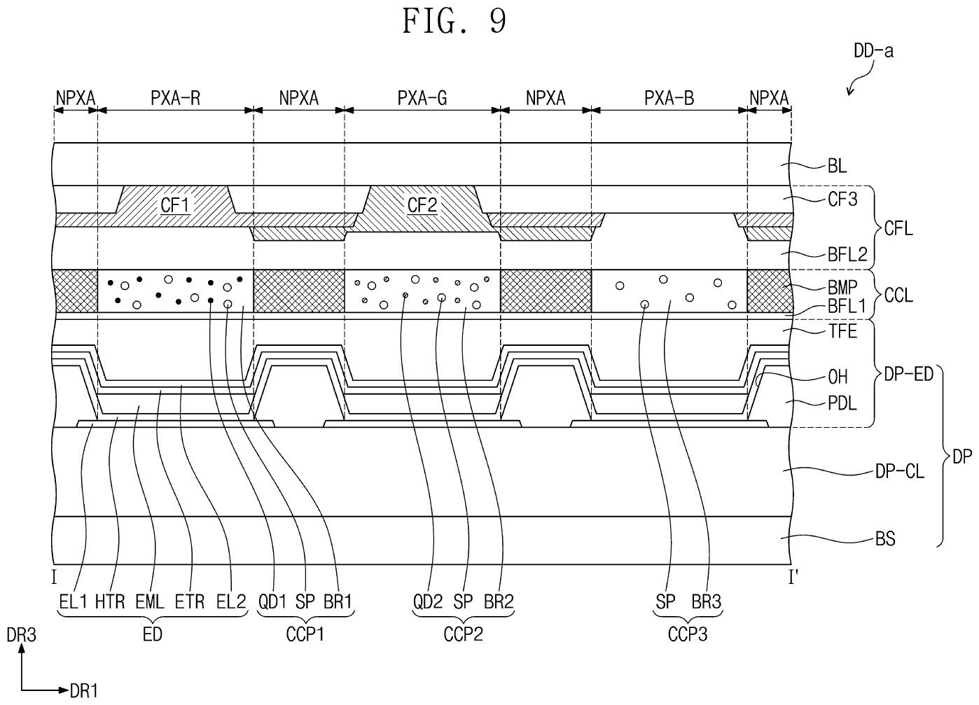

FIGS. 9 to 12 are each a schematic cross-sectional view of a display device according to an embodiment. Hereinafter, in describing the display devices according to embodiments as shown in FIGS. 9 to 12, the features that have been previously described above with respect to FIGS. 3 to 8 will not be described again, and the differing features will be described.

Referring to FIG. 9, a display device DD-a according to an embodiment may include a display panel DP that includes a display element layer DP-ED, a light control layer CCL disposed on the display panel DP, and a color filter layer CFL. In an embodiment shown in FIG. 9, the display panel DP may include a base layer BS, a circuit layer DP-CL provided on the base layer BS, and the display element layer DP-ED, and the display element layer DP-ED may include a light-emitting element ED.

The light-emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In embodiments, a structure of the light-emitting element ED shown in FIG. 9 may be the same as a structure of a light-emitting element ED according to one of FIGS. 5 to 8 as described above.

Referring to FIG. 9, the emission layer EML may be disposed in an opening OH defined in a pixel defining film PDL. For example, the emission layer EML, which is separated by the pixel defining film PDL and provided to correspond to each of the light emitting regions PXA-R, PXA-G, and PXA-B, may emit light in a same wavelength range. In the display device DD-a, the emission layer EML may emit blue light. Although not shown in the drawings, in an embodiment, the emission layer EML may be provided as a common layer throughout all of the light emitting regions PXA-R, PXA-G, and PXA-B.

The light control layer CCL may be disposed on the display panel DP. The light control layer CCL may include a light conversion body. The light conversion body may be a quantum dot, a phosphor, or the like. The light conversion body may convert the wavelength of a provided light and emit the converted light. For example, the light control layer CCL may be a layer that includes a quantum dot or a layer that includes a phosphor.

The light control layer CCL may include light control parts CCP1, CCP2, and CCP3. The light control parts CCP1, CCP2, and CCP3 may be spaced apart from each other.

Referring to FIG. 9, divided patterns BMP may be disposed between the light control parts CCP1, CCP2, and CCP3 that are spaced apart from each other, but embodiments are not limited thereto. In FIG. 9, it is shown that the divided patterns BMP do not overlap the light control parts CCP1, CCP2, and CCP3, but the edges of the light control parts CCP1, CCP2, and CCP3 may overlap at least a portion of the divided patterns BMP.

The light control layer CCL may include a first light control part CCP1 including a first quantum dot QD1 that converts first color light provided from the light-emitting element ED into second color light, a second light control part CCP2 including a second quantum dot QD2 that converts the first color light into third color light, and a third light control part CCP3 that transmits the first color light.

In an embodiment, the first light control part CCP1 may provide red light that is the second color light, and the second light control part CCP2 may provide green light that is the third color light. The third light control part CCP3 may provide blue light by transmitting the blue light that is the first color light provided from the light-emitting element ED. For example, the first quantum dot QD1 may be a red quantum dot, and the second quantum dot QD2 may be a green quantum dot. The quantum dots QD1 and QD2 may each be a quantum dot as described above.

The light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include a quantum dot but may include the scatterer SP.

The scatterer SP may be inorganic particles. For example, the scatterer SP may include at least one of TiO₂, ZnO, Al₂O₃, SiO₂, and hollow silica. The scatterer SP may include one of TiO₂, ZnO, Al₂O₃, SiO₂, and hollow silica, or may be a mixture of at least two materials selected from TiO₂, ZnO, Al₂O₃, SiO₂, and hollow silica.

The first light control part CCP1, the second light control part CCP2, and the third light control part CCP3 may respectively include base resins BR1, BR2, and BR3, in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed, and may include various resin compositions, which may be referred to as a binder. For example, the base resins BR1, BR2, and BR3 may be acrylic-based resins, urethane-based resins, silicone-based resins, epoxy-based resins, etc. The base resins BR1, BR2, and BR3 may each be a transparent resin. In an embodiment, the first base resin BR1, the second base resin BR2, and the third base resin BR3 may be the same as or different from each other.

The light control layer CCL may include a barrier layer BFL1. The barrier layer BFL1 may prevent the penetration of moisture and/or oxygen (hereinafter, referred to as ‘moisture/oxygen’). The barrier layer BFL1 may block the light control parts CCP1, CCP2, and CCP3 from exposure to moisture/oxygen. The barrier layer BFL1 may cover the light control parts CCP1, CCP2, and CCP3. In an embodiment, the barrier layer BFL2 may be provided between the light control parts CCP1, CCP2, and CCP3, and the filters CF1, CF2, and CF3.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film that secures light transmittance, etc. The barrier layers BFL1 and BFL2 may each independently further include an organic film. The barrier layers BFL1 and BFL2 may each independently have a single-layered structure or a multilayered structure.

In the display device DD-a, the color filter layer CFL may be disposed on the light control layer CCL. In an embodiment, the color filter layer CFL may be directly disposed on the light control layer CCL. For example, the barrier layer BFL2 may be omitted.

The color filter layer CFL may include filters CF1, CF2, and CF3. The color filter layer CFL may include a first filter CF1 that transmits second color light, a second filter CF2 that transmits third color light, and a third filter CF3 that transmits first color light. For example, the first filter CF1 may be a red filter, the second filter CF2 may be a green filter, and the third filter CF3 may be a blue filter. The filters CF1, CF2, and CF3 may each include a polymeric photosensitive resin and a pigment or dye. The first filter CF1 may include a red pigment or dye, the second filter CF2 may include a green pigment or dye, and the third filter CF3 may include a blue pigment or dye.

However, embodiments are not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

In an embodiment, the first filter CF1 and the second filter CF2 may each be a yellow filter. In another embodiment, the first filter CF1 and the second filter CF2 may not be provided as separate filters and may be provided as a unitary filter.

Although not shown in the drawings, in an embodiment, the color filter layer CFL may further include a light shielding part (not shown). The light shielding part (not shown) may be a black matrix. The light shielding part (not shown) may include an organic light shielding material or an inorganic light shielding material, each including a black pigment or a black dye.

The light shielding part (not shown) may prevent light leakage, and may separate boundaries between adjacent filters CF1, CF2, and CF3.

The first to third filters CF1, CF2, and CF3 may be respectively disposed in the red light emitting region PXA-R, the green light emitting region PXA-G, and the blue light emitting region PXA-B.

A base substrate BL may be disposed on the color filter layer CFL. The base substrate BL may provide a base surface on which the color filter layer CFL, the light control layer CCL, and the like are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

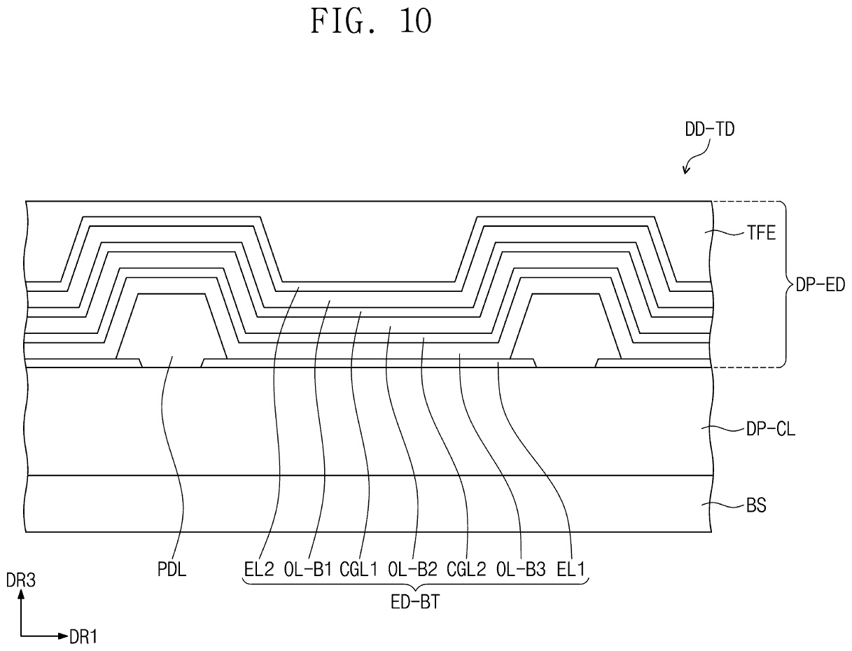

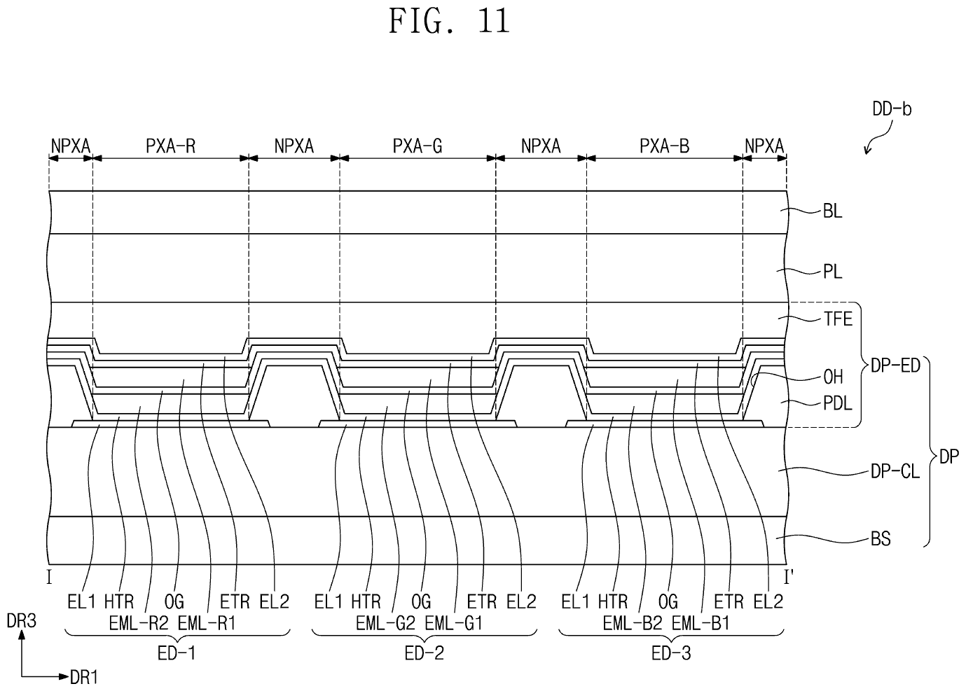

FIG. 10 is a schematic cross-sectional view of a portion of a display device according to an embodiment. In the display device DD-TD according to an embodiment, a light-emitting element ED-BT may include light emitting structures OL-B1, OL-B2, and OL-B3. The light-emitting element ED-BT may include a first electrode EL1 and a second electrode EL2 that face each other, and the light emitting structures OL-B1, OL-B2, and OL-B3, which are stacked in a thickness direction between the first electrode EL1 and the second electrode EL2. The light emitting structures OL-B1, OL-B2, and OL-B3 may each include a hole transport region HTR, an emission layer EML (FIG. 9), and an electron transport region ETR, which may be disposed in that order between the first electrode EL1 and the second electrode EL2.

For example, the light-emitting element ED-BT that is included in the display device DD-TD may be a light-emitting element having a tandem structure that includes multiple emission layers.

In an embodiment shown in FIG. 10, light emitted from the light emitting structures OL-B1, OL-B2, and OL-B3 may each be blue light. However, embodiments are not limited thereto, and the light emitted from each of the light emitting structures OL-B1, OL-B2, and OL-B3 may have wavelength ranges that are different from each other. For example, the light-emitting element ED-BT that includes the light emitting structures OL-B1, OL-B2, and OL-B3, which emit light having wavelength ranges that are different from each other, may emit white light.

Charge generation layers CGL1 and CGL2 may be disposed respectively between two adjacent light emitting structures among the light emitting structures OL-B1, OL-B2, and OL-B3. The charge generation layers CGL1 and CGL2 may each independently include a p-type charge generation layer and/or an n-type charge generation layer.

At least one of the light emitting structures OL-B1, OL-B2, and OL-B3 may include the fused polycyclic compound according to an embodiment. For example, at least one of the emission layers included in the light-emitting element ED-BT may include the fused polycyclic compound according to an embodiment.

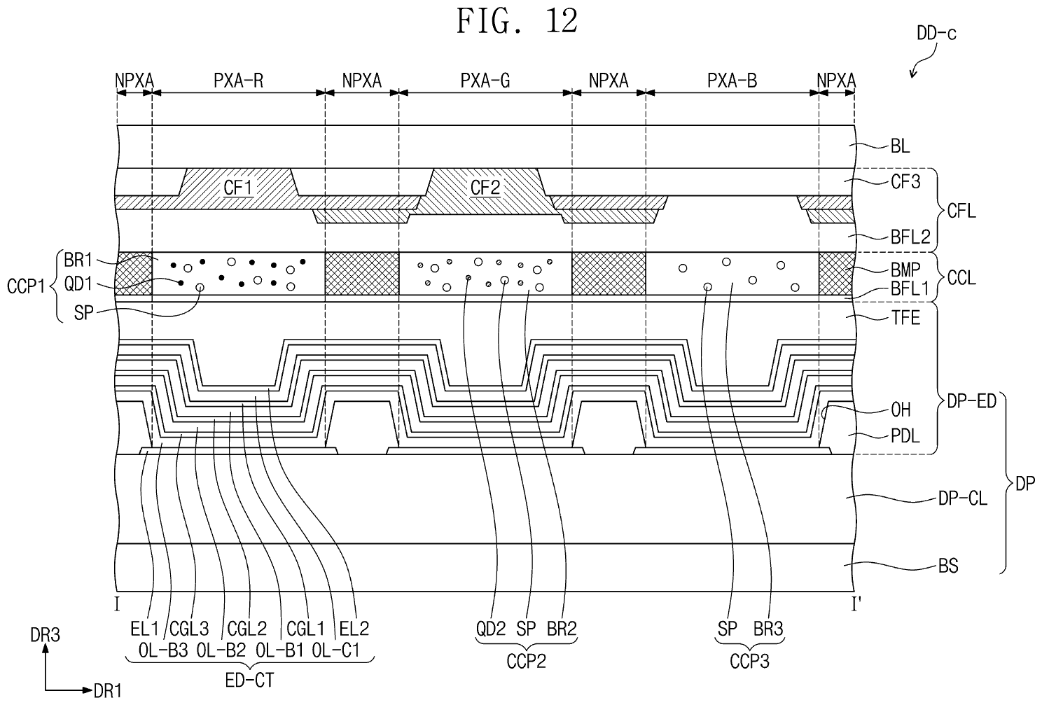

FIG. 11 is a schematic cross-sectional view of a display device DD-b according to an embodiment. FIG. 12 is a schematic cross-sectional view of a display device DD-c according to an embodiment.

Referring to FIG. 11, a display device DD-b according to an embodiment may include light-emitting elements ED-1, ED-2, and ED-3, in which two emission layers are stacked. In comparison to the display device DD shown in FIG. 4, the embodiment shown in FIG. 11 is different at least in that the first to third light-emitting elements ED-1, ED-2, and ED-3 each include two emission layers that are stacked in a thickness direction. In each of the first to third light-emitting elements ED-1, ED-2, and ED-3, the two emission layers may emit light in a same wavelength region.

The first light-emitting element ED-1 may include a first red emission layer EML-R1 and a second red emission layer EML-R2. The second light-emitting element ED-2 may include a first green emission layer EML-G1 and a second green emission layer EML-G2. The third light-emitting element ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may have a single-layered structure or a multilayered structure. The emission auxiliary part OG may include a charge generation layer. For example, the emission auxiliary part OG may include an electron transport region, a charge generation layer, and a hole transport region, which may be stacked in that order. The emission auxiliary part OG may be provided as a common layer throughout the first to third light-emitting elements ED-1, ED-2, and ED-3. However, embodiments are not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may each be disposed between the emission auxiliary part OG and the electron transport region ETR. The second red emission layer EML-R2, the second green emission layer EML-G2, and the second blue emission layer EML-B2 may each be disposed between the hole transport region HTR and the emission auxiliary part OG.

The first light-emitting element ED-1 may include the first electrode EL1, the hole transport region HTR, the second red emission layer EML-R2, the emission auxiliary part OG, the first red emission layer EML-R1, the electron transport region ETR, and the second electrode EL2, which are stacked in that order. The second light-emitting element ED-2 may include the first electrode EL1, the hole transport region HTR, the second green emission layer EML-G2, the emission auxiliary part OG, the first green emission layer EML-G1, the electron transport region ETR, and the second electrode EL2, which are stacked in that order. The third light-emitting element ED-3 may include the first electrode EL1, the hole transport region HTR, the second blue emission layer EML-B2, the emission auxiliary part OG, the first blue emission layer EML-B1, the electron transport region ETR, and the second electrode EL2, which are stacked in that order.

An optical auxiliary layer PL may be disposed on the display element layer DP-ED. The optical auxiliary layer PL may include a polarizing layer. The optical auxiliary layer PL may be disposed on the display panel DP and may control light that is reflected at the display panel DP from an external light. Although not shown in the drawings, in an embodiment, the optical auxiliary layer PL may be omitted from the display device DD-b.

At least one emission layer included in a display device DD-b shown in FIG. 11 may include the fused polycyclic compound according to an embodiment as described above. For example, in an embodiment, at least one of the first blue emission layer EML-B1 and the second blue emission layer EML-B2 may include the fused polycyclic compound according to an embodiment.

In contrast to FIGS. 10 and 11, FIG. 12 shows a display device DD-c that is different at least in that it includes four light emitting structures OL-B1, OL-B2, OL-B3, and OL-C1. A light-emitting element ED-CT may include a first electrode EL1 and a second electrode EL2 that face each other, and first to fourth light emitting structures OL-B1, OL-B2, OL-B3, and OL-C1 that are stacked in a thickness direction between the first electrode EL1 and the second electrode EL2.

Charge generation layers CGL1, CGL2, and CGL3 may be respectively disposed between two adjacent light emitting structures among the first to fourth light emitting structures OL-B1, OL-B2, OL-B3, and OL-C1. In an embodiment, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light in different wavelength regions.

The charge generation layers CGL1, CGL2, and CGL3 may each independently include a p-type charge generation layer and/or an n-type charge generation layer.

At least one of the light emitting structures OL-B1, OL-B2, OL-B3, and OL-C1 included in a display device DD-c may include the fused polycyclic compound according to an embodiment as described above. For example, in an embodiment, at least one of the first to third light emitting structures OL-B1, OL-B2, and OL-B3 may include the above-described fused polycyclic compound according to an embodiment.

The light-emitting element ED according to an embodiment may include the fused polycyclic compound represented by Formula 1 in at least one functional layer disposed between the first electrode EL1 and the second electrode EL2, thereby exhibiting excellent luminous efficiency and improved lifespan properties. For example, the fused polycyclic compound according to an embodiment may be included in the emission layer EML of the light-emitting element ED, and thus the light-emitting element according to an embodiment may exhibit long lifespan properties.

In an embodiment, an electronic device may include a display device that includes multiple light-emitting elements, and a control part that controls the display device. The electronic device may be a device that is activated according to an electrical signal. The electronic device may include display devices according to various embodiments. Examples of an electronic device may include large, medium-sized, and small devices, such as a television set, a monitor, a billboard, a personal computer, a laptop computer, a personal digital terminal, a display device for a vehicle, a game console, a portable electronic device, and a camera.

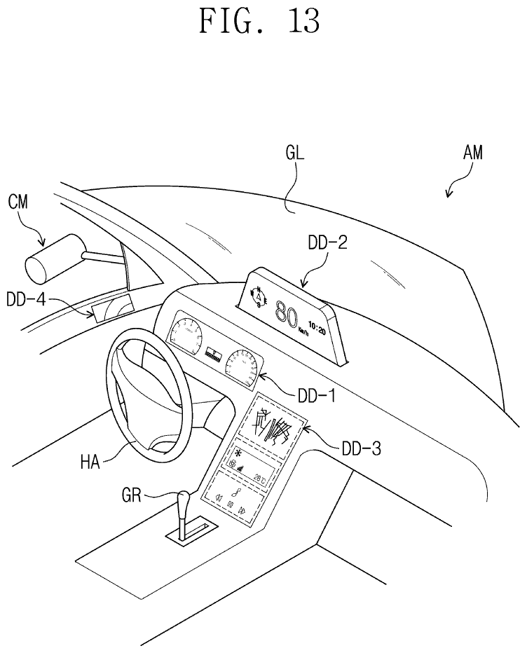

FIG. 13 is a schematic diagram of a vehicle AM in which first to fourth display devices DD-1, DD-2, DD-3, and DD-4 are disposed. At least one of the first to fourth display devices DD-1, DD-2, DD-3, and DD-4 may have a structure according to one of display devices DD, DD-TD, DD-a, DD-b, and DD-c, as described above with reference to FIGS. 3, 4, and 9 to 12.

FIG. 13 shows an automobile as a vehicle AM, but this is only an example, and the first to fourth display devices DD-1, DD-2, DD-3, and DD-4 may be disposed in various transportation means, such as a bicycle, a motorcycle, a train, a ship, and an airplane. In an embodiment, at least one of the first to fourth display devices DD-1, DD-2, DD-3, and DD-4, having a structure according to one of display devices DD, DD-TD, DD-a, DD-b, and DD-c, may be included in a personal computer, a laptop computer, a personal digital terminal, a game console, a portable electronic device, a television, a monitor, a billboard, or the like. However, these are merely provided as examples, and the display device may be included in other electronic devices.

At least one of the first to fourth display devices DD-1, DD-2, DD-3, and DD-4 may each independently include a light-emitting element ED according to an embodiment, as described with reference to any of FIGS. 5 to 8. The light-emitting element ED may include the fused polycyclic compound according to an embodiment. At least one of the first to fourth display devices DD-1, DD-2, DD-3, and DD-4 may each independently include the fused polycyclic compound according to an embodiment. At least one of the first to fourth display devices DD-1, DD-2, DD-3, and DD-4 may each independently include a light-emitting element ED that includes a fused polycyclic compound according to an embodiment, thereby exhibiting long lifespan properties.

Referring to FIG. 13, the vehicle AM may include a steering wheel HA and a gearshift GR for driving the vehicle AM. The vehicle AM may include a front window GL that is disposed so as to face the driver.

A first display device DD-1 may be disposed in a first region that overlaps the steering wheel HA. For example, the first display device DD-1 may be a digital cluster that displays first information of the vehicle AM. The first information may include a first scale that indicates a driving speed of the vehicle AM, a second scale that indicates an engine speed (for example, as revolutions per minute (RPM)), an image that represents a fuel gauge, etc. The first scale and the second scale may each be represented by a digital image.

A second display device DD-2 may be disposed in a second region facing the driver's seat and overlapping the front window GL. The driver's seat may be a seat where the steering wheel HA is disposed. For example, the second display device DD-2 may be a head up display (HUD) that displays second information of the vehicle AM. The second display device DD-2 may be optically transparent. The second information may include digital numbers that indicate a driving speed, and may further include information such as the current time. Although not shown in the drawings, in an embodiment, the second information of the second display device DD-2 may be displayed by being projected onto the front window GL.

A third display device DD-3 may be disposed in a third region that is adjacent to the gearshift GR. For example, the third display device DD-3 may be disposed between the driver's seat and the passenger seat, and may be a center information display (CID) for a vehicle that displays third information. The passenger seat may be a seat that is spaced apart from the driver's seat, and the gearshift GR may be disposed between the driver's seat and the passenger seat. The third information may include information about traffic conditions (e.g., navigation information), about music or radio that is playing, about a video (or an image) that is displayed, about temperatures inside the vehicle AM, etc.

A fourth display device DD-4 may be spaced apart from the steering wheel HA and the gearshift GR, and may be disposed in a fourth region that is adjacent to a side of the vehicle AM. For example, the fourth display device DD-4 may be a digital side-view mirror that displays fourth information. The fourth display device DD-4 may display an image that is external to the vehicle AM, which may be taken by a camera module CM that is disposed on the exterior of the vehicle AM. The fourth information may include an exterior image of the vehicle AM.

The first to fourth information as described above are only provided as examples, and the first to fourth display devices DD-1, DD-2, DD-3, and DD-4 may further display information on the interior and exterior of the vehicle AM. The first to fourth information may include information that is different from each other. However, embodiments are not limited thereto, and a part of the first to fourth information may include a same information as one another.

Hereinafter, a fused polycyclic compound according to an embodiment and a light-emitting element according to an embodiment will be described with reference to the Examples and the Comparative Examples. The Examples described below are only provided to assist in understanding the disclosure, and the scope thereof is not limited thereto.

### EXAMPLES

### 1. Synthesis of Fused Polycyclic Compound

A synthesis method of the fused polycyclic compound according to an embodiment will be explained in detail by describing synthesis methods for Compounds 5, 29, 77, 18, 72, 81, 89, 94, and 100. The methods for synthesizing a fused polycyclic compound according to an embodiment are provided only as examples, and the synthesis methods for the fused polycyclic compound according to an embodiment are not limited to the Examples below.

### (1) Synthesis of Compound 5

Compound 5 according to an embodiment may be synthesized by, for example, Reaction Scheme 1:

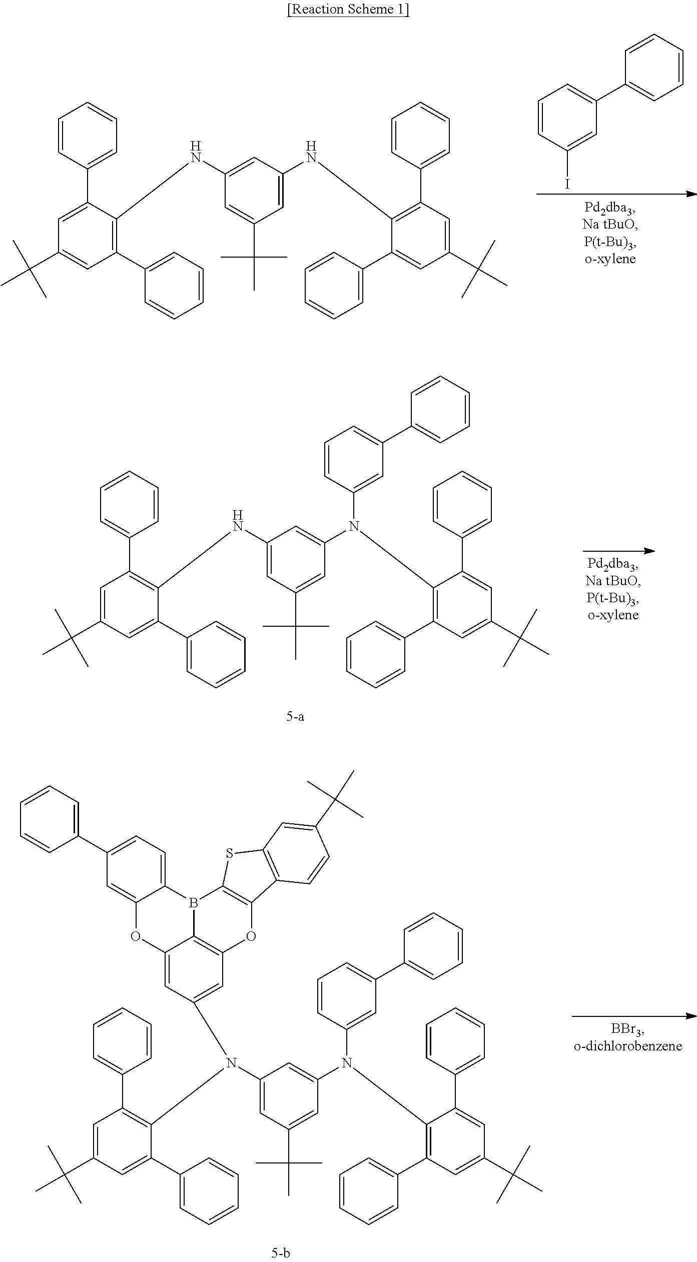

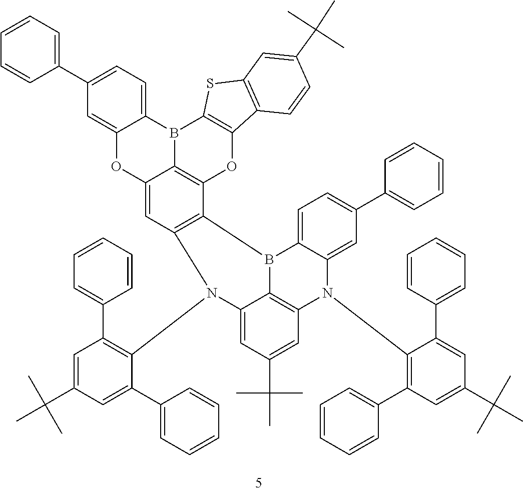 [SMILES: CC(C)(C)c1cc(-c2ccccc2)c(N2c3cc(-c4ccccc4)ccc3B3c4c2cc(C(C)(C)C)cc4N(c2c(-c4ccccc4)cc(C(C)(C)C)cc2-c2ccccc2)c2cc4c5c(c23)Oc2c(sc3cc(C(C)(C)C)ccc23)B5c2ccc(-c3ccccc3)cc2O4)c(-c2ccccc2)c1]

### 1) Synthesis of Intermediate Compound 5-a

In an argon atmosphere, in a flask of 2 L, 5-(tert-butyl)-N1,N3-bis(5′-(tert-butyl)-[1,1′:3′,1″-terphenyl]-2′-yl)benzene-1,3-diamine (10 g, 13.5 mmol), 3-iodobipheny (2 g, 7 mmol), Pd₂dba₃ (1.6 g, 1.9 mmol), tris-tert-butyl phosphine (P(t-Bu)₃, 1.6 mL, 3.8 mmol), and sodium tert-butoxide (Na tBuO, 5.8 g, 60 mmol) were mixed, dissolved in o-xylene of 150 mL, and the reaction solution was stirred at about 140° C. for about 2 hours. After cooling, water (1 L) and ethyl acetate (300 mL) were added, and the obtained mixture was subjected to extraction to collect an organic layer, was dried over MgSO₄, and filtered. A solvent was removed from the filtered solution under reduced pressure, and the obtained solid was purified and separated by column chromatography using silica gel with CH₂Cl₂ and hexane as a developing solvent to obtain Intermediate Compound 5-a (white solid, 3.4 g, yield: 54%).

ESI-LCMS: [M]⁺: C₆₆H₆₄N₂. 885.2506.

### 2) Synthesis of Intermediate Compound 5-b

In an argon atmosphere, in a flask of 2 L, Intermediate Compound 5-a (3.4 g, 3.8 mmol), 7-bromo-12-(tert-butyl)-3-phenyl-5,9-dioxa-14-thia-14b-borafluoreno[3,2,1-de]anthracene (2 g, 3.8 mmol), Pd₂dba₃ (1.6 g, 1.9 mmol), tris-tert-butyl phosphine (1.6 mL, 3.8 mmol), and sodium tert-butoxide (5.8 g, 60 mmol) were mixed, dissolved in o-xylene of 50 mL, and the reaction solution was stirred at about 140° C. for about 2 hours. After cooling, water (1 L) and ethyl acetate (300 mL) were added, and the obtained mixture was subjected to extraction to collect an organic layer, was dried over MgSO₄, and filtered. A solvent was removed from the filtered solution under reduced pressure, and the obtained solid was purified and separated by column chromatography using silica gel with CH₂Cl₂ and hexane as a developing solvent to obtain Intermediate Compound 5-b (yellow solid, 2.9 g, yield: 58%).

ESI-LCMS: [M]⁺: C₉₆H₈₅BN₂O₂S. 1340.6462.

### 3) Synthesis of Compound 5

In an argon atmosphere, in a flask of 1 L, Intermediate Compound 5-b (2.9 g, 2.1 mmol) was dissolved in o-dichlorobenzene of 50 mL, and BBr₃ (1.5 equiv.) was added. The reaction solution was stirred at about 140° C. for about 12 hours. After cooling, triethylamine was added to terminate the reaction, a solvent was removed under reduced pressure, and the obtained solid was purified and separated by column chromatography using silica gel with CH₂Cl₂ and hexane as a developing solvent to obtain Compound 5 (yellow solid, 3.2 g, yield: 23%).

ESI-LCMS: [M]⁺: C₉₆H₈₂B₂N₂O₂S. 1348.6340

¹H-NMR (CDCl₃): d=8.02 (m, 2H), 7.99 (s, 4H), 7.90 (d, 2H), 7.75 (d, 4H), 7.49 (m, 8H), 7.36 (m, 12H), 7.29 (s, 1H), 7.27 (s, 1H), 7.11 (m, 8H), 7.03 (s, 2H), 6.42 (s, 1H), 1.49 (s, 9H), 1.32 (s, 9H), 1.22 (s, 18H)

### (2) Synthesis of Compound 29

Compound 29 according to an embodiment may be synthesized by, for example, Reaction Scheme 2:

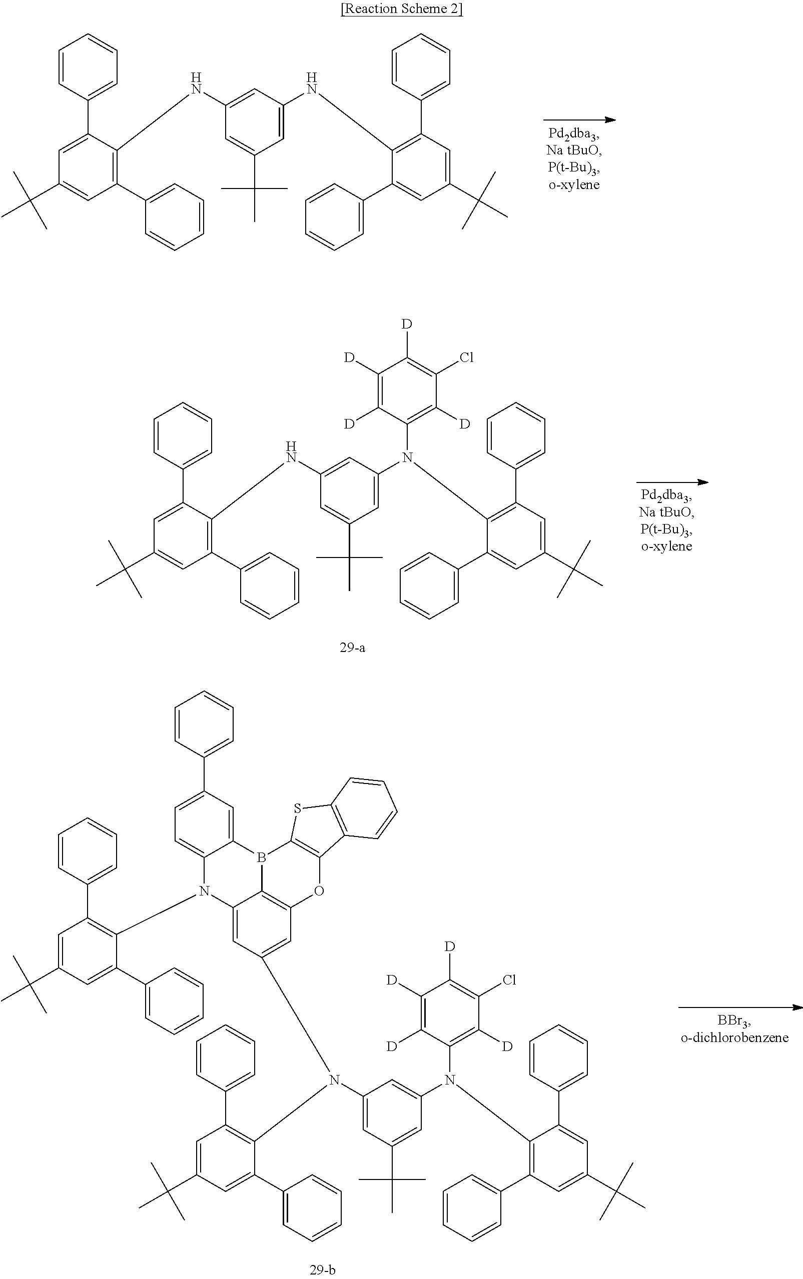

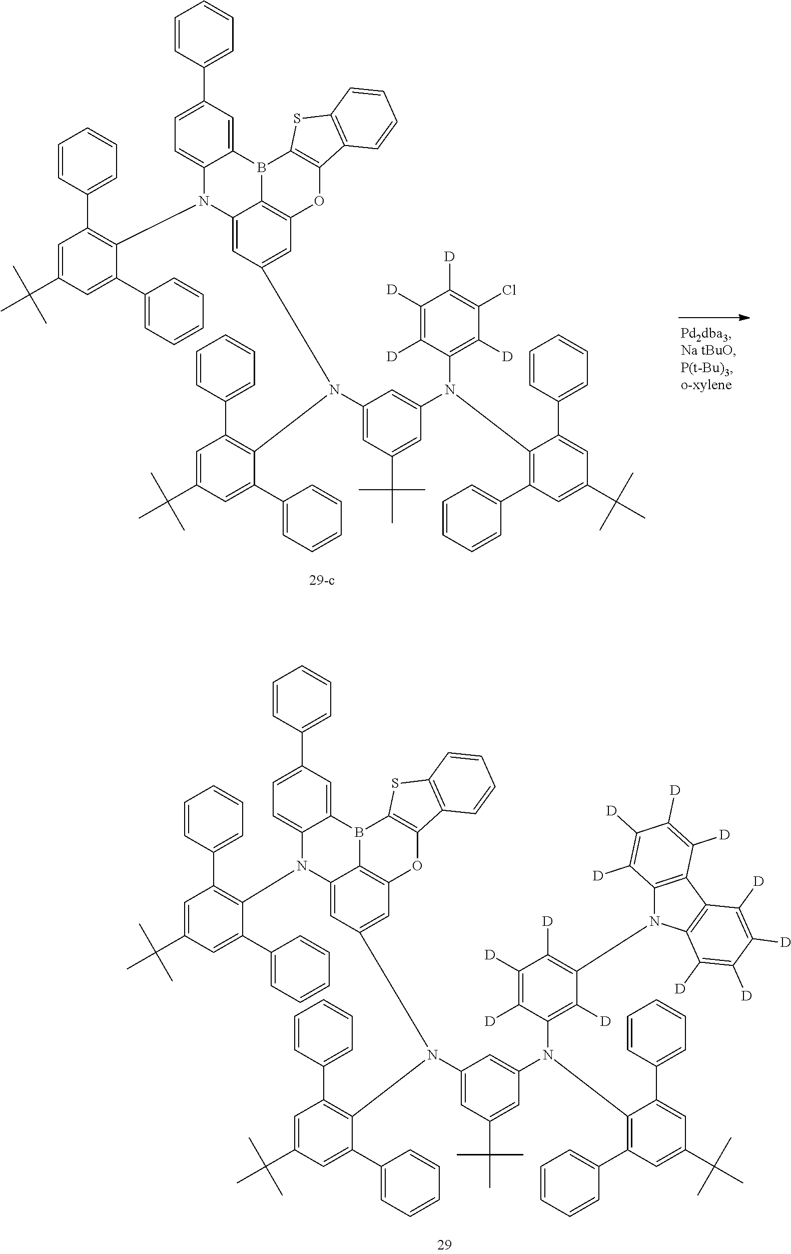

### 1) Synthesis of Intermediate Compound 29-a

In an argon atmosphere, in a flask of 2 L, 5-(tert-butyl)-N1,N3-bis(5′-(tert-butyl)-[1,1′:3′,1″-terphenyl]-2′-yl)benzene-1,3-diamine (10 g, 13.5 mmol), 1-chloro-3-iodobenzene-2,4,5,6-d4 (3.2 g, 7 mmol), pd₂dba₃ (1.6 g, 1.9 mmol), tris-tert-butyl phosphine (1.6 mL, 3.8 mmol), and sodium tert-butoxide (5.8 g, 60 mmol) were mixed, dissolved in o-xylene of 150 mL, and the reaction solution was stirred at about 140° C. for about 2 hours. After cooling, water (1 L) and ethyl acetate (300 mL) were added, and the obtained mixture was subjected to extraction to collect an organic layer, was dried over MgSO₄, and filtered. A solvent was removed from the filtered solution under reduced pressure, and the obtained solid was purified and separated by column chromatography using silica gel with CH₂Cl₂ and hexane as a developing solvent to obtain Intermediate Compound 29-a (white solid, 5.6 g, yield: 49%).

ESI-LCMS: [M]⁺: C₆₀H₅₅D₄ClN₂. 846.4648.

### 2) Synthesis of Intermediate Compound 29-b

In an argon atmosphere, in a flask of 2 L, Intermediate Compound 29-a (5.6 g, 6.6 mmol), 7-bromo-5-(5′-(tert-butyl)-[1,1′:3′,1″-terphenyl]-2′-yl)-2-phenyl-5H-9-oxa-14-thia-5-aza-14b-borafluoreno[3,2,1-de]anthracene (5 g, 7 mmol), Pd₂dba₃ (1.6 g, 1.9 mmol), tris-tert-butyl phosphine (1.6 mL, 3.8 mmol), and sodium tert-butoxide (5.8 g, 60 mmol) were added, and dissolved in o-xylene of 150 mL, and the reaction solution was stirred at about 140° C. for about 2 hours. After cooling, water (1 L) and ethyl acetate (300 mL) were added, and the obtained mixture was subjected to extraction to collect an organic layer, was dried over MgSO₄, and filtered. A solvent was removed from the filtered solution under reduced pressure, and the obtained solid was purified and separated by column chromatography using silica gel with CH₂Cl₂ and hexane as a developing solvent to obtain Intermediate Compound 29-b (yellow solid, 5.5 g, yield: 55%).

ESI-LCMS: [M]⁺: C₁₀₈H₈₉D₄BClN₃OS. 1529.7159.

### 3) Synthesis of Intermediate Compound 29-c

In an argon atmosphere, in a flask of 1 L, Intermediate Compound 29-b (5.5 g, 3.4 mmol) was dissolved in o-dichlorobenzene of 50 mL, and BBr₃ (1.5 equiv.) was added. The reaction solution was stirred at about 140° C. for about 12 hours. After cooling, triethylamine was added to terminate the reaction, a solvent was removed under reduced pressure, and the obtained solid was purified and separated by column chromatography using silica gel with CH₂Cl₂ and hexane as a developing solvent to obtain Intermediate Compound 29-c (yellow solid, 1.7 g, yield: 32%).

ESI-LCMS: [M]⁺: C₁₀₈H₈₇D₃B₂ClN₃OS. 1536.6917

### 4) Synthesis of Compound 29

In an argon atmosphere, in a flask of 2 L, Intermediate Compound 29-c (1.7 g, 1.1 mmol), 9H-carbazole-1,2,3,4,5,6,7,8-d8 (0.19 g, 1.1 mmol), Pd₂dba₃ (0.12 g, 0.14 mmol), tris-tert-butyl phosphine (0.12 mL, 0.28 mmol), and sodium tert-butoxide (0.8 g, 8.4 mmol) were mixed, dissolved in o-xylene of 30 mL, and the reaction solution was stirred at about 140° C. for about 2 hours. After cooling, water (1 L) and ethyl acetate (300 mL) were added, and the obtained mixture was subjected to extraction to collect an organic layer, was dried over MgSO₄, and filtered. A solvent was removed from the filtered solution under reduced pressure, and the obtained solid was purified and separated by column chromatography using silica gel with CH₂Cl₂ and hexane as a developing solvent to obtain Compound 29 (yellow solid, 1.4 g, yield: 77%).

ESI-LCMS: [M]⁺: C₁₂₀H₈₇D₁₁B₂N₄OS. 1675.8330.

¹H-NMR (CDCl3): d=8.05 (d, 1H), 7.99 (s, 6H), 7.89 (d, 1H), 7.75 (m, 2H), 7.61 (s, 1H), 7.50 (m, 7H), 7.43 (m, 18H), 7.11 (m, 12H), 7.00 (s, 2H), 6.39 (s, 1H), 1.39 (s, 9H), 1.29 (s, 9H) 1.21 (s, 18H)

### (3) Synthesis of Compound 77

Compound 77 according to an embodiment may be synthesized by, for example, Reaction Scheme 3:

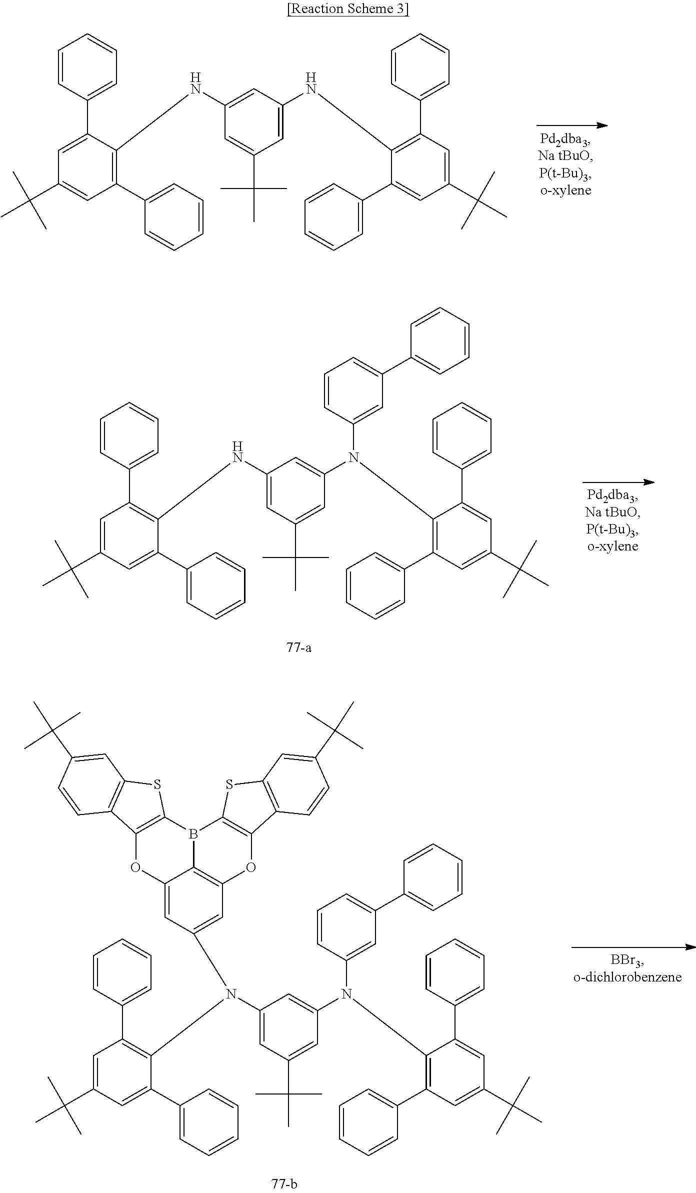

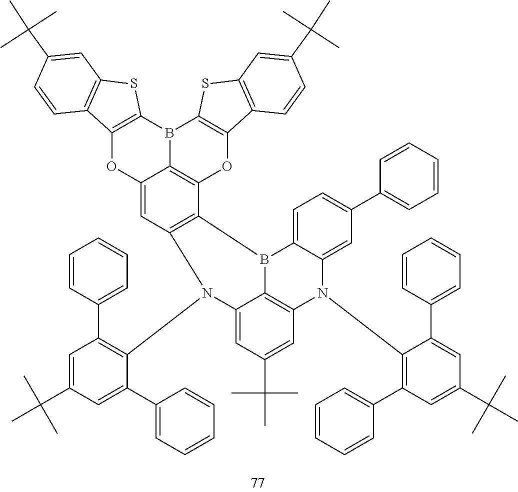 [SMILES: CC(C)(C)c1cc(-c2ccccc2)c(N2c3cc(-c4ccccc4)ccc3B3c4c2cc(C(C)(C)C)cc4N(c2c(-c4ccccc4)cc(C(C)(C)C)cc2-c2ccccc2)c2cc4c5c(c23)Oc2c(sc3cc(C(C)(C)C)ccc23)B5c2sc3cc(C(C)(C)C)ccc3c2O4)c(-c2ccccc2)c1]

### 1) Synthesis of Intermediate Compound 77-a

In an argon atmosphere, in a flask of 2 L, 5-(tert-butyl)-N1,N3-bis(5′-(tert-butyl)-[1,1′:3′,1″-terphenyl]-2′-yl)benzene-1,3-diamine (10 g, 13.5 mmol), 3-iodobiphenyl (2 g, 7 mmol), Pd₂dba₃ (1.6 g, 1.9 mmol), tris-tert-butyl phosphine (1.6 mL, 3.8 mmol), and sodium tert-butoxide (5.8 g, 60 mmol) were mixed, dissolved in o-xylene of 150 mL, and the reaction solution was stirred at about 140° C. for about 2 hours. After cooling, water (1 L) and ethyl acetate (300 mL) were added, and the obtained mixture was subjected to extraction to collect an organic layer, was dried over MgSO₄, and filtered. A solvent was removed from the filtered solution under reduced pressure, and the obtained solid was purified and separated by column chromatography using silica gel with CH₂Cl₂ and hexane as a developing solvent to obtain Intermediate Compound 77-a (white solid, 3.4 g, yield: 54%).

ESI-LCMS: [M]⁺: C₆₆H₁₄N₂. 885.2506.

### 2) Synthesis of Intermediate Compound 77-b

In an argon atmosphere, in a flask of 2 L, Intermediate Compound 77-a (3.4 g, 3.8 mmol), 2,12-di-tert-butyl-7-iodo-5,9-dioxa-14,15-dithia-14b-boradiindeno[2,1-a:1′,2′-j]phenalene (2.4 g, 8 mmol), Pd₂dba₃ (1.6 g, 3.8 mmol), tris-tert-butyl phosphine (1.6 mL, 3.8 mmol), and sodium tert-butoxide (5.8 g, 60 mmol) were mixed, dissolved in o-xylene of 150 mL, and the reaction solution was stirred at about 140° C. for about 2 hours. After cooling, water (1 L) and ethyl acetate (300 mL) were added, and the obtained mixture was subjected to extraction to collect an organic layer, was dried over MgSO₄, and filtered. A solvent was removed from the filtered solution under reduced pressure, and the obtained solid was purified and separated by column chromatography using silica gel with CH₂Cl₂ and hexane as a developing solvent to obtain Intermediate Compound 77-b (yellow solid, 3 g, yield: 59%).

ESI-LCMS: [M]⁺: C₉₆H₈₉BN₂O₂S₂. 1376.6559.

### 3) Synthesis of Compound 77

In an argon atmosphere, in a flask of 1 L, Intermediate Compound 77-b (3 g, 2.2 mmol) was dissolved in o-dichlorobenzene of 50 mL, and BBr₃ (1.5 equiv.) was added. The reaction solution was stirred at about 140° C. for about 12 hours. After cooling, triethylamine was added to terminate the reaction, a solvent was removed under reduced pressure, and the obtained solid was purified and separated by column chromatography using silica gel with CH₂Cl₂ and hexane as a developing solvent to obtain Compound 77 (yellow solid, 0.8 g, yield: 26%).

ESI-LCMS: [M]⁺: C₉₆H₄₇D₁₅BClN₂Si. 1384.63

¹H-NMR (CDCl3): d=8.02 (m, 4H), 7.91 (s, 4H), 7.83 (d, 1H), 7.71 (m, 2H), 7.44 (m, 14H), 7.27 (s, 1H), 7.08 (m, 12H), 6.89 (s, 2H), 6.23 (s, 1H), 1.31 (s, 18H), 1.26 (s, 9H), 1.19 (s, 18H)

### (4) Synthesis of Compound 18

Compound 18 according to an embodiment may be synthesized by, for example, Reaction Scheme 4:

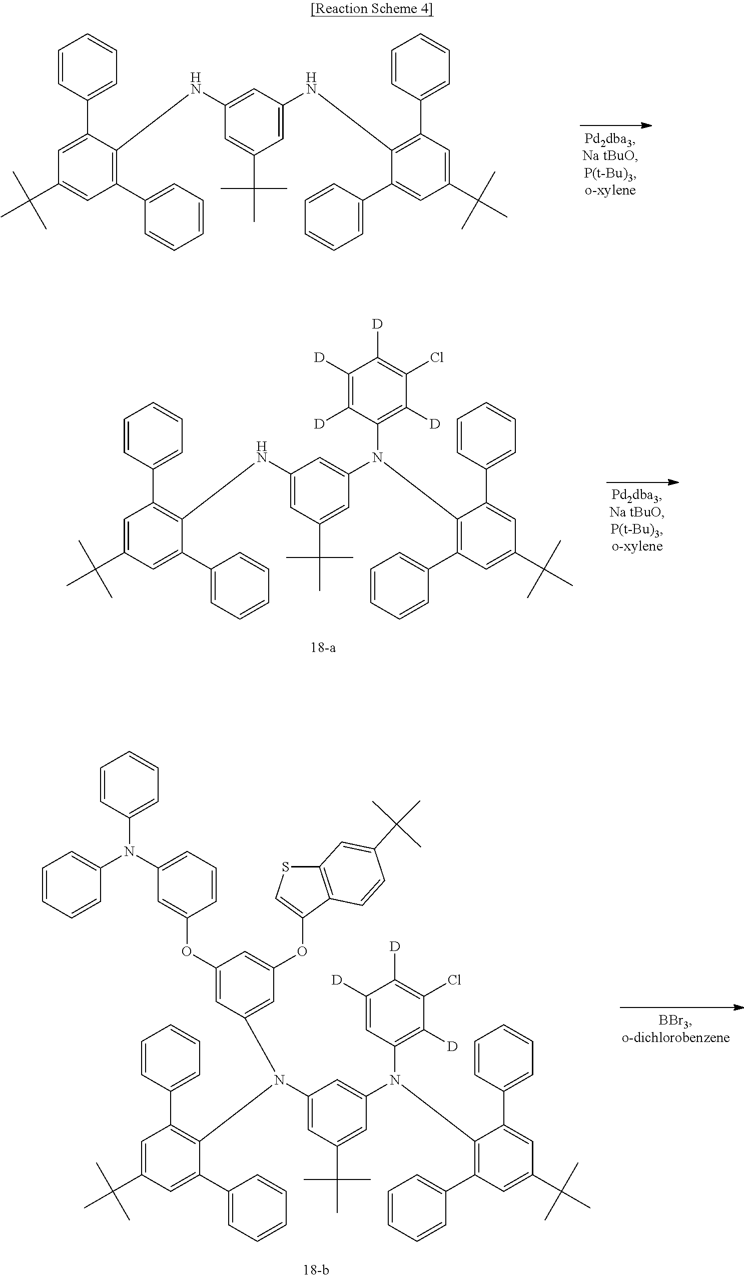

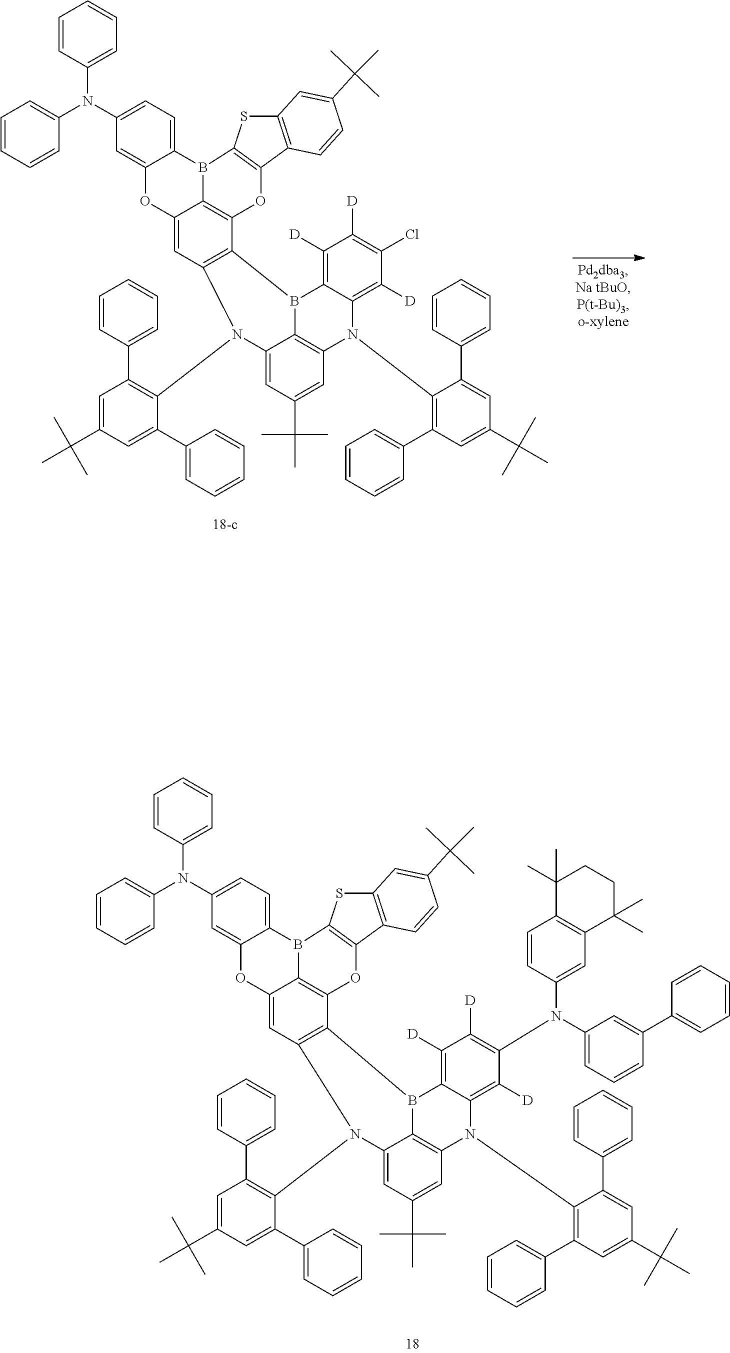 [SMILES: [2H]c1c([2H])c2c(c([2H])c1Cl)N(c1c(-c3ccccc3)cc(C(C)(C)C)cc1-c1ccccc1)c1cc(C(C)(C)C)cc3c1B2c1c(cc2c4c1Oc1c(sc5cc(C(C)(C)C)ccc15)B4c1ccc(N(c4ccccc4)c4ccccc4)cc1O2)N3c1c(-c2ccccc2)cc(C(C)(C)C)cc1-c1ccccc1 ; [2H]c1c([2H])c(N(c2cccc(-c3ccccc3)c2)c2ccc3c(c2)C(C)(C)CCC3(C)C)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1c(sc2cc(C(C)(C)C)ccc12)B4c1ccc(N(c2ccccc2)c2ccccc2)cc1O3]

### 1) Synthesis of Intermediate Compound 18-a

In an argon atmosphere, in a flask of 2 L, 5-(tert-butyl)-N1,N3-bis (5′-(tert-butyl)-[1,1′:3′,1″-terphenyl]-2′-yl)benzene-1,3-diamine (10 g, 13.6 mmol), 1-chloro-3-iodobenzene-2,4,5,6-d4 (3.3 g, 13.6 mmol), Pd₂dba₃ (1.6 g, 1.9 mmol), tris-tert-butyl phosphine (1.6 mL, 3.8 mmol), and sodium tert-butoxide (5.8 g, 60 mmol) were mixed, dissolved in o-xylene of 150 mL, and the reaction solution was stirred at about 140° C. for about 2 hours. After cooling, water (1 L) and ethyl acetate (300 mL) were added, and the obtained mixture was subjected to extraction to collect an organic layer, was dried over MgSO₄, and filtered. A solvent was removed from the filtered solution under reduced pressure, and the obtained solid was purified and separated by column chromatography using silica gel with CH₂Cl₂ and hexane as a developing solvent to obtain Intermediate Compound 18-a (white solid, 6.8 g, yield: 59%).

ESI-LCMS: [M]⁺: C₆₀H₅₅D₄ClN₂. 846.4602.

### 2) Synthesis of Intermediate Compound 18-b

In an argon atmosphere, in a flask of 2 L, Intermediate Compound 18-a (6.8 g, 8 mmol), 3-(3-((6-(tert-butyl)benzo[b]thiophen-3-yl)oxy)-5-iodophenoxy)-N,N-diphenylaniline (5.4 g, 8 mmol), Pd₂dba₃ (0.7 g, 0.8 mmol), tris-tert-butyl phosphine (0.7 mL, 1.6 mmol), and sodium tert-butoxide (2.9 g, 30 mmol) were mixed, dissolved in o-xylene of 80 mL, and the reaction solution was stirred at about 140° C. for about 2 hours. After cooling, water (1 L) and ethyl acetate (300 mL) were added, and the obtained mixture was subjected to extraction to collect an organic layer, was dried over MgSO₄, and filtered. A solvent was removed from the filtered solution under reduced pressure, and the obtained solid was purified and separated by column chromatography using silica gel with CH₂Cl₂ and hexane as a developing solvent to obtain Intermediate Compound 18-b (white solid, 7.2 g, yield: 65%).

ESI-LCMS: [M]⁺: C₉₆H₈₅D₃ClN₃O₂S. 1384.5448.

### 3) Synthesis of Intermediate Compound 18-c

In an argon atmosphere, in a flask of 1 L, Intermediate Compound 18-b (7 g, 5 mmol) was dissolved in o-dichlorobenzene of 50 mL, and BBr₃ (1.5 equiv.) was added. The reaction solution was stirred at about 140° C. for about 12 hours. After cooling, triethylamine was added to terminate the reaction, a solvent was removed under reduced pressure, and the obtained solid was purified and separated by column chromatography using silica gel with CH₂Cl₂ and hexane as a developing solvent to obtain Intermediate Compound 18-c (yellow solid, 1.5 g, yield: 22%).

ESI-LCMS: [M]⁺: C₉₆H₇₉D₃B₂ClN₃O₂S. 1400.6246

### 4) Synthesis of Compound 18

In an argon atmosphere, in a flask of 2 L, Intermediate Compound 18-c (1.5 g, 1 mmol), N—([1,1′-biphenyl]-3-yl)-5,5,8,8-tetramethyl-5,6,7,8-tetrahydronaphthalen-2-amine (0.4 g, 1 mmol), Pd₂dba₃ (0.1 g, 0.1 mmol), tris-tert-butyl phosphine (0.1 mL, 0.1 mmol), and sodium tert-butoxide (0.3 g, 3 mmol) were mixed, dissolved in o-xylene of 10 mL, and the reaction solution was stirred at about 140° C. for about 2 hours. After cooling, water (1 L) and ethyl acetate (300 mL) were added, and the obtained mixture was subjected to extraction to collect an organic layer, was dried over MgSO₄, and filtered. A solvent was removed from the filtered solution under reduced pressure, and the obtained solid was purified and separated by column chromatography using silica gel with CH₂Cl₂ and hexane as a developing solvent to obtain Compound 18 (yellow solid, 1.1 g, yield: 69%).

ESI-LCMS: [M]⁺: C₉₆H₈₅D₃ClN₃O₂S. 1719.87.

¹H-NMR (CDCl3): d=7.99 (s, 1H), 7.93 (d, 1H), 7.75 (d, 2H), 7.67 (d, 1H), 7.55 (d, 1H), 7.49 (m, 3H), 7.43 (m, 5H), 7.32 (m, 12H), 7.27 (s, 1H), 7.12 (m, 2H), 7.04 (m, 8H), 6.99 (s, 2H), 6.88 (m, 3H), 6.71 (s, 1H), 6.42 (m, 2H), 1.48 (s, 4H), 1.36 (s, 8H), 1.31 (s, 18H), 1.24 (s, 9H), 1.21 (s, 9H)

### (5) Synthesis of Compound 81

Compound 81 according to an embodiment may be synthesized by, for example, Reaction Scheme 5:

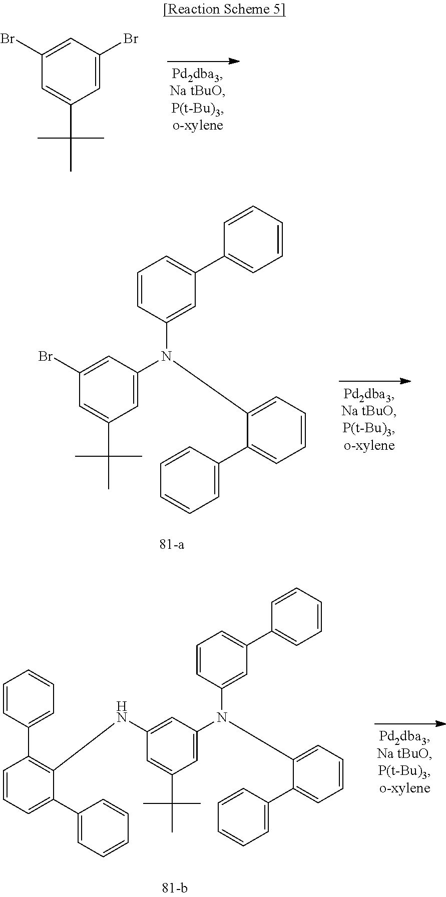 [SMILES: CC(C)(C)c1cc(Br)cc(Br)c1 ; CC(C)(C)c1cc(Br)cc(N(c2cccc(-c3ccccc3)c2)c2ccccc2-c2ccccc2)c1 ; CC(C)(C)c1cc(Nc2c(-c3ccccc3)cccc2-c2ccccc2)cc(N(c2cccc(-c3ccccc3)c2)c2ccccc2-c2ccccc2)c1]

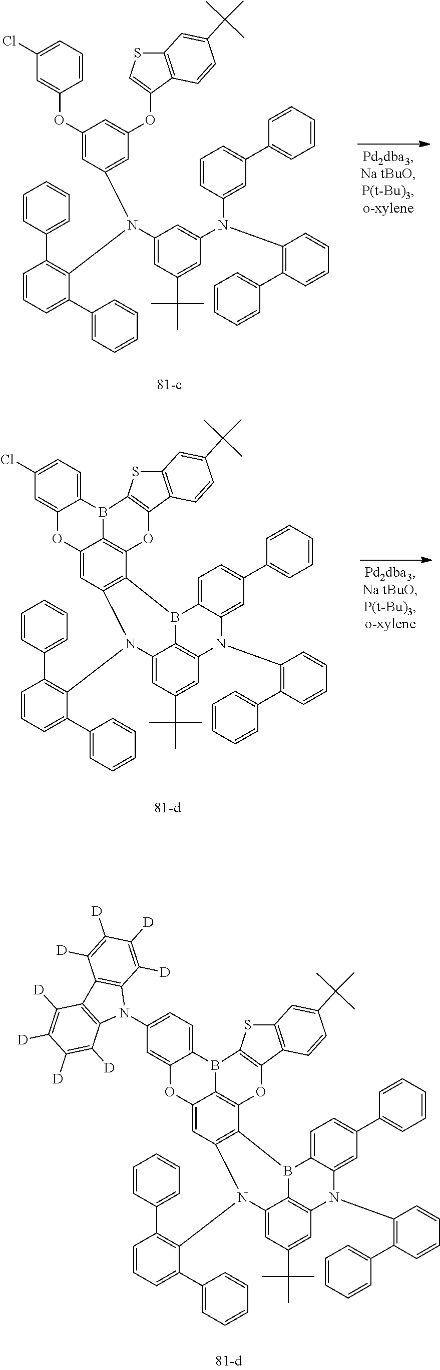 [SMILES: CC(C)(C)c1cc(N(c2cccc(-c3ccccc3)c2)c2ccccc2-c2ccccc2)cc(N(c2cc(Oc3cccc(Cl)c3)cc(Oc3csc4cc(C(C)(C)C)ccc34)c2)c2c(-c3ccccc3)cccc2-c2ccccc2)c1 ; CC(C)(C)c1cc2c3c(c1)N(c1c(-c4ccccc4)cccc1-c1ccccc1)c1cc4c5c(c1B3c1ccc(-c3ccccc3)cc1N2c1ccccc1-c1ccccc1)Oc1c(sc2cc(C(C)(C)C)ccc12)B5c1ccc(Cl)cc1O4 ; [2H]c1c([2H])c([2H])c2c(c1[2H])c1c([2H])c([2H])c([2H])c([2H])c1n2-c1ccc2c(c1)Oc1cc3c(c4c1B2c1sc2cc(C(C)(C)C)ccc2c1O4)B1c2ccc(-c4ccccc4)cc2N(c2ccccc2-c2ccccc2)c2cc(C(C)(C)C)cc(c21)N3c1c(-c2ccccc2)cccc1-c1ccccc1]

### 1) Synthesis of Intermediate Compound 81-a

In an argon atmosphere, in a flask of 2 L, 1,3-dibromo-5-(tert-butyl)benzene (10 g, 34 mmol), N—([1,1′-biphenyl]-3-yl)-[1,1′-biphenyl]-2-amine (5.5 g, 17 mmol), Pd₂dba₃ (1.6 g, 1.9 mmol), tris-tert-butyliphosphine (1.6 mL, 3.8 mmol), and sodium tert-butoxide (5.8 g, 60 mmol) were mixed, dissolved in o-xylene of 150 mL, and the reaction solution was stirred at about 140° C. for about 2 hours. After cooling, water (1 L) and ethyl acetate (300 mL) were added, and the obtained mixture was subjected to extraction to collect an organic layer, was dried over MgSO₄, and filtered. A solvent was removed from the filtered solution under reduced pressure, and the obtained solid was purified and separated by column chromatography using silica gel with CH₂Cl₂ and hexane as a developing solvent to obtain Intermediate Compound 81-a (white solid, 6.0 g, yield: 66%).

ESI-LCMS: [M]⁺: C₃₄H₃₀BrN. 531.1615

### 2) Synthesis of Intermediate Compound 81-b

In an argon atmosphere, in a flask of 2 L, Intermediate Compound 81-a (6 g, 11.2 mmol), [1,1′:3′,1″-terphenyl]-2′-amine (2.7 g, 11.2 mmol), Pd₂dba₃ (0.7 g, 0.8 mmol), tris-tert-butyl phosphine (0.7 mL, 1.6 mmol), and sodium tert-butoxide (2.9 g, 30 mmol) were mixed, dissolved in o-xylene of 80 mL, and the reaction solution was stirred at about 140° C. for about 2 hours. After cooling, water (1 L) and ethyl acetate (300 mL) were added, and the obtained mixture was subjected to extraction to collect an organic layer, was dried over MgSO₄, and filtered. A solvent was removed from the filtered solution under reduced pressure, and the obtained solid was purified and separated by column chromatography using silica gel with CH₂Cl₂ and hexane as a developing solvent to obtain Intermediate Compound 81-b (white solid, 5.8 g, yield: 75%).

ESI-LCMS: [M]⁺: C₅₂H₄₄N₂. 696.3501.

### 3) Synthesis of Intermediate Compound 81-c

In an argon atmosphere, in a flask of 2 L, Intermediate Compound 81-b (5.8 g, 8.3 mmol), 6-(tert-butyl)-3-(3-(3-chlorophenoxy)-5-iodophenoxy)benzo[b]thiophene (4.4 g, 8.3 mmol), Pd₂dba₃ (0.7 g, 0.8 mmol), tris-tert-butyl phosphine (0.7 mL, 1.6 mmol), and sodium tert-butoxide (2.9 g, 30 mmol) were added, and dissolved in o-xylene of 80 mL, and the reaction solution was stirred at about 140° C. for about 2 hours. After cooling, water (1 L) and ethyl acetate (300 mL) were added, and the obtained mixture was subjected to extraction to collect an organic layer, was dried over MgSO₄, and filtered. A solvent was removed from the filtered solution under reduced pressure, and the obtained solid was purified and separated by column chromatography using silica gel with CH₂Cl₂ and hexane as a developing solvent to obtain Intermediate Compound 81-c (white solid, 6.2 g, yield: 68%).

ESI-LCMS: [M]⁺: C₇₆H6₃ClN₂O₂S. 1102.4335.

### 4) Synthesis of Intermediate Compound 81-d

In an argon atmosphere, in a flask of 1 L, Intermediate Compound 81-c (6 g, 5.4 mmol) was dissolved in o-dichlorobenzene of 50 mL, and BBr₃ (2.5 equiv.) was added. The reaction solution was stirred at about 140° C. for about 12 hours. After cooling, triethylamine was added to terminate the reaction, a solvent was removed under reduced pressure, and the obtained solid was purified and separated by column chromatography using silica gel with CH₂Cl₂ and hexane as a developing solvent to obtain Intermediate Compound 81-d (yellow solid, 1.26 g, yield: 21%).

ESI-LCMS: [M]⁺: C₇₆H₅₇B₂ClN₂O₂S. 1118.4003

### 5) Synthesis of Compound 81

In an argon atmosphere, in a flask of 2 L, Intermediate Compound 81-d (1.2 g, 1 mmol), 9H-carbazole-1,2,3,4,5,6,7,8-d8 (0.18 g, 1 mmol), Pd₂dba₃ (0.1 g, 0.1 mmol), tris-tert-butyl phosphine (0.1 mL, 0.1 mmol), and sodium tert-butoxide (0.3 g, 3 mmol) were mixed, dissolved in o-xylene of 10 mL, and the reaction solution was stirred at about 140° C. for about 2 hours. After cooling, water (1 L) and ethyl acetate (300 mL) were added, and the obtained mixture was subjected to extraction to collect an organic layer, was dried over MgSO₄, and filtered. A solvent was removed from the filtered solution under reduced pressure, and the obtained solid was purified and separated by column chromatography using silica gel with CH₂Cl₂ and hexane as a developing solvent to obtain Compound 81 (yellow solid, 0.8 g, yield: 65%).

ESI-LCMS: [M]⁺: C₈₈H₅₇D₈B₂N₃O₂S. 1257.5537.

¹H-NMR (CDCl₃): d=8.55 (d, 1H), 8.22 (d, 4H), 8.10 (d, 1H), 8.02 (s, 1H), 7.97 (d, 1H), 7.85 (d, 1H), 7.75 (d, 2H), 7.45 (m, 6H), 7.37 (m, 12H), 7.25 (s, 1H), 7.08 (m, 9H), 7.06 (s, 2H), 6.42 (s, 1H), 1.32 (s, 9H), 1.29 (s, 9H)

### (6) Synthesis of Compound 89

Compound 89 according to an embodiment may be synthesized by, for example, Reaction Scheme 6:

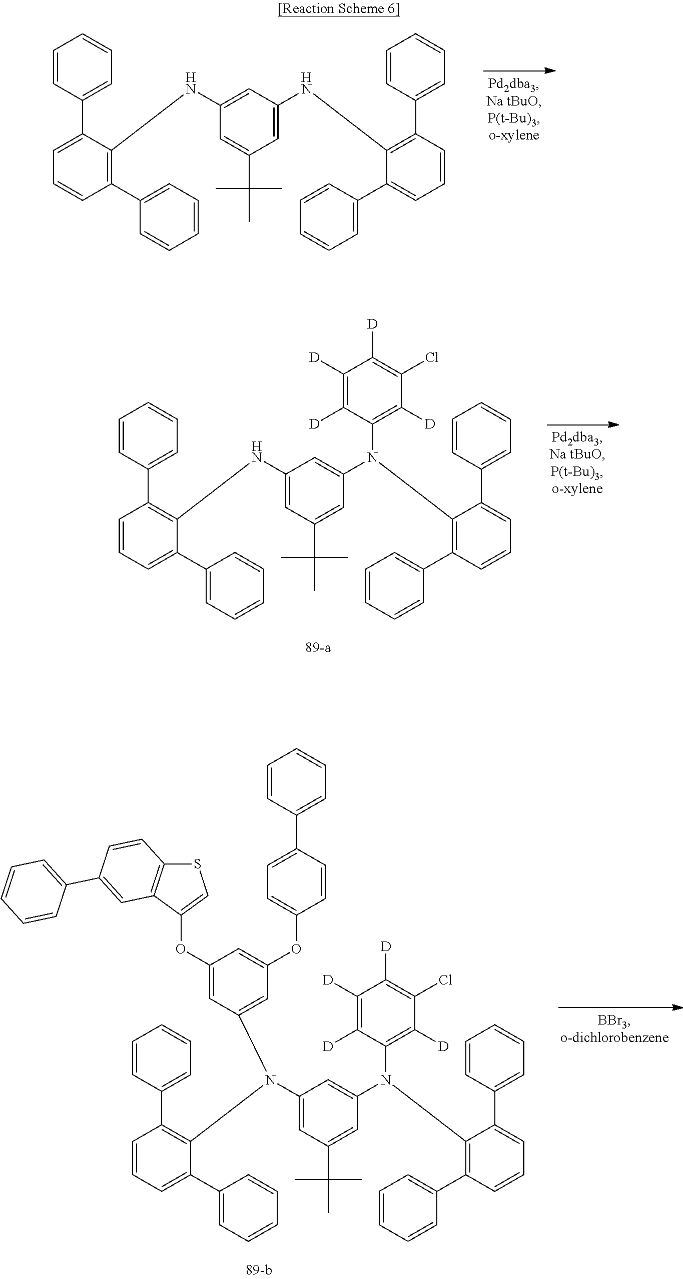 [SMILES: CC(C)(C)c1cc(Nc2c(-c3ccccc3)cccc2-c2ccccc2)cc(Nc2c(-c3ccccc3)cccc2-c2ccccc2)c1 ; [2H]c1c([2H])c(Cl)c([2H])c(N(c2cc(Nc3c(-c4ccccc4)cccc3-c3ccccc3)cc(C(C)(C)C)c2)c2c(-c3ccccc3)cccc2-c2ccccc2)c1[2H] ; [2H]c1c([2H])c(Cl)c([2H])c(N(c2cc(N(c3cc(Oc4ccc(-c5ccccc5)cc4)cc(Oc4csc5ccc(-c6ccccc6)cc45)c3)c3c(-c4ccccc4)cccc3-c3ccccc3)cc(C(C)(C)C)c2)c2c(-c3ccccc3)cccc2-c2ccccc2)c1[2H]]

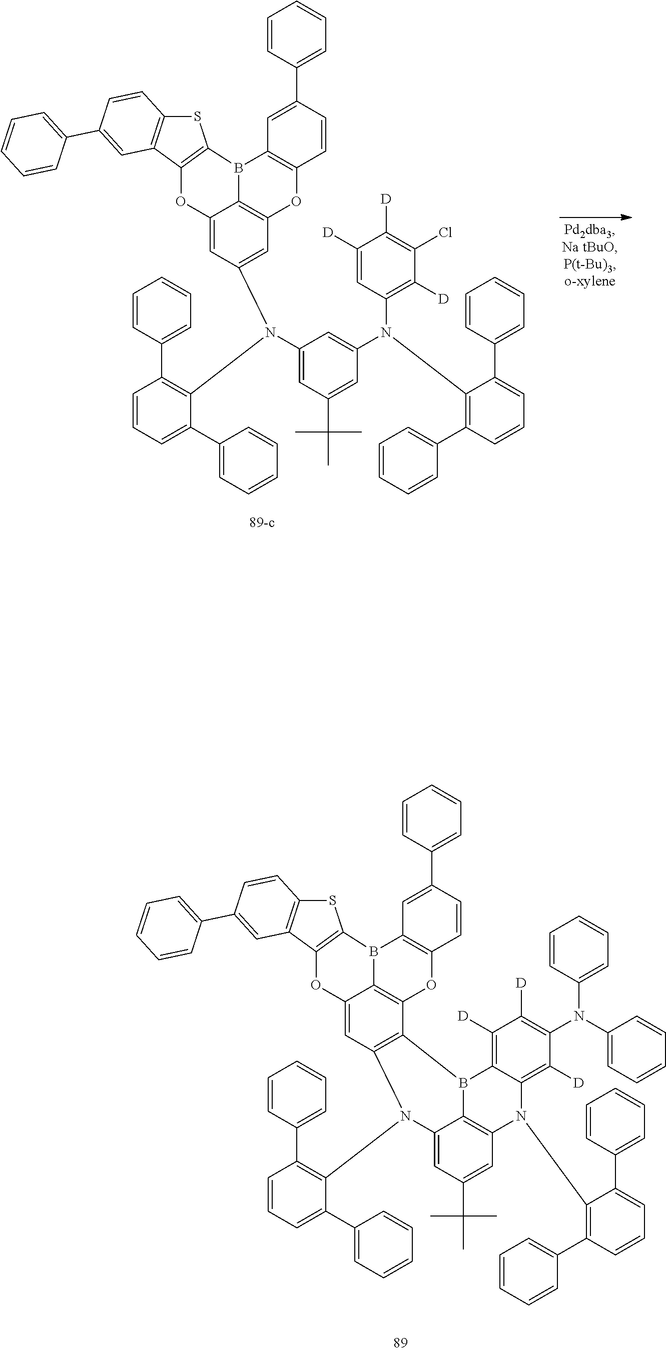 [SMILES: [2H]c1cc(N(c2cc(N(c3cc4c5c(c3)Oc3c(sc6ccc(-c7ccccc7)cc36)B5c3cc(-c5ccccc5)ccc3O4)c3c(-c4ccccc4)cccc3-c3ccccc3)cc(C(C)(C)C)c2)c2c(-c3ccccc3)cccc2-c2ccccc2)c([2H])c(Cl)c1[2H] ; [2H]c1c([2H])c(N(c2ccccc2)c2ccccc2)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)Oc1ccc(-c2ccccc2)cc1B4c1sc2ccc(-c4ccccc4)cc2c1O3]

### 2) Synthesis of Intermediate Compound 89-b

In an argon atmosphere, in a flask of 2 L, Intermediate Compound 89-a (6.4 g, 8.7 mmol), 3-(3-([1,1′-biphenyl]-4-yloxy)-5-iodophenoxy)-5-phenylbenzo[b]thiophene (5.2 g, 8.7 mmol), Pd₂dba₃ (0.7 g, 0.8 mmol), tris-tert-butyl phosphine (0.7 mL, 1.6 mmol), and sodium tert-butoxide (2.9 g, 30 mmol) were mixed, dissolved in o-xylene of 80 mL, and the reaction solution was stirred at about 140° C. for about 2 hours. After cooling, water (1 L) and ethyl acetate (300 mL) were added, and the obtained mixture was subjected to extraction to collect an organic layer, was dried over MgSO₄, and filtered. A solvent was removed from the filtered solution under reduced pressure, and the obtained solid was purified and separated by column chromatography using silica gel with CH₂Cl₂ and hexane as a developing solvent to obtain Intermediate Compound 89-b (white solid, 7.3 g, yield: 70%).

ESI-LCMS: [M]⁺: C₈₄H₅₉D₄ClN₂O₂S. 1202.4548.

### 3) Synthesis of Intermediate Compound 89-c

In an argon atmosphere, in a flask of 1 L, Intermediate Compound 89-b (7.3 g, 6 mmol) was dissolved in o-dichlorobenzene of 50 mL, and BBr₃ (2.5 equiv.) was added. The reaction solution was stirred at about 140° C. for about 12 hours. After cooling, triethylamine was added to terminate the reaction, a solvent was removed under reduced pressure, and the obtained solid was purified and separated by column chromatography using silica gel with CH₂Cl₂ and hexane as a developing solvent to obtain Intermediate Compound 89-c (yellow solid, 1.77 g, yield: 24%).

ESI-LCMS: [M]⁺: C₈₄H₅₄D₃B₂ClN₂O₂S. 1217.4248

### 4) Synthesis of Compound 89

In an argon atmosphere, in a flask of 2 L, Intermediate Compound 89-c (1.7 g, 1.4 mmol), diphenylamine (0.23 g, 1.4 mmol), Pd₂dba₃ (0.1 g, 0.1 mmol), tris-tert-butyl phosphine (0.1 mL, 0.1 mmol), and sodium tert-butoxide (0.3 g, 3 mmol) were mixed, dissolved in o-xylene of 20 mL, and the reaction solution was stirred at about 140° C. for about 2 hours. After cooling, water (1 L) and ethyl acetate (300 mL) were added, and the obtained mixture was subjected to extraction to collect an organic layer, was dried over MgSO₄, and filtered. A solvent was removed from the filtered solution under reduced pressure, and the obtained solid was purified and separated by column chromatography using silica gel with CH₂Cl₂ and hexane as a developing solvent to obtain Compound 89 (yellow solid, 1.28 g, yield: 68%).

ESI-LCMS: [M]⁺: C₉₆H₆₄D₃B₂N₃O₂S. 1350.5342.

¹H-NMR (CDCl₃): d=8.25 (s, 1H), 8.20 (d, 4H), 8.12 (d, 1H), 7.99 (d, 1H), 7.75 (d, 2H), 7.67 (d, 2H), 7.53 (m, 3H), 7.43 (m, 12H), 7.39 (m, 2H), 7.24 (m, 4H), 7.11 (d, 4H), 7.08 (m, 8H), 7.00 (t, 2H), 6.88 (s, 2H), 6.39 (s, 1H), 1.31 (s, 9H)

### (7) Synthesis of Compound 94

Compound 94 according to an embodiment may be synthesized by, for example, Reaction Scheme 7:

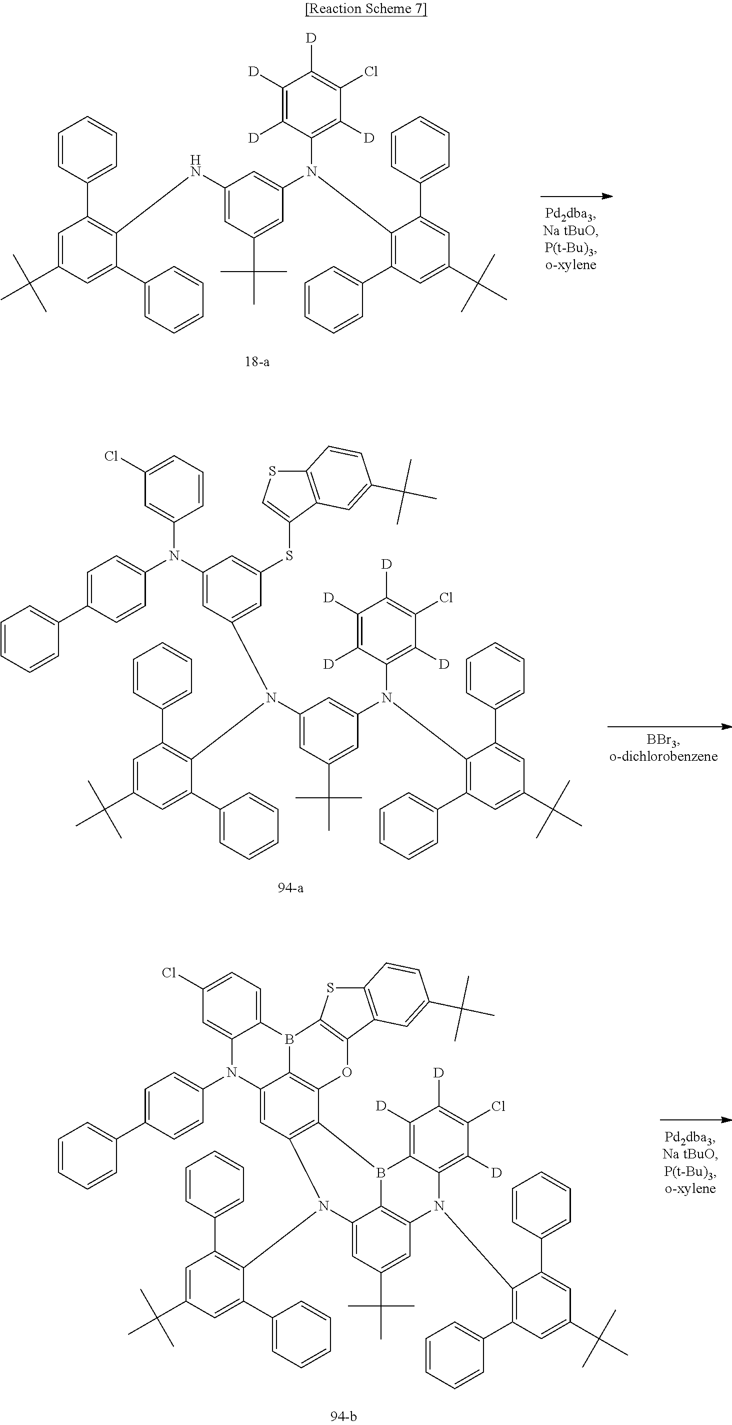

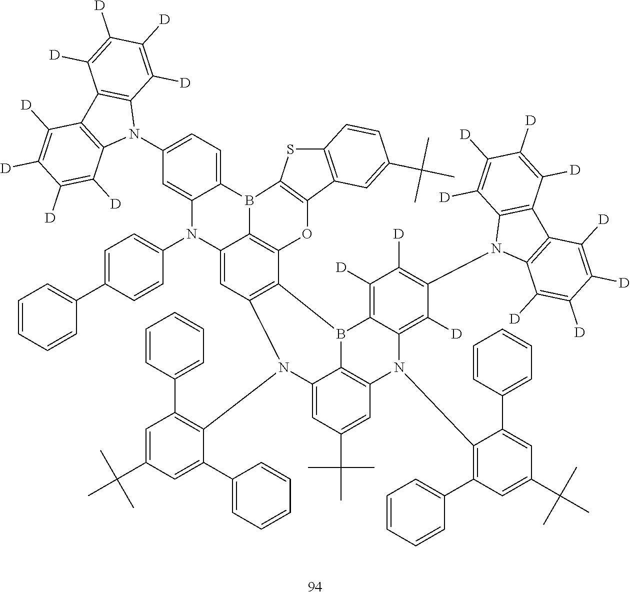 [SMILES: [2H]c1c([2H])c(-n2c3c([2H])c([2H])c([2H])c([2H])c3c3c([2H])c([2H])c([2H])c([2H])c32)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1c(sc2ccc(C(C)(C)C)cc12)B4c1ccc(-n2c4c([2H])c([2H])c([2H])c([2H])c4c4c([2H])c([2H])c([2H])c([2H])c42)cc1N3c1ccc(-c2ccccc2)cc1]

### 1) Synthesis of Intermediate Compound 94-a

In an argon atmosphere, in a flask of 2 L, Intermediate Compound 18-a (10 g, 12 mmol), N-(3-((5-(tert-butyl)benzo[b]thiophen-3-yl)thio)-5-iodophenyl)-N-(3-chlorophenyl)-[1,1′-biphenyl]-4-amine (8.3 g, 12 mmol), Pd₂dba₃ (1.6 g, 1.9 mmol), tris-tert-butyl phosphine (1.6 mL, 3.8 mmol), and sodium tert-butoxide (5.8 g, 60 mmol) were mixed, dissolved in o-xylene of 150 mL, and the reaction solution was stirred at about 140° C. for about 2 hours. After cooling, water (1 L) and ethyl acetate (300 mL) were added, and the obtained mixture was subjected to extraction to collect an organic layer, was dried over MgSO₄, and filtered. A solvent was removed from the filtered solution under reduced pressure, and the obtained solid was purified and separated by column chromatography using silica gel with CH₂Cl₂ and hexane as a developing solvent to obtain Intermediate Compound 94-a (white solid, 11.6 g, yield: 68%).

ESI-LCMS: [M]⁺: C₉₆H₈₃D₄Cl₂N₃S₂. 1419.6046

### 2) Synthesis of Intermediate Compound 94-b

In an argon atmosphere, in a flask of 1 L, Intermediate Compound 94-a (11.6 g, 8.2 mmol) was dissolved in o-dichlorobenzene of 50 mL, and BBr₃ (2.5 equiv.) was added. The reaction solution was stirred at about 140° C. for about 12 hours. After cooling, triethylamine was added to terminate the reaction, a solvent was removed under reduced pressure, and the obtained solid was purified and separated by column chromatography using silica gel with CH₂Cl₂ and hexane as a developing solvent to obtain Intermediate Compound 94-b (yellow solid, 2.58 g, yield: 22%).

ESI-LCMS: [M]⁺: C₉₆H7₈D₃B₂Cl₂N3S₂. 1434.5619

### 3) Synthesis of Compound 94

In an argon atmosphere, in a flask of 2 L, Intermediate Compound 94-b (2.58 g, 1.8 mmol), 9H-carbazole-1,2,3,4,5,6,7,8-d8 (0.62 g, 3.6 mmol), Pd₂dba₃ (0.1 g, 0.1 mmol), tris-tert-butyl phosphine (0.1 mL, 0.1 mmol), and sodium tert-butoxide (0.3 g, 3 mmol) were mixed, dissolved in o-xylene of 20 mL, and the reaction solution was stirred at about 140° C. for about 2 hours. After cooling, water (1 L) and ethyl acetate (300 mL) were added, and the obtained mixture was subjected to extraction to collect an organic layer, was dried over MgSO₄, and filtered. A solvent was removed from the filtered solution under reduced pressure, and the obtained solid was purified and separated by column chromatography using silica gel with CH₂Cl₂ and hexane as a developing solvent to obtain Compound 94 (yellow solid, 2.0 g, yield: 65%).

ESI-LCMS: [M]⁺: C₁₂₀H₇₈D₁₉B₂N₅S₂. 1712.8694.

¹H-NMR (CDCl₃): d=7.99 (s, 4H), 7.85 (d, 1H), 7.73 (m, 4H), 7.55 (m, 4H), 7.46 (m, 12H), 7.37 (m, 4H), 7.23 (s, 1H), 7.08 (m, 8H), 7.00 (s, 2H), 6.71 (s, 1H), 1.36 (s, 9H), 1.31 (s, 18H), 1.25 (s, 9H)

### (8) Synthesis of Compound 100

Compound 100 according to an embodiment may be synthesized by, for example, Reaction Scheme 8

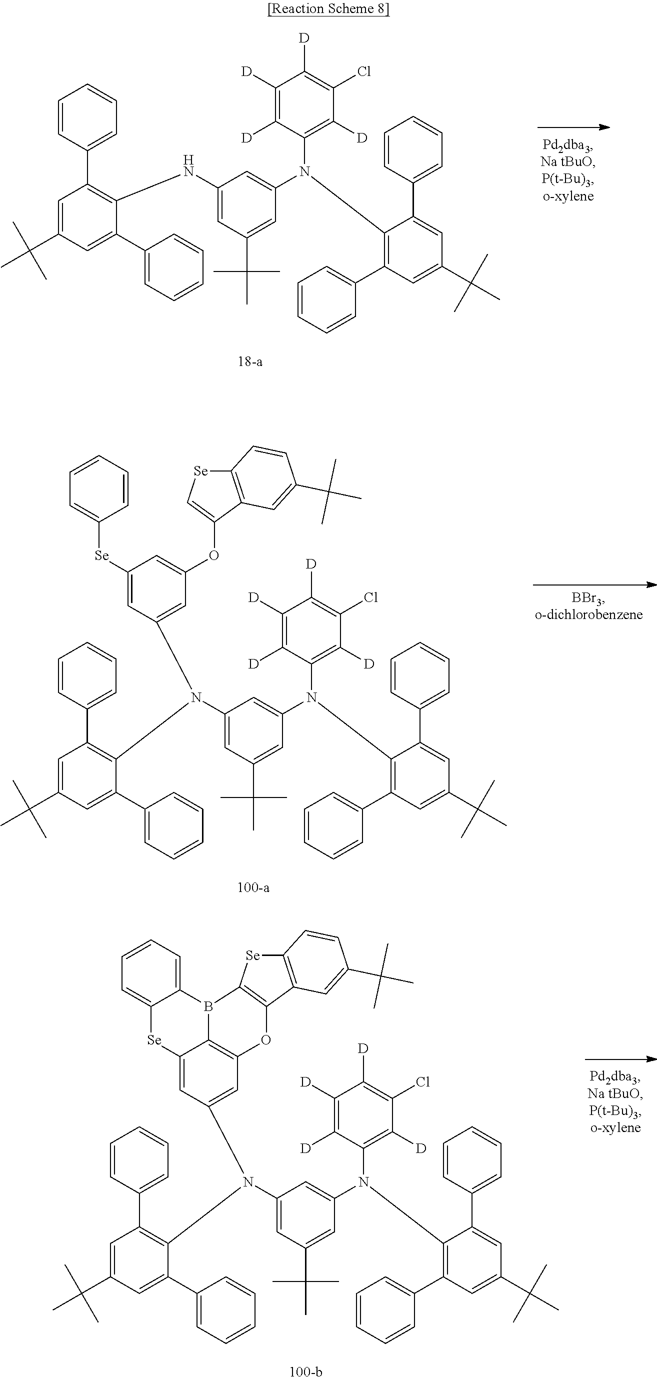

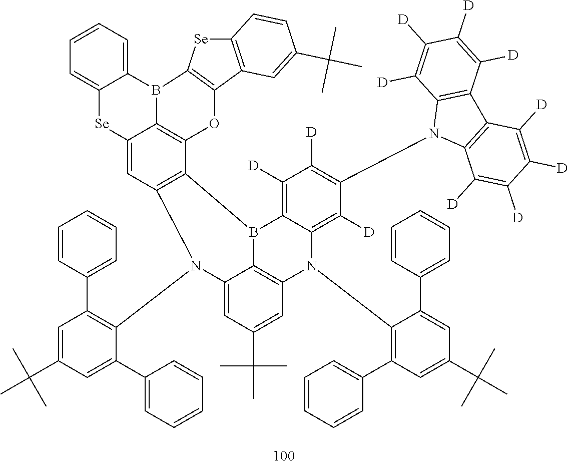 [SMILES: [2H]c1c([2H])c(-n2c3c([2H])c([2H])c([2H])c([2H])c3c3c([2H])c([2H])c([2H])c([2H])c32)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1c([se]c2ccc(C(C)(C)C)cc12)B4c1ccccc1[Se]3]

### 1) Synthesis of Intermediate Compound 100-a

In an argon atmosphere, in a flask of 2 L, Intermediate Compound 18-a (10 g, 12 mmol), 5-(tert-butyl)-3-(3-iodo-5-(phenylselanyl)phenoxy)benzo[b]selenophene (8 g, 12 mmol), Pd₂dba₃ (1.6 g, 1.9 mmol), tris-tert-butyl phosphine (1.6 mL, 3.8 mmol), and sodium tert-butoxide (5.8 g, 60 mmol) were mixed, dissolved in o-xylene of 150 mL, and the reaction solution was stirred at about 140° C. for about 2 hours. After cooling, water (1 L) and ethyl acetate (300 mL) were added, and the obtained mixture was subjected to extraction to collect an organic layer, was dried over MgSO₄, and filtered. A solvent was removed from the filtered solution under reduced pressure, and the obtained solid was purified and separated by column chromatography using silica gel with CH₂Cl₂ and hexane as a developing solvent to obtain Intermediate Compound 100-a (white solid, 9.7 g, yield: 58%).

ESI-LCMS: [M]⁺: C₈₄H₇₅D₄ClN₂OSe₂. 1330.4518

### 2) Synthesis of Intermediate Compound 100-b

In an argon atmosphere, in a flask of 1 L, Intermediate Compound 100-a (9 g, 6.5 mmol) was mixed, dissolved in o-dichlorobenzene of 50 mL, and BBr₃ (2.5 equiv.) was added. The reaction solution was stirred at about 140° C. for about 12 hours. After cooling, triethylamine was added to terminate the reaction, a solvent was removed under reduced pressure, and the obtained solid was purified and separated by column chromatography using silica gel with CH₂Cl₂ and hexane as a developing solvent to obtain Intermediate Compound 100-b (yellow solid, 1.6 g, yield: 18%).

ESI-LCMS: [M]⁺: C₈₄H₇₀D₃B₂ClN₂OSe₂. 1345.3326

### 3) Synthesis of Compound 100

In an argon atmosphere, in a flask of 2 L, Intermediate Compound 100-b (1.6 g, 1.1 mmol), 9H-carbazole-1,2,3,4,5,6,7,8-d8 (0.2 g, 1.1 mmol), Pd₂dba₃ (0.1 g, 0.1 mmol), tris-tert-butyl phosphine (0.1 mL, 0.1 mmol), and sodium tert-butoxide (0.3 g, 3 mmol) were mixed, dissolved in o-xylene of 20 mL, and the reaction solution was stirred at about 140° C. for about 2 hours. After cooling, water (1 L) and ethyl acetate (300 mL) were added, and the obtained mixture was subjected to extraction to collect an organic layer, was dried over MgSO₄, and filtered. A solvent was removed from the filtered solution under reduced pressure, and the obtained solid was purified and separated by column chromatography using silica gel with CH₂Cl₂ and hexane as a developing solvent to obtain Compound 100 (yellow solid, 1.2 g, yield: 73%).

ESI-LCMS: [M]⁺: C₉₆H₇₀D₁₁B₂N₃OSe₂. 1484.4801.

¹H-NMR (CDCl3): d=7.91 (s, 4H), 7.75 (d, 1H), 7.43 (m, 12H), 7.35 (m, 2H), 7.22 (m, 2H), 7.13 (s, 1H), 7.09 (m, 8H), 7.00 (s, 2H), 1.33 (s, 9H), 1.29 (s, 18H), 1.22 (s, 9H)

### (9) Synthesis of Compound 72

Compound 72 according to an embodiment may be synthesized by, for example, Reaction Scheme 9:

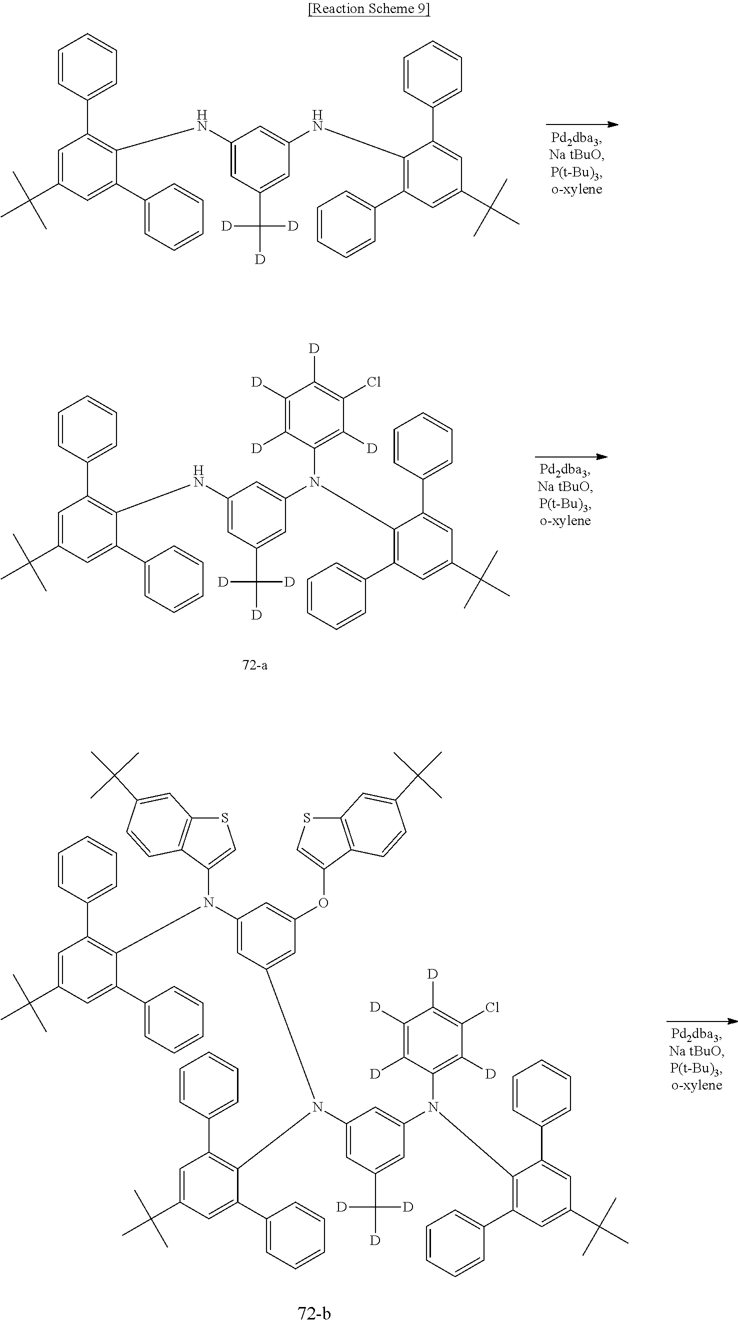

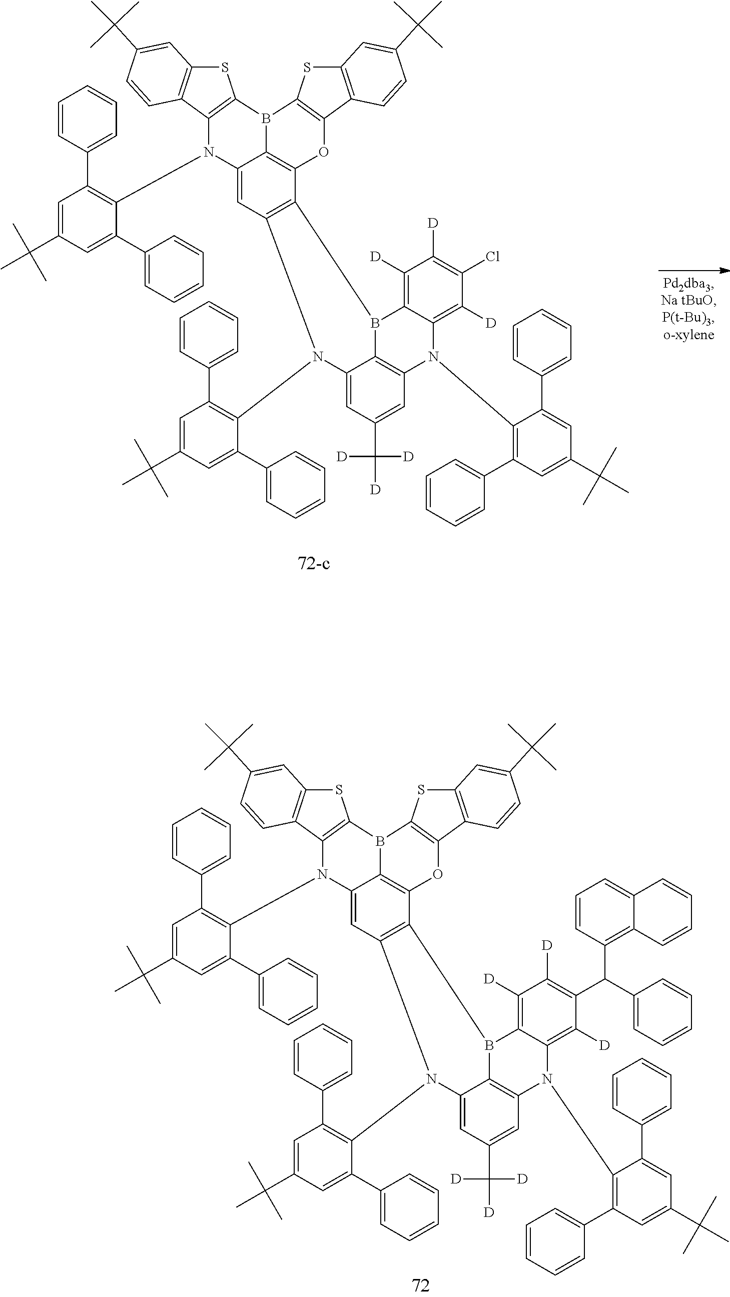

### 1) Synthesis of Intermediate Compound 72-a

In an argon atmosphere, in a flask of 2 L, N1,N3-bis(5′-(tert-butyl)-[1,1′:3′,1″-terphenyl]-2′-yl)-5-(methyl-d3)benzene-1,3-diamine (10 g, 14 mmol), 1-chloro-3-iodobenzene-2,4,5,6-d4 (3.4 g, 12 mmol), Pd₂dba₃ (1.6 g, 1.9 mmol), tris-tert-butyl phosphine (1.6 mL, 3.8 mmol), and sodium tert-butoxide (5.8 g, 60 mmol) were mixed, dissolved in o-xylene of 150 mL, and the reaction solution was stirred at about 140° C. for about 2 hours. After cooling, water (1 L) and ethyl acetate (300 mL) were added, and the obtained mixture was subjected to extraction to collect an organic layer, was dried over MgSO₄, and filtered. A solvent was removed from the filtered solution under reduced pressure, and the obtained solid was purified and separated by column chromatography using silica gel with CH₂Cl₂ and hexane as a developing solvent to obtain Intermediate Compound 72-a (white solid, 6.5 g, yield: 58%).

ESI-LCMS: [M]⁺: C₅₇H₄₆D₇ClN₂. 807.4399

### 2) Synthesis of Intermediate Compound 72-b

In an argon atmosphere, in a flask of 2 L, Intermediate Compound 72-a (6.5 g, 8 mmol), 6-(tert-butyl)-N-(5′-(tert-butyl)-[1,1′:3′,1″-terphenyl]-2′-yl)-N-(3-((6-(tert-butyl)benzo[b]thiophen-3-yl)oxy)-5-iodophenyl)benzo[b]thiophen-3-amine (7.2 g, 8 mmol), Pd₂dba₃ (1.6 g, 1.9 mmol), tris-tert-butyl phosphine (1.6 mL, 3.8 mmol), and sodium tert-butoxide (5.8 g, 60 mmol) were mixed, dissolved in o-xylene of 150 mL, and the reaction solution was stirred at about 140° C. for about 2 hours. After cooling, water (1 L) and ethyl acetate (300 mL) were added, and the obtained mixture was subjected to extraction to collect an organic layer, was dried over MgSO₄, and filtered. A solvent was removed from the filtered solution under reduced pressure, and the obtained solid was purified and separated by column chromatography using silica gel with CH₂Cl₂ and hexane as a developing solvent to obtain Intermediate Compound 72-b (white solid, 8.5 g, yield: 67%).

ESI-LCMS: [M]⁺: C₁₀₉H₉₅D₇ClN₃OS₂. 1574.7667

### 3) Synthesis of Intermediate Compound 72-c

In an argon atmosphere, in a flask of 1 L, Intermediate Compound 72-b (8.5 g, 5.4 mmol) was mixed, dissolved in o-dichlorobenzene of 100 mL, and BBr₃ (2.5 equiv.) was added. The reaction solution was stirred at about 140° C. for about 12 hours. After cooling, triethylamine was added to terminate the reaction, a solvent was removed under reduced pressure, and the obtained solid was purified and separated by column chromatography using silica gel with CH₂Cl₂ and hexane as a developing solvent to obtain Intermediate Compound 72-c (yellow solid, 1.8 g, yield: 21%).

ESI-LCMS: [M]⁺: C₁₀₉H₉₀D₆B₂ClN₃OS₂. 1589.7299

### 4) Synthesis of Compound 72

In an argon atmosphere, in a flask of 2 L, Intermediate Compound 72-c (1.8 g, 1.1 mmol), N-phenylnaphthalen-1-amine (0.25 g, 1.1 mmol), Pd₂dba₃ (0.1 g, 0.1 mmol), tris-tert-butyl phosphine (0.1 mL, 0.1 mmol), and sodium tert-butoxide (0.3 g, 3 mmol) were mixed, dissolved in o-xylene of 20 mL, and the reaction solution was stirred at about 140° C. for about 2 hours. After cooling, water (1 L) and ethyl acetate (300 mL) were added, and the obtained mixture was subjected to extraction to collect an organic layer, was dried over MgSO₄, and filtered. A solvent was removed from the filtered solution under reduced pressure, and the obtained solid was purified and separated by column chromatography using silica gel with CH₂Cl₂ and hexane as a developing solvent to obtain Compound 72 (yellow solid, 1.46 g, yield: 75%).

ESI-LCMS: [M]⁺: C₁₂₅H₁₀₂D₆B₂N₄OS₂. 1772.8572.

¹H-NMR (CDCl₃): d=8.15 (d, 1H), 8.05 (d, 2H), 7.94 (s, 4H), 7.78 (m, 5H), 7.63 (m, 2H), 7.55 (m, 8H), 7.43 (m, 12H), 7.24 (m, 4H), 7.08 (m, 12H), 7.00 (m, 3H), 6.91 (s, 2H), 6.39 (s, 1H), 1.39 (s, 18H), 1.33 (s, 18H), 1.27 (s, 9H), 1.23 (s, 9H)

### 2. Evaluation of Physical Properties of Example Compounds and Comparative Example Compounds

Physical properties of Compounds 5, 29, 77, 18, 72, 81, 89, 94, and 100, which are Examples Compounds, and Comparative Example Compounds C1 and C2, which are Comparative Example Compounds, were evaluated, and the results are listed in Table 1 below.

An absorption wavelength (l_{Abs}), an emission wavelength (l_{Emi}), Stokes-shift, and luminous efficiency (photoluminescence quantum yield, PLQY), a delayed fluorescence speed (tau), and a full width at half maximum (FWHM), in a solution, of each of the Example Compounds and the Comparative Example Compounds was measured, and the measurement results were listed in Table 1 below.

In Table 1, measurement of l_{Abs} was performed using UV-1800 UV/Visible scanning spectrophotometer made by SHIMADZU corporation equipped with a deuterium/tungsten-halogen light source and a silicon photodiode, using Labsolution UV-Vis software. Measurement of l_{Emi} was performed using a FluoroMax+ spectrometer made by HORIBA. Ltd., equipped with a xenon light source and a monochromator, using FluorEssence software. Stokes shift is a difference between wavelengths at maximum energy absorption and maximum energy emission. PLQY was measured using a Quantaurus-QY Absolute PL quantum yield spectrometer made by Hamamatsu corporation, equipped with a xenon light source, a monochromator, a photonic multichannel analyzer, and an integrating sphere, using PLQY measurement software.

TABLE 1

| | | HOMO | 1_{Abs} | 1_{Emi} | tau | Stokes- | PLQY | FWHM |
|---|---|---|---|---|---|---|---|---|
| | Dopant | (eV) | (nm) | (nm) | (vs) | shift | (%) | (nm) |
| Example 1 | Compound 5 | −5.30 | 450 | 458 | 2.7 | 8 | 99 | 28 |
| Example 2 | Compound 29 | −5.43 | 448 | 455 | 1.9 | 7 | 99 | 29 |
| Example 3 | Compound 77 | −5.27 | 447 | 453 | 1.3 | 6 | 98 | 26 |
| Example 4 | Compound 18 | −5.15 | 446 | 453 | 0.9 | 7 | 99 | 20 |
| Example 5 | Compound 72 | −5.17 | 445 | 451 | 0.8 | 6 | 99 | 18 |
| Example 6 | Compound 81 | −5.33 | 451 | 459 | 2.1 | 8 | 99 | 27 |
| Example 7 | Compound 89 | −5.17 | 447 | 454 | 1.0 | 7 | 99 | 21 |
| Example 8 | Compound 94 | −5.47 | 449 | 455 | 1.4 | 6 | 99 | 26 |
| Example 9 | Compound 100 | −5.39 | 450 | 460 | 0.8 | 10 | 97 | 28 |
| Comparative | Compound C1 | −5.25 | 434 | 452 | 9.6 | 18 | 79 | 44 |
| Example 1 | | | | | | | | |
| Comparative | Compound C2 | −5.35 | 450 | 458 | 112 | 8 | 84 | 32 |
| Example 2 | | | | | | | | |

Referring to Table 1, the fused polycyclic compound according to embodiments may be used as an emission material that emits blue light. The Example Compounds each have, compared to Comparative Example Compounds C1 and C2, a narrow Stokes-shift, a high PLQY, and a narrow full width at half maximum. It can be confirmed that the first substituent, which is introduced in the CT core of the Example Compounds, includes a five-membered ring, which makes increases molecular rigidity and enhances charge transfer (CT) properties, thereby improving RISC rates and increasing delayed fluorescence speed (tau). Referring to both Table 1 and Table 2, in a TADF element using an organometallic complex, in a case where Stokes-shift is equal to or less than about 10 nm, it can be confirmed that as PLQY increases, as a full width at half maximum becomes narrower, and as tau becomes faster, element lifespan, efficiency, and color coordinates are improved, and thus the Example Compounds are more suitable for being used as materials for the light-emitting elements than the Comparative Example Compounds.

### 2. Manufacture and Evaluation of Light-Emitting Element

### (1) Manufacture of Light-Emitting Element Group 1

Light-emitting elements in Light-emitting Element Group 1 according to an embodiment containing the fused polycyclic compound according to an embodiment was manufactured by the following method. The light-emitting elements according to Example 1-1 to Example 1-6 were respectively manufactured using Compounds 5, 29, 77, 81, 94 and 100, which are the above-described Example Compounds, as a dopant material in the emission layer.

The dopant material in the emission layer corresponds to an emission material. The light-emitting elements according to Comparative Example 1-1 and Comparative Example 1-2 respectively correspond to the light-emitting elements manufactured using Comparative Example Compound C1 and Comparative Example Compound C2 as a dopant material in the emission layer.

### [Example Compounds]

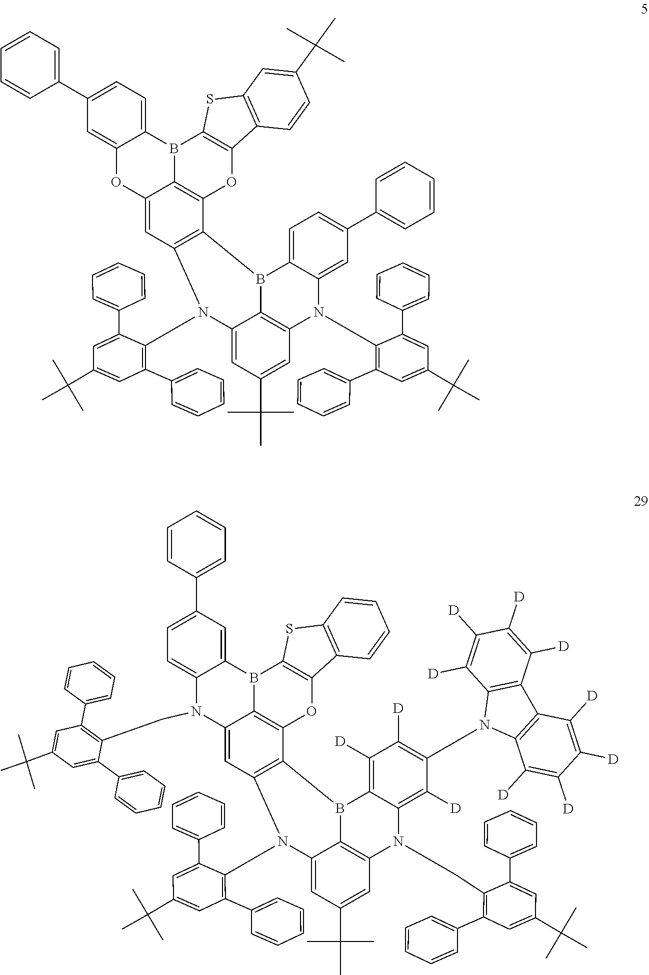

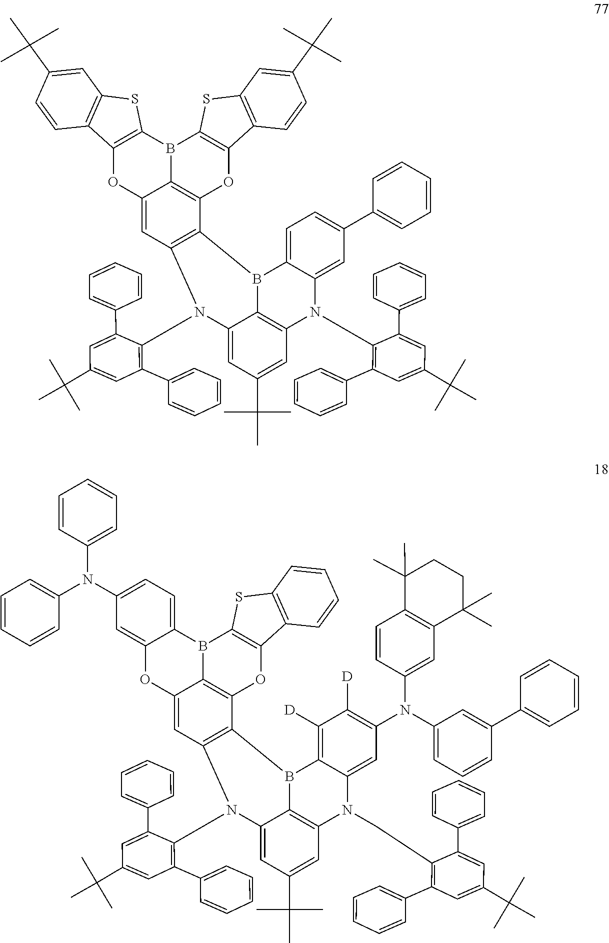 [SMILES: CC(C)(C)c1cc(-c2ccccc2)c(CN2c3cc(-c4ccccc4)ccc3B3c4c2cc(C(C)(C)C)cc4N(Cc2c(-c4ccccc4)cc(C(C)(C)C)cc2-c2ccccc2)c2cc4c5c(c23)Oc2c(sc3cc(C(C)(C)C)ccc23)B5c2sc3cc(C(C)(C)C)ccc3c2O4)c(-c2ccccc2)c1 ; [2H]c1c(N(c2cccc(-c3ccccc3)c2)c2ccc3c(c2)C(C)(C)CCC3(C)C)cc2c(c1[2H])B1c3c(cc(C(C)(C)C)cc3N(Cc3c(-c4ccccc4)cc(C(C)(C)C)cc3-c3ccccc3)c3cc4c5c(c31)Oc1c(sc3ccccc13)B5c1ccc(N(c3ccccc3)c3ccccc3)cc1O4)N2CCc1c(-c2ccccc2)cc(C(C)(C)C)cc1-c1ccccc1]

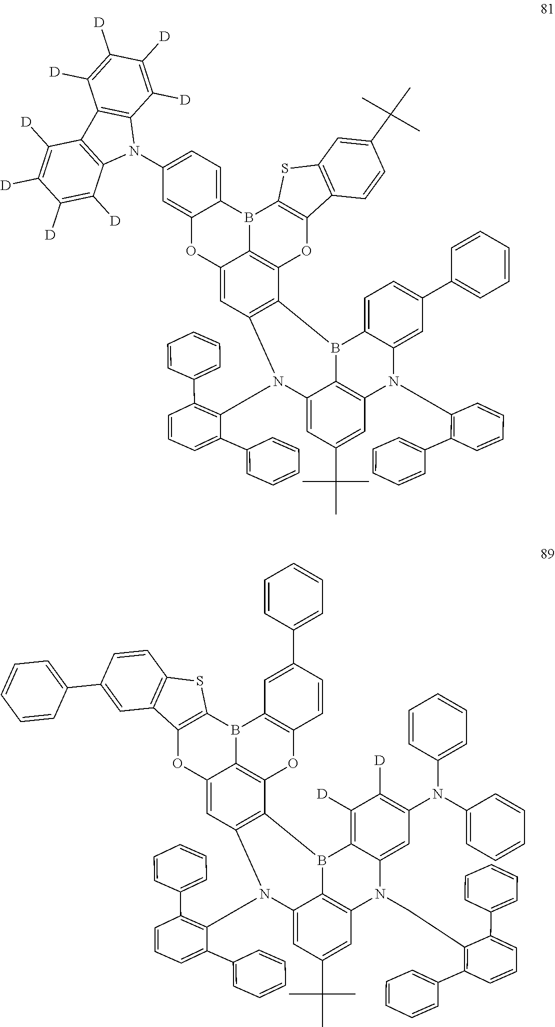 [SMILES: [2H]c1c([2H])c([2H])c2c(c1[2H])c1c([2H])c([2H])c([2H])c([2H])c1n2-c1ccc2c(c1)Oc1cc3c(c4c1B2c1sc2cc(C(C)(C)C)ccc2c1O4)B1c2ccc(-c4ccccc4)cc2N(Cc2ccccc2-c2ccccc2)c2cc(C(C)(C)C)cc(c21)N3Cc1c(-c2ccccc2)cccc1-c1ccccc1 ; [2H]c1c(N(c2ccccc2)c2ccccc2)cc2c(c1[2H])B1c3c(cc(C(C)(C)C)cc3N(Cc3c(-c4ccccc4)cccc3-c3ccccc3)c3cc4c5c(c31)Oc1ccc(-c3ccccc3)cc1B5c1sc3ccc(-c5ccccc5)cc3c1O4)N2CCc1c(-c2ccccc2)cccc1-c1ccccc1]

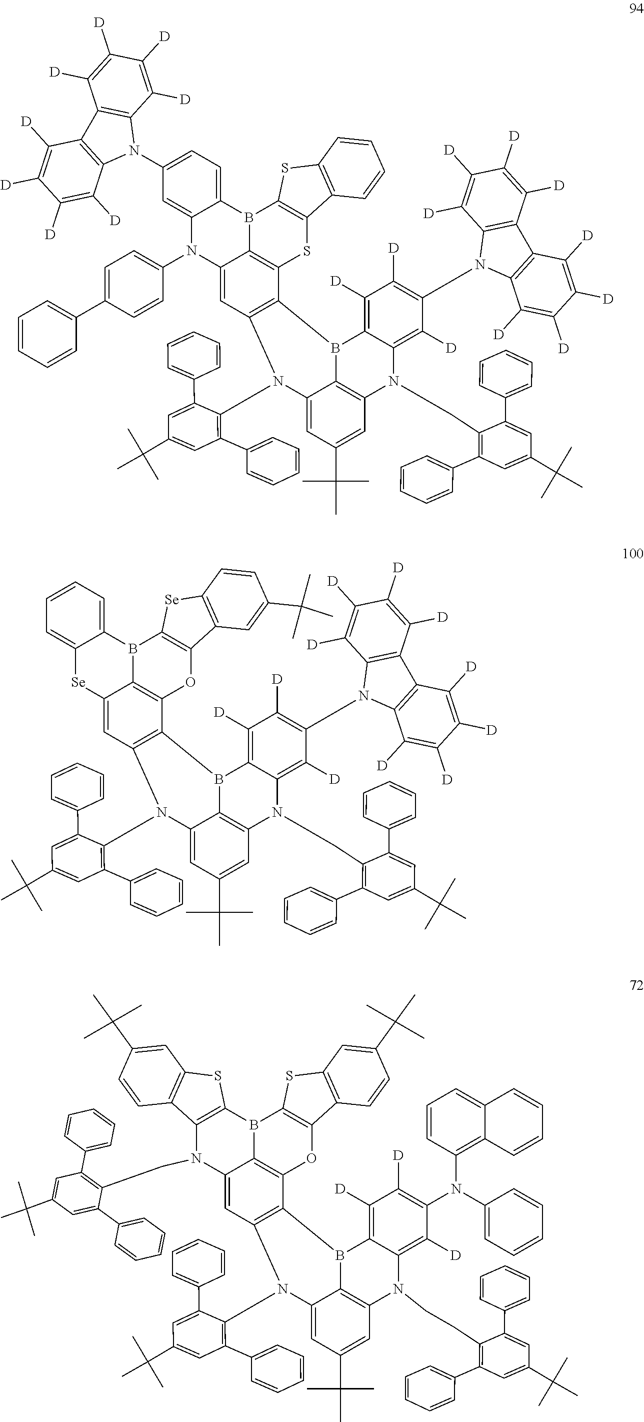

### [Comparative Example Compounds]

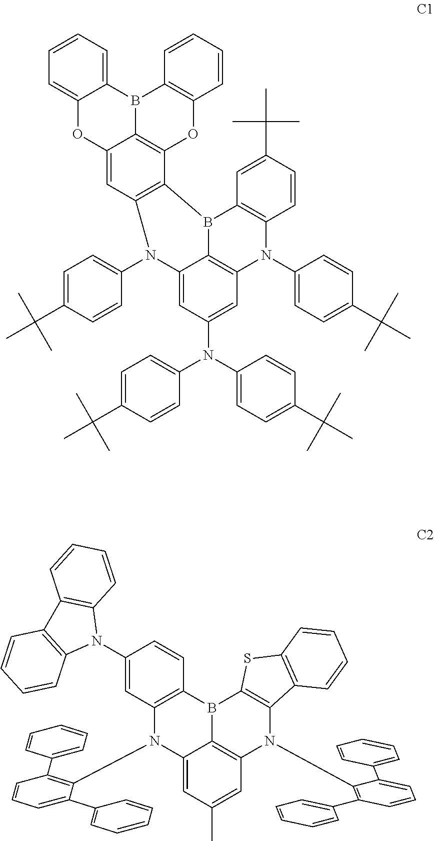 [SMILES: CC(C)(C)c1ccc(N(c2ccc(C(C)(C)C)cc2)c2cc3c4c(c2)N(c2ccc(C(C)(C)C)cc2)c2cc5c6c(c2B4c2cc(C(C)(C)C)ccc2N3c2ccc(C(C)(C)C)cc2)Oc2ccccc2B6c2ccccc2O5)cc1 ; Cc1cc2c3c(c1)N(c1c(-c4ccccc4)cccc1-c1ccccc1)c1c(sc4ccccc14)B3c1ccc(-n3c4ccccc4c4ccccc43)cc1N2c1c(-c2ccccc2)cccc1-c1ccccc1]

In the light-emitting elements according to Examples and Comparative Examples in Light-emitting Element Group 1, a glass substrate (made by Corning Co.), on which an ITO electrode of about 15 Ω/cm² (1,200 Å) was formed as a first electrode, was cut to a size of about 50 mm×50 mm×0.7 mm, cleansed by ultrasonic waves using isopropyl alcohol and pure water for about five minutes each, and irradiated with ultraviolet rays for about 30 minutes and exposed to ozone to be cleansed. The glass substrate was mounted on a vacuum deposition apparatus.

NPD was deposited on the first electrode to form a hole injection layer having a thickness of about 300 Å, Compound H-1-19 was deposited on the hole injection layer to form a hole transport layer having a thickness of about 200 Å, and CzSi was deposited on the hole transport layer to form an electron blocking layer having a thickness of about 100 Å.

A mixed host in which a second compound and a third compound according to embodiments were mixed at a weight ratio of about 1:1, a fourth compound, and an Example Compound or a Comparative Example Compound were co-deposited at a weight ratio of about 85:14:1 to form an emission layer having a thickness of about 200 Å. TSPO1 was deposited on the emission layer to form a hole blocking layer having a thickness of about 200 Å. TPBi was deposited on the hole blocking layer to form an electron transport layer having a thickness of about 300 Å, and LiF was deposited on the electron transport layer to form an electron injection layer having a thickness of about 10 Å. A second electrode having a thickness of about 3,000 Å was formed using Al, thereby forming a LiF/Al electrode. A capping layer having a thickness of about 700 Å was formed using Compound P4.

Each layer was formed by a vacuum deposition method. Compound HT1 from Compound Group 2 as described above was used as the second compound, Compound ETH66 from Compound Group 3 as described above was used as the third compound, and Compound AD-39 from Compound Group 4 as described above was used as the fourth compound.

Compounds used for manufacturing the light-emitting elements in Light-emitting Element Group 1 according to the Examples and the Comparative Examples are disclosed below. The materials below were used in manufacture of elements by purifying commercial products by sublimation.

### [Materials Used for Manufacture of Light-Emitting Element in Light-Emitting Element Group 1]

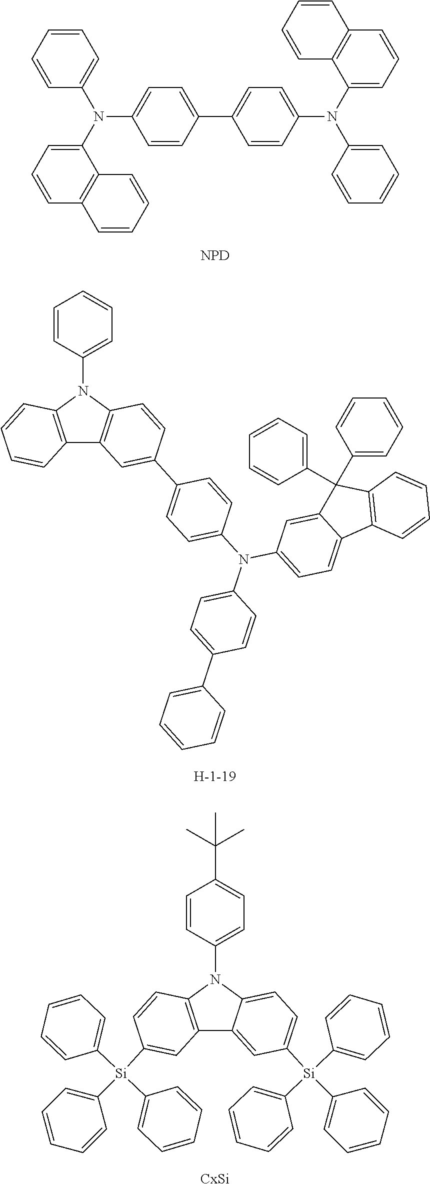 [SMILES: c1ccc(N(c2ccc(-c3ccc(N(c4ccccc4)c4cccc5ccccc45)cc3)cc2)c2cccc3ccccc23)cc1 ; "NPD" ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; CC(C)(C)c1ccc(-n2c3ccc([Si](c4ccccc4)(c4ccccc4)c4ccccc4)cc3c3cc([Si](c4ccccc4)(c4ccccc4)c4ccccc4)ccc32)cc1]

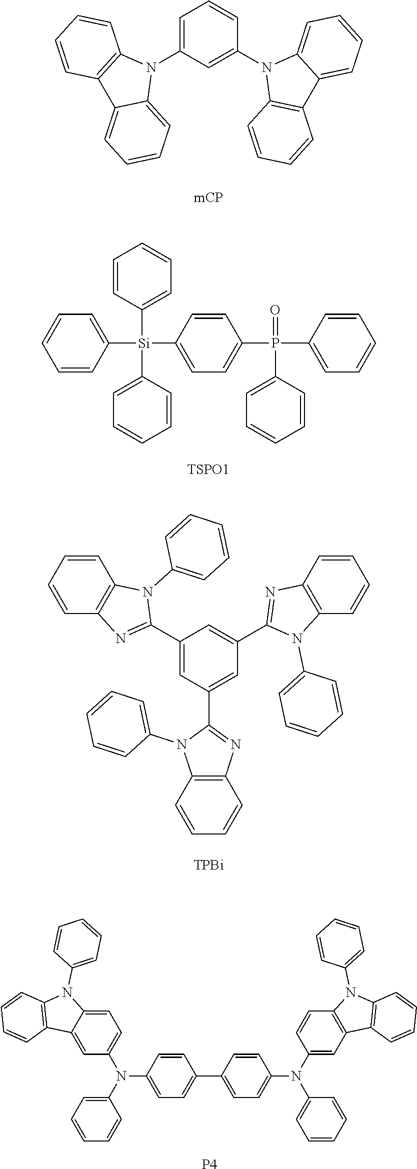

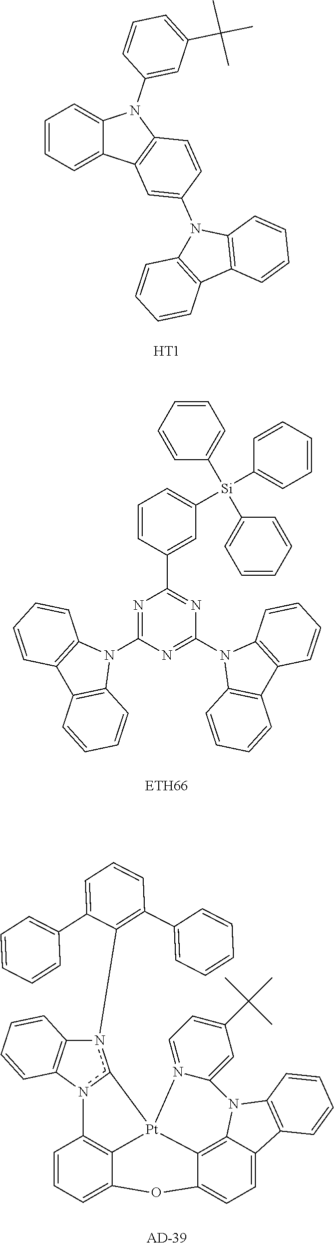

### (2) Evaluation of Properties of Light-Emitting Elements in Light-Emitting Element Group 1

For each light-emitting element in Light-emitting Element Group 1, which uses Example Compounds 5,29, 77, 81, 94, and 100, and Comparative Example Compounds C1 and C2 as an emission material, top luminous efficiency, emission wavelength, lifespan, and color coordinates were evaluated. The evaluation results for the light-emitting elements according to Example 1-1 to Example 1-6, Comparative Example 1-1, and Comparative Example 1-2 were listed in Table 2. In the evaluation results of the properties of the light-emitting elements according to examples and comparative examples listed in Table 2, the driving voltage and a current density were measured using V7000 OLED IVL Test System, (Polaronix). In order to evaluate properties of the light-emitting elements manufactured according to Examples 1-1 to 1-6, Comparative Example 1-1 and Comparative Example 1-2, in Light-emitting Element Group 1, the driving voltage, and the top efficiency (cd/A/y) were measured at a current density of about 10 mA/cm². The emission efficiency was measured using Keithley MU 236 and luminance meter PR650 at a luminance of about 1000 cd/m².

To perform evaluation of lifespan (T95), the time taken for luminance to deteriorate from an initial value to 95% thereof when the light-emitting element being continuously driven at a current density of about 10 mA/cm² was measured, and a comparative element lifespan was calculated as by comparing the measured time to that of the light-emitting element according to Comparative Example 1-1.

TABLE 2

| | Host | | | | | | | |
|---|---|---|---|---|---|---|---|---|
| | (Second | | | | Top | Emission | | Color |
| | compound/ | Fourth | | Driving | luminous | wave- | | coordi- |
| | Third | Com- | | voltage | efficiency | length | Lifespan | nates |
| | compound) | pound | Dopant | (V) | (cd/A/y) | (nm) | (T95) | (CIE y) |
| Example 1-1 | HT1/ETH66 | AD-39 | Compound 5 | 3.8 | 550 | 459 | 7.2 | 0.050 |
| Example 1-2 | HT1/ETH66 | AD-39 | Compound 29 | 3.9 | 570 | 456 | 9.4 | 0.047 |
| Example 1-3 | HT1/ETH66 | AD-39 | Compound 77 | 3.9 | 500 | 454 | 6.9 | 0.045 |
| Example 1-4 | HT1/ETH66 | AD-39 | Compound 81 | 3.7 | 550 | 460 | 5.8 | 0.052 |
| Example 1-5 | HT1/ETH66 | AD-39 | Compound 94 | 3.7 | 560 | 456 | 9.8 | 0.045 |
| Example 1-6 | HT1/ETH66 | AD-39 | Compound 100 | 3.9 | 530 | 461 | 3.7 | 0.053 |
| Comparative | HT1/ETH66 | AD-39 | Compound C1 | 4.3 | 400 | 457 | 1 | 0.050 |
| Example 1-1 | | | | | | | | |
| Comparative | HT1/ETH66 | AD-39 | Compound C2 | 4.1 | 250 | 460 | 0.1 | 0.053 |
| Example 1-2 | | | | | | | | |

Referring to the results listed in Table 2, it can be confirmed that the light-emitting elements according to examples, which use the fused polycyclic compound according to an embodiment as an emission material, have low driving voltage and improved properties in luminous efficiency and lifespan, compared to the light-emitting element according to comparative examples.

The fused polycyclic compound according to an embodiment includes a fused ring that includes two boron atoms and has combined properties of multiple resonance (MR) and charge transfer (CT). Since one or two first substituents according to an embodiment are fused on the core exhibiting charge transfer properties, the fused polycyclic compound according to an embodiment may have increased electron-withdrawing and narrow full width at half maximum properties. Therefore, the light-emitting elements according to Examples 1-1 to 1-6 containing the fused polycyclic compounds according to embodiments as an emission material may have improved effects on color coordinates and efficiency.

It can be confirmed that the fused polycyclic compound according to an embodiment includes a sterically hindered bulky substituent such as a substituted or unsubstituted terphenyl group, linked to a nitrogen atom of the core that exhibits multiple resonance properties, and thus the light-emitting elements according to Examples 1-1 to 1-6 containing the fused polycyclic compound according to an embodiment as an emission material exhibit significantly improved lifespan properties compared to the light-emitting elements according to comparative examples.

The light-emitting elements according to Comparative Examples 1-1 and 1-2 exhibit the results of high driving voltage and reduced element lifespan and efficiency, compared to the light-emitting elements according to the Examples. Comparative Example Compound C1 included in the light-emitting element of Comparative Example 1-1 may exhibit mixed properties of multiple resonance (MR) and charge transfer (CT). However, in Comparative Example Compound C1, no first substituent is fused to the CT core, and no bulky substituent such as a substituted or unsubstituted terphenyl group is linked to the MR core, and thus Comparative Example Compound C1 has large values of full width at half maximum and Stokes-shift, as compared to the Example Compounds. Therefore, the light-emitting element according to Comparative Example Compound C1 exhibits results of a significant decrease in lifespan and reduced efficiency, compared to the light-emitting elements according to examples.

It can be confirmed that since Comparative Example Compound C2 contained in the light-emitting element according to Comparative Example 1-2 has a structure that lacks a charge transfer (CT) core, and thus, tau is extremely slow, and the light-emitting element according to Comparative Example 1-2 using Comparative Example Compound C2 as an emission material exhibit results of a significant decrease in lifespan and luminous efficiency, compared to the light-emitting elements according to examples.

### (3) Manufacture of Light-Emitting Elements in Light-Emitting Element Group 2

In Light-emitting Element Group 2, light-emitting elements according to an embodiment containing the fused polycyclic compound according to an embodiment in the emission layer was manufactured by the following method. The light-emitting elements according to Example 2-1 to Example 2-3 were manufactured using the fused polycyclic compounds of Compounds 18, 89, and 72, which are Example Compounds, as a dopant material in the emission layer. The light-emitting element according to Comparative Example 2-1 corresponds to the light-emitting element manufactured using Comparative Example Compound C3 as a dopant material in the emission layer. Each light-emitting element in Light-emitting Element Group 2 was manufactured in the same manner as the light-emitting elements in Light-emitting Element Group 1 as described above, except for the emission layer. In the light-emitting element in Light-emitting Element Group 2, the host compound and an Example Compound or a Comparative Example Compound were co-deposited at a weight ratio of about 98:2 to form an emission layer having a thickness of about 200 Å. The host material used for manufacture of the light-emitting elements in Light-emitting Element Group 2 is α,β-ADN.

### [Example Compounds]

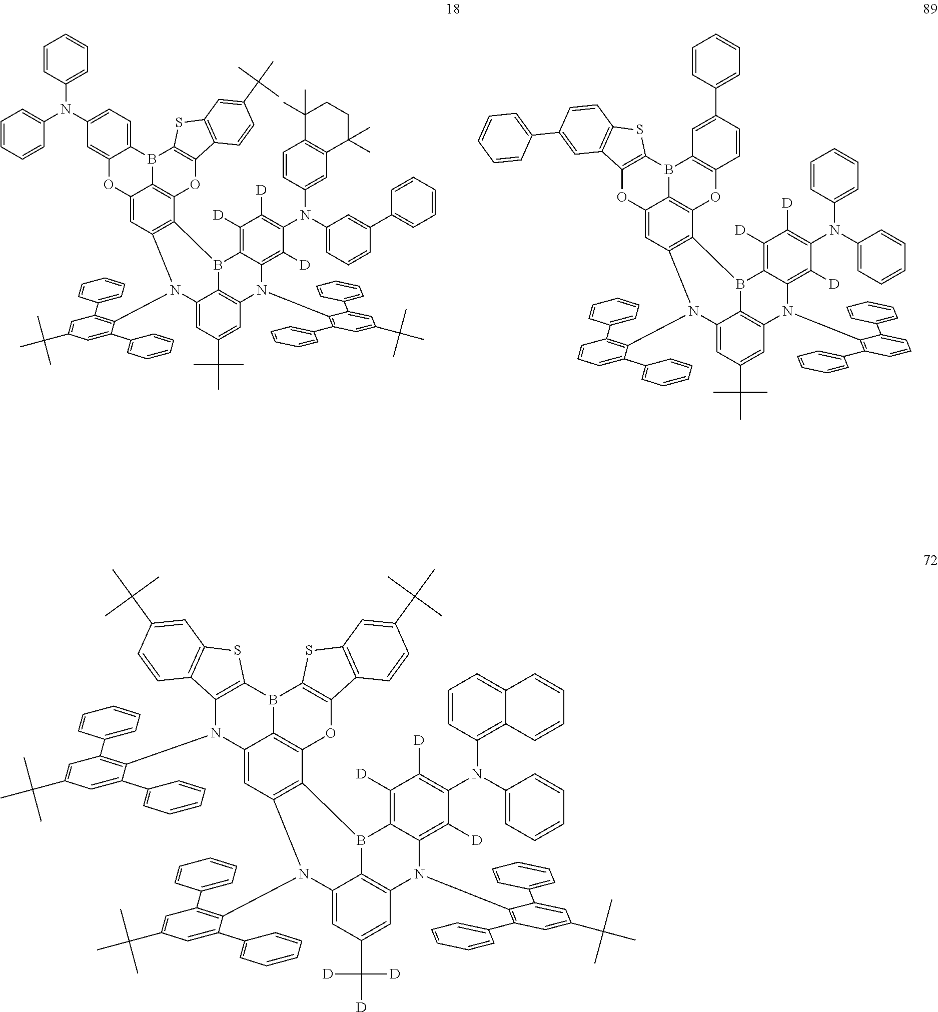

### [Comparative Example Compound]

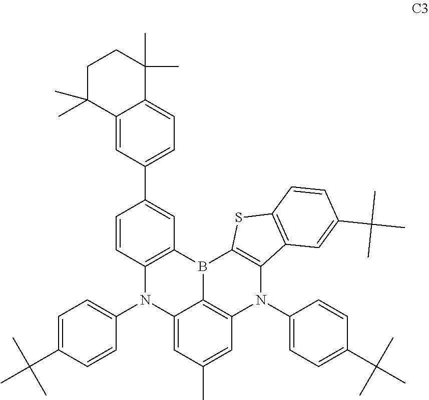 [SMILES: Cc1cc2c3c(c1)N(c1ccc(C(C)(C)C)cc1)c1c(sc4ccc(C(C)(C)C)cc14)B3c1cc(-c3ccc4c(c3)C(C)(C)CCC4(C)C)ccc1N2c1ccc(C(C)(C)C)cc1]

### (Materials Used for Manufacture of Light-Emitting Elements in Light-Emitting Element Group 2)

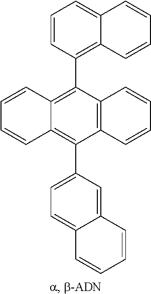 [SMILES: c1ccc2cc(-c3c4ccccc4c(-c4cccc5ccccc45)c4ccccc34)ccc2c1]

### (4) Evaluation of Properties of Light-Emitting Elements in Light-Emitting Element Group 2

Evaluation was performed for driving voltage, top luminous efficiency, emission wavelength, lifespan, and color coordinates of the light-emitting elements in Light-emitting Element Group 2, which uses Example Compounds 18, 72, and 89, and Comparative Example C3 as an emission material. Table 3 shows the evaluation results of Light-emitting elements according to Example 2-1 to Example 2-3 and Comparative Example 2-1, in Light-emitting Element Group 2. In the evaluation results of the light-emitting elements in Light-emitting Element Group 2 shown in Table 3, driving voltage (V), top luminous efficiency (cd/A/y), emission wavelength, lifespan, and color coordinates of each of the light-emitting elements in Light-emitting Element Group 2 were measured in the same manner as those of the light-emitting elements in Light-emitting Element Group 1. To perform evaluation of lifespan (T95), the time taken for luminance to deteriorate from an initial value to 95% thereof when the light-emitting element being continuously driven at a current density of about 10 mA/cm² was measured, and a comparative element lifespan was calculated by comparing the measured time to that of the light-emitting element according to Comparative Example 2-1.

TABLE 3

| | | | | Top | | | |
|---|---|---|---|---|---|---|---|
| | | | Driving | luminous | Emission | | Color |
| | | | voltage | efficiency | wavelength | Lifespan | coordinates |
| | Host | Dopant | (V) | (cd/A/y) | (nm) | (T95) | (CIE y) |
| Example 2-1 | α,β-ADN | Compound 18 | 3.1 | 280 | 453 | 120% | 0.041 |
| Example 2-2 | α,β-ADN | Compound 72 | 3.0 | 300 | 455 | 115% | 0.043 |
| Example 2-3 | α,β-ADN | Compound 89 | 3.0 | 290 | 453 | 135% | 0.040 |
| Comparative | α,β-ADN | Compound C3 | 3.5 | 220 | 455 | 100% | 0.045 |
| Example 2-1 | | | | | | | |

Referring to the results in Table 3, it can be confirmed that the light-emitting elements according to Example 2-1 to Example 2-3 in Light-emitting Element Group 2, which uses the fused polycyclic compound according to an embodiment as an emission material, have low driving voltage and improved properties of luminous efficiency and lifespan compared to the light-emitting element according to Comparative Example 2-1.

The light-emitting element according to an embodiment may exhibit improved element properties in high efficiency and long lifespan.

The fused polycyclic compound according to an embodiment may contribute to improving in high efficiency and long lifespan of the light-emitting element when it is included in the emission layer of a light-emitting element.

The display device according to an embodiment may exhibit excellent display quality.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light-emitting element comprising:
a first electrode;
a second electrode disposed on the first electrode; and
an emission layer disposed between the first electrode and the second electrode, wherein
the emission layer includes a first compound represented by Formula 1: 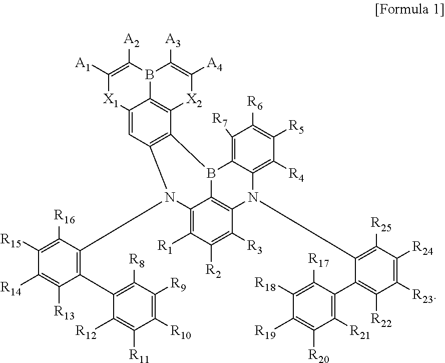
wherein in Formula 1,
X₁ and X₂ are each independently O, S, Se, Te, N(R₂₆), or Si(R₂₇)(R₂₈),
R₁ to R₂₈ are each independently a hydrogen atom, a deuterium atom, a halogen atom, a cyano group, a nitro group, a substituted or unsubstituted silyl group, a substituted or unsubstituted oxy group, a substituted or unsubstituted amine group, a substituted or unsubstituted alkyl group having 1 to 60 carbons, a substituted or unsubstituted cycloalkyl group having 3 to 60 ring-forming carbons, a substituted or unsubstituted alkenyl group having 2 to 60 carbons, a substituted or unsubstituted aryl group having 6 to 60 ring-forming carbons, or a substituted or unsubstituted heteroaryl group having 2 to 60 ring-forming carbons, or bonded to an adjacent group to form a ring,
at least one of R₁₆ and R₂₅ is each independently a substituted or unsubstituted phenyl group,
at least one of a pair of A₁ and A₂ and a pair of A₃ and A₄ is each independently bonded to a first substituent represented by Formula S-1, and
the remainder of a pair of A₁ and A₂ and a pair of A₃ and A₄ that is not bonded to the first substituent represented by Formula S-1 is bonded to a second substituent represented by Formula S-2: 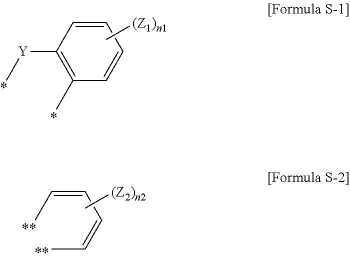
wherein in Formula S-1,
Y is O, S, Se, Te, N(Rₛ₁), or Si(Rₛ₂)(Rₛ₃), and
wherein in Formula S-1 and Formula S-2,
Rₛ₁ to Rₛ₃, Z₁, and Z₂ are each independently a hydrogen atom, a deuterium atom, a halogen atom, a cyano group, a nitro group, a substituted or unsubstituted silyl group, a substituted or unsubstituted oxy group, a substituted or unsubstituted amine group, a substituted or unsubstituted alkyl group having 1 to 60 carbons, a substituted or unsubstituted cycloalkyl group having 3 to 60 ring-forming carbons, a substituted or unsubstituted alkenyl group having 2 to 60 carbons, a substituted or unsubstituted aryl group having 6 to 60 ring-forming carbons, or a substituted or unsubstituted heteroaryl group having 2 to 60 ring-forming carbons, or bonded to an adjacent group to form a ring,
n1 and n2 are each independently an integer from 0 to 4, and
*- and **- each represents a bond to the pair of A₁ and A₂ or the pair of A₃ and A₄ in Formula 1.

2. The light-emitting element of claim 1, wherein the first compound is represented by one of Formula 2 to Formula 4: 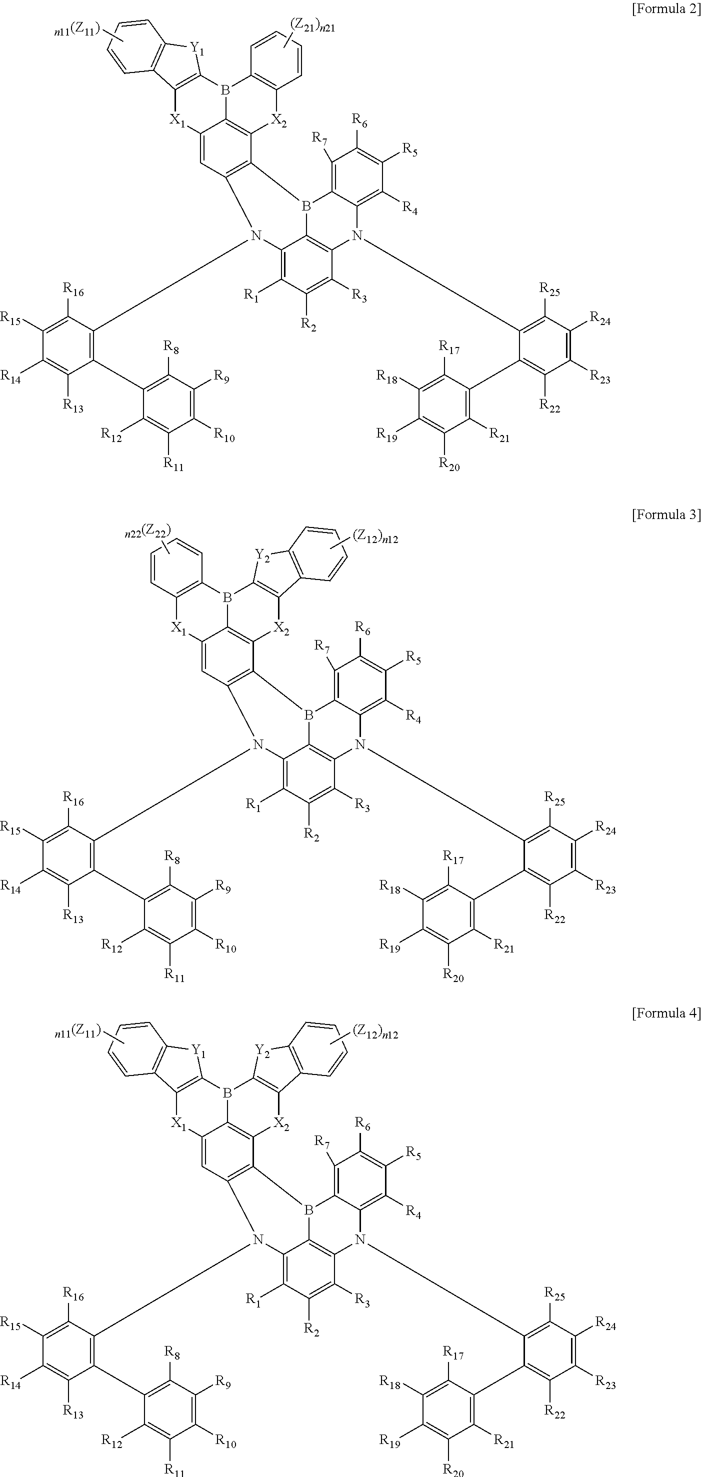
wherein in Formula 2 to Formula 4,
Y₁ and Y₂ are each independently O, S, Se, Te, N(R_{y1}), or Si(R_{y2})(R_{y3}),
Z₁, Z₁₂, Z₂₁, Z₂₂, R_{y1}, R_{y2}, and R_{y3} are each independently a hydrogen atom, a deuterium atom, a halogen atom, a cyano group, a nitro group, a substituted or unsubstituted silyl group, a substituted or unsubstituted oxy group, a substituted or unsubstituted amine group, a substituted or unsubstituted alkyl group having 1 to 60 carbons, a substituted or unsubstituted cycloalkyl group having 3 to 60 ring-forming carbons, a substituted or unsubstituted alkenyl group having 2 to 60 carbons, a substituted or unsubstituted aryl group having 6 to 60 ring-forming carbons, or a substituted or unsubstituted heteroaryl group having 2 to 60 ring-forming carbons, or bonded to an adjacent group to form a ring,
n11, n12, n21, and n22 are each independently an integer from 0 to 4, and
X₁, X₂, and R₁ to R₂₅ are the same as defined in Formula 1.

3. The light-emitting element of claim 2, wherein the first compound is represented by one of Formula 2-1 to Formula 2-3: 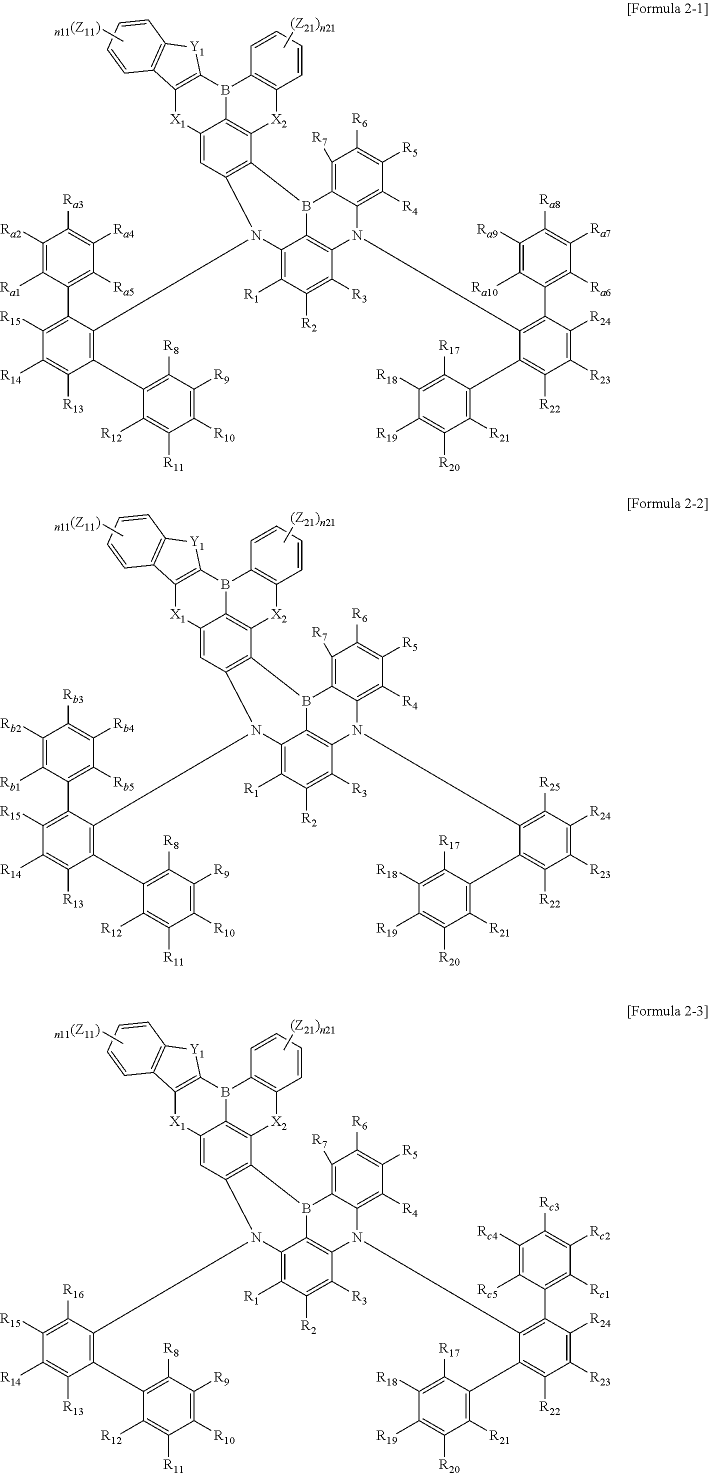
wherein in Formula 2-1 to Formula 2-3,
Rₐ₁ to Rₐ₁₀, R_{b1} to R_{b5}, and R_{b1} to R_{b5} are each independently a hydrogen atom, a deuterium atom, a substituted or unsubstituted alkyl group having 1 to 30 carbons, or a substituted or unsubstituted aryl group having 6 to 30 ring-forming carbons,
X₁, X₂, and R₁ to R₂₅ are the same as defined in Formula 1, and
Y₁, Z₁₁, Z₂₁, n11, and n21 are the same as defined in Formula 2.

4. The light-emitting element of claim 2, wherein the first compound represented by one of Formula 3-1 to Formula 3-3: 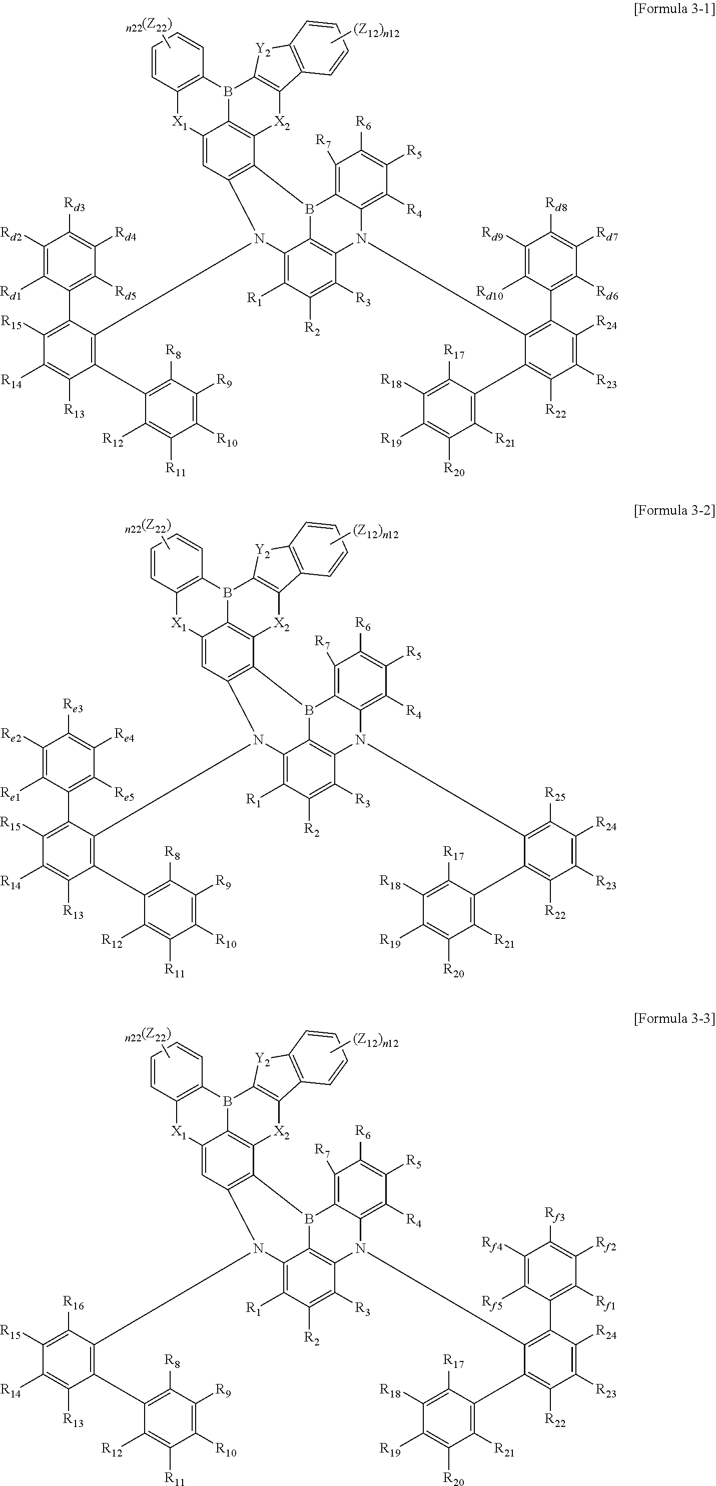
wherein in Formula 3-1 to Formula 3-3,
R_{d1} to R_{d10}, Rₑ₁ to Rₑ₅, and R_{f1} to R_{f5} are each independently a hydrogen atom, a deuterium atom, a substituted or unsubstituted alkyl group having 1 to 30 carbons, or a substituted or unsubstituted aryl group having 6 to 30 ring-forming carbons,
X₁, X₂, and R₁ to R₂₅ are the same as defined in Formula 1, and
Y₂, Z₁₂, Z₂₂, n12, and n22 are the same as defined Formula 3.

5. The light-emitting element of claim 2, wherein the first compound is represented by one of Formula 4-1 to Formula 4-3: 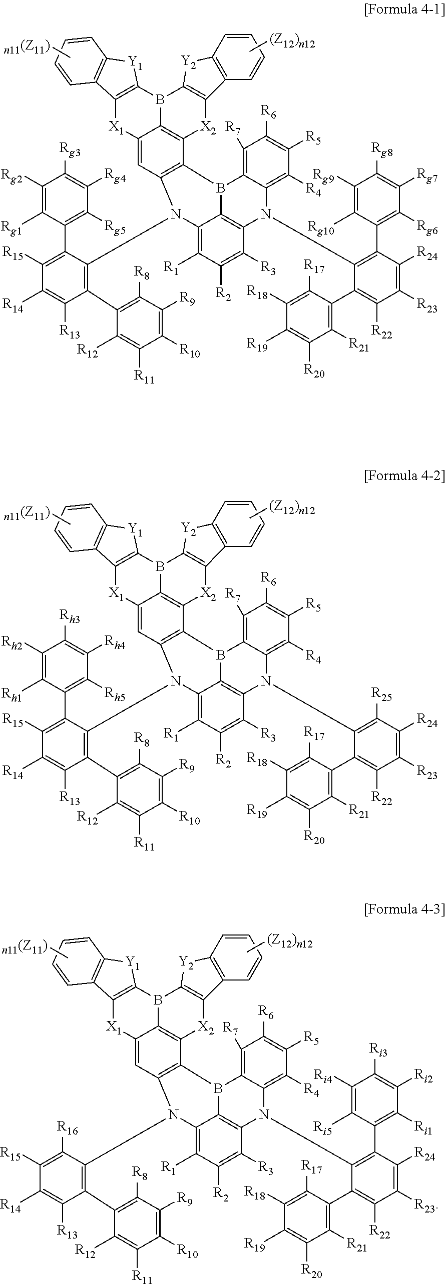
wherein in Formula 4-1 to Formula 4-3,
R_{g1} to R_{g10}, Rₕ₁ to Rₕ₅, and Rᵢ₁ to Rᵢ₅ are each independently a hydrogen atom, a deuterium atom, a substituted or unsubstituted alkyl group having 1 to 30 carbons, or a substituted or unsubstituted aryl group having 6 to 30 ring-forming carbons,
X₁, X₂, and R₁ to R₂₅ are the same as defined in Formula 1, and
Y₁, Y₂, Z₁₁, Z₁₂, n11, and n12 are the same as defined in Formula 4.

6. The light-emitting element of claim 1, wherein
at least one of X₁ and X₂ is O, and
the remainder of X₁ and X₂ that is not O is S, Se, Te, N(R₂₆), or Si(R₂₇)(R₂₈).

7. The light-emitting element of claim 1, wherein R₄ to R₇ are each independently a deuterium atom, a substituted or unsubstituted amine group, a substituted or unsubstituted t-butyl group, a substituted or unsubstituted phenyl group, or a substituted or unsubstituted carbazole group.

8. The light-emitting element of claim 1, wherein
Z₁ is a hydrogen atom, a deuterium atom, a substituted or unsubstituted methyl group, a substituted or unsubstituted t-butyl group, a substituted or unsubstituted phenyl group, a substituted or unsubstituted carbazole group, or a substituted or unsubstituted diphenylamine group, and
Z₂ is a hydrogen atom, a deuterium atom, a substituted or unsubstituted t-butyl group, a substituted or unsubstituted phenyl group, a substituted or unsubstituted carbazole group, a substituted or unsubstituted diphenylamine group, or a substituted or unsubstituted dibiphenylamine group.

9. The light-emitting element of claim 1, wherein the first compound comprises at least one deuterium atom as a substituent.

10. The light-emitting element of claim 1, wherein the emission layer further comprises:
at least one of a second compound represented by Formula HT-1, a third compound represented by Formula ET-1, and a fourth compound represented by Formula D-1: 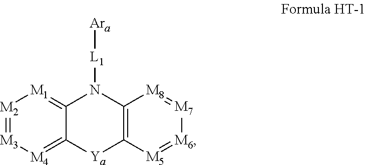
wherein in Formula HT-1,
M₁ to M₈ are each independently N or C(R₅₁),
L₁ is a direct linkage, a substituted or unsubstituted arylene group having 6 to 30 ring-forming carbons, or a substituted or unsubstituted heteroarylene group having 2 to 30 ring-forming carbons,
Yₐ is a direct linkage, C(R₅₂)(R₅₃), or Si(R₅₄)(R₅₅),
Arₐ is a substituted or unsubstituted aryl group having 6 to 30 ring-forming carbons or a substituted or unsubstituted heteroaryl group having 2 to 30 ring-forming carbons, and
R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbons, a substituted or unsubstituted alkenyl group having 2 to 20 carbons, a substituted or unsubstituted aryl group having 6 to 60 ring-forming carbons, or a substituted or unsubstituted heteroaryl group having 2 to 60 ring-forming carbons, or bonded to an adjacent group to form a ring; 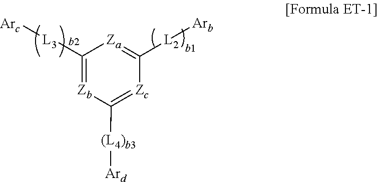
wherein in Formula ET-1,
at least one of Zₐ to Ze is N,
the remainder of Zₐ to Z_{c} are each independently C(R₅₆),
R₅₆ is a hydrogen atom, a deuterium atom, a substituted or unsubstituted alkyl group having 1 to 20 carbons, a substituted or unsubstituted aryl group having 6 to 60 ring-forming carbons, or a substituted or unsubstituted heteroaryl group having 2 to 60 ring-forming carbons,
b1 to b3 are each independently an integer from 0 to 10,
Ar_{b} to Ar_{d} are each independently a hydrogen atom, a deuterium atom, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons, and
L₂ to L₄ are each independently a direct linkage, a substituted or unsubstituted arylene group having 6 to 30 ring-forming carbons, or a substituted or unsubstituted heteroarylene group having 2 to 30 ring-forming carbons; 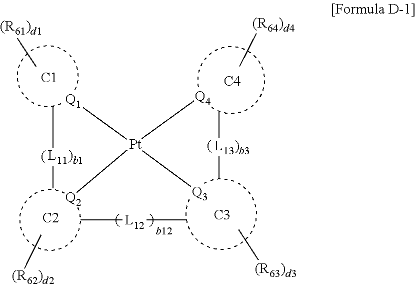
wherein in Formula D-1,
Q₁ to Q₄ are each independently C or N,
C1 to C4 are each independently a substituted or unsubstituted hydrocarbon ring having 5 to 30 ring-forming carbons or a substituted or unsubstituted heterocycle having 2 to 30 ring-forming carbons,
L₁ to L₁₃ are each independently a direct linkage, *—O—*, *—S—* , 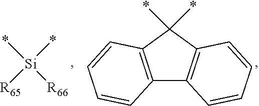
a substituted or unsubstituted alkylene group having 1 to 20 carbons, a substituted or unsubstituted arylene group having 6 to 30 ring-forming carbons, or a substituted or unsubstituted heteroarylene group having 2 to 30 ring-forming carbons,
b11 to b13 are each independently 0 or 1,
R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbons, a substituted or unsubstituted alkenyl group having 2 to 20 carbons, a substituted or unsubstituted aryl group having 6 to 60 ring-forming carbons, or a substituted or unsubstituted heteroaryl group having 2 to 60 ring-forming carbons, or bonded to an adjacent group to form a ring, and
d1 to d4 are each independently an integer from 0 to 4.

11. The light-emitting element of claim 1, wherein the emission layer further comprises:
a compound represented by Formula E-1: 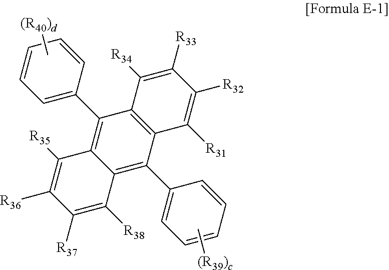
wherein in Formula E-1,
R₃₁ to R₄₀ are each independently a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbons, a substituted or unsubstituted alkenyl group having 2 to 10 carbons, a substituted or unsubstituted aryl group having 6 to 30 ring-forming carbons, or a substituted or unsubstituted heteroaryl group having 2 to 30 ring-forming carbons, or bonded to an adjacent group to form a ring, and
c and d are each independently an integer from 0 to 5.

12. The light-emitting element of claim 1, wherein the first compound comprises at least one compound selected from Compound Group 1: 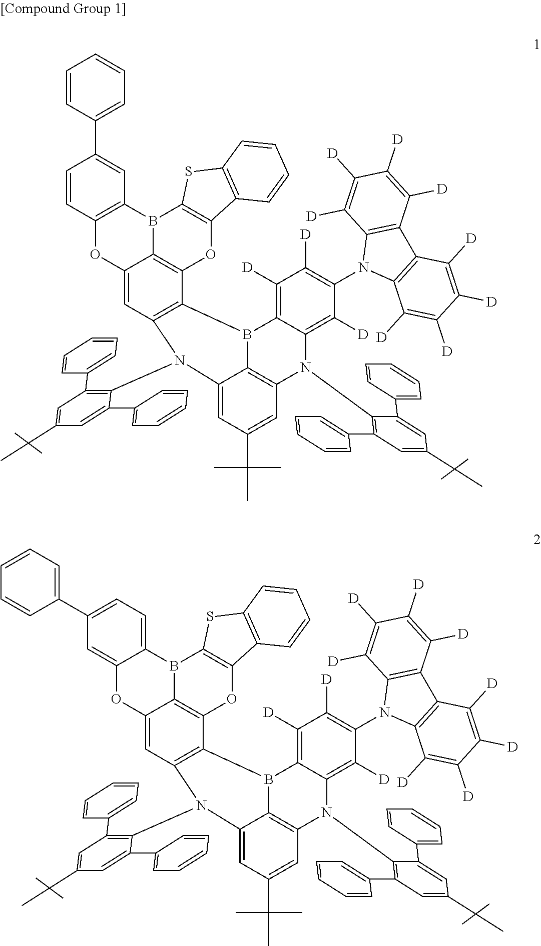 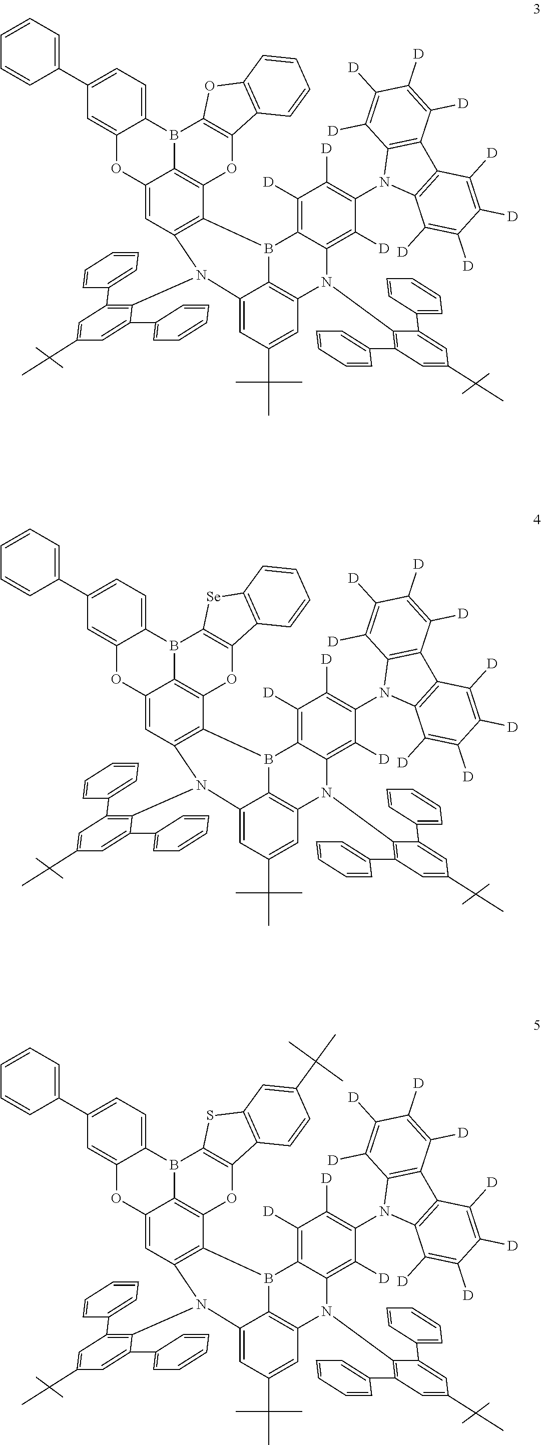 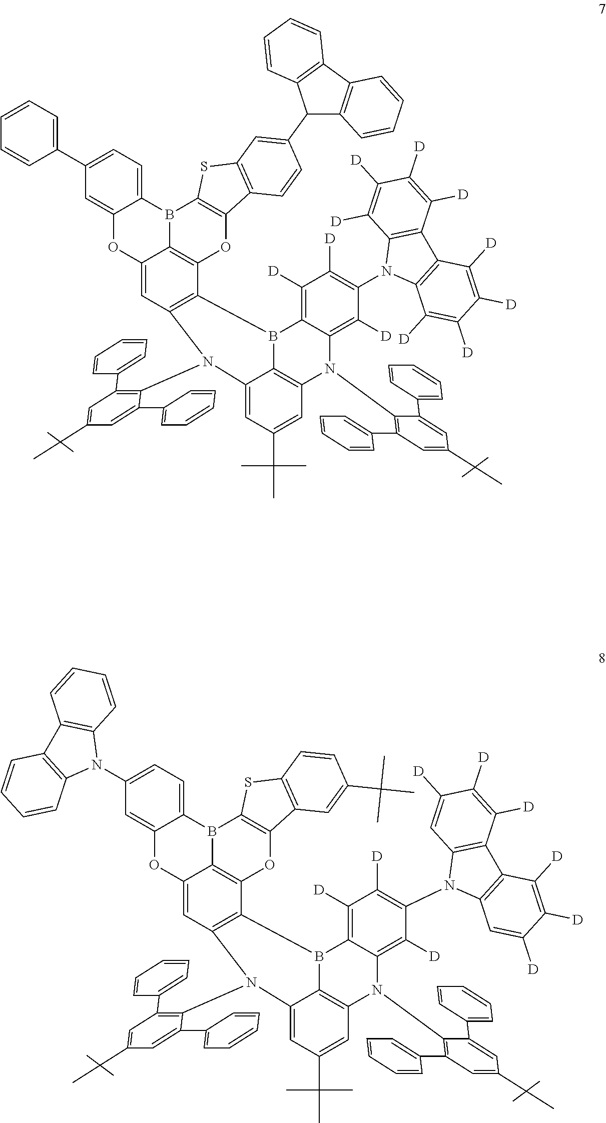 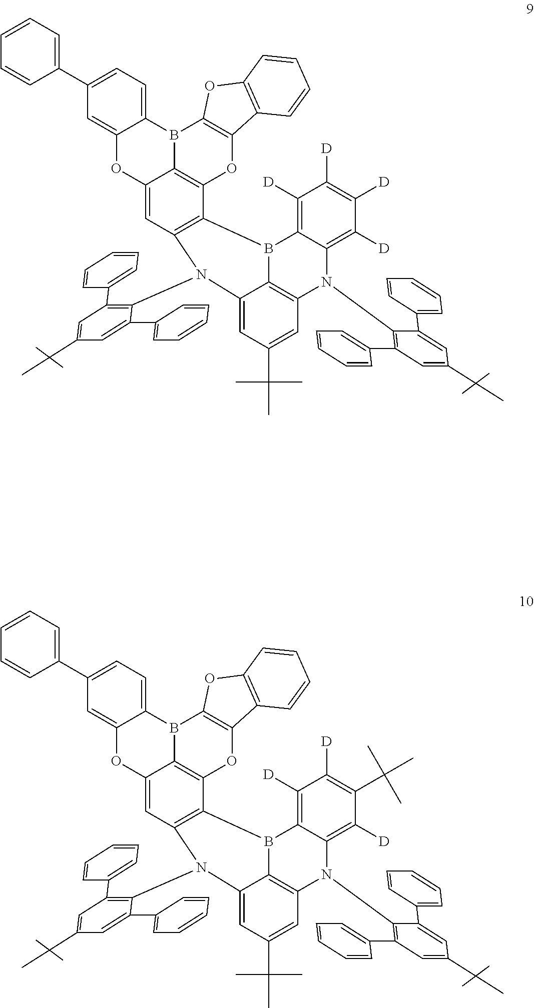 [SMILES: [2H]c1c([2H])c([2H])c2c(c1[2H])B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1c(oc2ccccc12)B4c1ccc(-c2ccccc2)cc1O3 ; [2H]c1c([2H])c(C(C)(C)C)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1c(oc2ccccc12)B4c1ccc(-c2ccccc2)cc1O3] 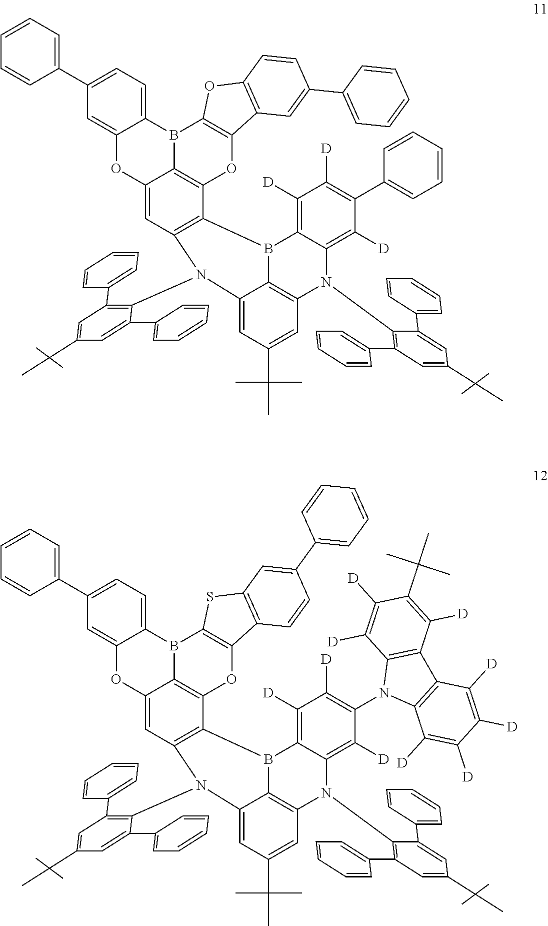 [SMILES: [2H]c1c([2H])c(-c2ccccc2)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1c(oc2ccc(-c5ccccc5)cc12)B4c1ccc(-c2ccccc2)cc1O3 ; [2H]c1c([2H])c(-n2c3c([2H])c([2H])c([2H])c([2H])c3c3c([2H])c(C(C)(C)C)c([2H])c([2H])c32)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1c(sc2cc(-c5ccccc5)ccc12)B4c1ccc(-c2ccccc2)cc1O3] 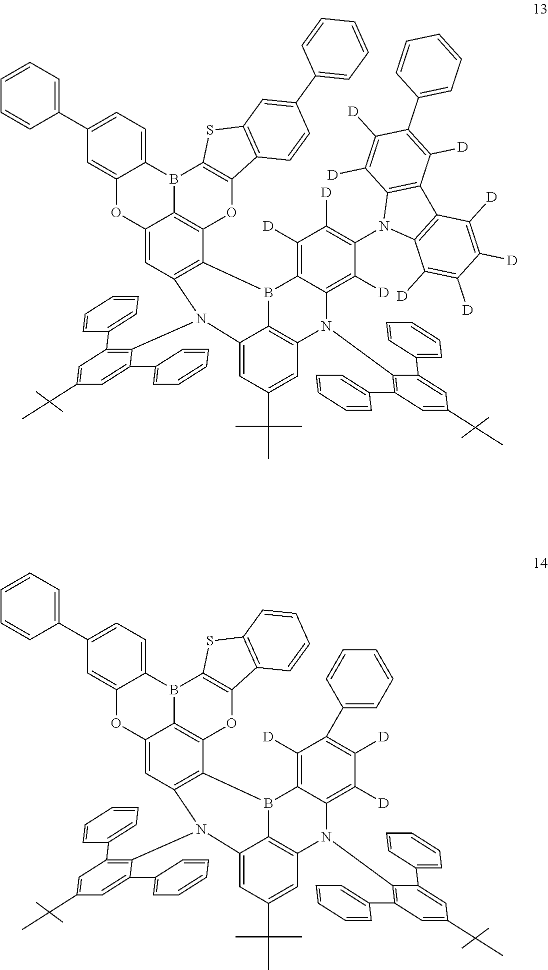 [SMILES: [2H]c1c([2H])c(-n2c3c([2H])c([2H])c([2H])c([2H])c3c3c([2H])c(-c4ccccc4)c([2H])c([2H])c32)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1c(sc2cc(-c5ccccc5)ccc12)B4c1ccc(-c2ccccc2)cc1O3 ; [2H]c1c([2H])c2c(c([2H])c1-c1ccccc1)B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1c(sc2ccccc12)B4c1ccc(-c2ccccc2)cc1O3] 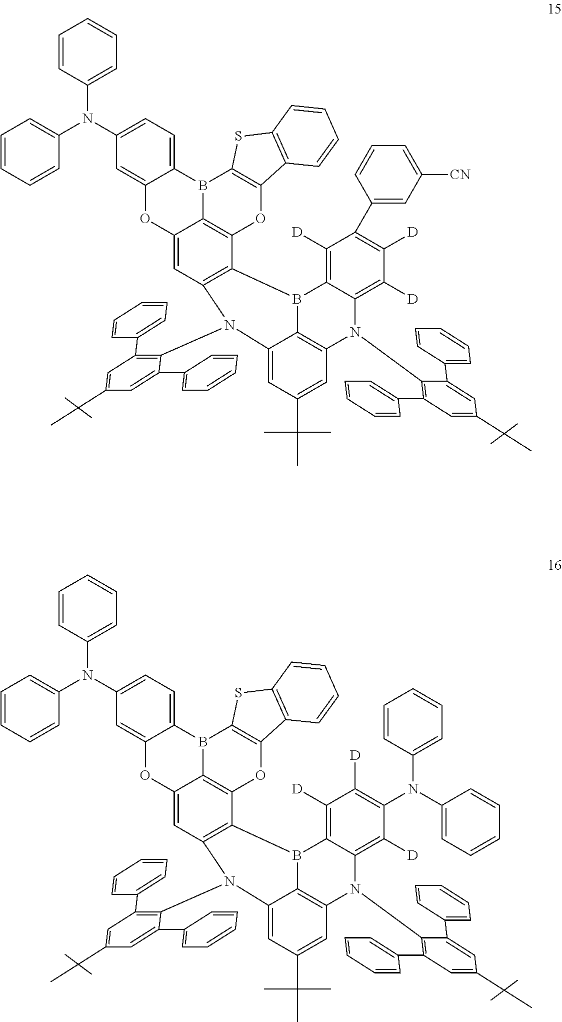 [SMILES: [2H]c1c([2H])c2c(c([2H])c1-c1cccc(C#N)c1)B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1c(sc2ccccc12)B4c1ccc(N(c2ccccc2)c2ccccc2)cc1O3 ; [2H]c1c([2H])c(N(c2ccccc2)c2ccccc2)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1c(sc2ccccc12)B4c1ccc(N(c2ccccc2)c2ccccc2)cc1O3] 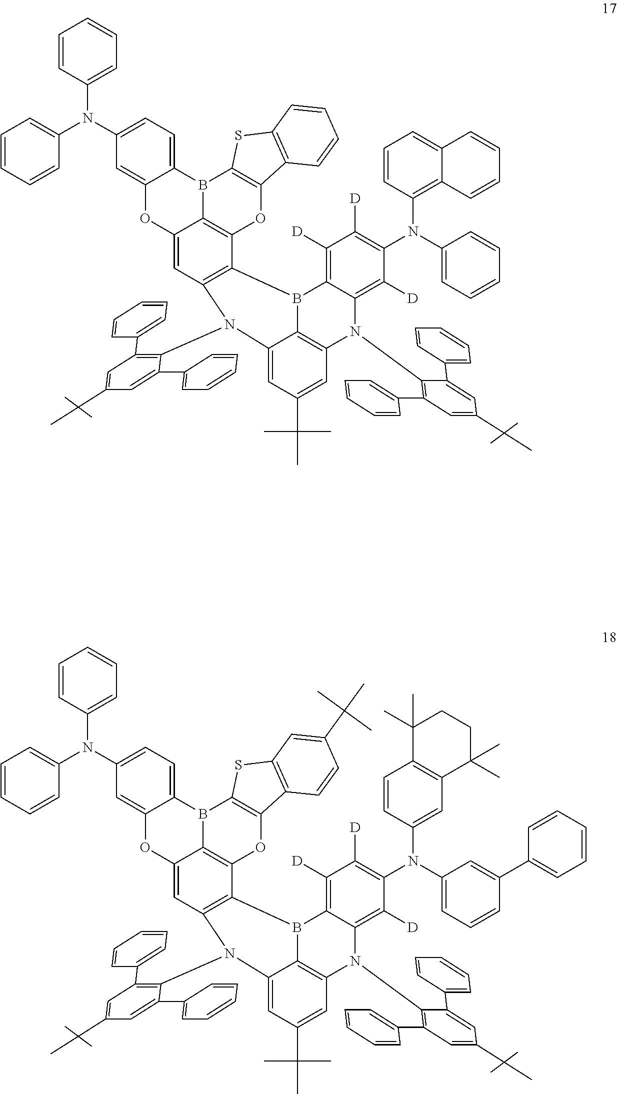 [SMILES: [2H]c1c([2H])c(N(c2ccccc2)c2cccc3ccccc23)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1c(sc2ccccc12)B4c1ccc(N(c2ccccc2)c2ccccc2)cc1O3 ; [2H]c1c([2H])c(N(c2cccc(-c3ccccc3)c2)c2ccc3c(c2)C(C)(C)CCC3(C)C)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1c(sc2cc(C(C)(C)C)ccc12)B4c1ccc(N(c2ccccc2)c2ccccc2)cc1O3] 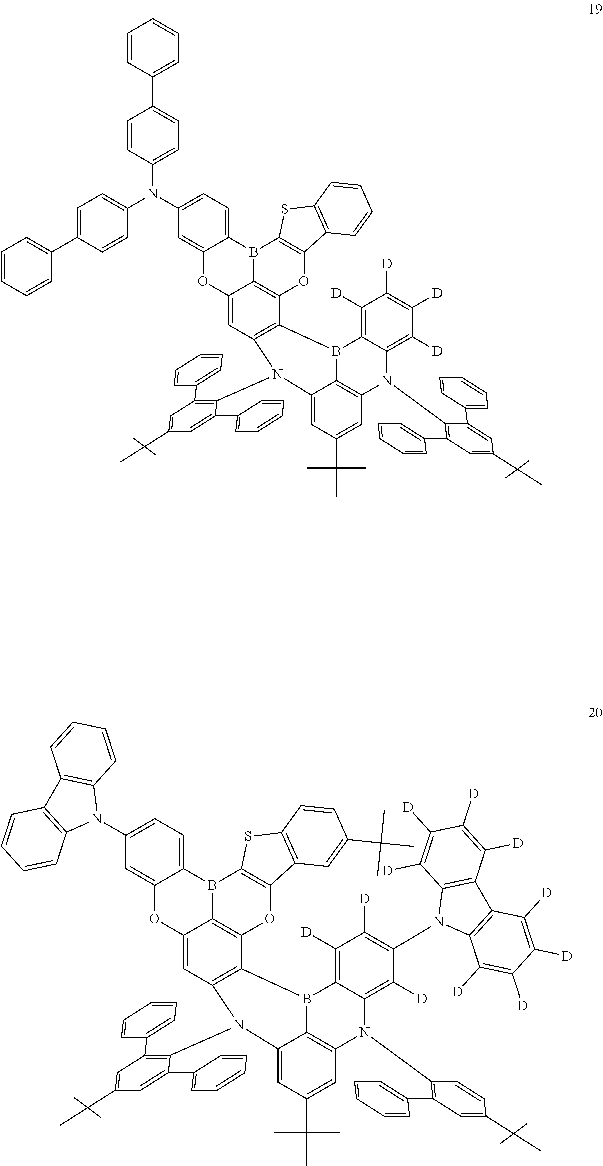 [SMILES: [2H]c1c([2H])c([2H])c2c(c1[2H])B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1c(sc2ccccc12)B4c1ccc(N(c2ccc(-c4ccccc4)cc2)c2ccc(-c4ccccc4)cc2)cc1O3 ; [2H]c1c([2H])c(-n2c3c([2H])c([2H])c([2H])c([2H])c3c3c([2H])c([2H])c([2H])c([2H])c32)c([2H])c2c1B1c3c(cc(C(C)(C)C)cc3N2c2ccc(C(C)(C)C)cc2-c2ccccc2)N(c2c(-c3ccccc3)cc(C(C)(C)C)cc2-c2ccccc2)c2cc3c4c(c21)Oc1c(sc2ccc(C(C)(C)C)cc12)B4c1ccc(-n2c4ccccc4c4ccccc42)cc1O3] 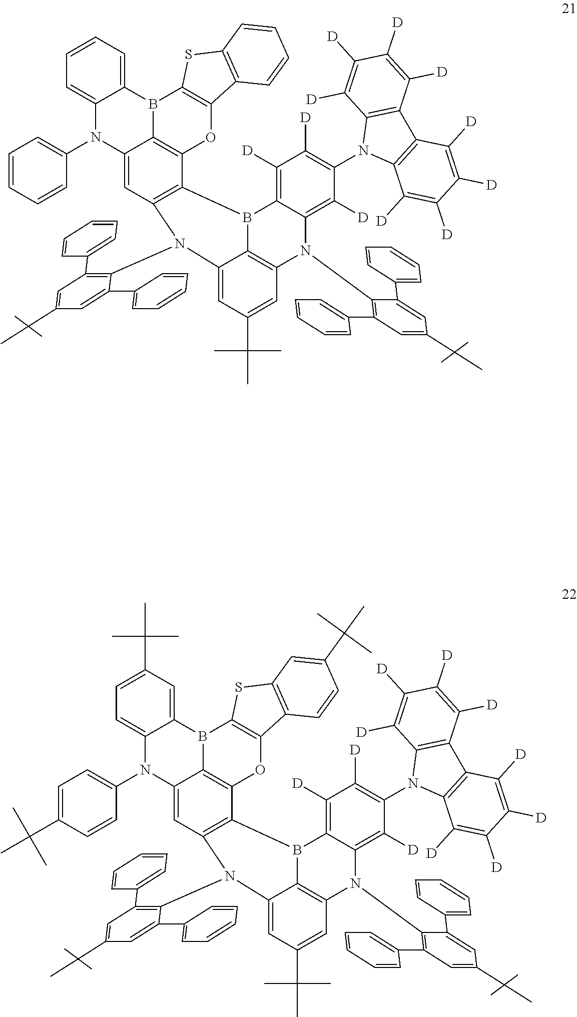 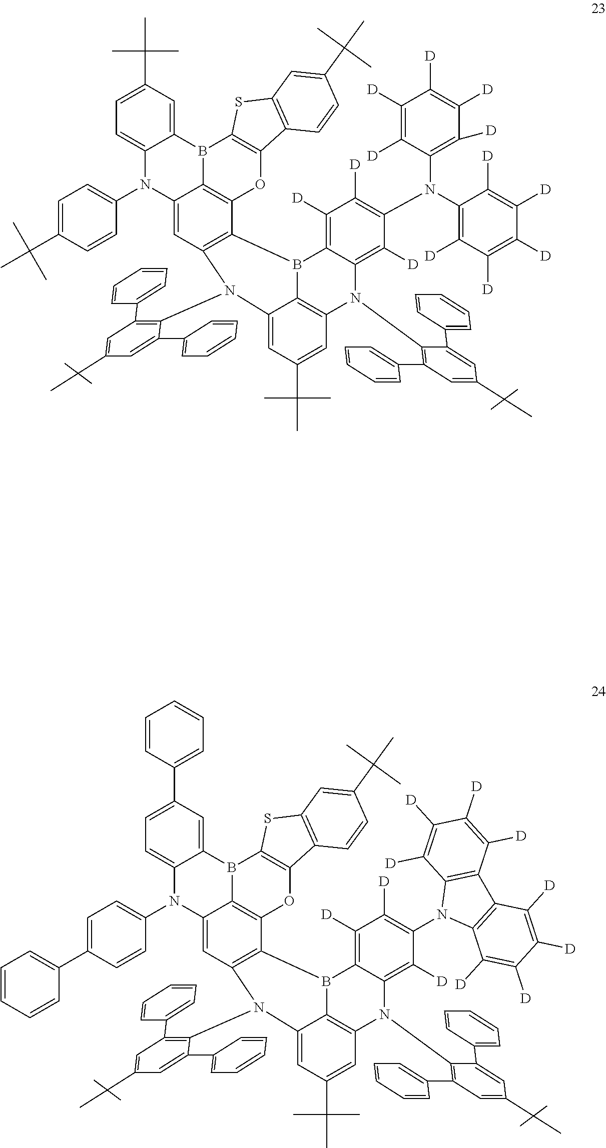 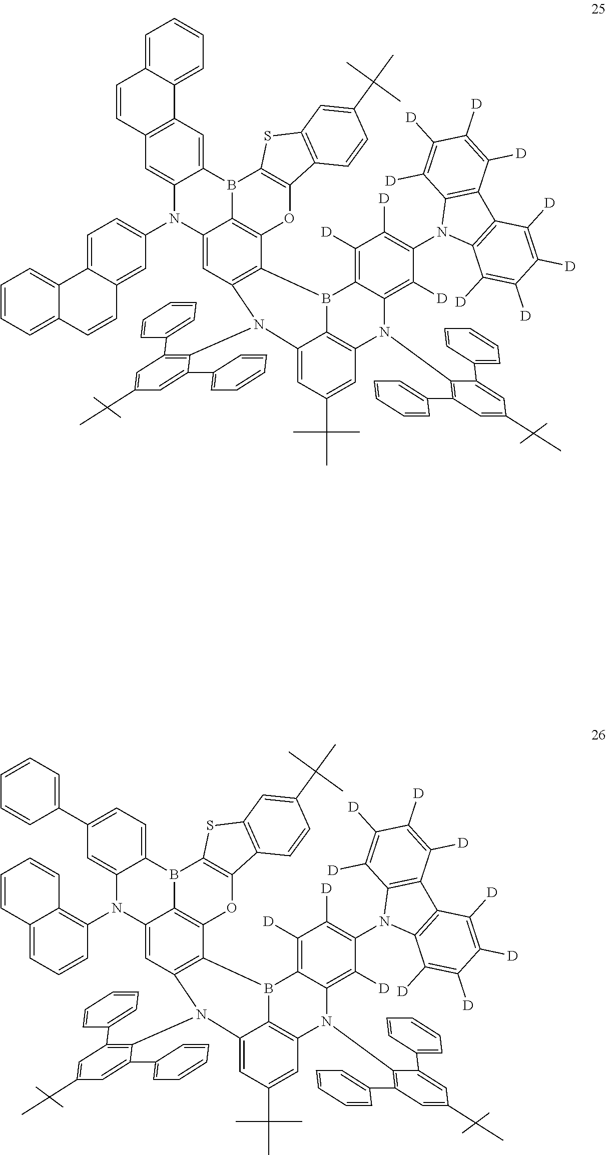 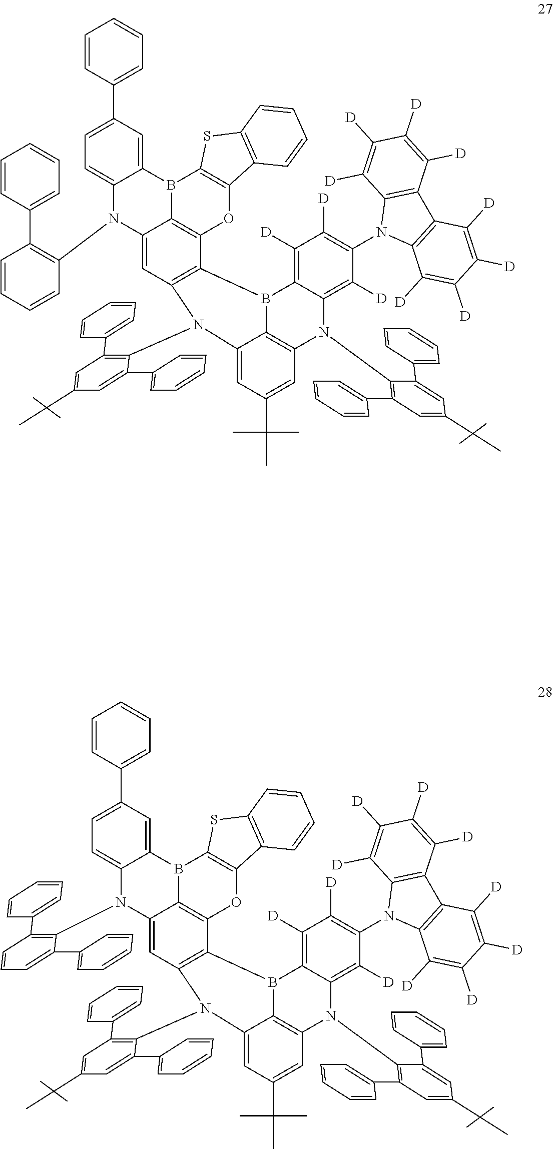 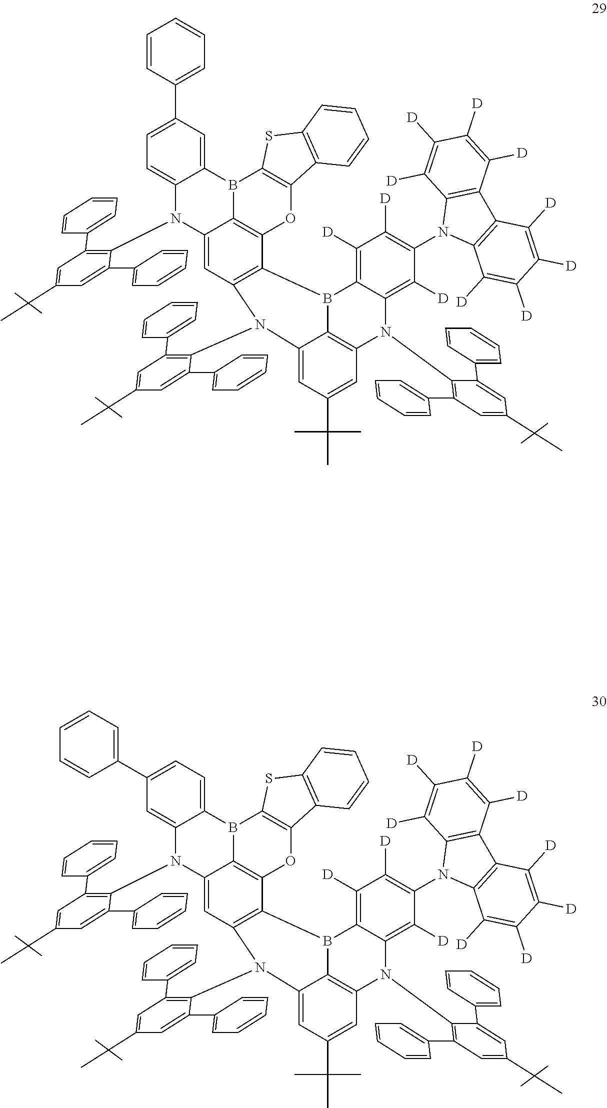 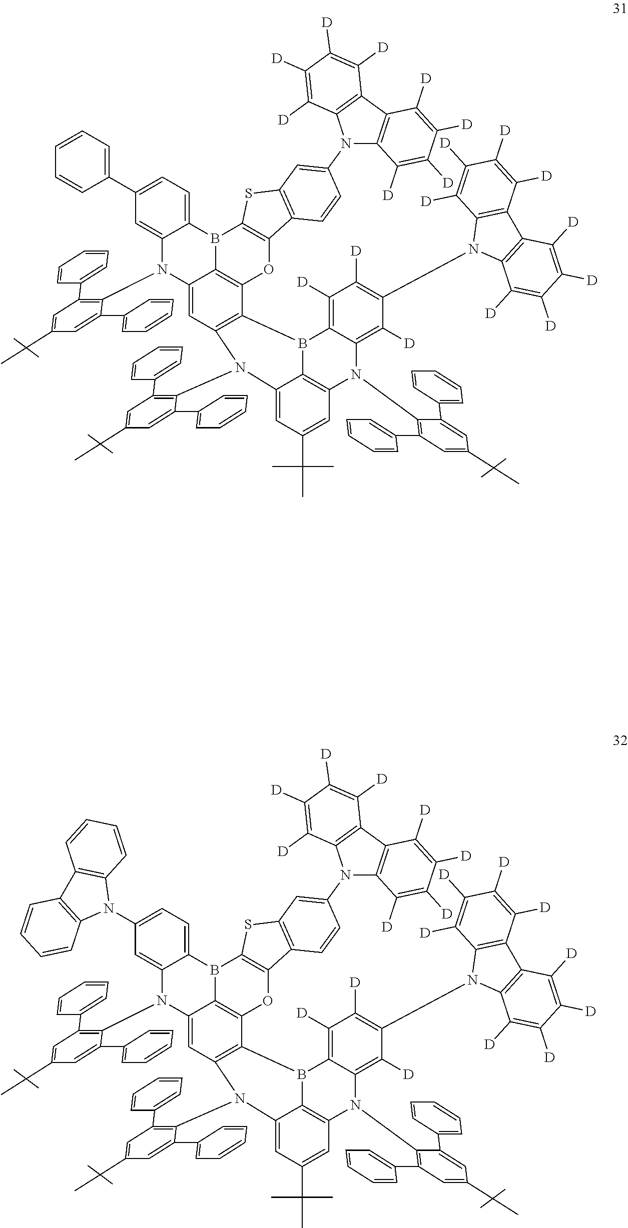 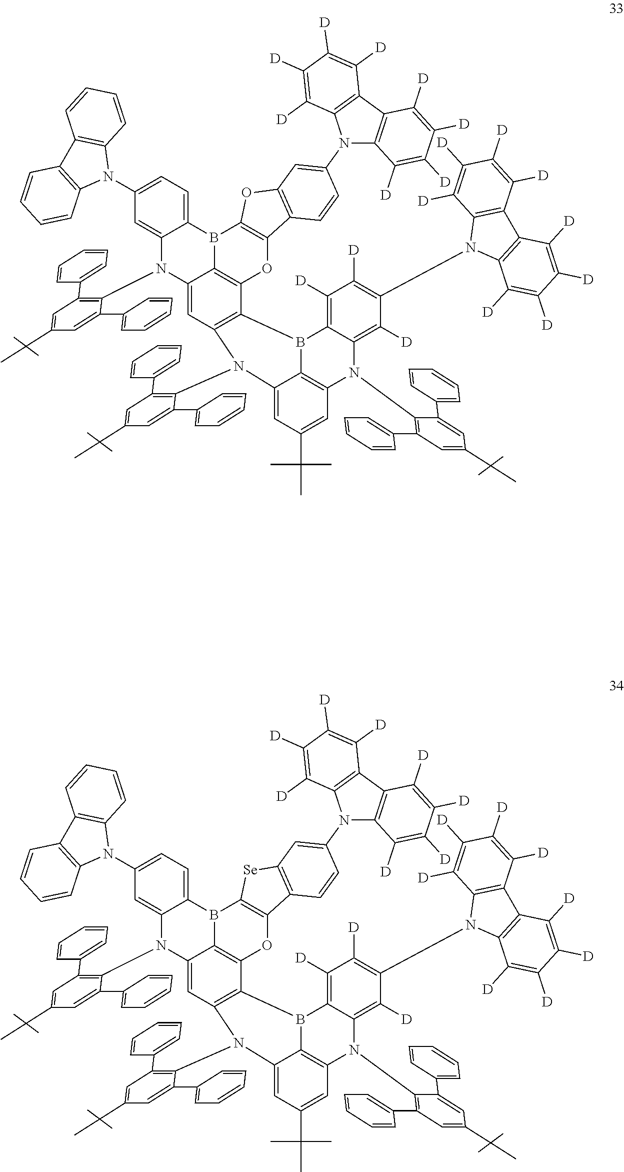 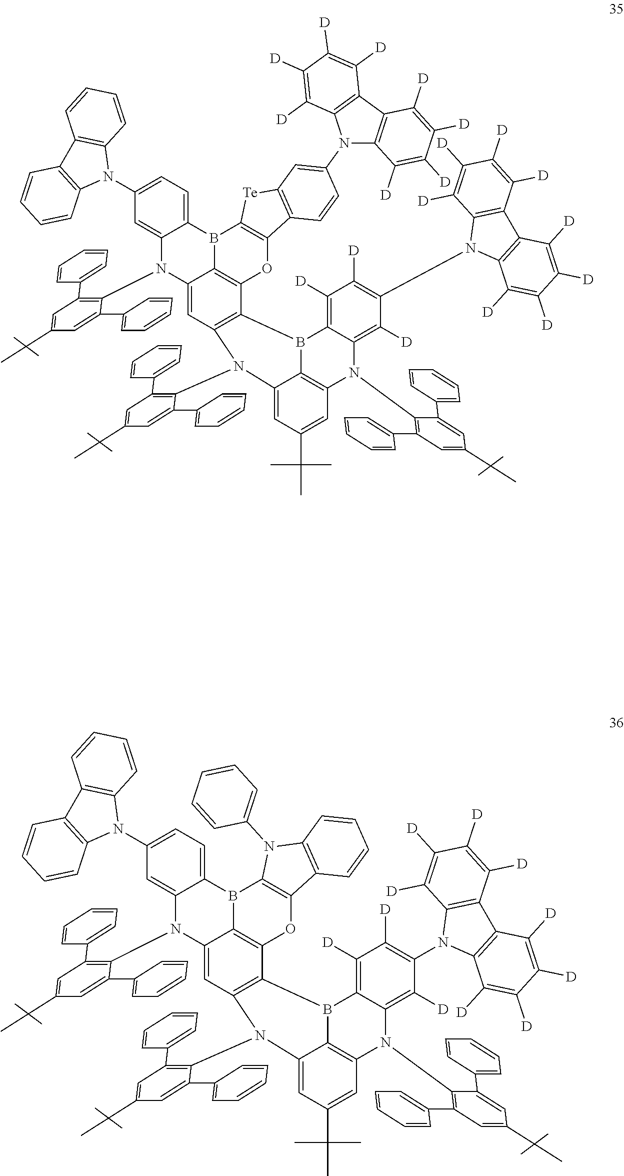 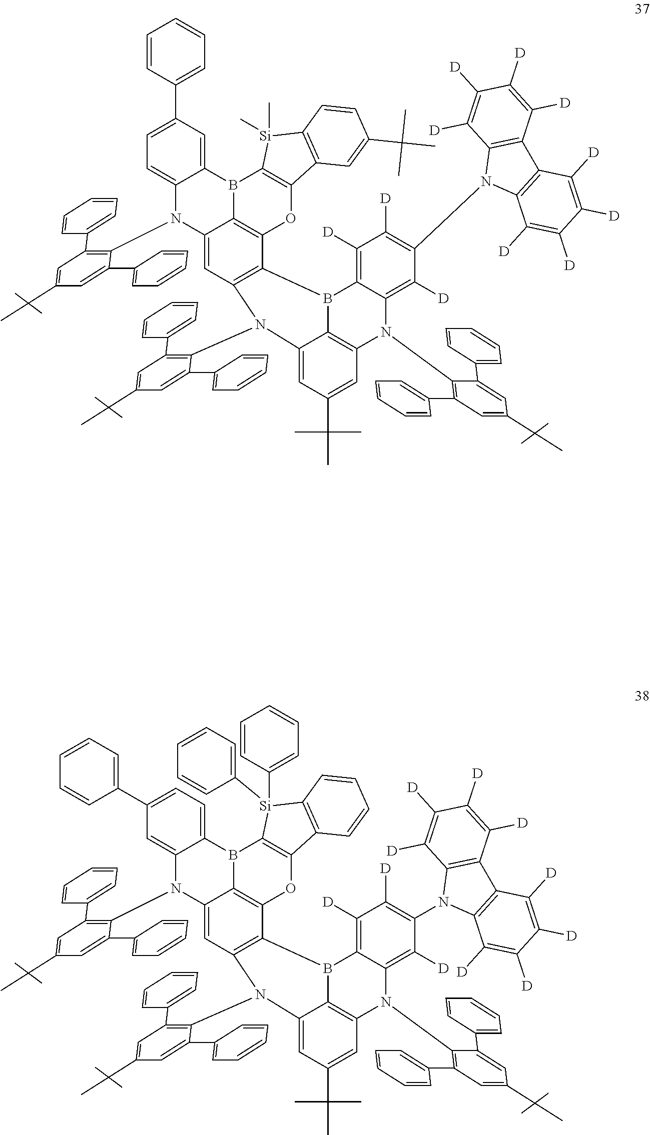 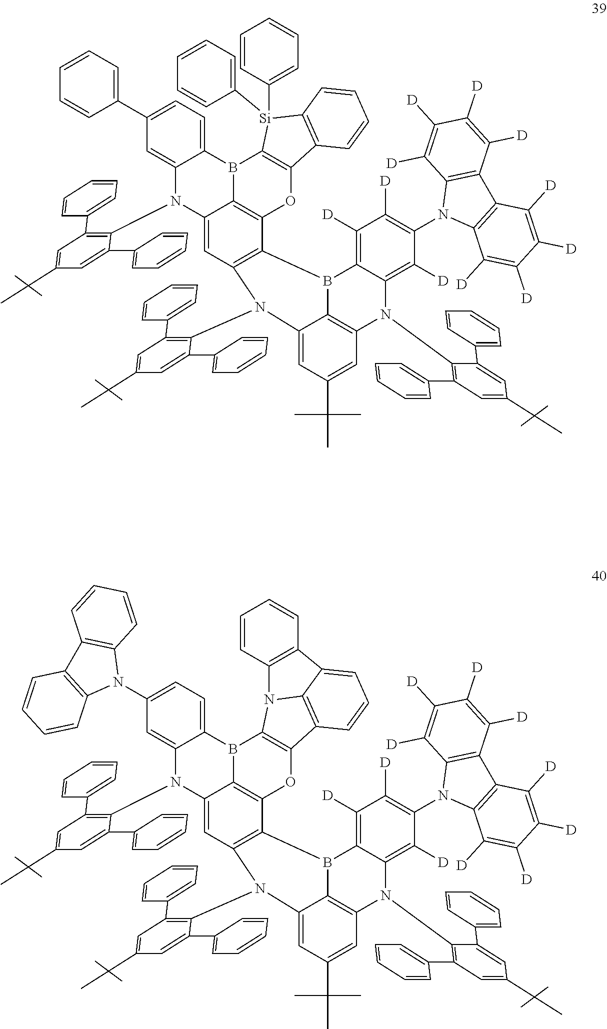 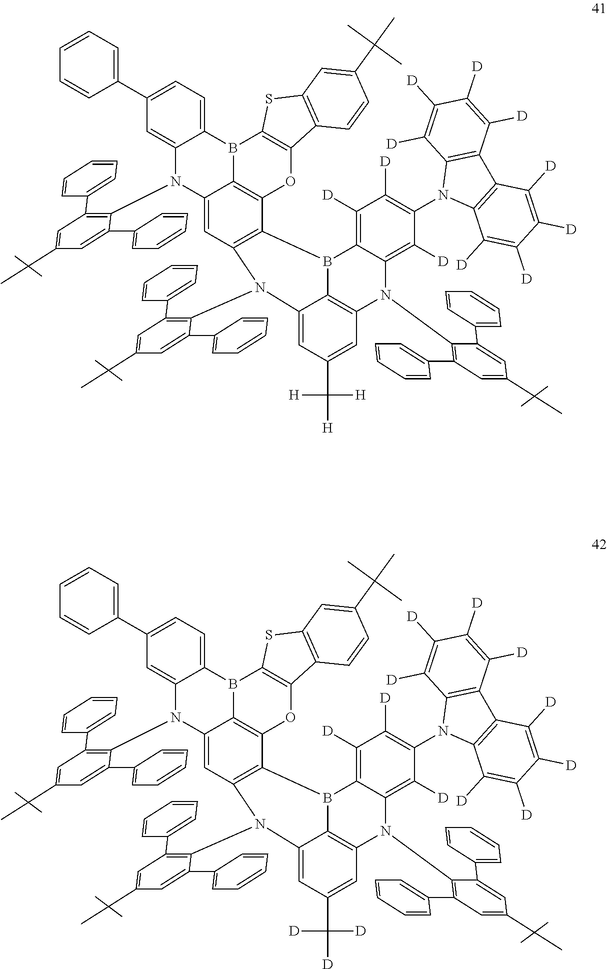 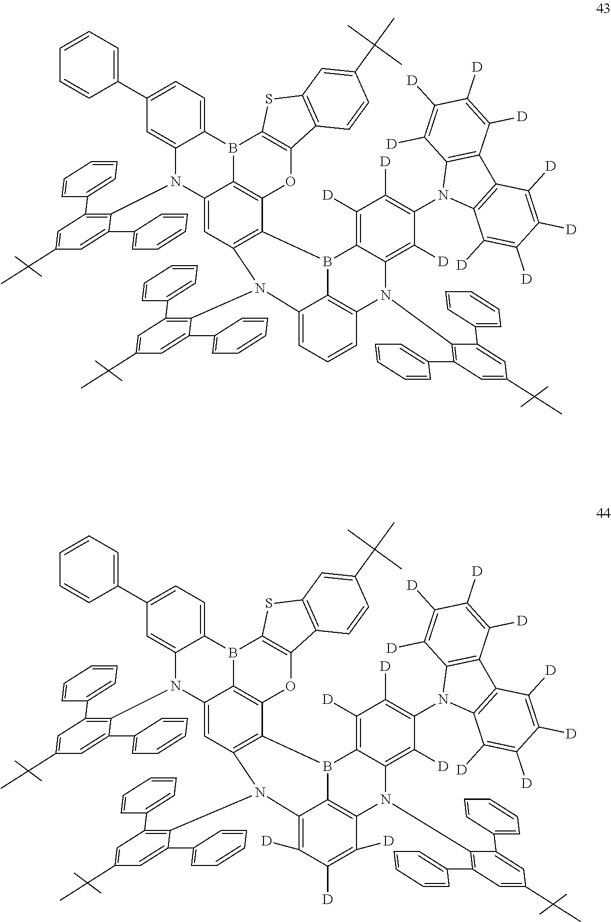 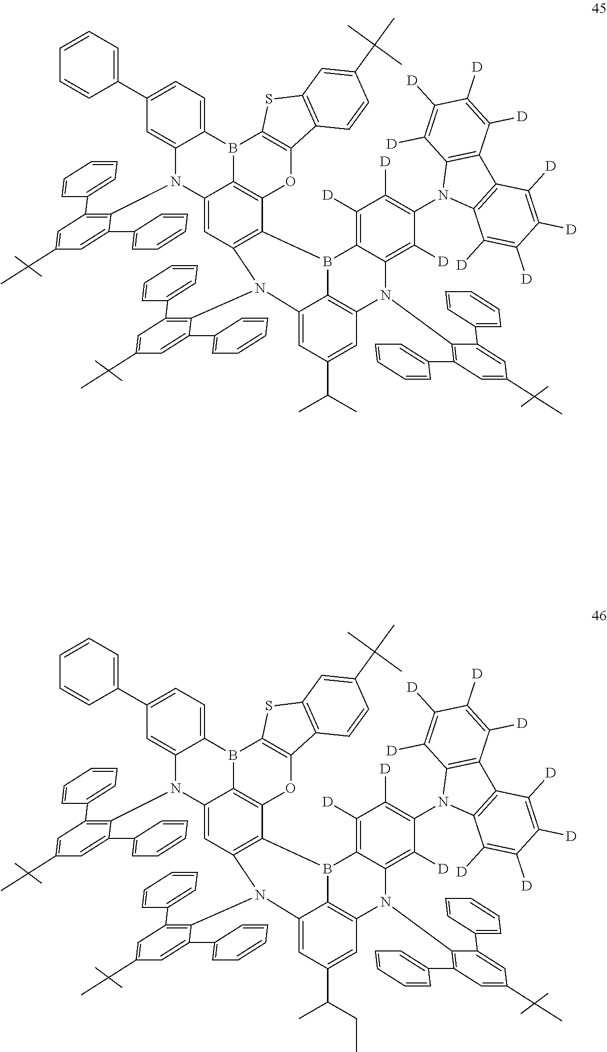 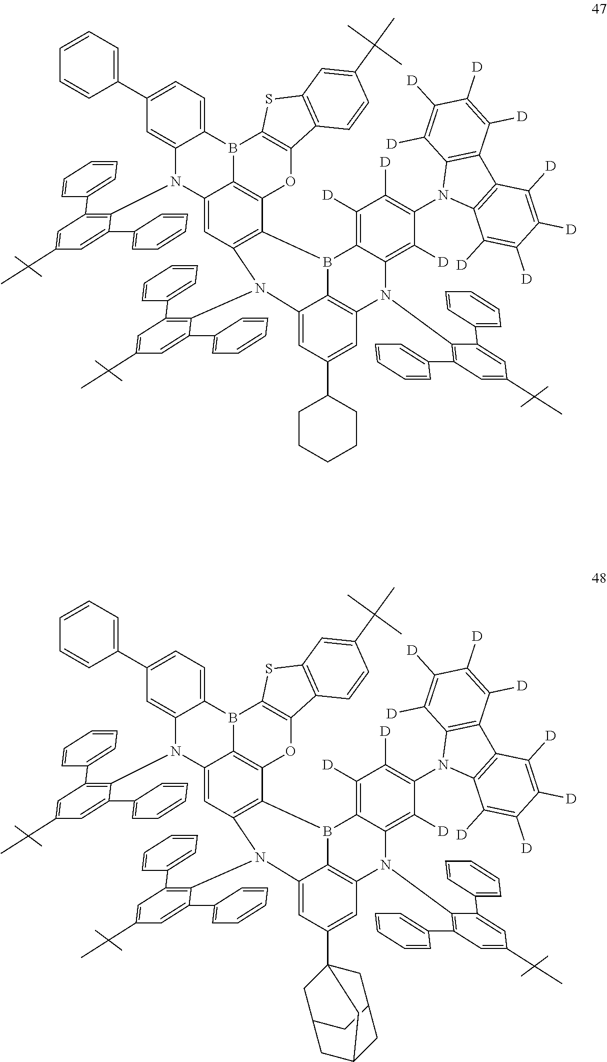 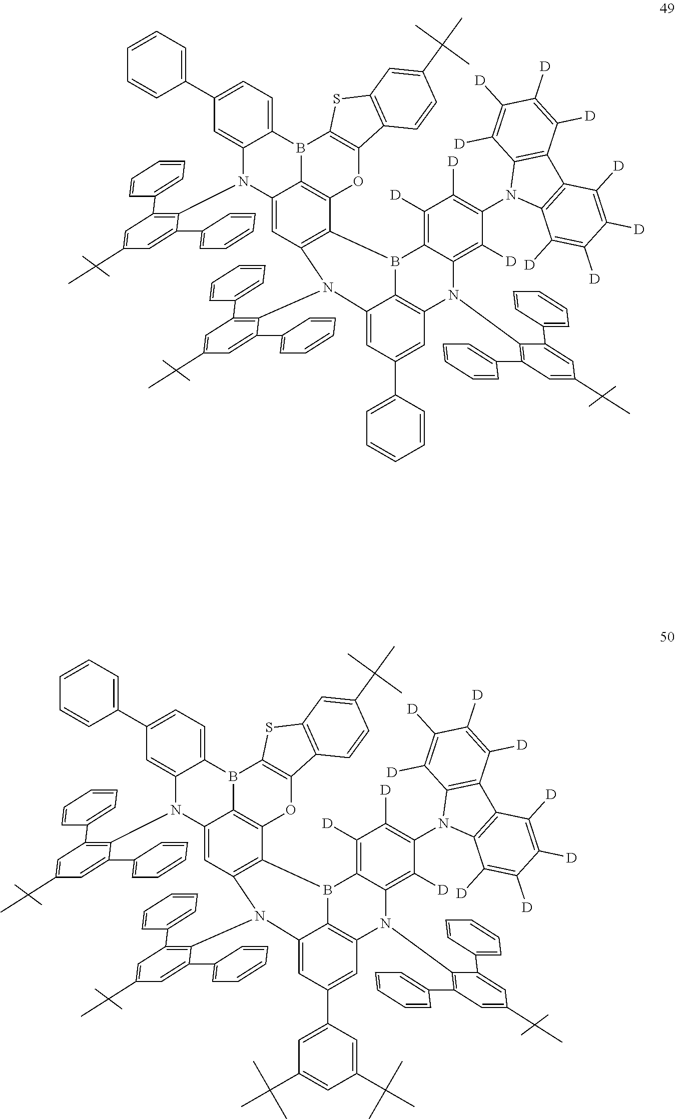 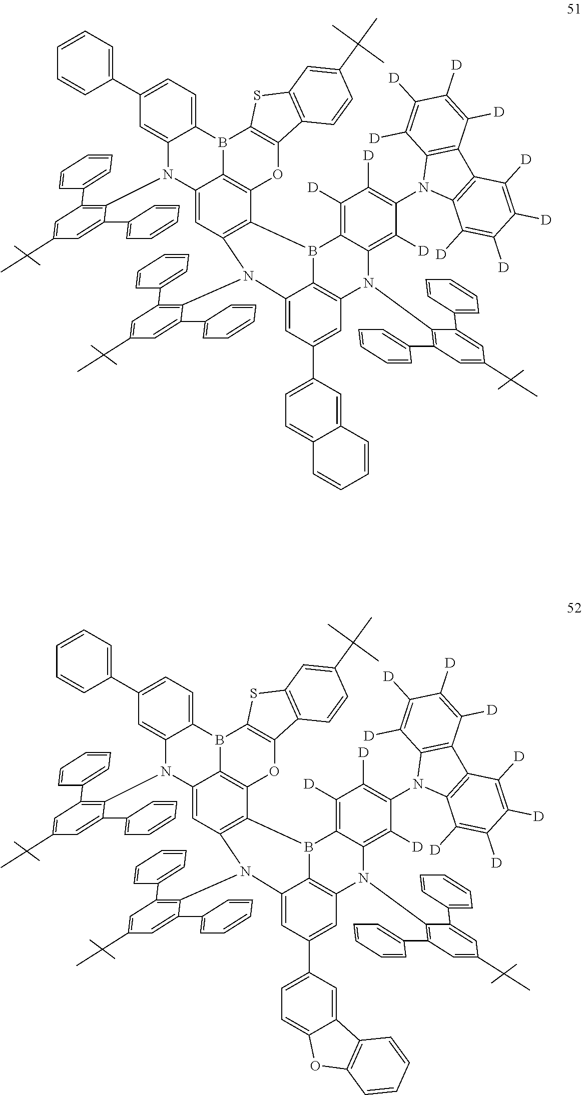 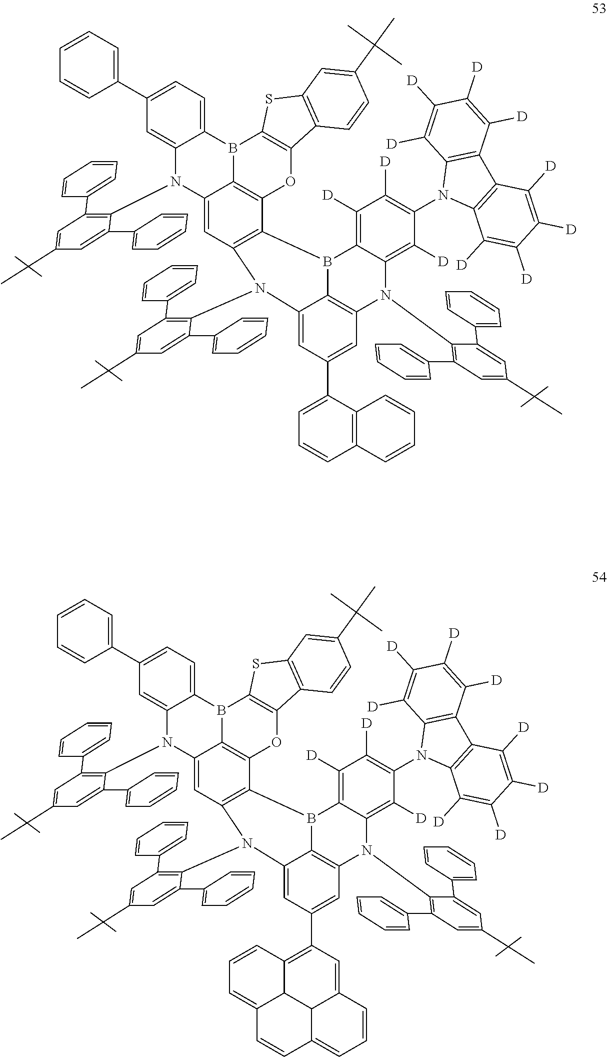 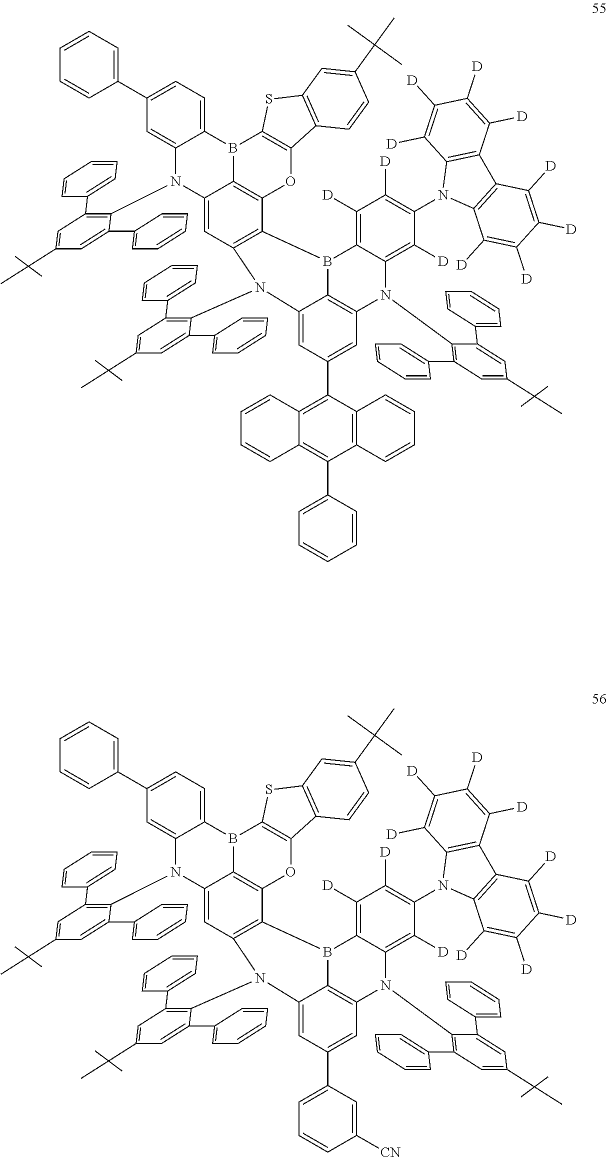 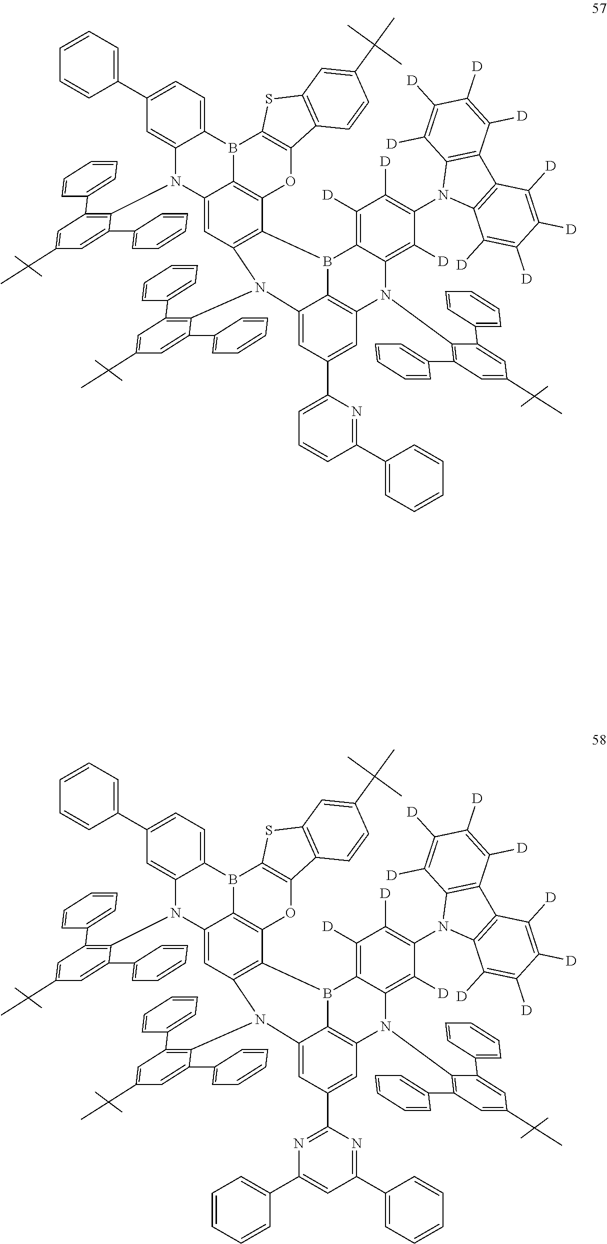 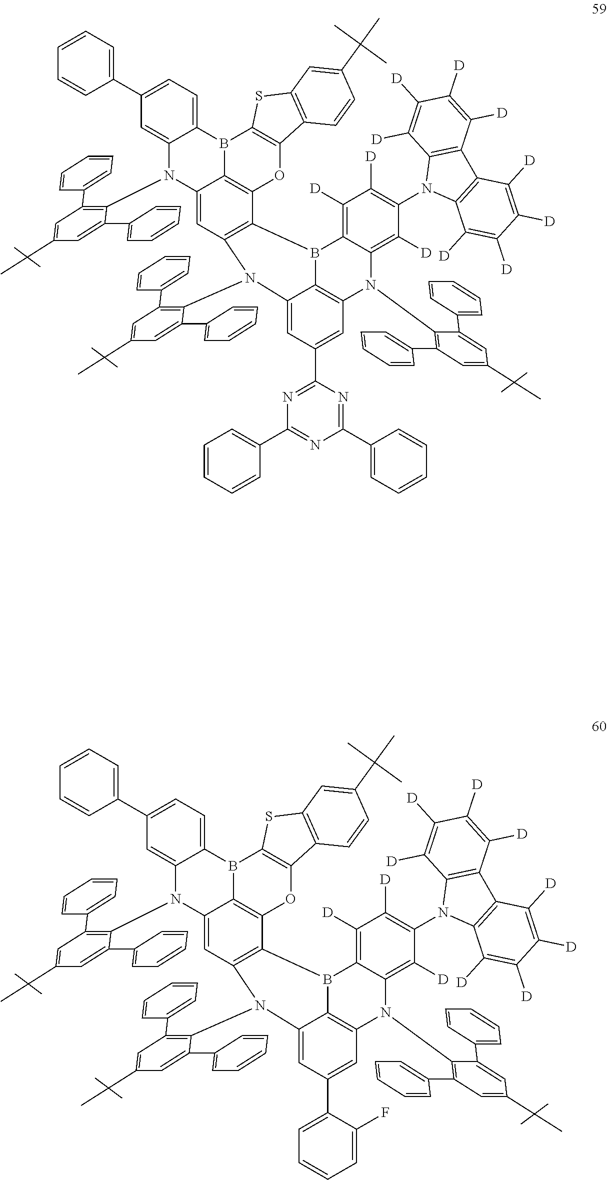 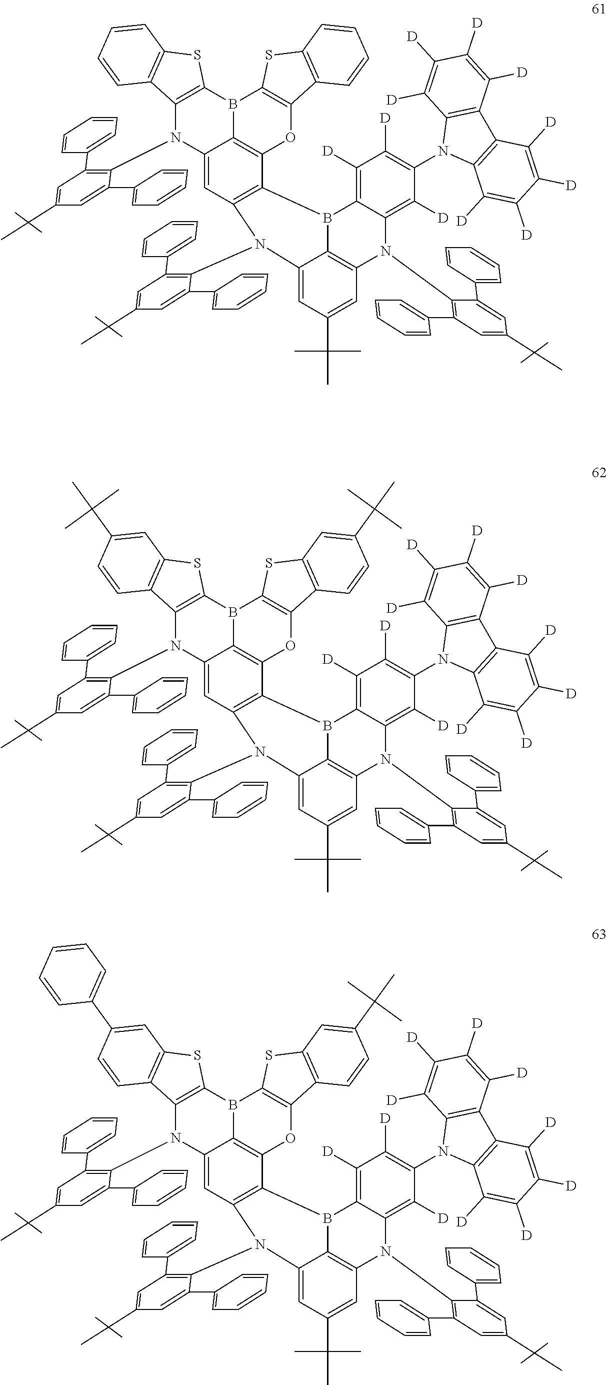 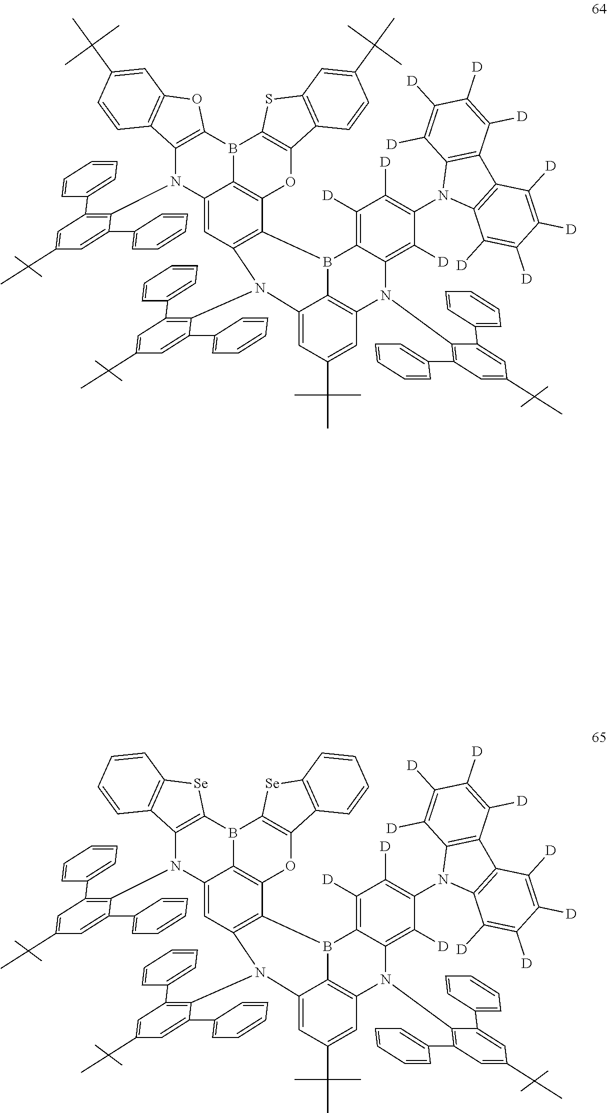 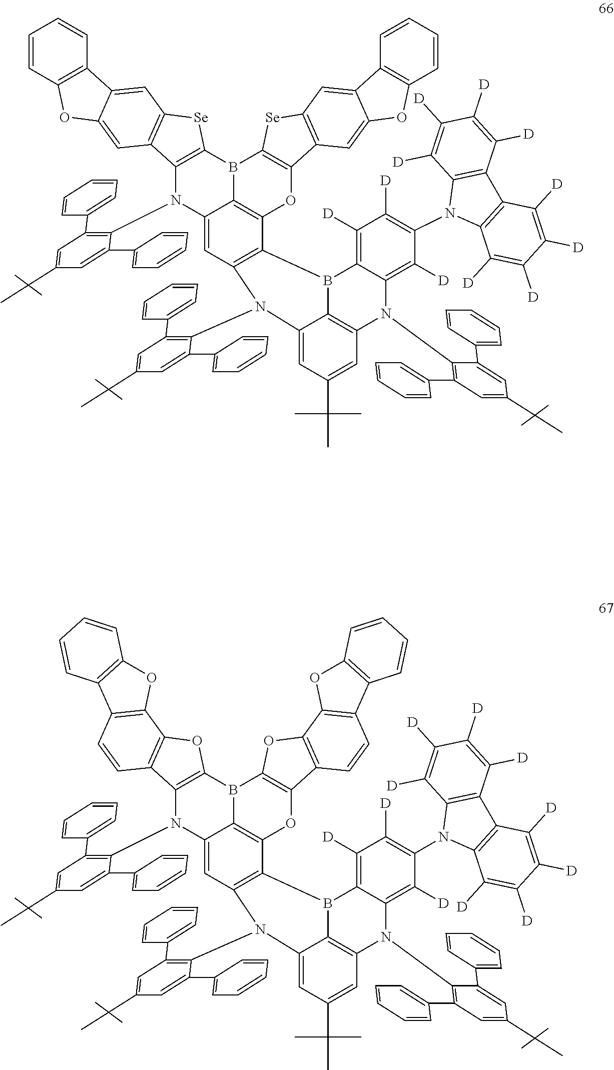 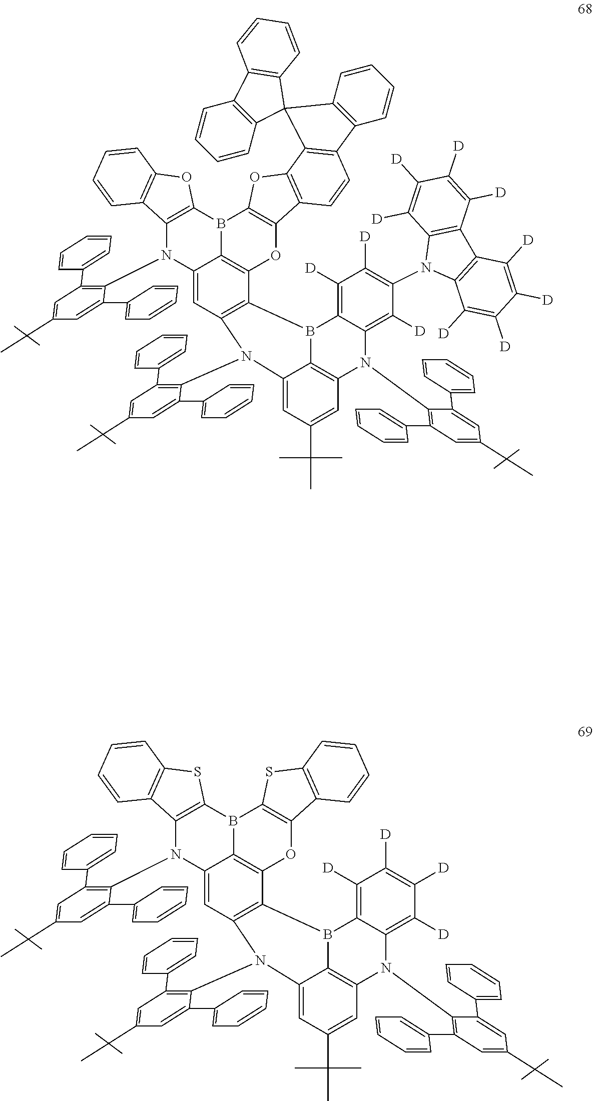 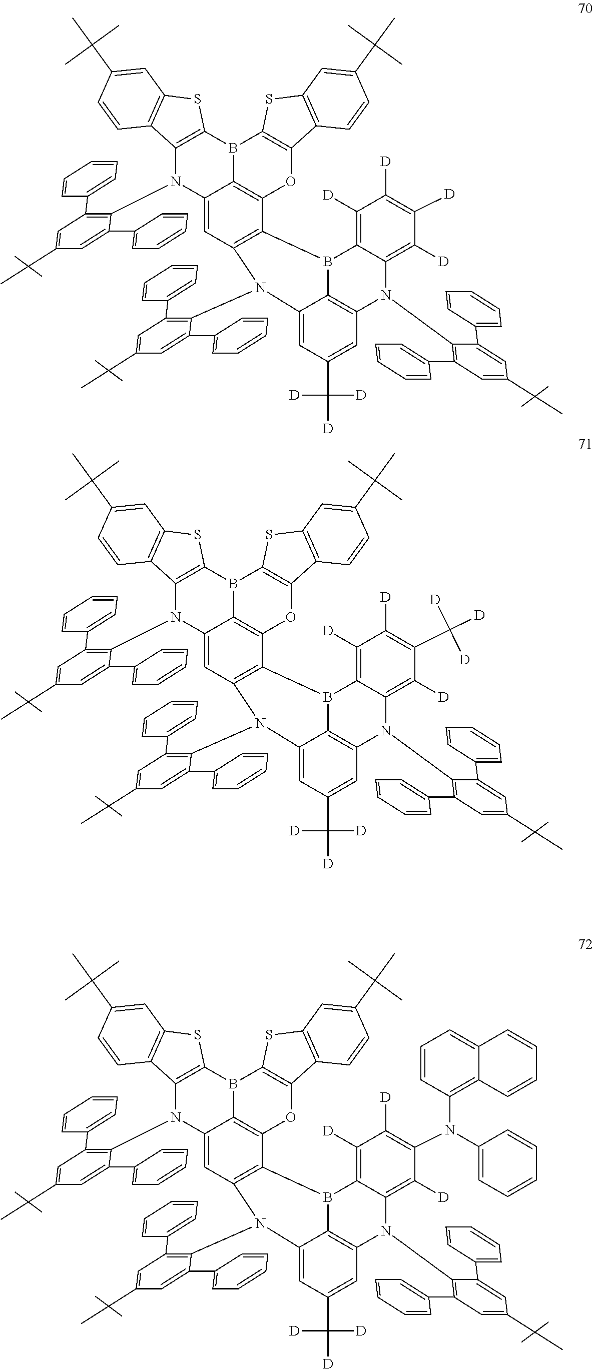 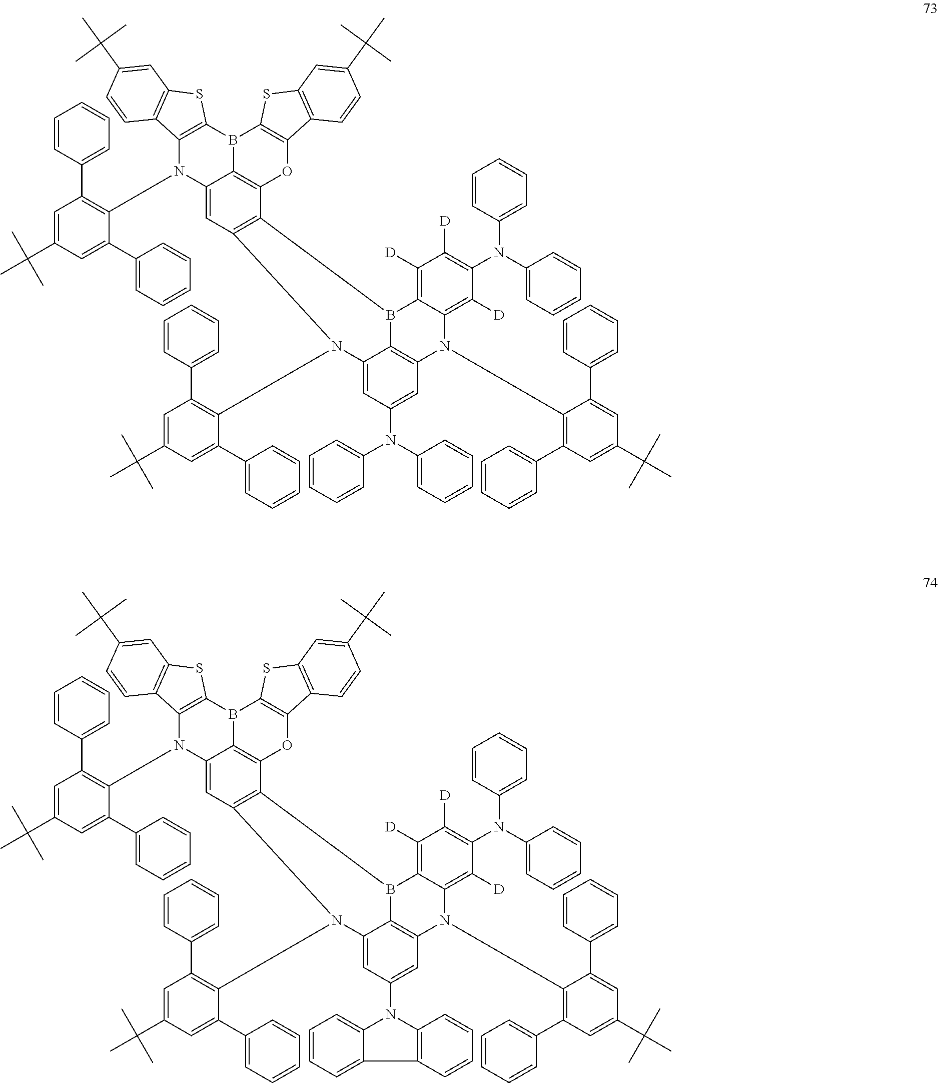 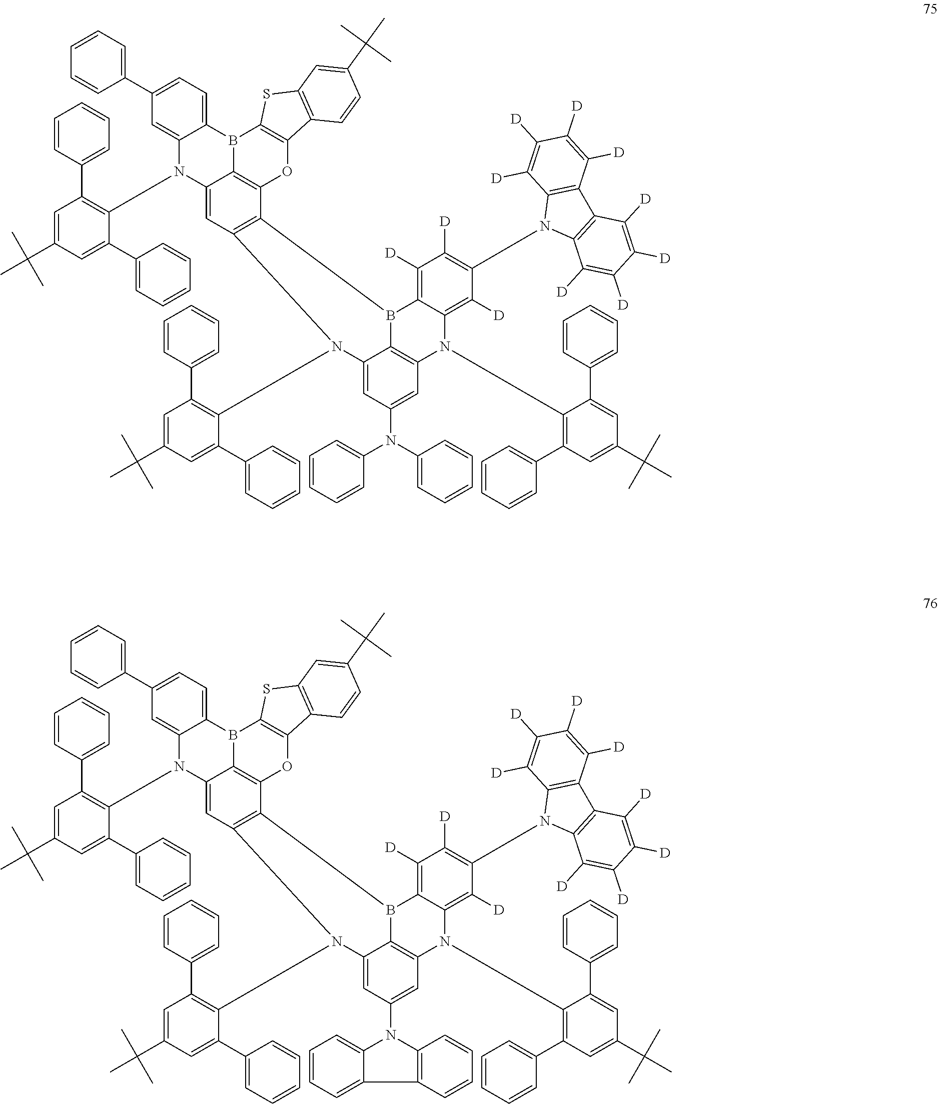 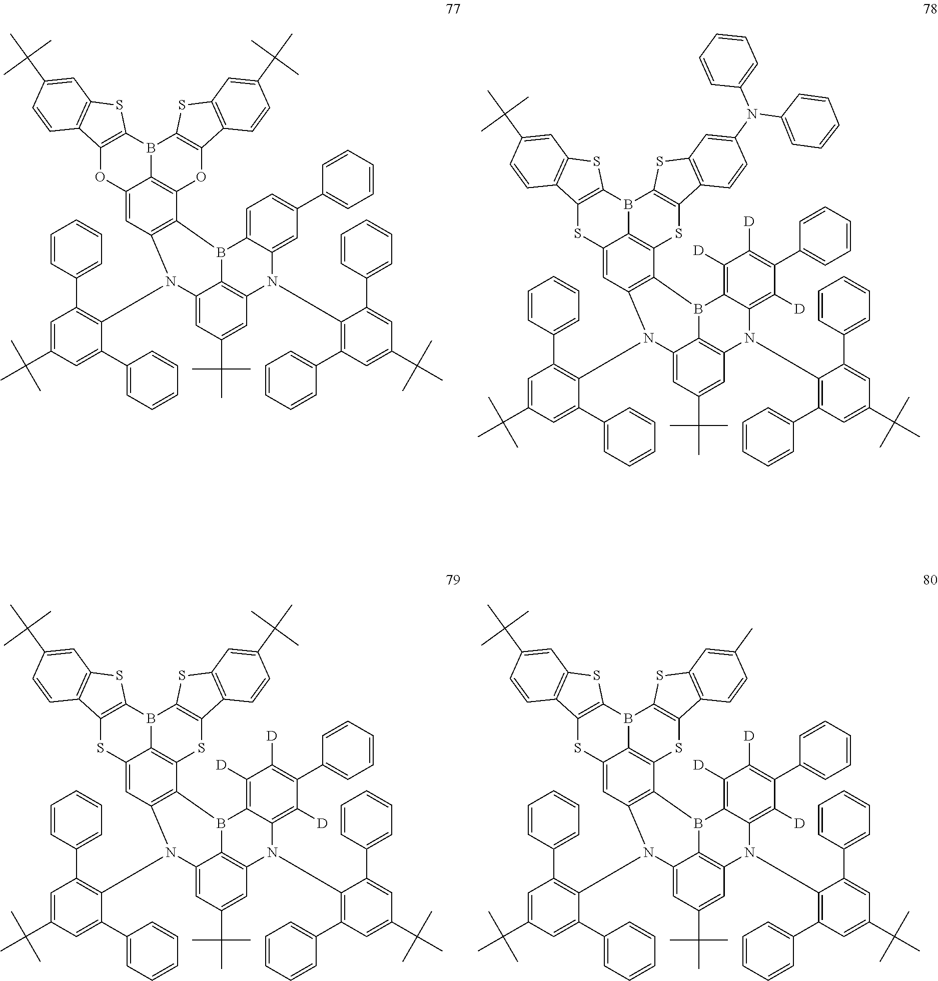 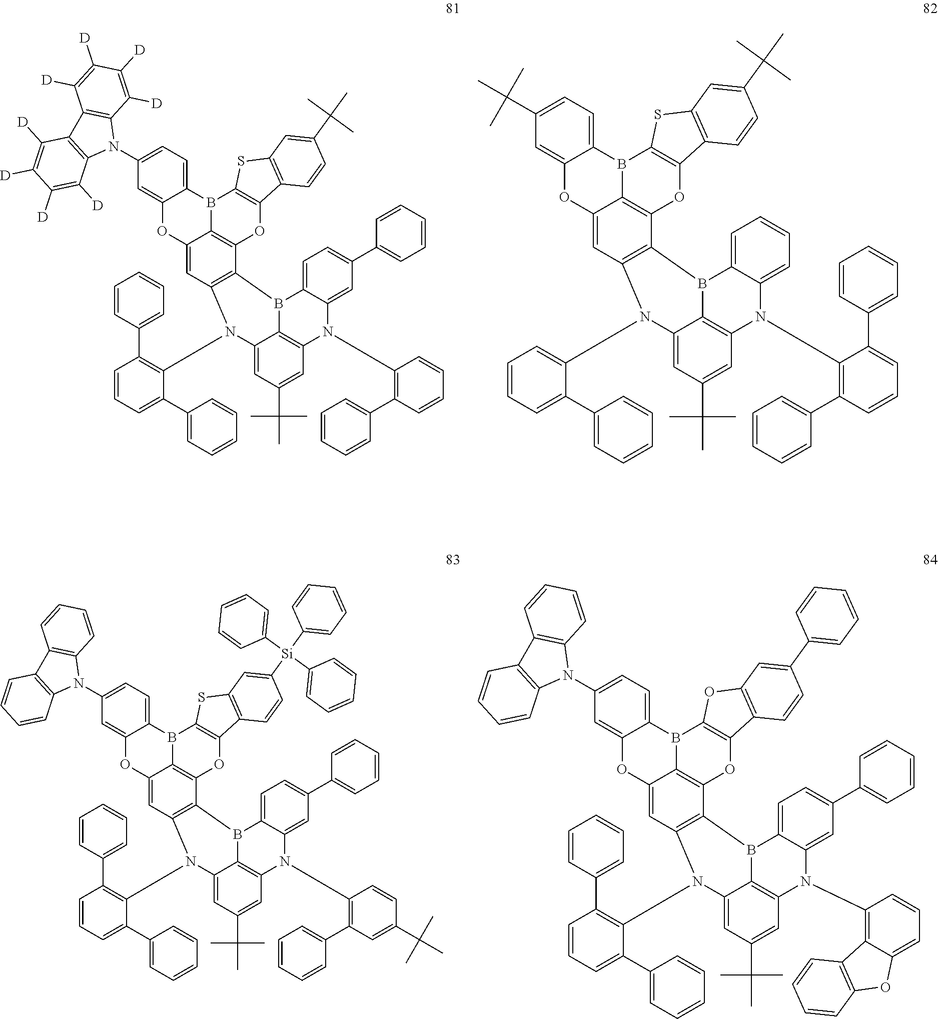 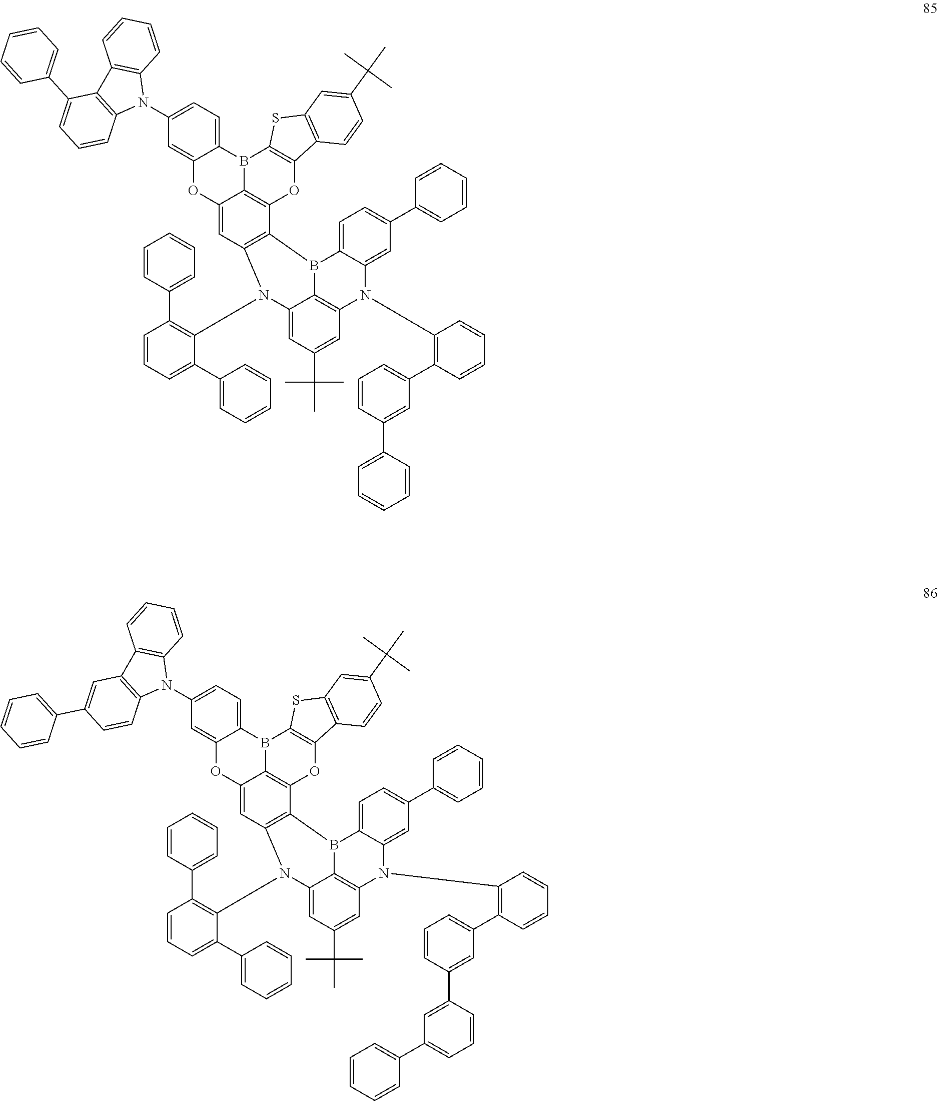 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1ccccc1-c1cccc(-c2ccccc2)c1)Oc1c(sc2cc(C(C)(C)C)ccc12)B5c1ccc(-n2c3ccccc3c3c(-c5ccccc5)cccc32)cc1O4 ; CC(C)(C)c1cc2c3c(c1)N(c1c(-c4ccccc4)cccc1-c1ccccc1)c1cc4c5c(c1B3c1ccc(-c3ccccc3)cc1N2c1ccccc1-c1cccc(-c2cccc(-c3ccccc3)c2)c1)Oc1c(sc2cc(C(C)(C)C)ccc12)B5c1ccc(-n2c3ccccc3c3cc(-c5ccccc5)ccc32)cc1O4] 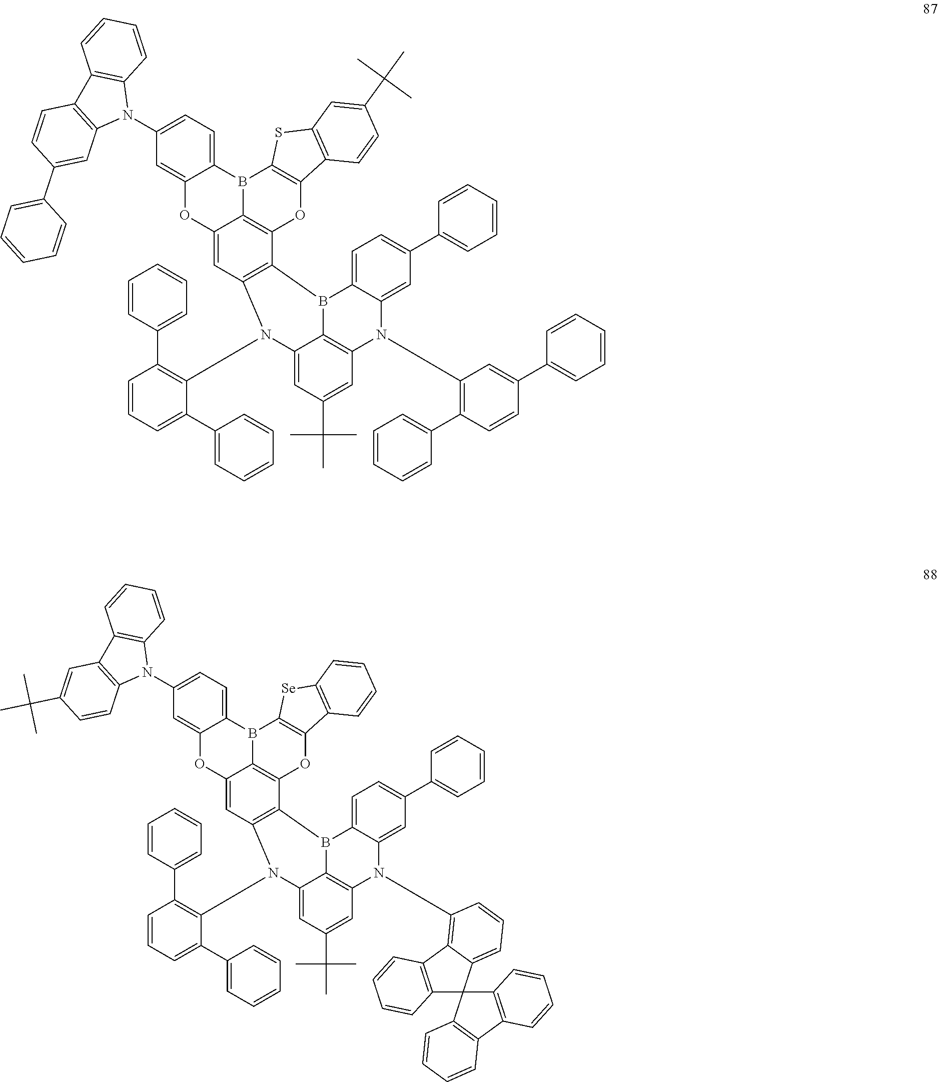 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1cc(-c2ccccc2)ccc1-c1ccccc1)Oc1c(sc2cc(C(C)(C)C)ccc12)B5c1ccc(-n2c3ccccc3c3ccc(-c5ccccc5)cc32)cc1O4 ; CC(C)(C)c1cc2c3c(c1)N(c1c(-c4ccccc4)cccc1-c1ccccc1)c1cc4c5c(c1B3c1ccc(-c3ccccc3)cc1N2c1cccc2c1-c1ccccc1C21c2ccccc2-c2ccccc21)Oc1c([se]c2ccccc12)B5c1ccc(-n2c3ccccc3c3cc(C(C)(C)C)ccc32)cc1O4] 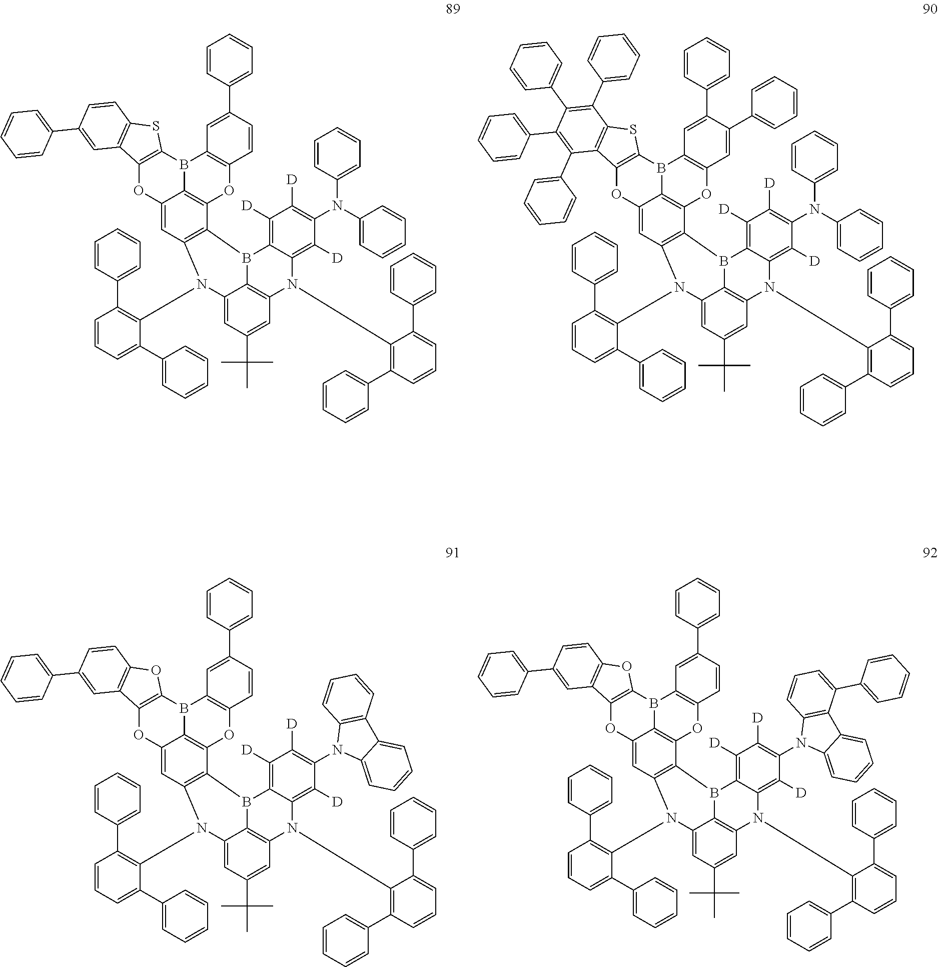 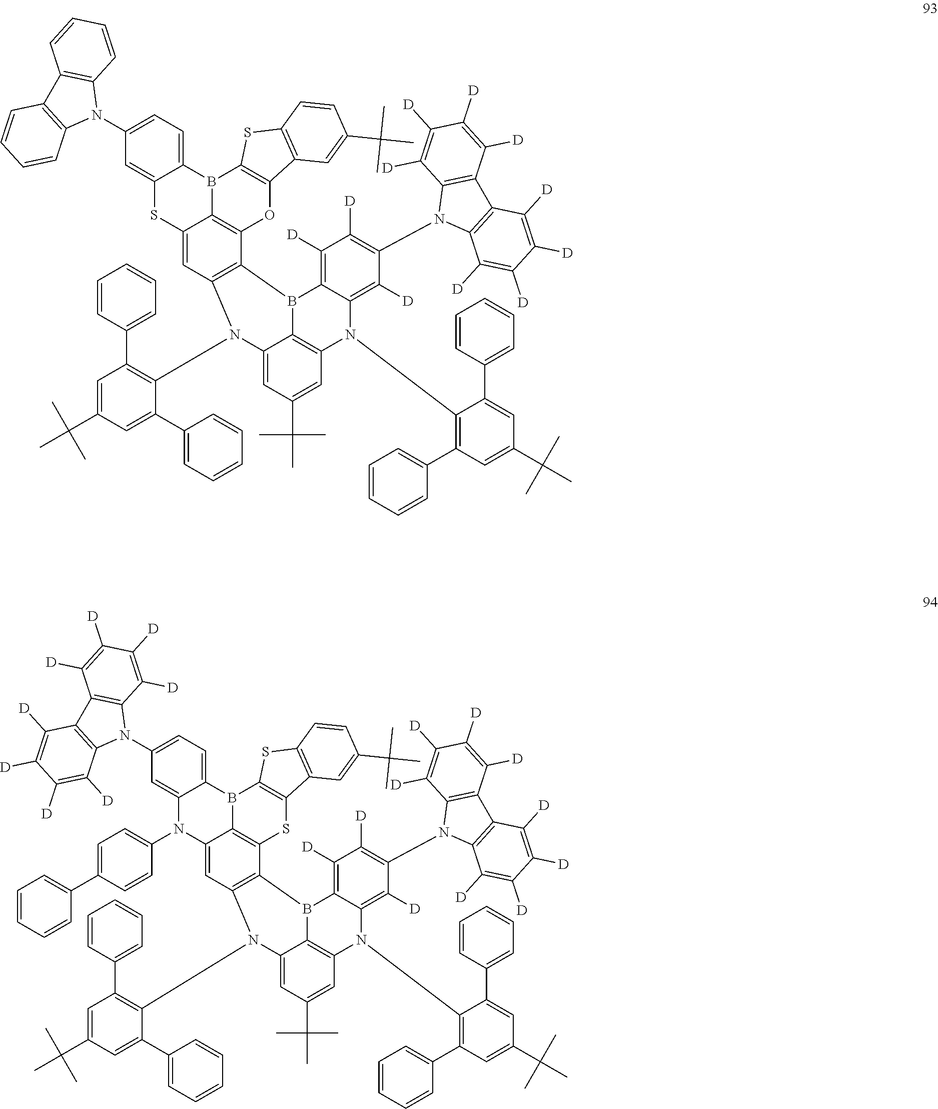 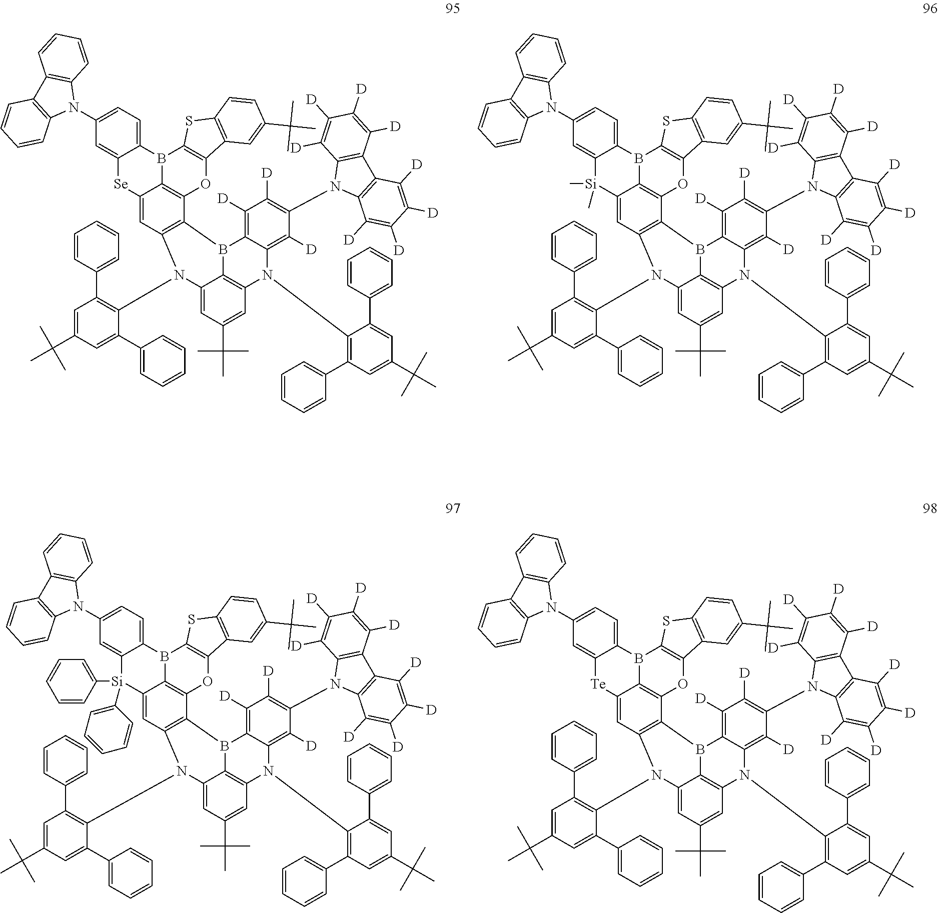 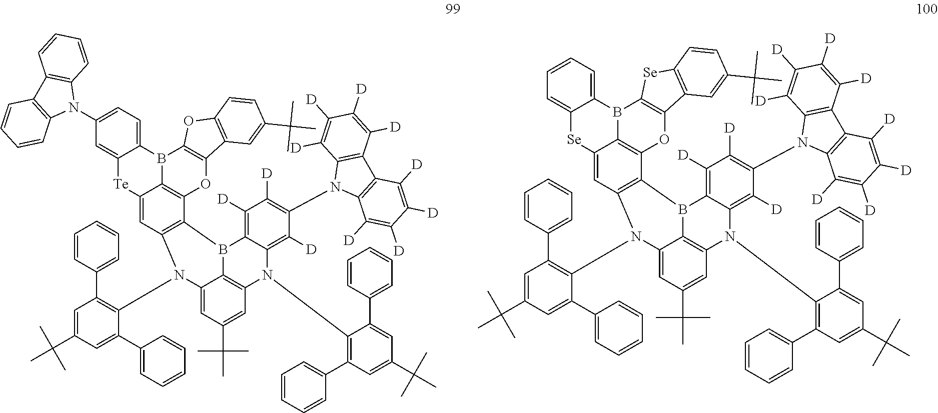
wherein in Compound Group 1,
D represents a deuterium atom.

13. A fused polycyclic compound represented by Formula 1: 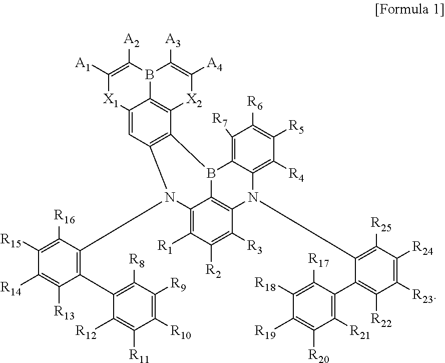
wherein in Formula 1,
X₁ and X₂ are each independently O, S, Se, Te, N(R₂₆), or Si(R₂₇)(R₂₈),
R₁ to R₂₈ are each independently a hydrogen atom, a deuterium atom, a halogen atom, a cyano group, a nitro group, a substituted or unsubstituted silyl group, a substituted or unsubstituted oxy group, a substituted or unsubstituted amine group, a substituted or unsubstituted alkyl group having 1 to 60 carbons, a substituted or unsubstituted cycloalkyl group having 3 to 60 ring-forming carbons, a substituted or unsubstituted alkenyl group having 2 to 60 carbons, a substituted or unsubstituted aryl group having 6 to 60 ring-forming carbons, or a substituted or unsubstituted heteroaryl group having 2 to 60 ring-forming carbons, or bonded to an adjacent group to form a ring,
at least one of R₁₆ and R₂₅ is each independently a substituted or unsubstituted phenyl group,
at least one of a pair of A₁ and A₂ and a pair of A₃ and A₄ is each independently bonded to a first substituent represented by Formula S-1, and
the remainder of a pair of A₁ and A₂ and a pair of A₃ and A₄ that is not bonded to the first substituent represented by Formula S-1 is bonded to a second substituent represented by Formula S-2: 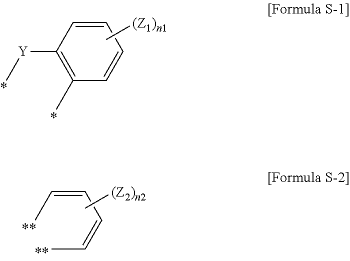
wherein in Formula S-1,
Y is O, S, Se, Te, N(Rₛ₁), or Si(Rₛ₂)(Rₛ₃), and
wherein in Formula S-1 and Formula S-2,
Rₛ₁ to Rₛ₃, Z₁, and Z₂ are each independently a hydrogen atom, a deuterium atom, a halogen atom, a cyano group, a nitro group, a substituted or unsubstituted silyl group, a substituted or unsubstituted oxy group, a substituted or unsubstituted amine group, a substituted or unsubstituted alkyl group having 1 to 60 carbons, a substituted or unsubstituted cycloalkyl group having 3 to 60 ring-forming carbons, a substituted or unsubstituted alkenyl group having 2 to 60 carbons, a substituted or unsubstituted aryl group having 6 to 60 ring-forming carbons, or a substituted or unsubstituted heteroaryl group having 2 to 60 ring-forming carbons, or bonded to an adjacent group to form a ring,
n1 and n2 are each independently an integer from 0 to 4, and
*- and **- each represents a bond to the pair of A₁ and A₂ or the pair of A₃ and A₄ in Formula 1.

14. The fused polycyclic compound of claim 13, wherein the fused polycyclic compound is represented by one of Formula 2 to Formula 4: 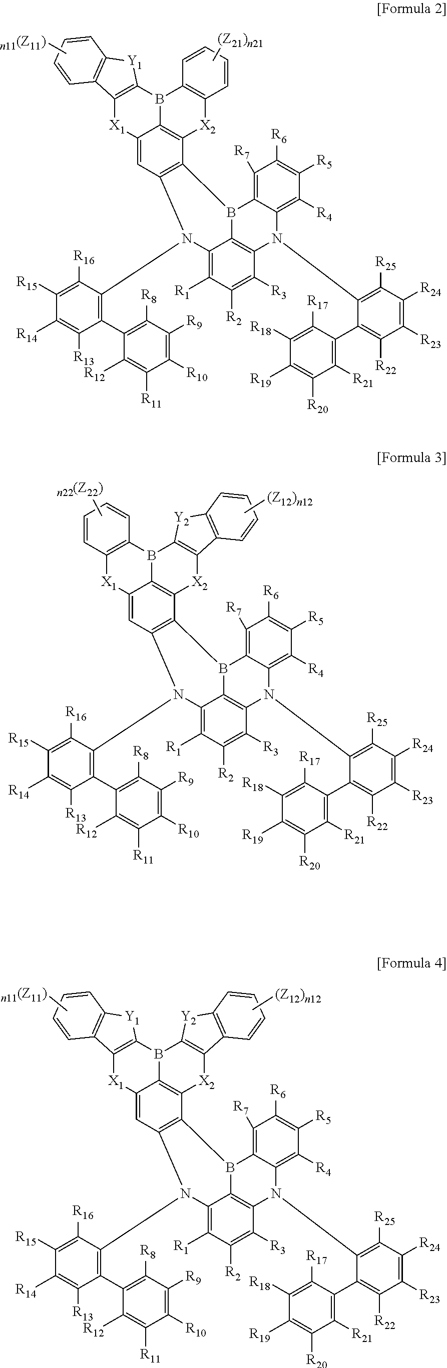
wherein in Formula 2 to Formula 4,
Y₁ and Y₂ are each independently O, S, Se, Te, N(R_{y1}), or Si(R_{y2})(R_{y3}),
Z₁, Z₁₂, Z₂₁, Z₂₂, R_{y1}, R_{y2}, and R_{y3} are each independently a hydrogen atom, a deuterium atom, a halogen atom, a cyano group, a nitro group, a substituted or unsubstituted silyl group, a substituted or unsubstituted oxy group, a substituted or unsubstituted amine group, a substituted or unsubstituted alkyl group having 1 to 60 carbons, a substituted or unsubstituted cycloalkyl group having 3 to 60 ring-forming carbons, a substituted or unsubstituted alkenyl group having 2 to 60 carbons, a substituted or unsubstituted aryl group having 6 to 60 ring-forming carbons, or a substituted or unsubstituted heteroaryl group having 2 to 60 ring-forming carbons, or bonded to an adjacent group to form a ring,
n11, n12, n21, and n22 are each independently an integer from 0 to 4, and
X₁, X₂, and R₁ to R₂₅ are the same as defined in Formula 1.

15. The fused polycyclic compound of claim 14, wherein the fused polycyclic compound is represented by one of Formula 2-1 to Formula 2-3: 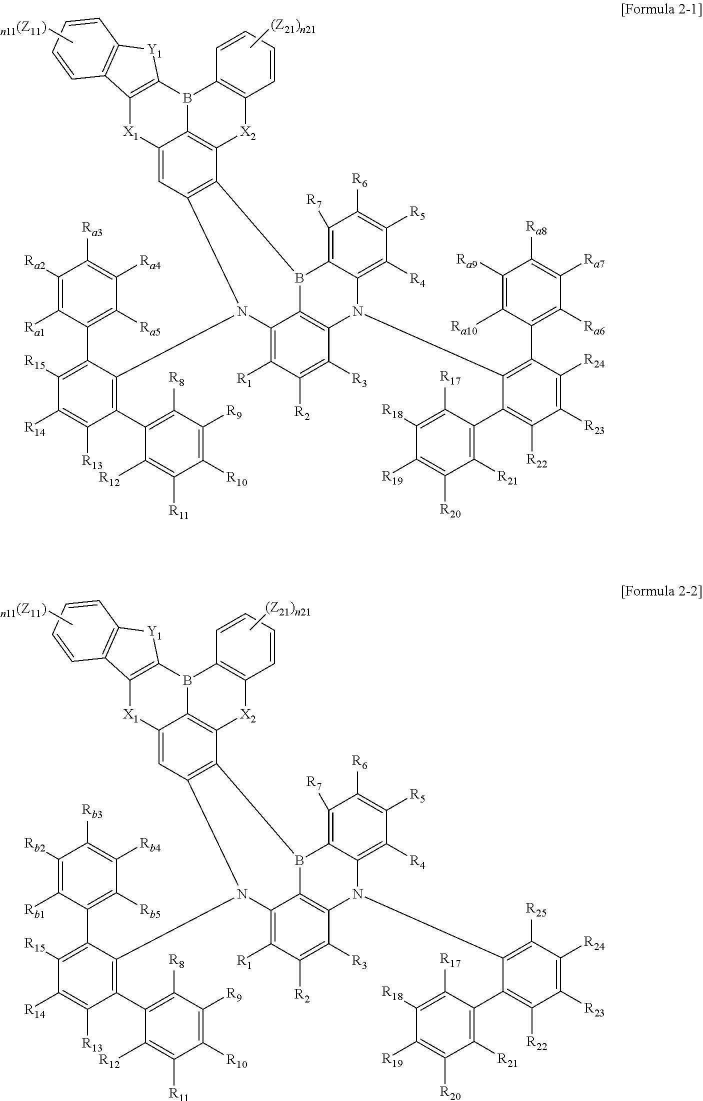 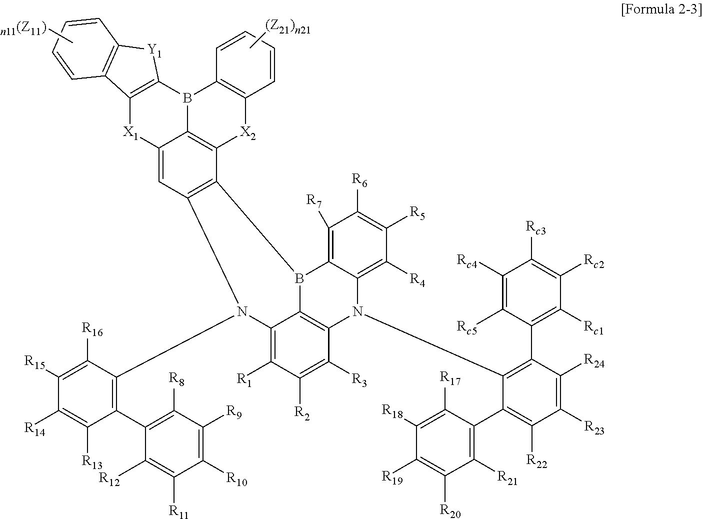
wherein in Formula 2-1 to Formula 2-3,
Rₐ₁ to Rₐ₁₀, R_{b1} to R_{b5}, and R_{b1} to R_{b5} are each independently a hydrogen atom, a deuterium atom, a substituted or unsubstituted alkyl group having 1 to 30 carbons, or a substituted or unsubstituted aryl group having 6 to 30 ring-forming carbons,
X₁, X₂, and R₁ to R₂₅ are the same as defined in Formula 1, and
Y₁, Z₁₁, Z₂₁, n11, and n21 are the same as defined in Formula 2.

16. The fused polycyclic compound of claim 14, wherein the fused polycyclic compound is represented by one of Formula 3-1 to Formula 3-3: 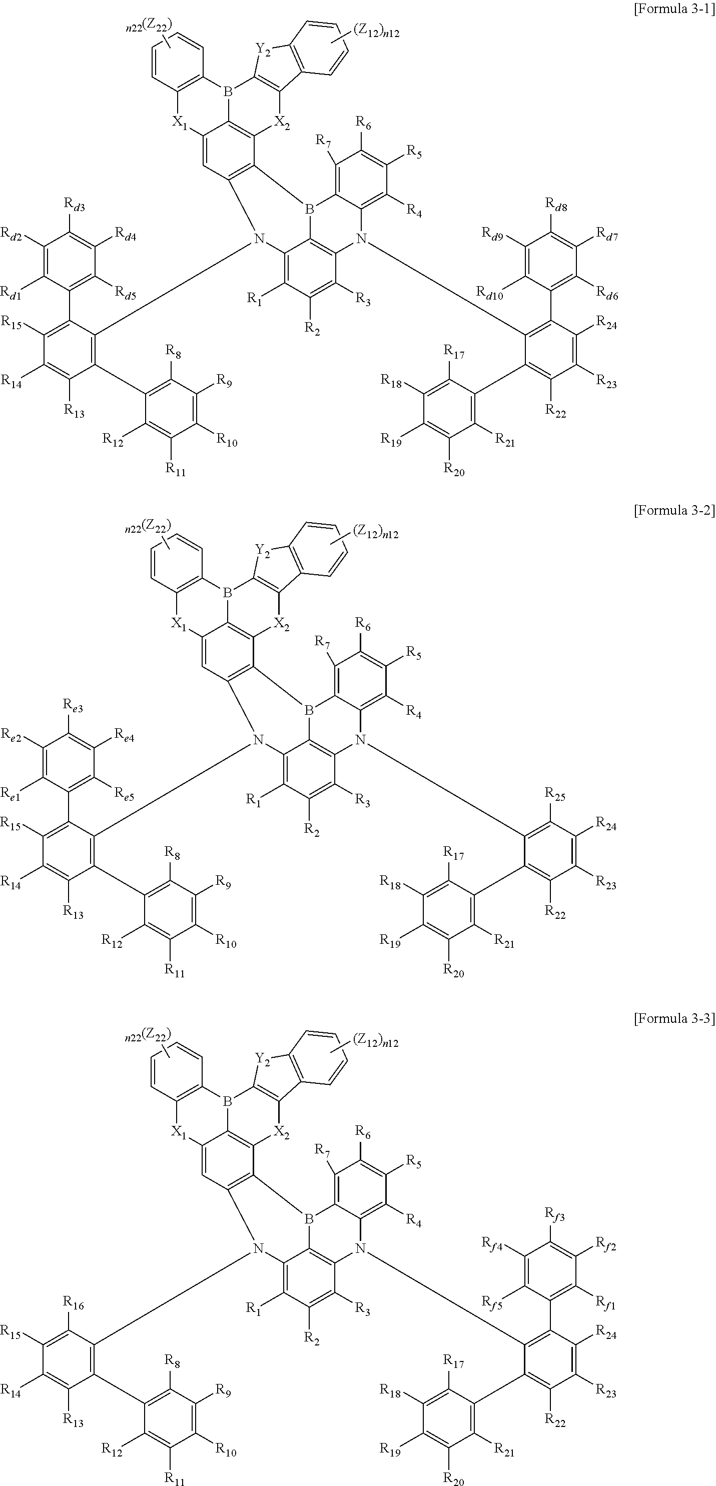
wherein in Formula 3-1 to Formula 3-3,
R_{d1} to R_{d10}, Rₑ₁ to Rₑ₅, and R_{f1} to R_{f5} are each independently a hydrogen atom, a deuterium atom, a substituted or unsubstituted alkyl group having 1 to 30 carbons, or a substituted or unsubstituted aryl group having 6 to 30 ring-forming carbons,
X₁, X₂, and R₁ to R₂₅ are the same as defined in Formula 1, and
Y₂, Z₁₂, Z₂₂, n11, and n22 are the same as defined in Formula 3.

17. The fused polycyclic compound of claim 14, wherein the fused polycyclic compound is represented by one of Formula 4-1 to Formula 4-3: 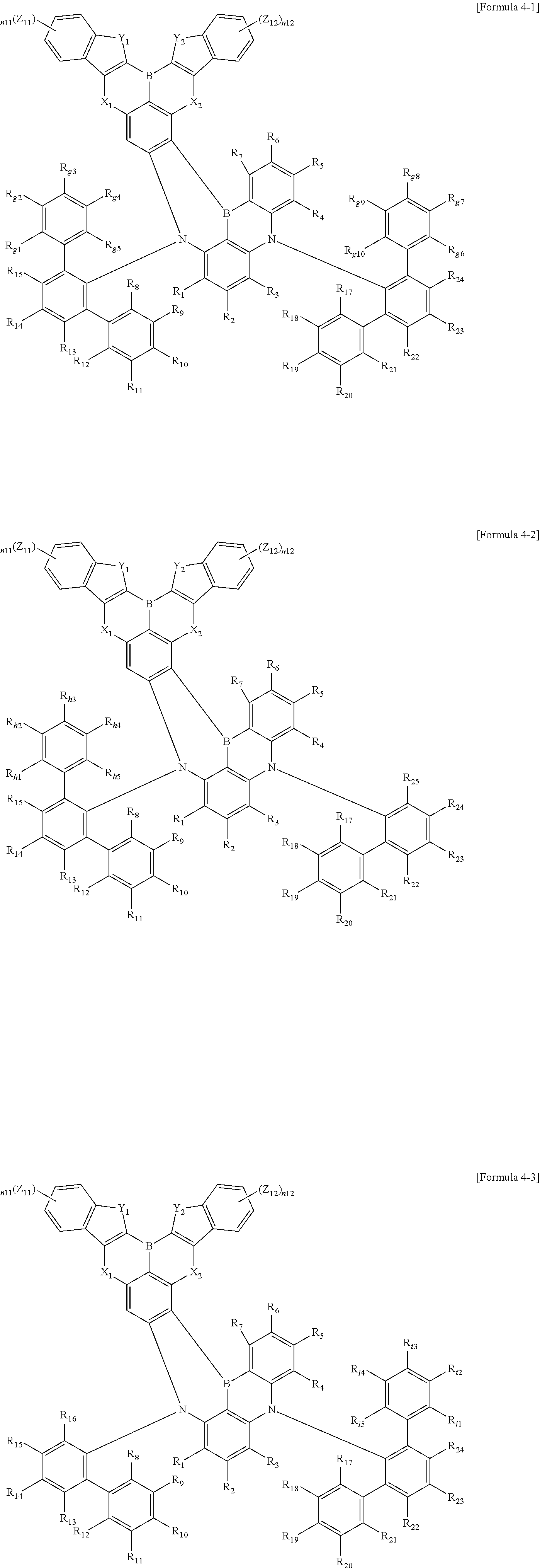
wherein in Formula 4-1 to Formula 4-3,
R_{g1} to R_{g10}, Rₕ₁ to Rₕ₅, and Rᵢ₁ to Rᵢ₅ are each independently a hydrogen atom, a deuterium atom, a substituted or unsubstituted alkyl group having 1 to 30 carbon atoms, or a substituted or unsubstituted aryl group having 6 to 30 ring-forming carbon atoms,
X₁, X₂, and R₁ to R₂₅ are the same as defined in Formula 1, and
Y₁, Y₂, Z₁₁, Z₁₂, n11, and n12 are the same as defined in Formula 4.

18. The fused polycyclic compound of claim 13, wherein the fused polycyclic compound is selected from Compound Group 1: 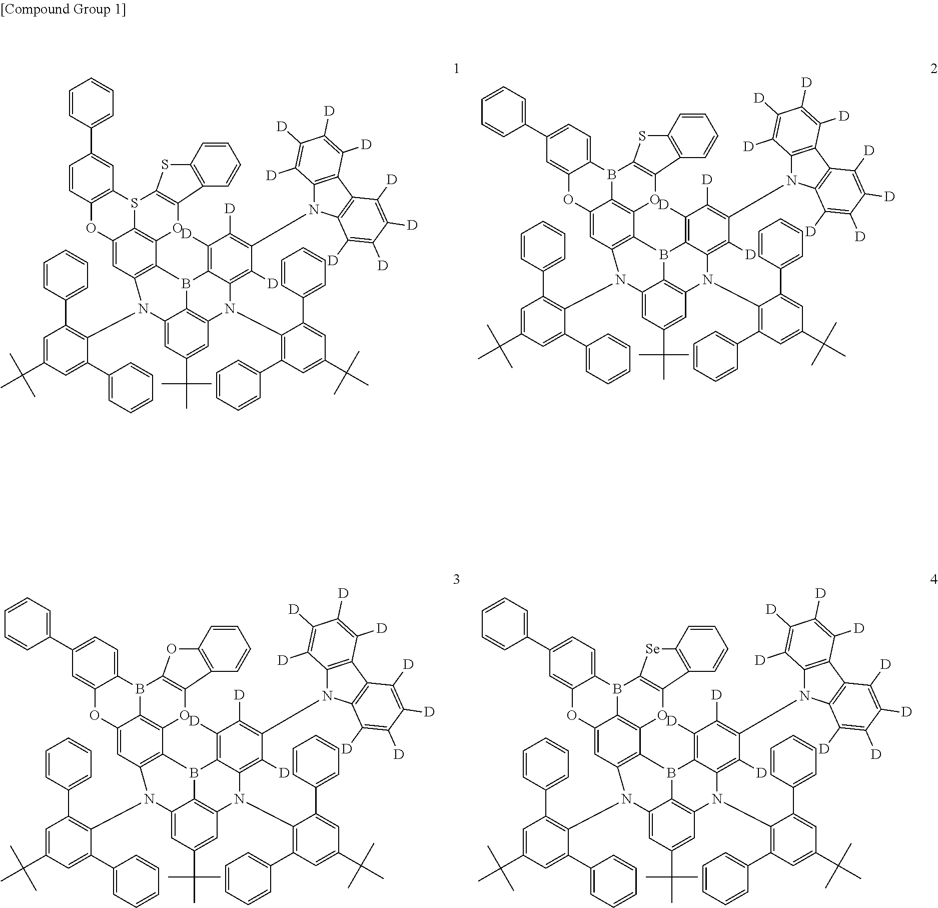 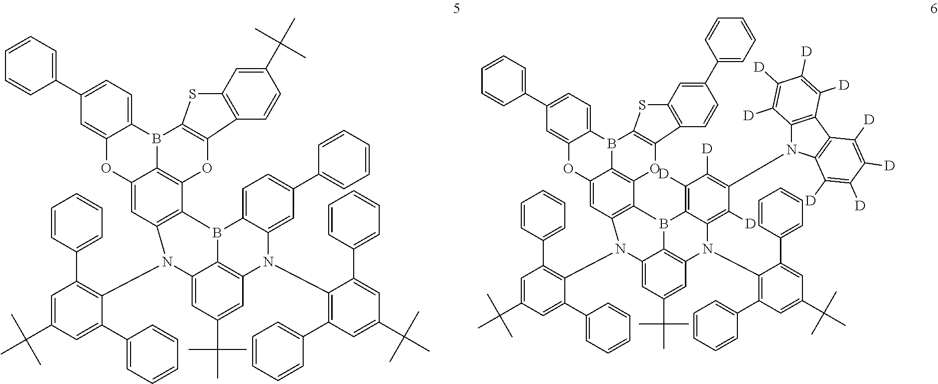 [SMILES: CC(C)(C)c1cc(-c2ccccc2)c(N2c3cc(-c4ccccc4)ccc3B3c4c2cc(C(C)(C)C)cc4N(c2c(-c4ccccc4)cc(C(C)(C)C)cc2-c2ccccc2)c2cc4c5c(c23)Oc2c(sc3cc(C(C)(C)C)ccc23)B5c2ccc(-c3ccccc3)cc2O4)c(-c2ccccc2)c1 ; [2H]c1cc(B2c3c(N(C)c4c(-c5ccccc5)cc(C(C)(C)C)cc4-c4ccccc4)cc(C(C)(C)C)cc3N(c3c(-c4ccccc4)cc(C(C)(C)C)cc3-c3ccccc3)c3cc4c5c(c32)Oc2c(sc3cc(-c6ccccc6)ccc23)B5c2ccc(-c3ccccc3)cc2O4)c([2H])c([2H])c1-n1c2c([2H])c([2H])c([2H])c([2H])c2c2c([2H])c([2H])c([2H])c([2H])c21] 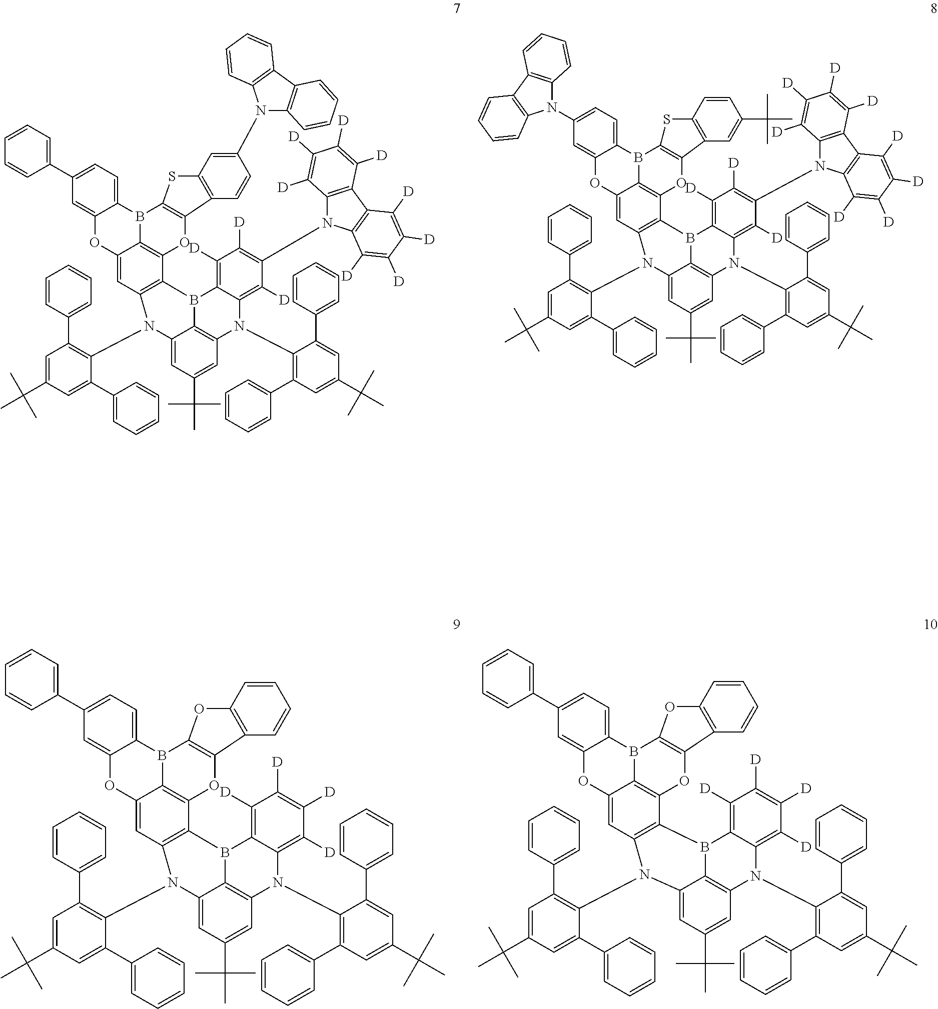 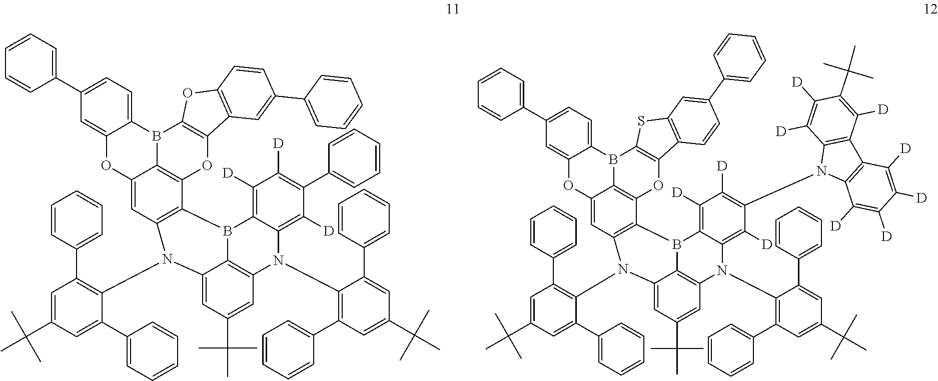 [SMILES: [2H]c1cc(B2c3c(N(C)c4c(-c5ccccc5)cc(C(C)(C)C)cc4-c4ccccc4)cc(C(C)(C)C)cc3N(c3c(-c4ccccc4)cc(C(C)(C)C)cc3-c3ccccc3)c3cc4c5c(c32)Oc2c(oc3ccc(-c6ccccc6)cc23)B5c2ccc(-c3ccccc3)cc2O4)c([2H])c([2H])c1-c1ccccc1 ; [2H]c1cc(B2c3c(N(C)c4c(-c5ccccc5)cc(C(C)(C)C)cc4-c4ccccc4)cc(C(C)(C)C)cc3N(c3c(-c4ccccc4)cc(C(C)(C)C)cc3-c3ccccc3)c3cc4c5c(c32)Oc2c(sc3cc(-c6ccccc6)ccc23)B5c2ccc(-c3ccccc3)cc2O4)c([2H])c([2H])c1-n1c2c([2H])c([2H])c([2H])c([2H])c2c2c([2H])c(C(C)(C)C)c([2H])c([2H])c21] 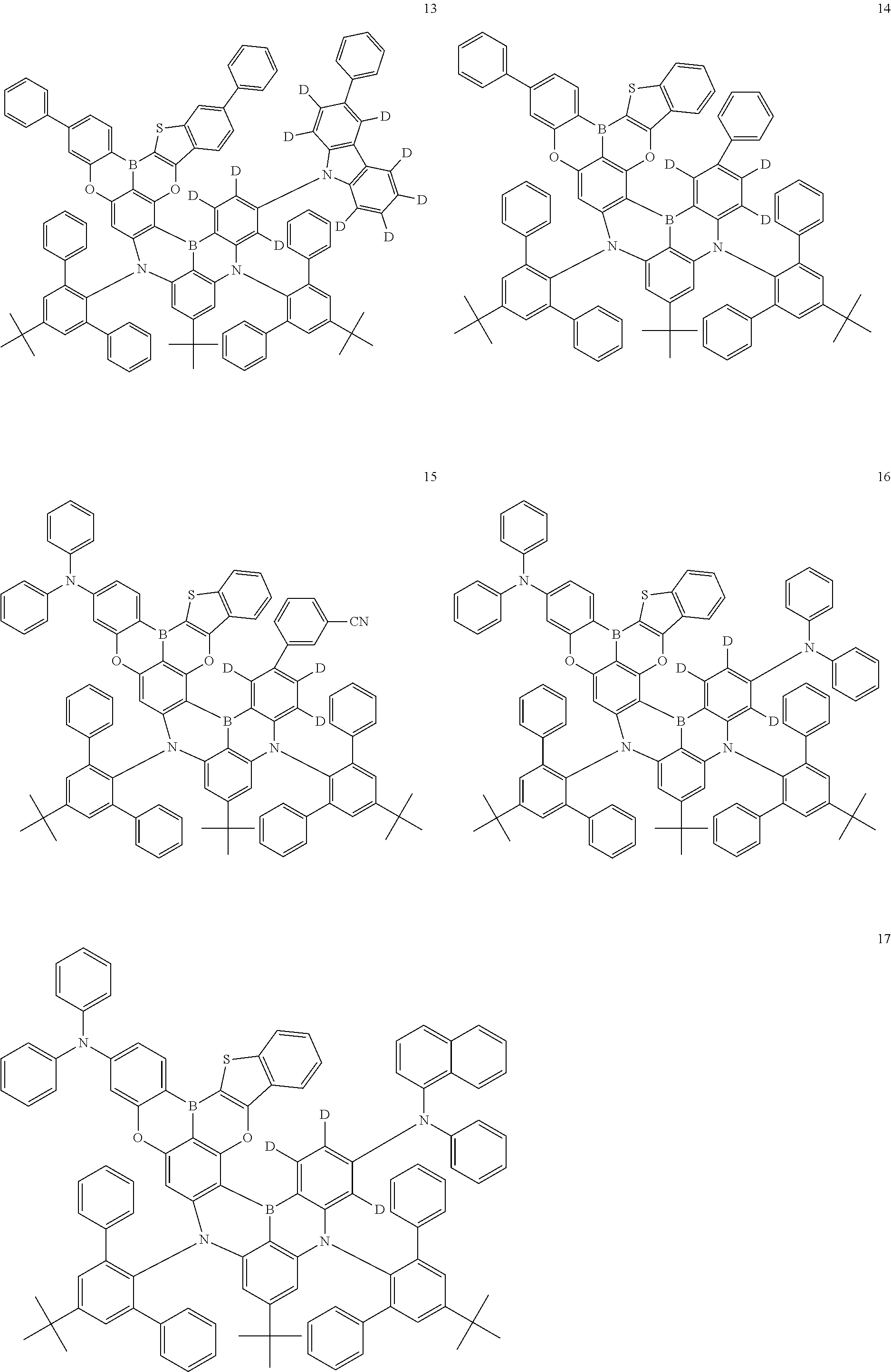 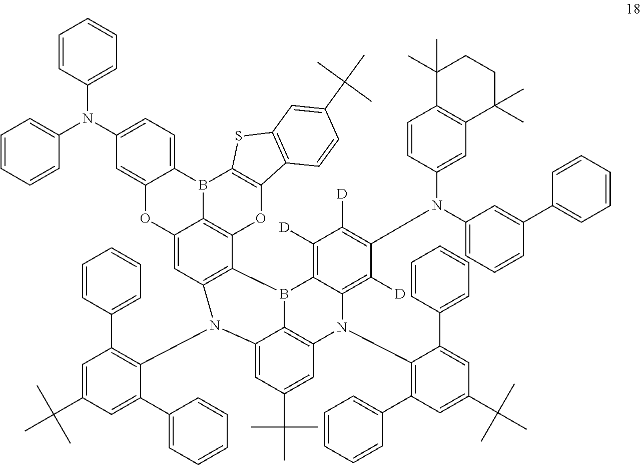 [SMILES: [2H]c1cc(B2c3c(N(C)c4c(-c5ccccc5)cc(C(C)(C)C)cc4-c4ccccc4)cc(C(C)(C)C)cc3N(c3c(-c4ccccc4)cc(C(C)(C)C)cc3-c3ccccc3)c3cc4c5c(c32)Oc2c(sc3cc(C(C)(C)C)ccc23)B5c2ccc(N(c3ccccc3)c3ccccc3)cc2O4)c([2H])c([2H])c1N(c1cccc(-c2ccccc2)c1)c1ccc2c(c1)C(C)(C)CCC2(C)C] 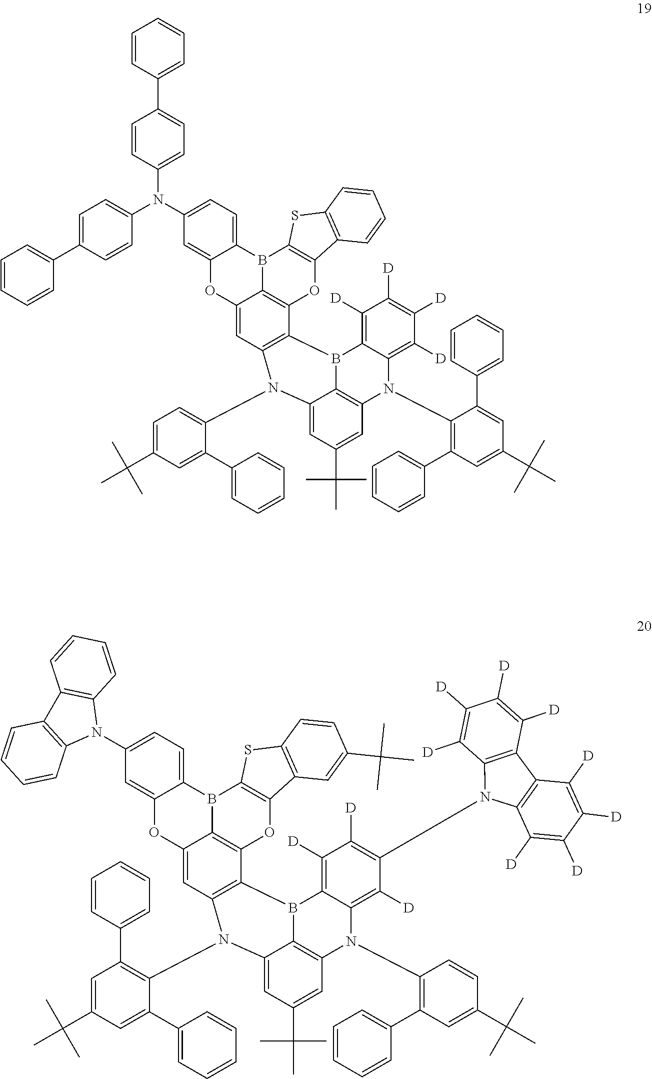 [SMILES: [2H]c1cc(B2c3c(N(C)c4c(-c5ccccc5)cc(C(C)(C)C)cc4-c4ccccc4)cc(C(C)(C)C)cc3N(c3ccc(C(C)(C)C)cc3-c3ccccc3)c3cc4c5c(c32)Oc2c(sc3ccccc23)B5c2ccc(N(c3ccc(-c5ccccc5)cc3)c3ccc(-c5ccccc5)cc3)cc2O4)c([2H])c([2H])c1[2H] ; [2H]c1cc(B2c3c(N(C)c4ccc(C(C)(C)C)cc4-c4ccccc4)cc(C(C)(C)C)cc3N(c3c(-c4ccccc4)cc(C(C)(C)C)cc3-c3ccccc3)c3cc4c5c(c32)Oc2c(sc3ccc(C(C)(C)C)cc23)B5c2ccc(-n3c5ccccc5c5ccccc53)cc2O4)c([2H])c([2H])c1-n1c2c([2H])c([2H])c([2H])c([2H])c2c2c([2H])c([2H])c([2H])c([2H])c21] 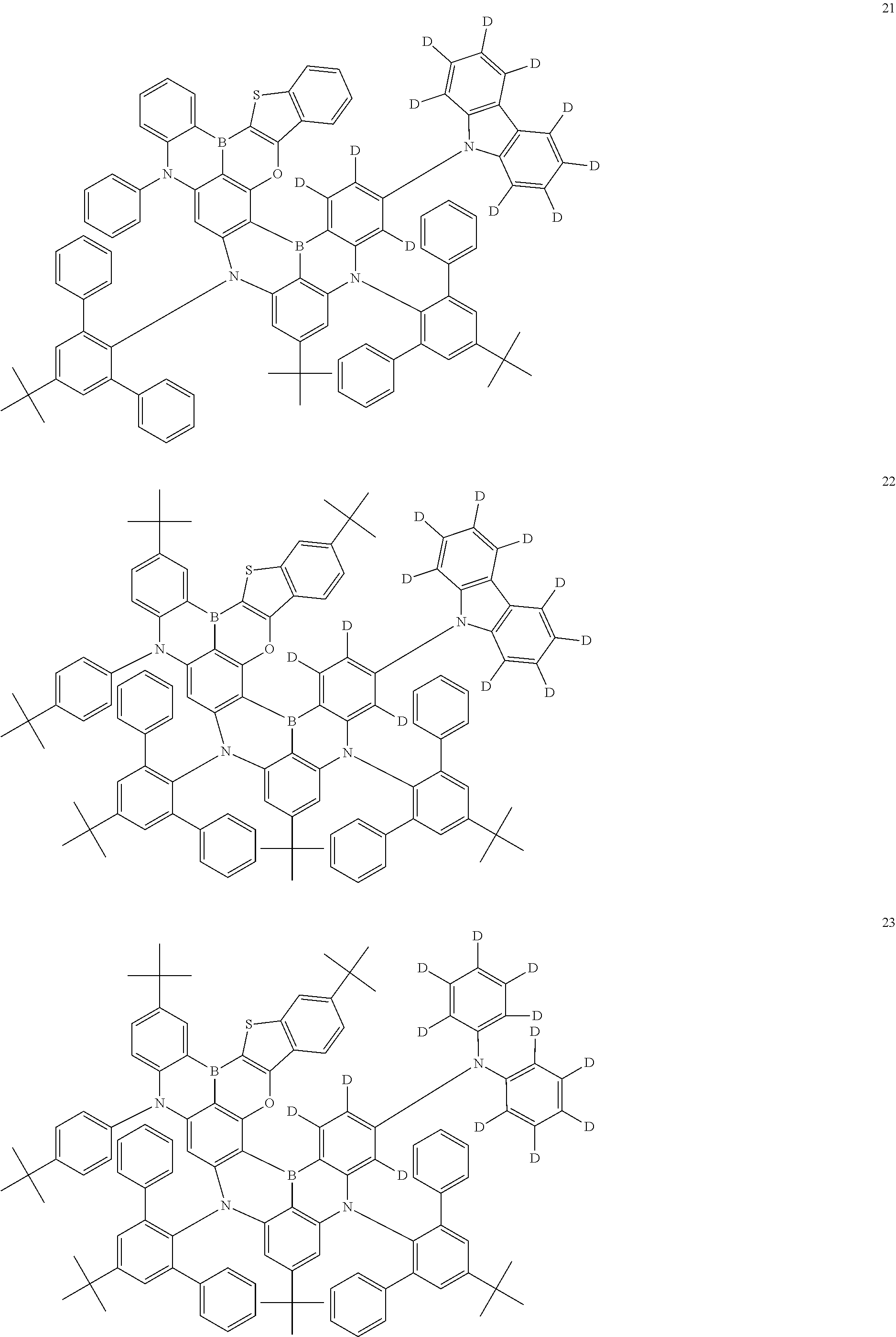 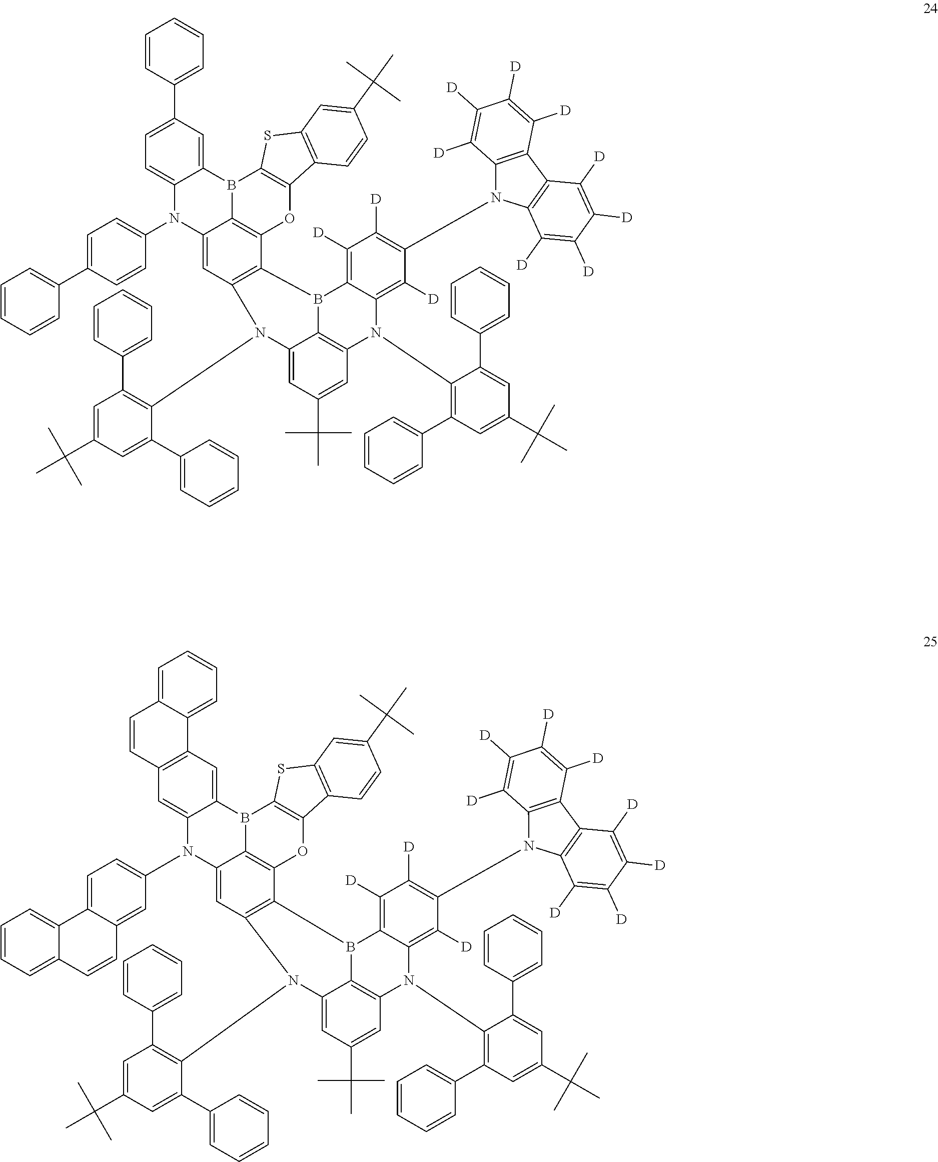 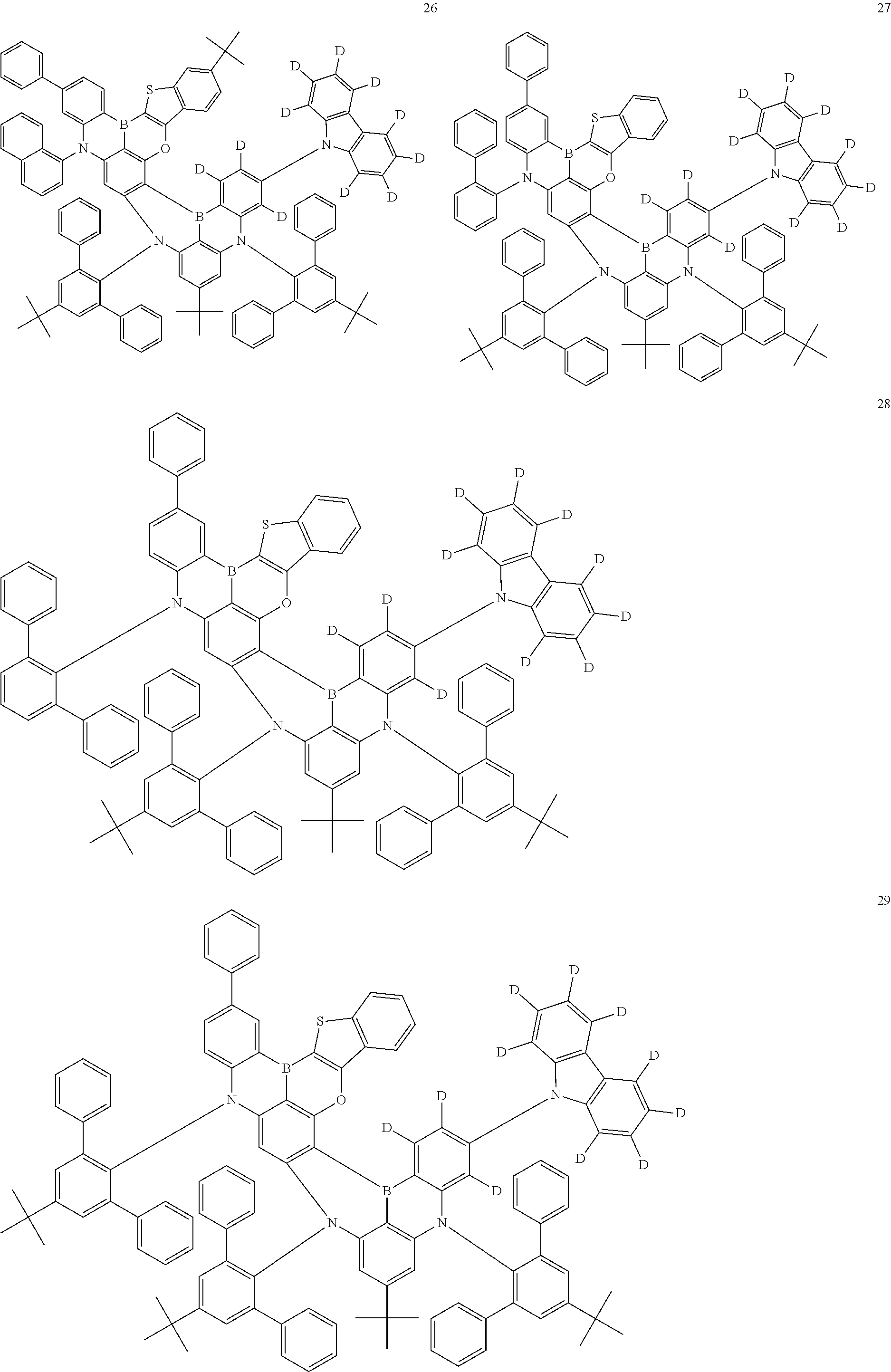 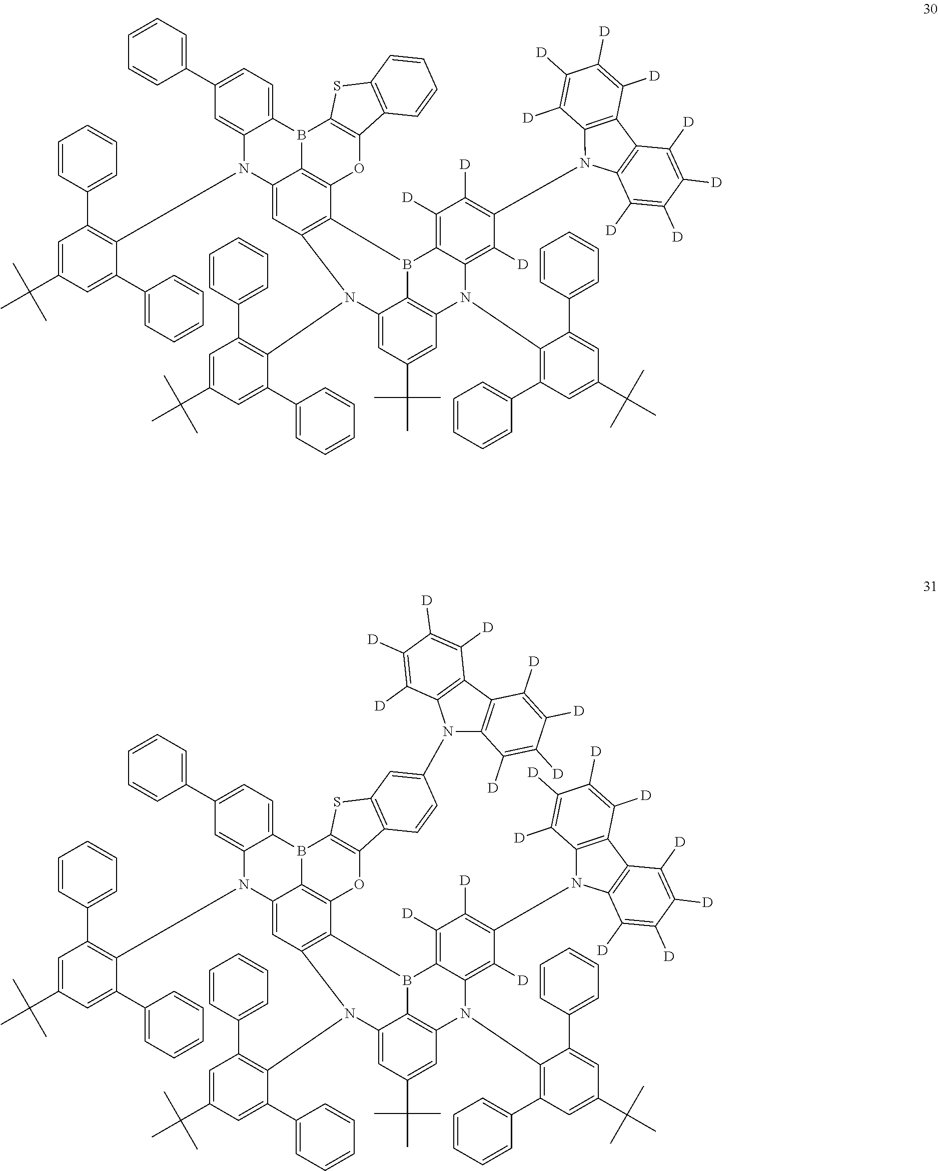 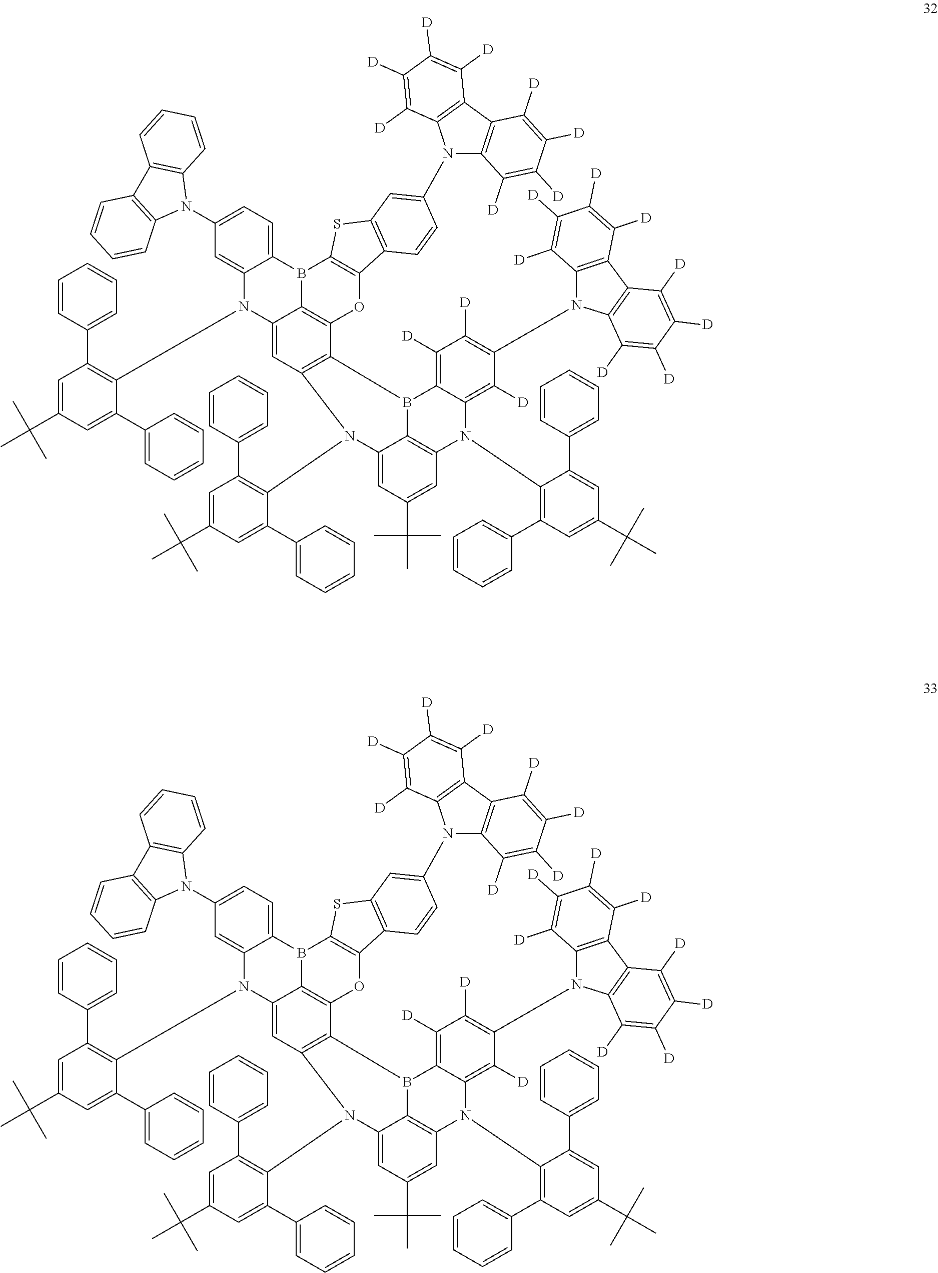 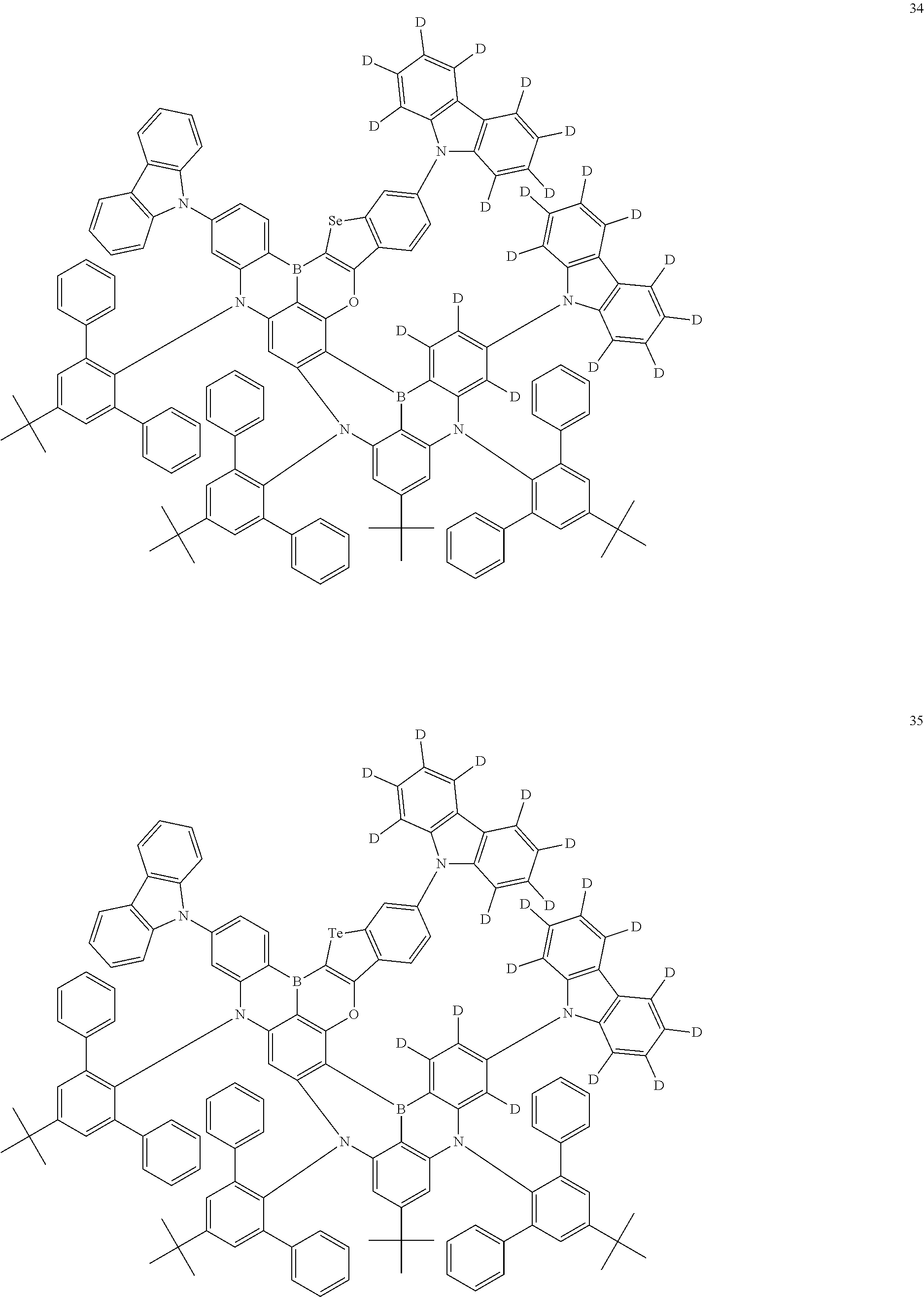 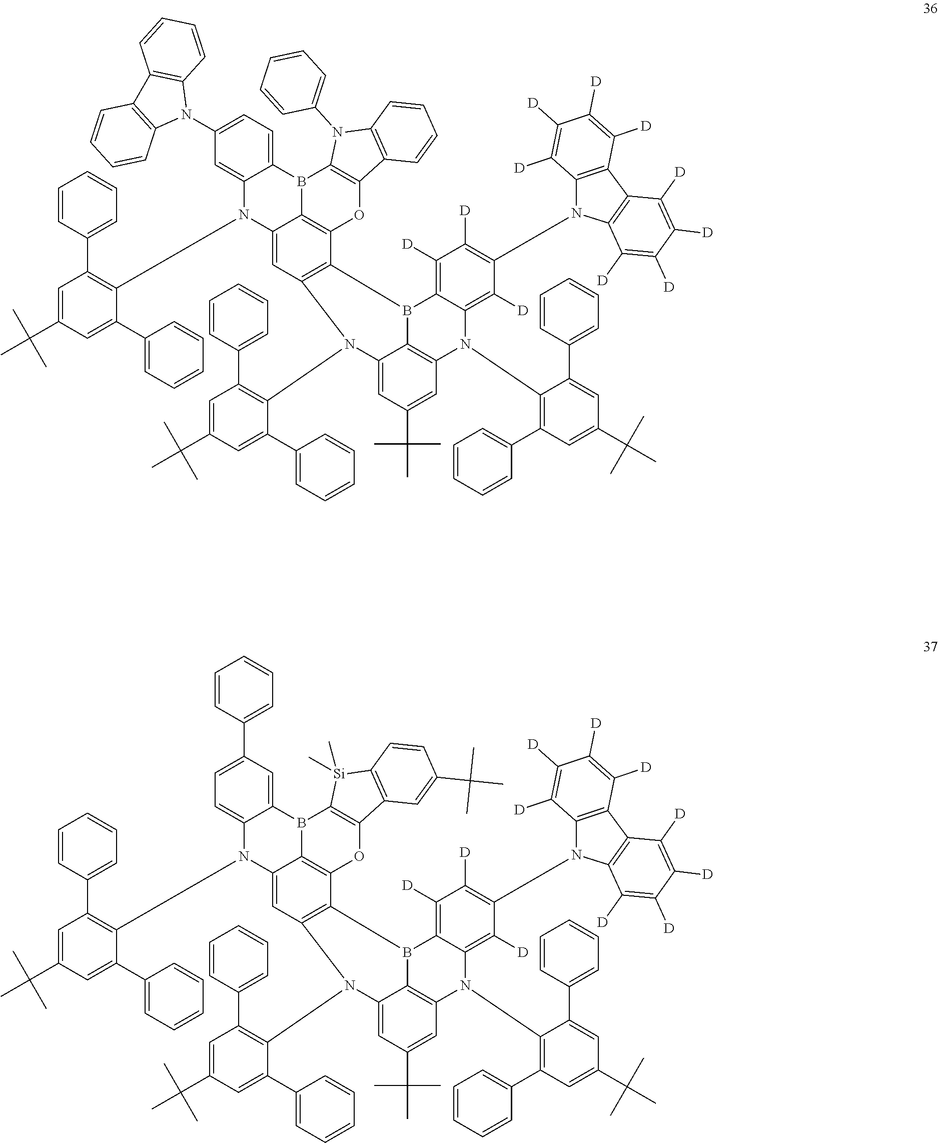 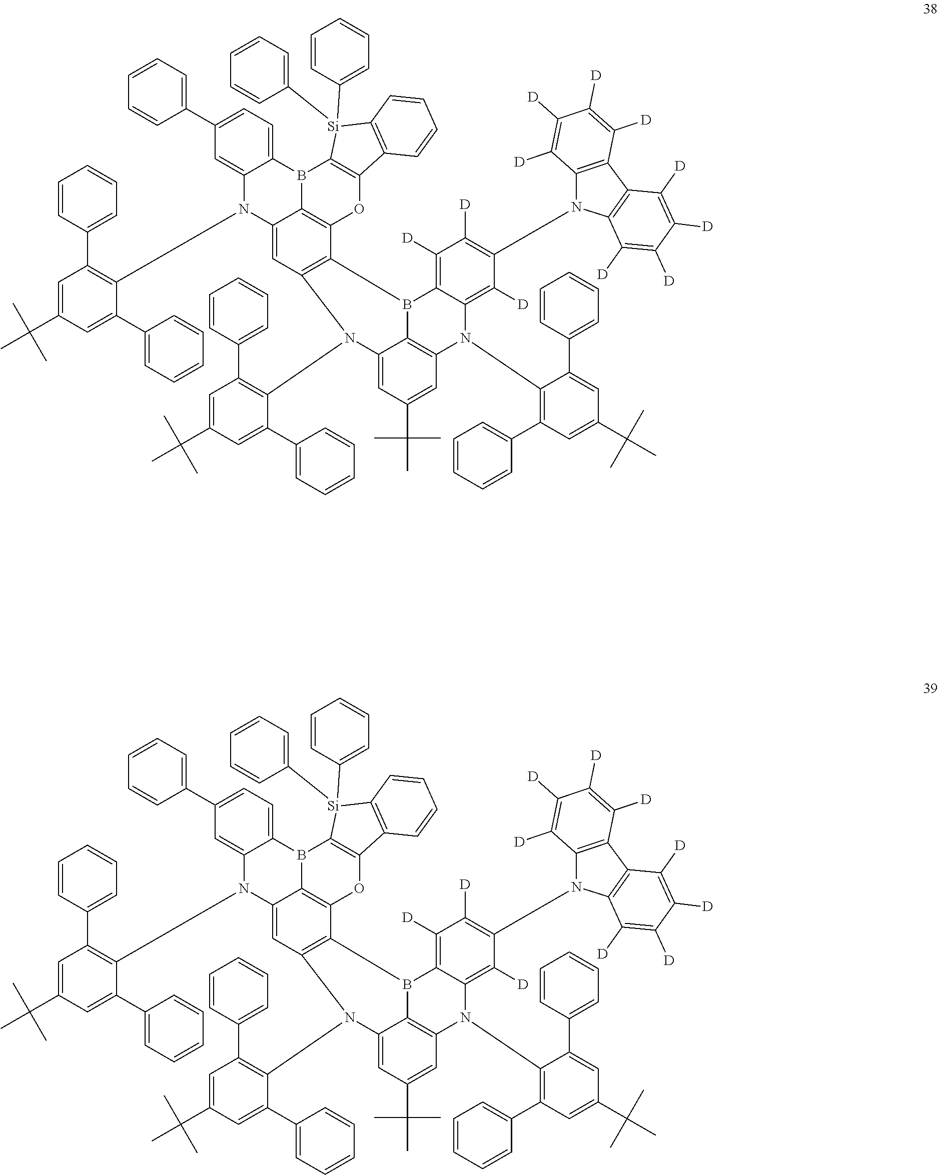 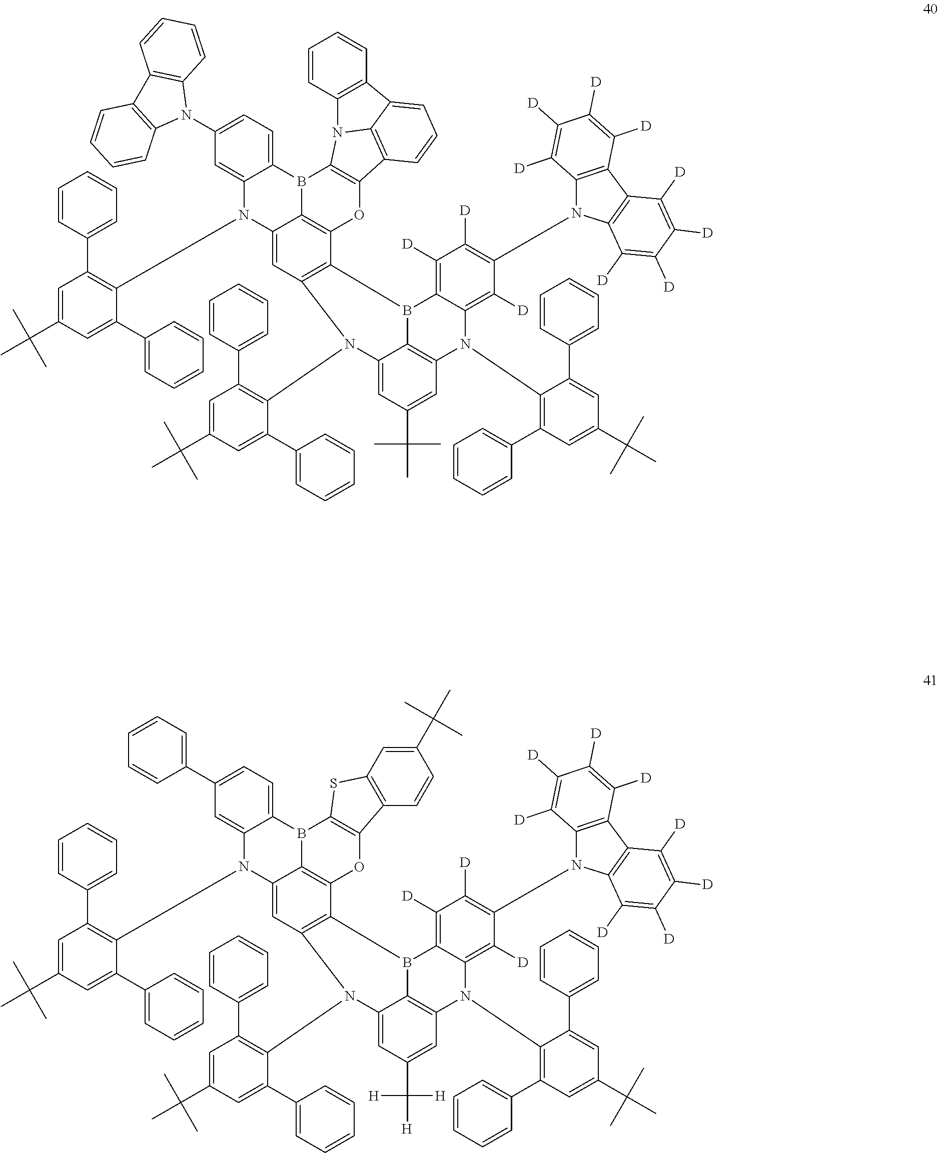 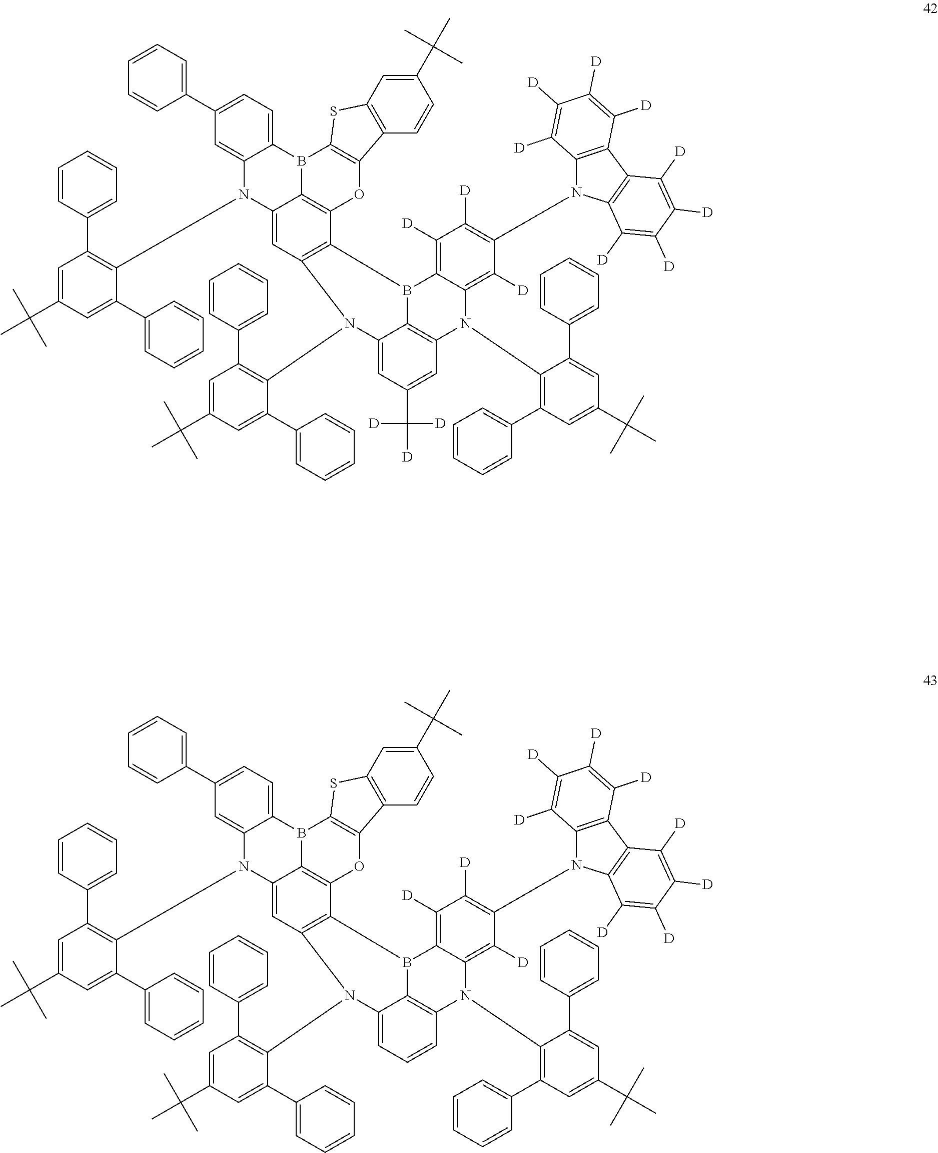 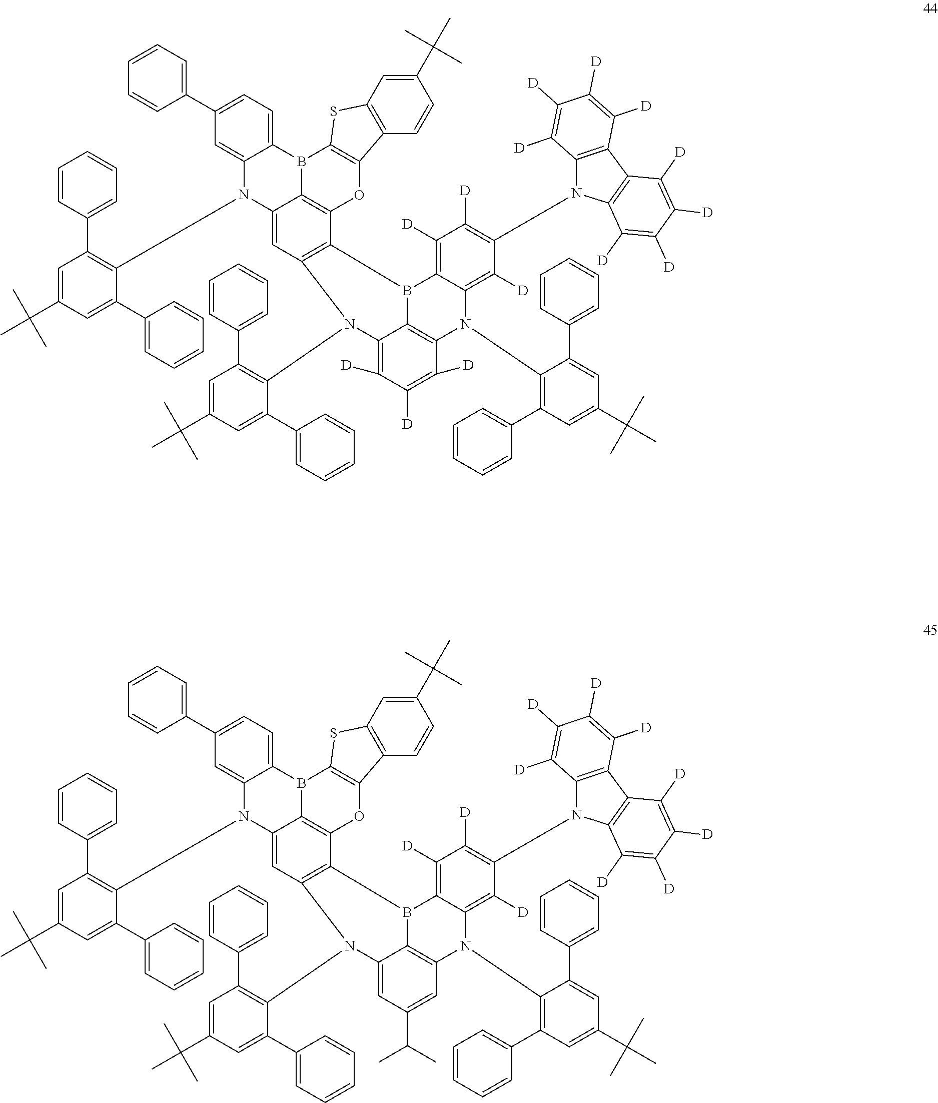 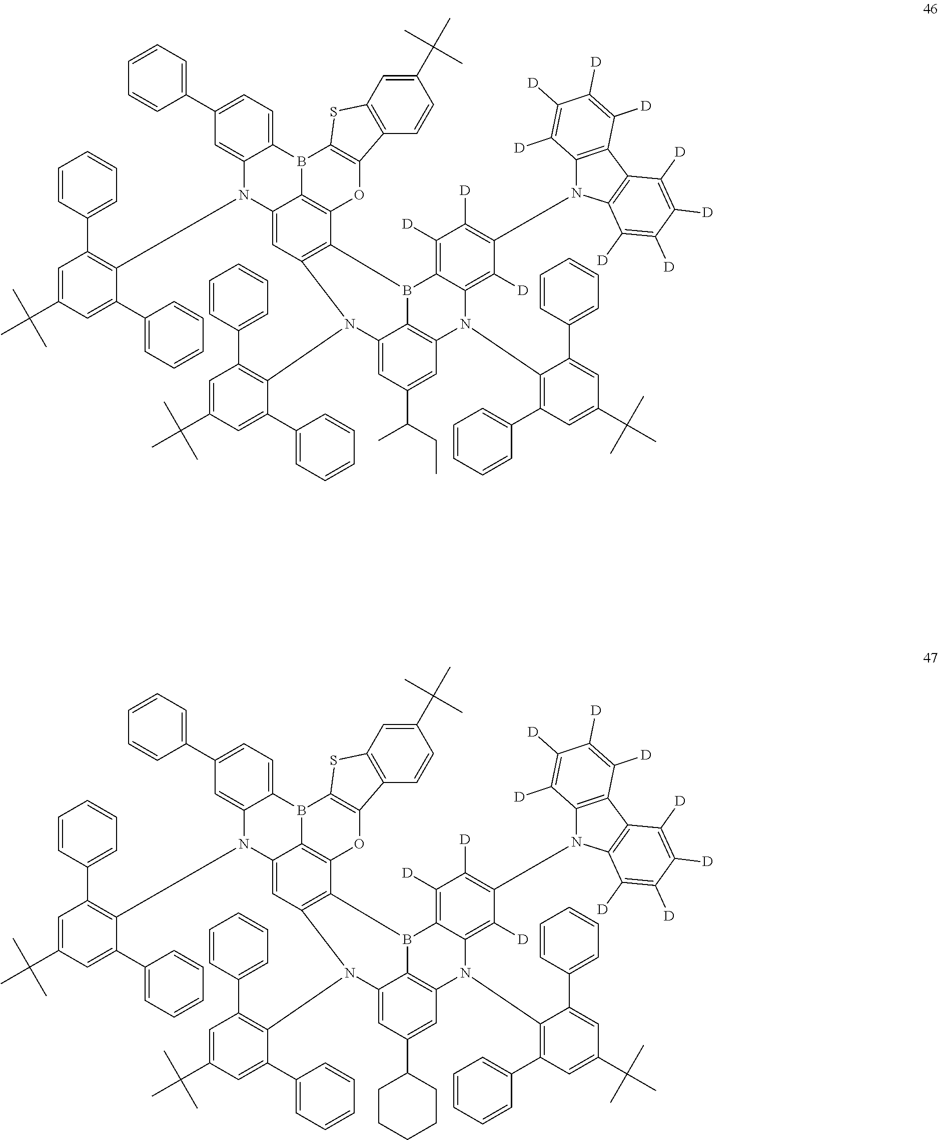 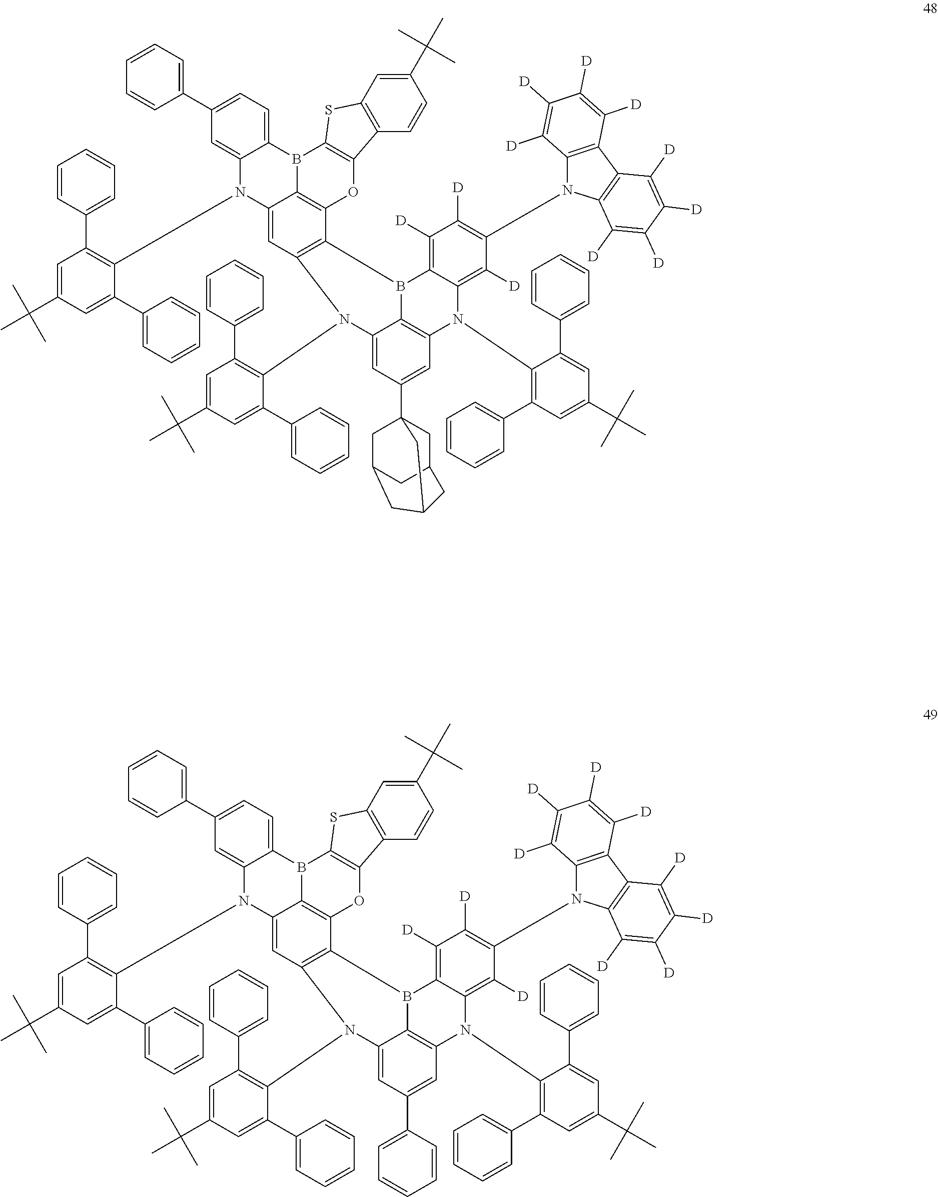 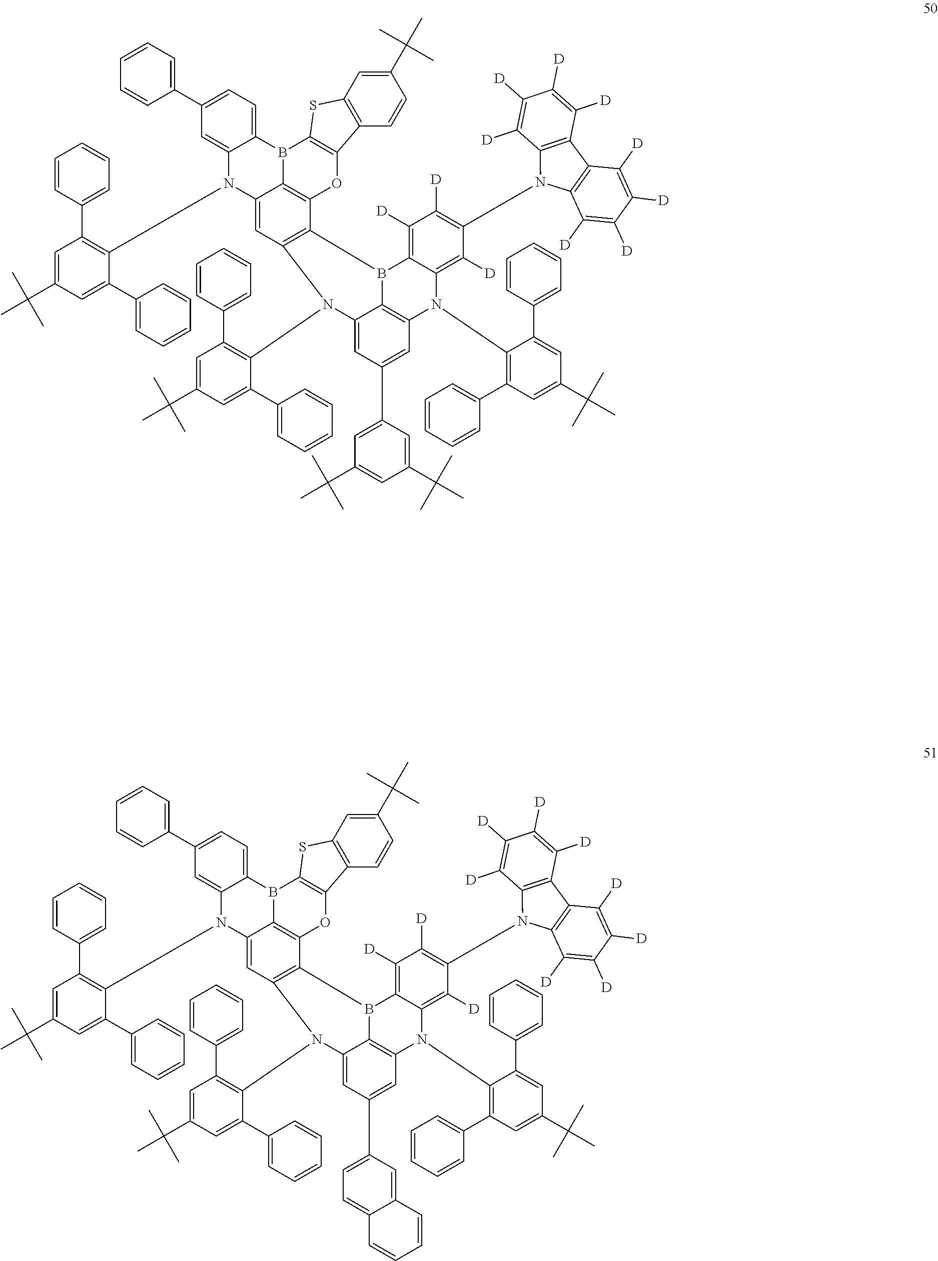 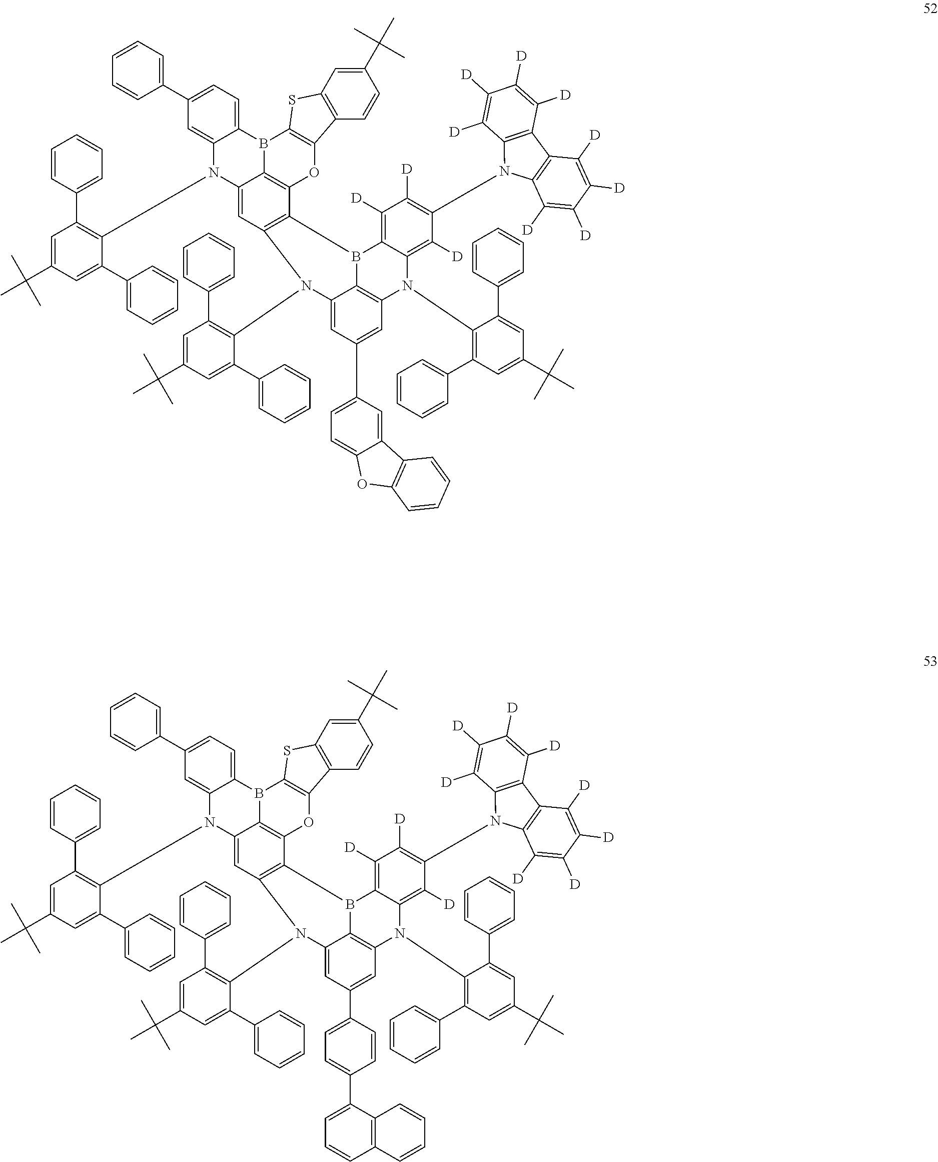 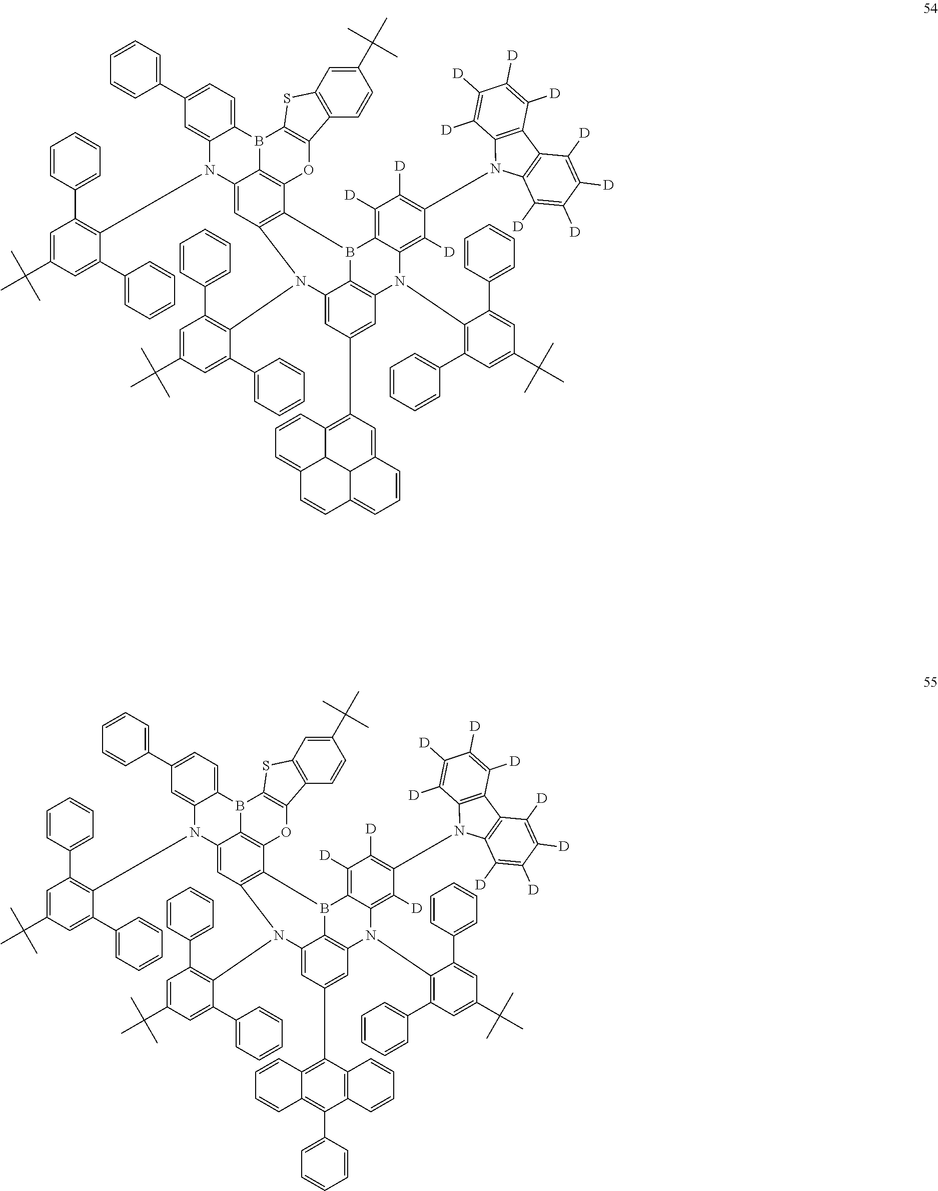 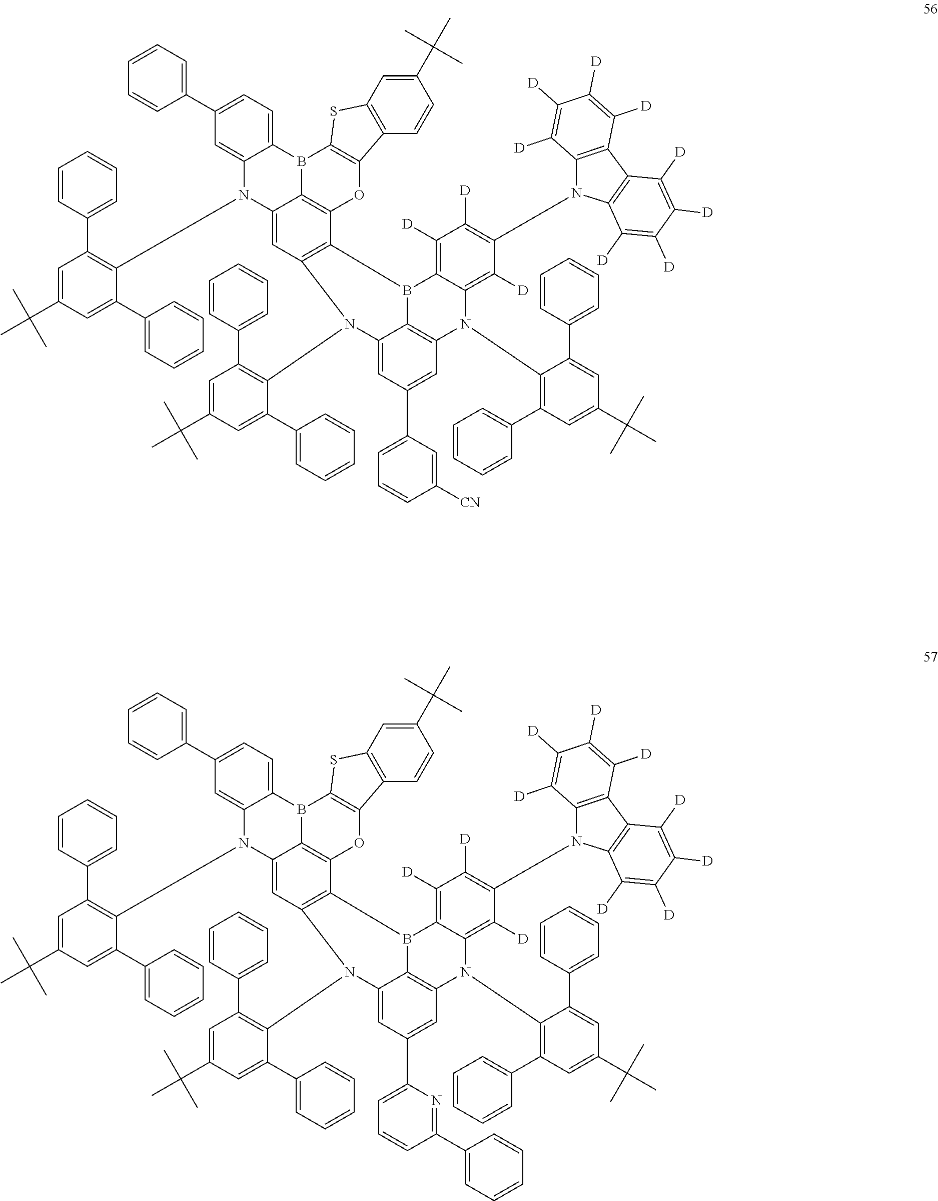 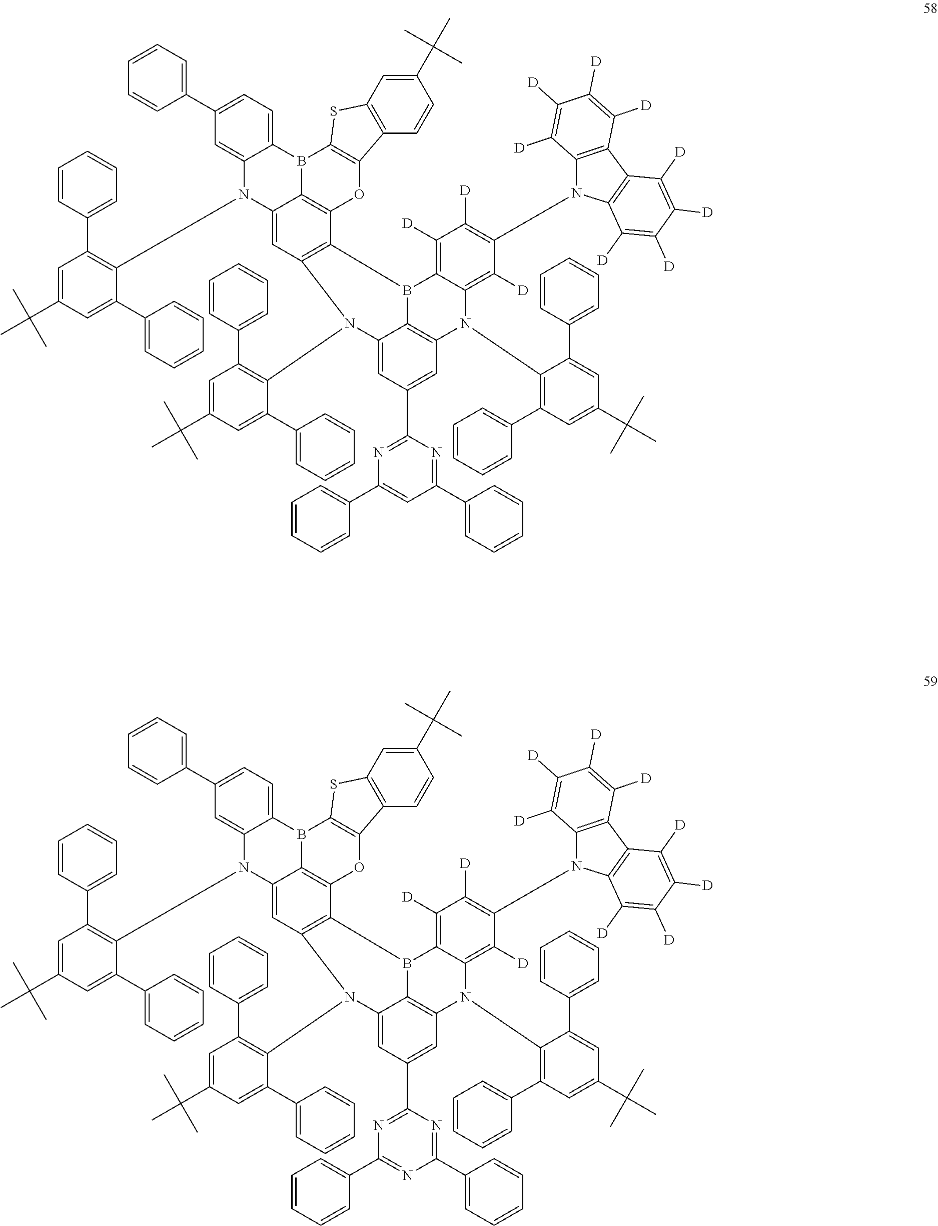 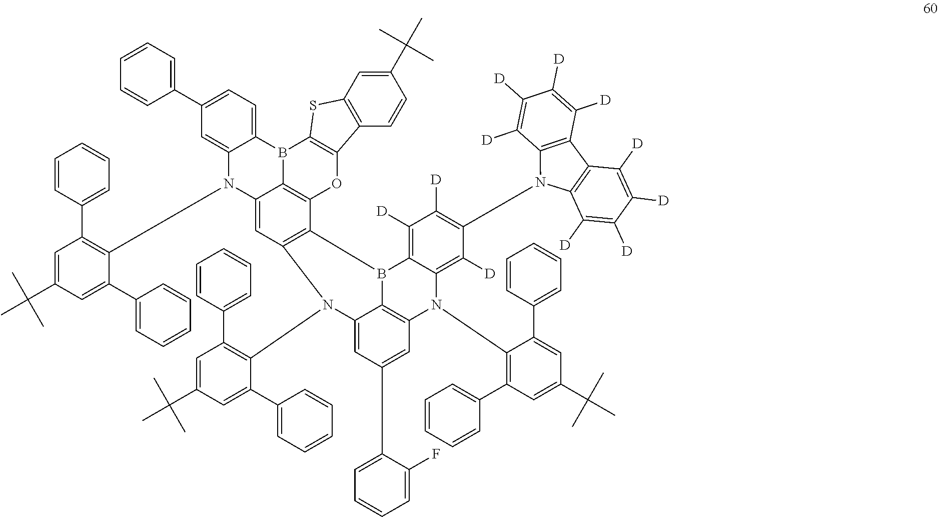 [SMILES: [2H]c1cc(B2c3c(N(C)c4c(-c5ccccc5)cc(C(C)(C)C)cc4-c4ccccc4)cc(-c4ccccc4F)cc3N(c3c(-c4ccccc4)cc(C(C)(C)C)cc3-c3ccccc3)c3cc4c5c(c32)Oc2c(sc3cc(C(C)(C)C)ccc23)B5c2ccc(-c3ccccc3)cc2N4c2c(-c3ccccc3)cc(C(C)(C)C)cc2-c2ccccc2)c([2H])c([2H])c1-n1c2c([2H])c([2H])c([2H])c([2H])c2c2c([2H])c([2H])c([2H])c([2H])c21] 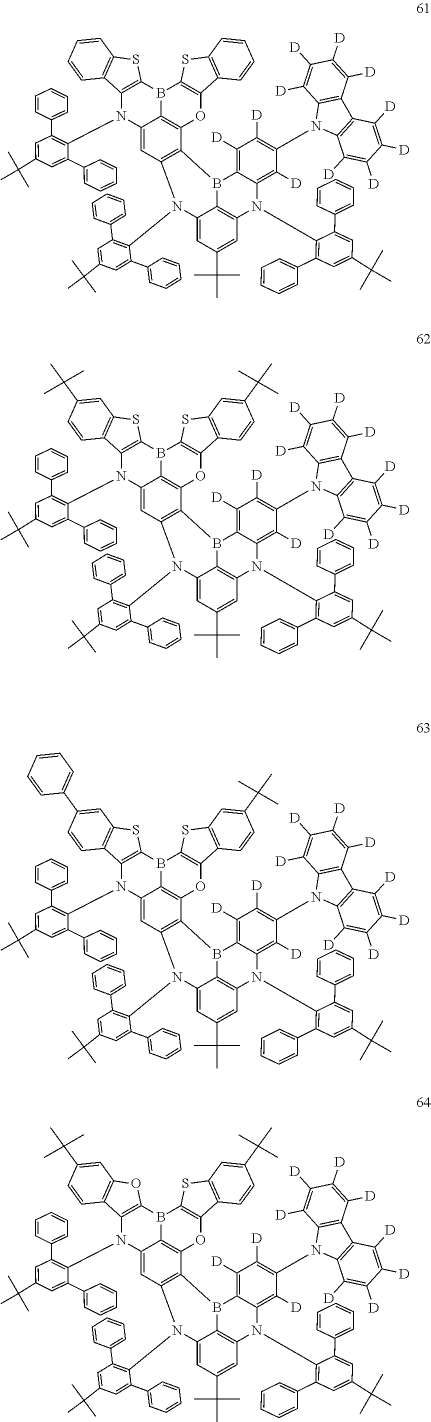 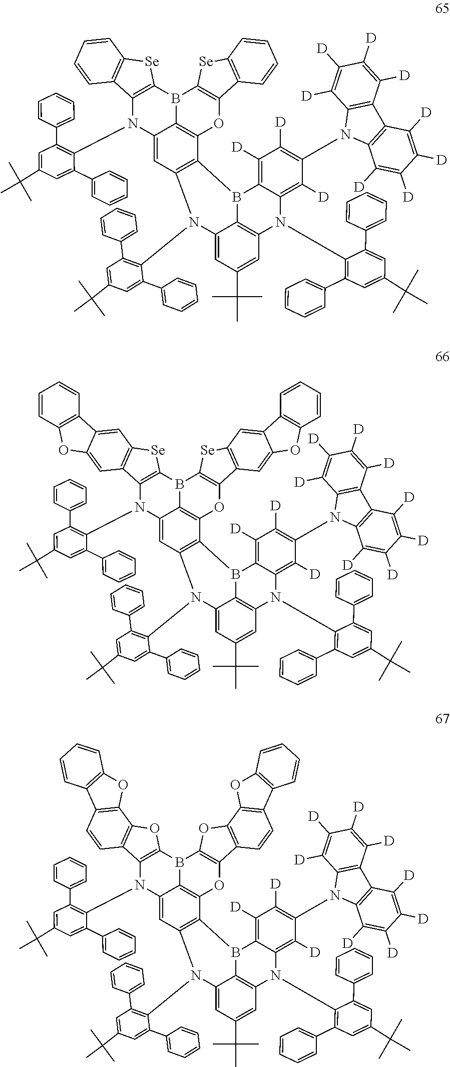 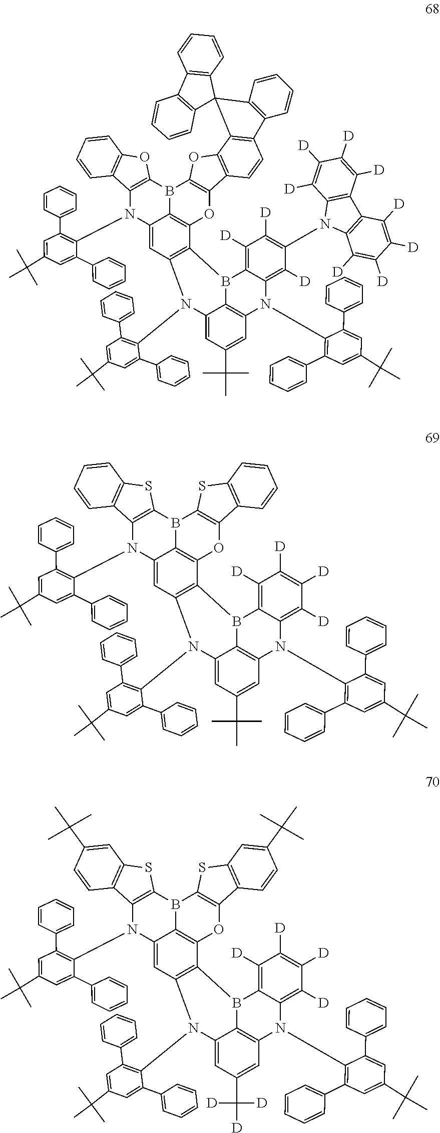 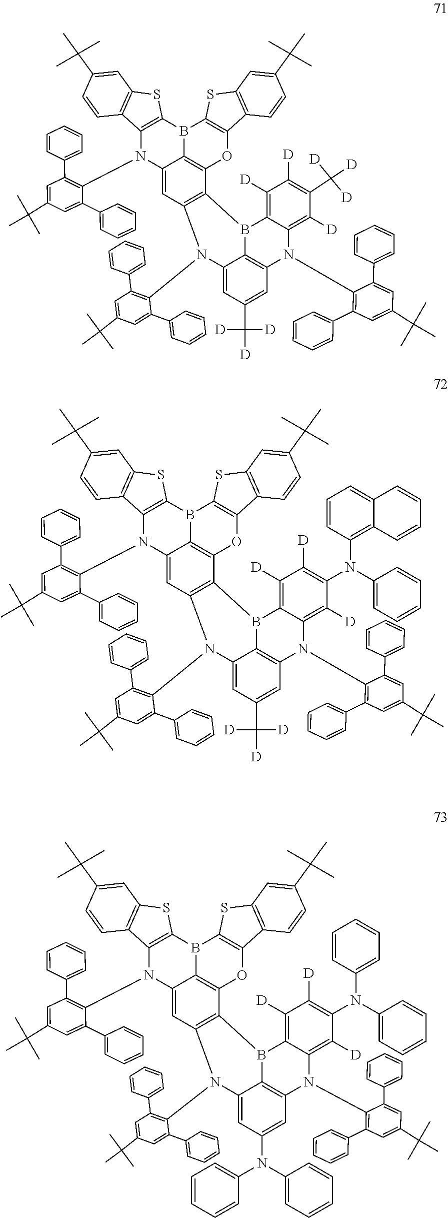 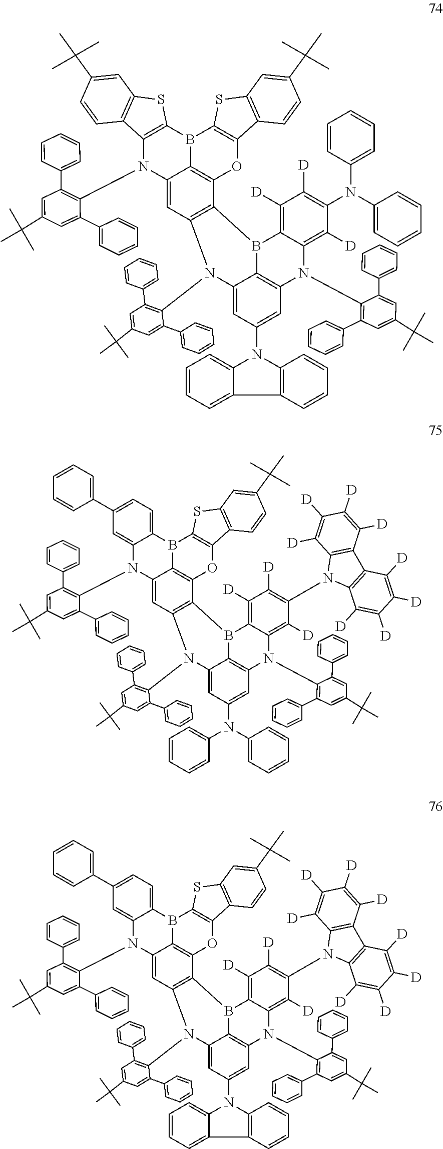 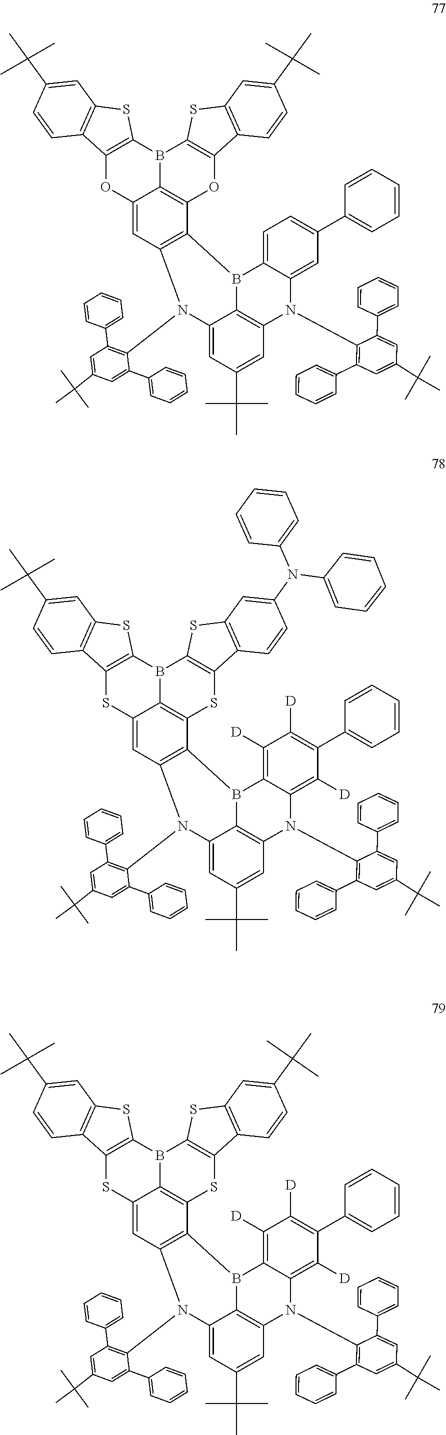 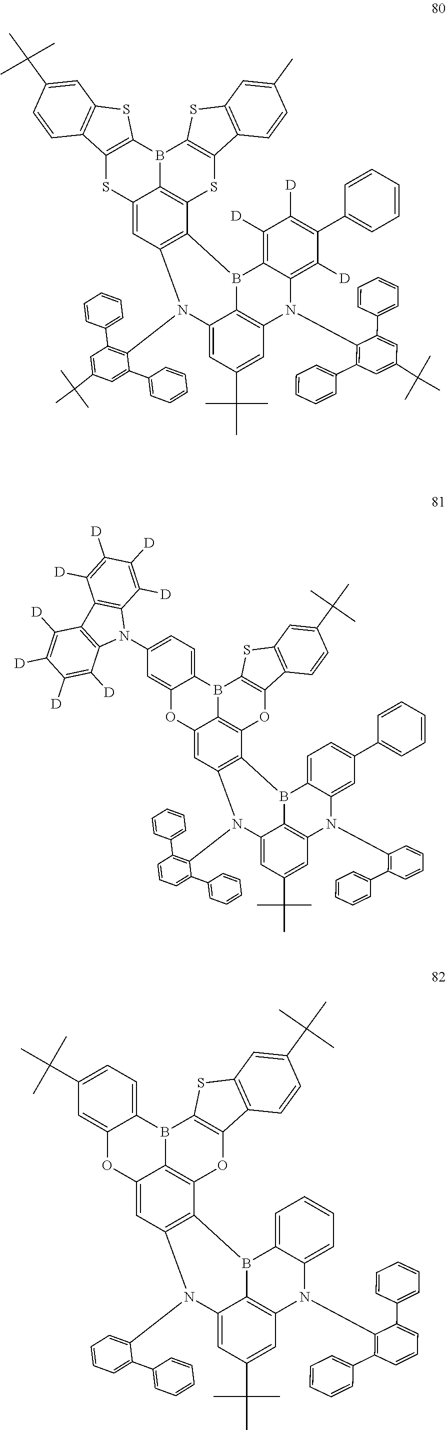 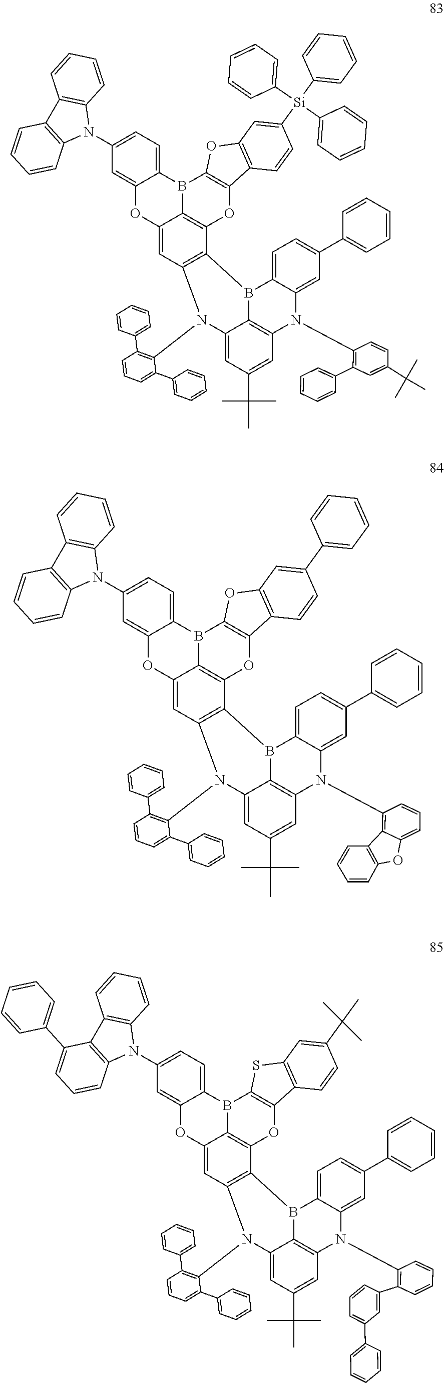 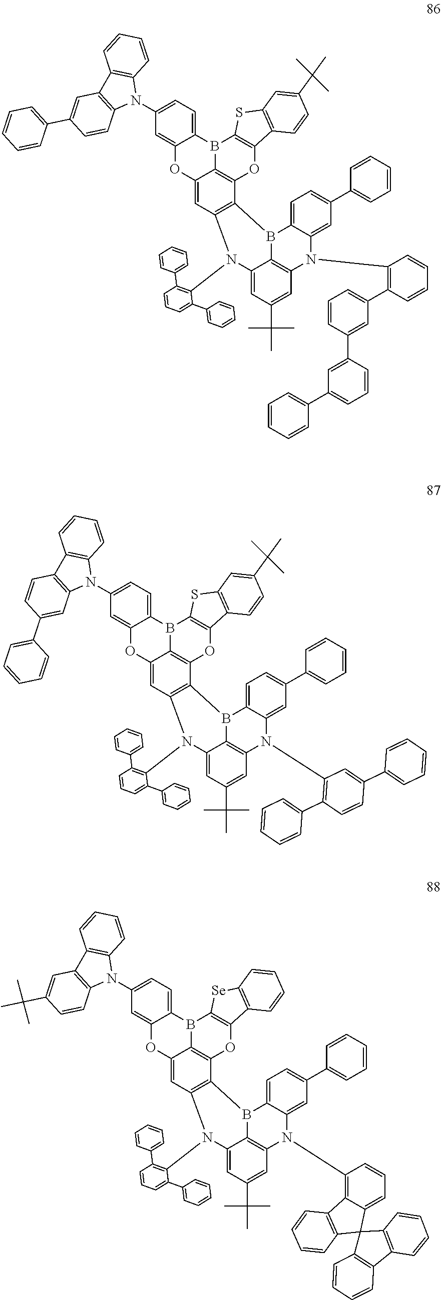 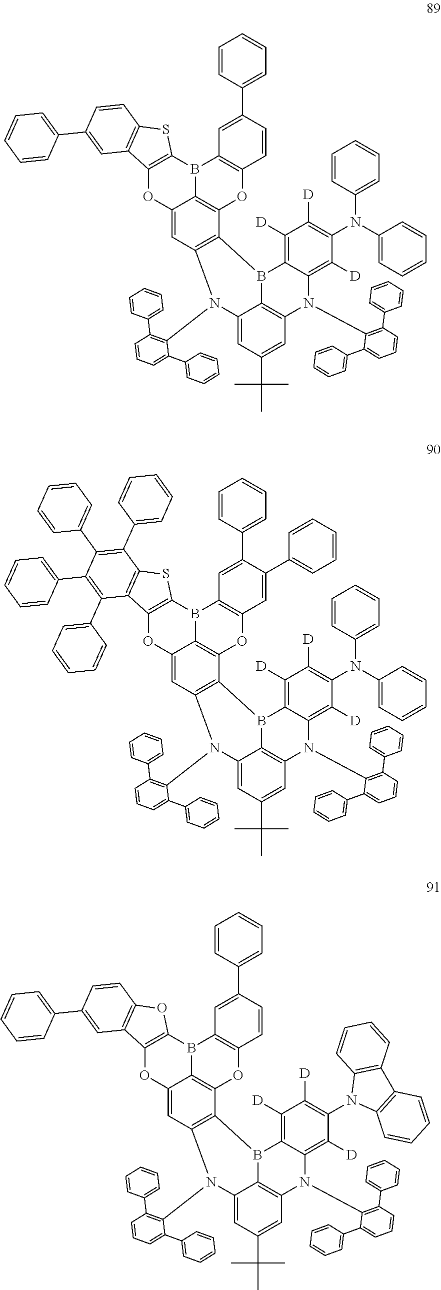 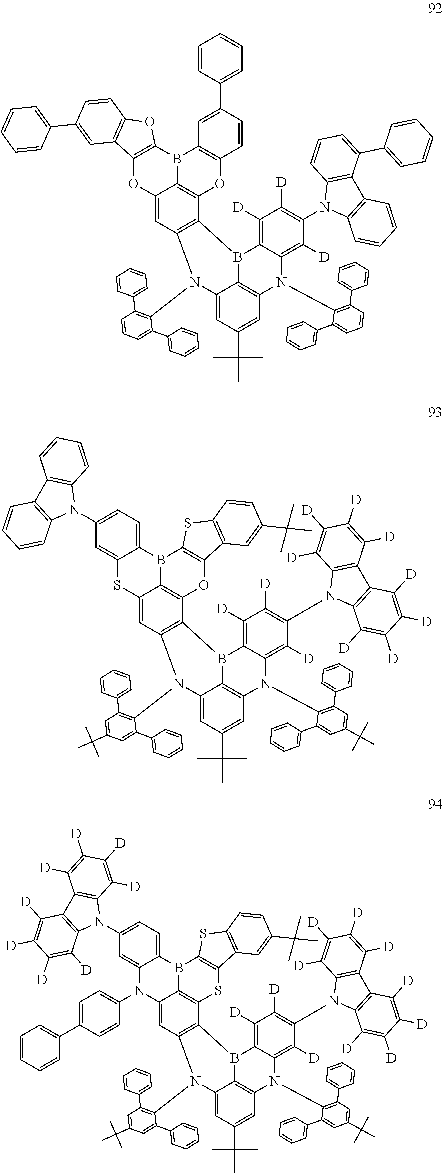 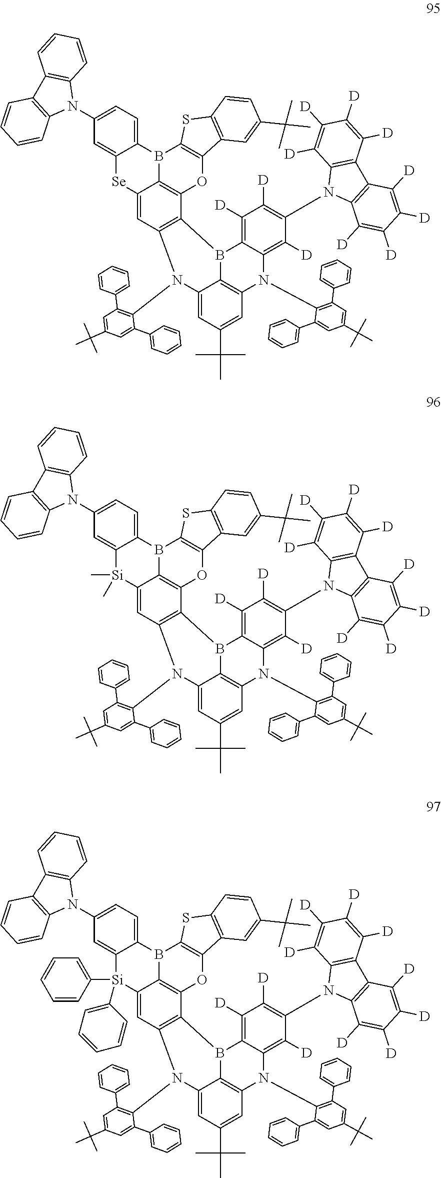 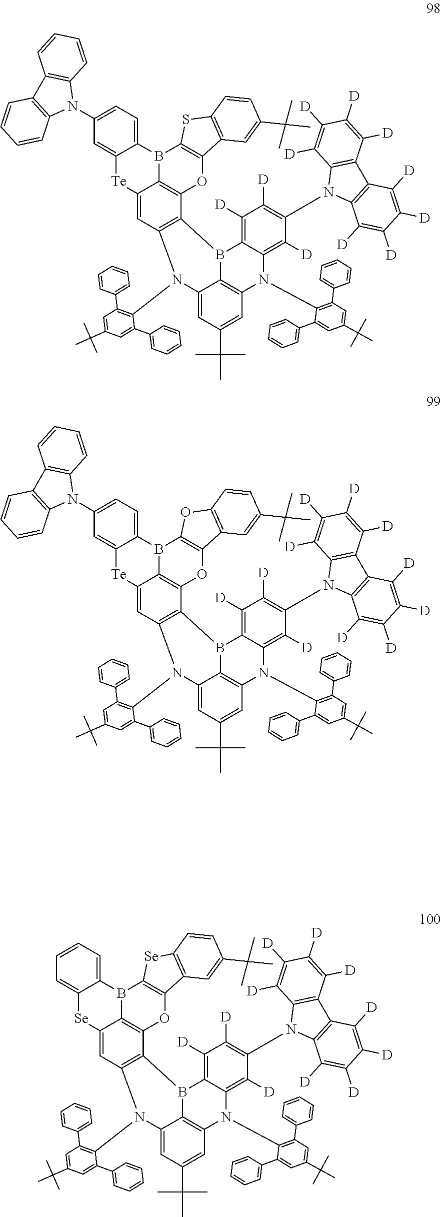
wherein in Compound Group 1,
D represents a deuterium atom.

19. An electronic device comprising a display device, the display device comprising:
a circuit layer disposed on a base layer; and
a display element layer disposed on the circuit layer, wherein
the display element layer includes a light-emitting element, and
the light-emitting element includes:
a first electrode;
a second electrode disposed on the first electrode; and
an emission layer disposed between the first electrode and the second electrode, and
the emission layer includes a fused polycyclic compound represented by Formula 1: 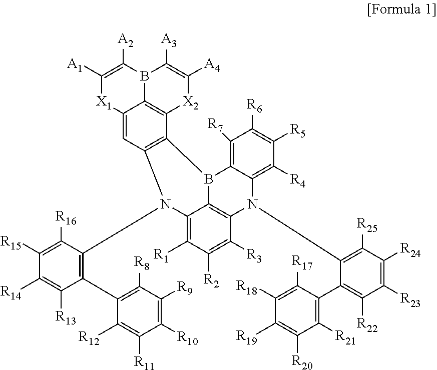
wherein in Formula 1,
X₁ and X₂ are each independently O, S, Se, Te, N(R₂₆), or Si(R₂₇)(R₂₈),
R₁ to R₂₈ are each independently a hydrogen atom, a deuterium atom, a halogen atom, a cyano group, a nitro group, a substituted or unsubstituted silyl group, a substituted or unsubstituted oxy group, a substituted or unsubstituted amine group, a substituted or unsubstituted alkyl group having 1 to 60 carbons, a substituted or unsubstituted cycloalkyl group having 3 to 60 ring-forming carbons, a substituted or unsubstituted alkenyl group having 2 to 60 carbons, a substituted or unsubstituted aryl group having 6 to 60 ring-forming carbons, or a substituted or unsubstituted heteroaryl group having 2 to 60 ring-forming carbons, or bonded to an adjacent group to form a ring,
at least one R₁₆ and R₂₅ is each independently a substituted or unsubstituted phenyl group,
at least one of a pair of A₁ and A₂ and a pair of A₃ and A₄ is each independently bonded to a first substituent represented by Formula S-1, and
the remainder of a pair of A₁ and A₂ and a pair of A₃ and A₄ that is not bonded to the first substituent represented by Formula S-1 is bonded to a second substituent represented by Formula S-2: 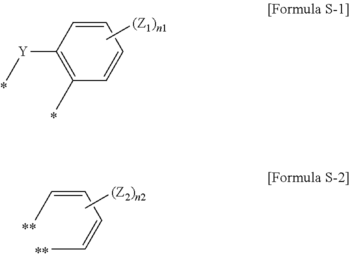
wherein in Formula S-1,
Y is O, S, Se, Te, N(Rₛ₁), or Si(Rₛ₂)(Rₛ₃), and
wherein in Formula S-1 and Formula S-2,
Rₛ₁ to Rₛ₃, Z₁, and Z₂ are each independently a hydrogen atom, a deuterium atom, a halogen atom, a cyano group, a nitro group, a substituted or unsubstituted silyl group, a substituted or unsubstituted oxy group, a substituted or unsubstituted amine group, a substituted or unsubstituted alkyl group having 1 to 60 carbons, a substituted or unsubstituted cycloalkyl group having 3 to 60 ring-forming carbons, a substituted or unsubstituted alkenyl group having 2 to 60 carbons, a substituted or unsubstituted aryl group having 6 to 60 ring-forming carbons, or a substituted or unsubstituted heteroaryl group having 2 to 60 ring-forming carbons, or bonded to an adjacent group to form a ring,
n1 and n2 are each independently an integer from 0 to 4, and
*- and **- each represents a bond to the pair of A₁ and A₂ or the pair of A₃ and A₄ in Formula 1.

20. The electronic device of claim 19, wherein the electronic device is a television, a monitor, a game console, a personal computer, a personal digital assistant, a laptop computer, a display device for vehicles, a mobile electronic device, or a camera.
